(19) United States
(12) Patent Application Publication
(10) Pub. No.: US 2024/0315134 A1
(43) Pub. Date: Sep. 19, 2024

(54) LIGHT EMITTING DEVICE AND FUSED POLYCYCLIC COMPOUND FOR THE SAME

(71) Applicant: Samsung Display Co., Ltd., Yongin-si (KR)

(72) Inventors: MUN-KI SIM, Yongin-si (KR); SUN YOUNG PAK, Yongin-si (KR); JUNHA PARK, Yongin-si (KR); Kyoung SUNWOO, Yongin-si (KR); CHANSEOK OH, Yongin-si (KR); Giwoong HAN, Yongin-si (KR)

(21) Appl. No.: 18/504,085

(22) Filed: Nov. 7, 2023

(30) Foreign Application Priority Data
Feb. 20, 2023 (KR) 10-2023-0022066

(51) Int. Cl. H10K 85/60; C07F 5/02; C09K 11/06

(52) U.S. Cl. CPC H10K 85/658; C07F 5/027; C09K 11/06; C07B 2200/05; C09K 2211/1007; C09K 2211/1018; H10K 50/12; H10K 2101/20; H10K 2101/90

(57) ABSTRACT

A light emitting device that includes a first electrode, a second electrode provided on the first electrode, and an emission layer provided between the first electrode and the second electrode is provided. The emission layer includes a fused polycyclic compound, and may also include at least one of a second compound, a third compound, or a fourth compound. The fused polycyclic compound includes three aromatic rings fused by boron and nitrogen atoms and also includes substituents with steric properties that may reduce or prevent the negative impact caused by intermolecular interactions and improve the emission efficiency and service life of the light emitting device.

### CROSS-REFERENCE TO RELATED APPLICATIONS

This patent application claims priority to and the benefit of Korean Patent Application No. 10-2023-0022066, filed on Feb. 20, 2023, the entire content of which is hereby incorporated by reference.

### BACKGROUND

### 1. Field

The present disclosure herein relates to a light emitting device and a fused polycyclic compound utilized therein.

### 2. Description of the Related Art

Lately, organic electroluminescence display devices and/or the like have been actively developed as image display devices. The organic electroluminescence display devices and/or the like are display devices that are so-called “self-luminescent” light emitting devices in which holes and electrons injected from a first electrode and a second electrode recombine in an emission layer. Subsequently, a luminescent material located in the emission layer emits light to accomplish display (e.g., of an image).

Implementation of the light emitting devices in a display apparatus requires (or there is a desire for) greater light efficiency and service life. Therefore, the need exists for the development of materials for light emitting devices which are capable of stably attaining such characteristics (or desires).

For example, in an effort to implement or obtain a highly efficient light emitting device, technologies pertaining to phosphorescence emission utilizing triplet state energy or delayed fluorescence utilizing triplet-triplet annihilation (TTA) in which singlet excitons are generated through the collision of triplet excitons are being developed. Also, the development of materials for thermally activated delayed fluorescence (TADF) materials utilizing a delayed fluorescence phenomenon are under development.

### SUMMARY

One or more aspects of embodiments of the present disclosure are directed toward a light emitting device having improved light emitting efficiency, and service life.

One or more aspects of embodiments of the present disclosure are directed toward a fused polycyclic compound as a material for a light emitting device, which improves light emitting efficiency and service life.

One or more embodiments of the present disclosure include a light emitting device including a first electrode, a second electrode provided on the first electrode, and an emission layer provided between the first electrode and the second electrode, wherein the emission layer includes a first compound represented by Formula 1, and at least one selected from among a second compound represented by Formula HT-1, a third compound represented by Formula ET-1, and/or a fourth compound represented by Formula D-1.

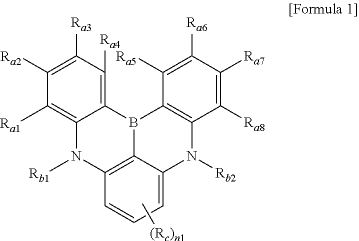

In Formula 1, Rₐ₁ to Rₐ₈ are each independently represented by Formula 2, a hydrogen atom, a deuterium atom, or a substituted or unsubstituted aryl group having 6 to 30 ring-forming carbon atoms, (in which) at least one of Rₐ₁ to Rₐ₈ is represented by Formula 2, n1 is an integer of 0 to 3, and R_{b1}, R_{b2}, and R_{c} may each independently be a hydrogen atom, a deuterium atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

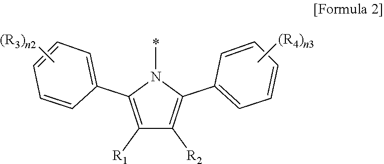

In Formula 2, R₁ and R₂ may each independently be a hydrogen atom, a deuterium atom, a cyano group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring, n2 and n3 may each independently be an integer of 0 to 5, and R₃ and R₄ may each independently be a hydrogen atom, a deuterium atom, a cyano group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms.

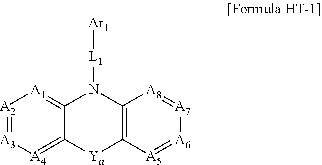

In Formula HT-1, A₁ to A₈ may each independently be N or CR₅₁, and L₁ is a direct linkage, a substituted or unsubstituted arylene group having 6 to 30 ring-forming carbon atoms, or a substituted or unsubstituted heteroarylene group having 2 to 30 ring-forming carbon atoms, Yₐ is a direct linkage, CR₅₂R₅₃, or SiR₅₄R₅₅, Ar₁ is a substituted or unsubstituted aryl group having 6 to 30 ring-forming carbon atoms, or a substituted or unsubstituted heteroaryl group having 2 to 30 ring-forming carbon atoms, and R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 ring-forming carbon atoms, a substituted or unsubstituted aryl group having 6 to 60 ring-forming carbon atoms, or a substituted or unsubstituted heteroaryl group having 2 to 60 ring-forming carbon atoms, and/or bonded to an adjacent group to form a ring.

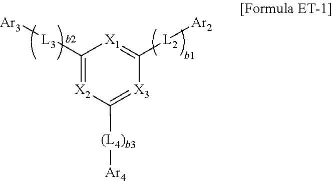

In Formula ET-1, X₁ to X₃ are each independently N or CR₅₆, (in which) at least one of X₁ to X₃ is N, R₅₆ are each independently a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, b1 to b3 may each independently be an integer of 0 to 10, Ar₂ to Ar₄ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and L2 to L4 may each independently be a direct linkage, a substituted or unsubstituted arylene group having 6 to 30 ring-forming carbon atoms, or a substituted or unsubstituted heteroarylene group having 2 to 30 ring-forming carbon atoms.

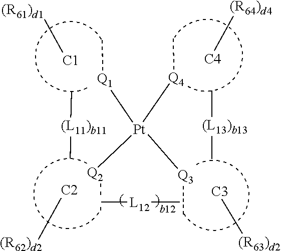

In Formula D-1, Q₁ to Q₄ may each independently be C or N, C1 to C4 may each independently be a substituted or unsubstituted hydrocarbon ring having 5 to 30 ring-forming carbon atoms, or a substituted or unsubstituted heterocycle having 2 to 30 ring-forming carbon atoms, L11 to L13 may each independently be a direct linkage,

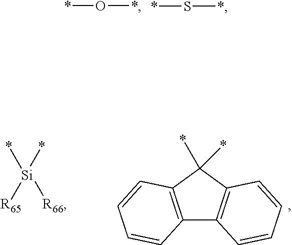

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms, b11 to b13 may each independently be 0 or 1, R₆₁ to R₆₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 ring-forming carbon atoms, a substituted or unsubstituted aryl group having 6 to 60 ring-forming carbon atoms, or a substituted or unsubstituted heteroaryl group having 2 to 60 ring-forming carbon atoms, and d1 to d4 may each independently be an integer of 0 to 4.

In one or more embodiments, the emission layer may be to emit (e.g., configured to emit) delayed fluorescence.

In one or more embodiments, the emission layer may be to emit (e.g., configured to emit) light having a central emission wavelength of about 430 nm to about 490 nm.

In one or more embodiments, Formula 1 may be represented by Formula 1-A1 or Formula 1-A2.

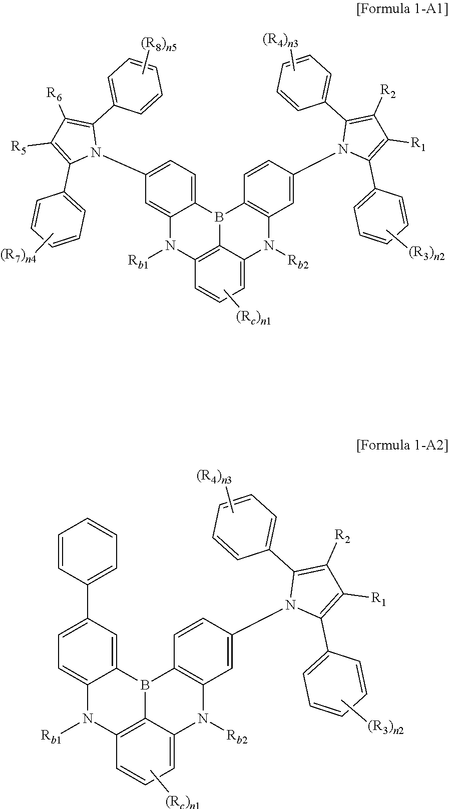

In Formula 1-A1, R₅ and R₆ may each independently be a hydrogen atom, a deuterium atom, a cyano group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring, n4 and n5 may each independently be an integer of 0 to 5, R₇ and R₈ may each independently be a hydrogen atom, a deuterium atom, a cyano group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and in Formulas 1-A1 and 1-A2, n1 to n3, R_{b1}, R_{b2}, R_{c}, and R₁ to R₄ may each independently be as defined in Formulas 1 and 2.

In one or more embodiments, Formula 2 may be represented by any one selected from among Formulas 2-1 to 2-6.

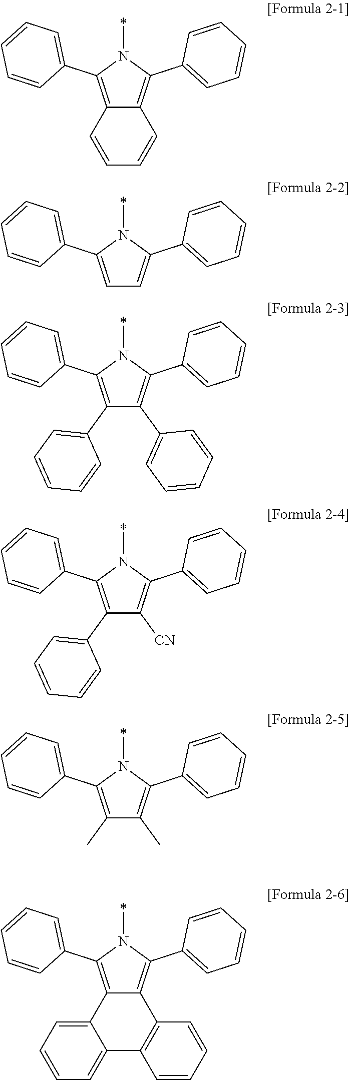

In one or more embodiments, Formula 1 may be represented by Formula 1-B.

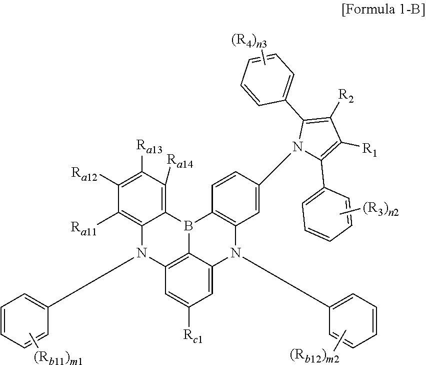

In Formula 1-B, Rₐ₁₁ to Rₐ₁₄ may each independently be a hydrogen atom, a deuterium atom, or a substituted or unsubstituted aryl group having 6 to 30 ring-forming carbon atoms, or represented by Formula 2, m1 and m2 may each independently be an integer of 0 to 5, R_{b1} and R_{b12} may each independently be a hydrogen atom, a deuterium atom, a substituted or unsubstituted alkyl group having 1 to 20 carbon atoms, or a substituted or unsubstituted aryl group having 6 to 30 ring-forming carbon atoms, R_{c1} is a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and n2, n3, and R₁ to R₄ may each independently be as defined in Formula 2.

In one or more embodiments, Formula 1-B may be represented by Formula 1-B1 or Formula 1-B2.

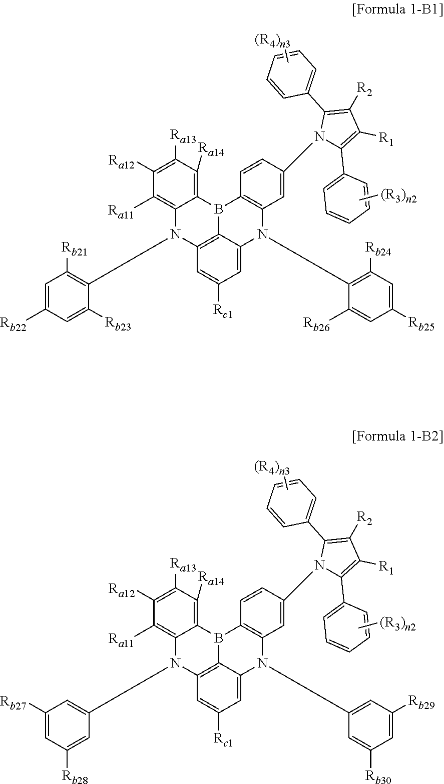

In Formulas 1-B1 and 1-B2, R_{b21} to R_{b30} may each independently be a hydrogen atom, a deuterium atom, a substituted or unsubstituted t-butyl group, or a substituted or unsubstituted phenyl group, and n2, n3, R₁ to R₄, Rₐ₁₁ to Rₐ₁₄, and R_{c1} may each independently be as defined in Formula 1-B.

In one or more embodiments, in Formula 1-B, R_{c1} may be a substituted or unsubstituted t-butyl group, a substituted or unsubstituted aryl amine group, a substituted or unsubstituted phenyl group, a substituted or unsubstituted pyrrole group, a substituted or unsubstituted isoindole group, a substituted or unsubstituted dibenzofuran group, a substituted or unsubstituted carbazole group, or a substituted or unsubstituted acridine group.

In one or more embodiments, in Formula 1-B, R_{c1} may be represented by any one selected from among RC-1 to RC-15.

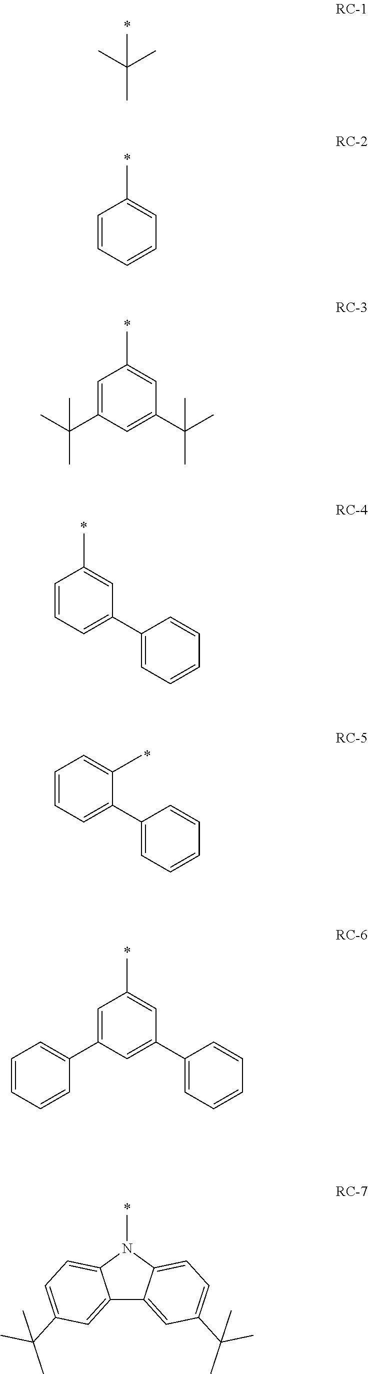

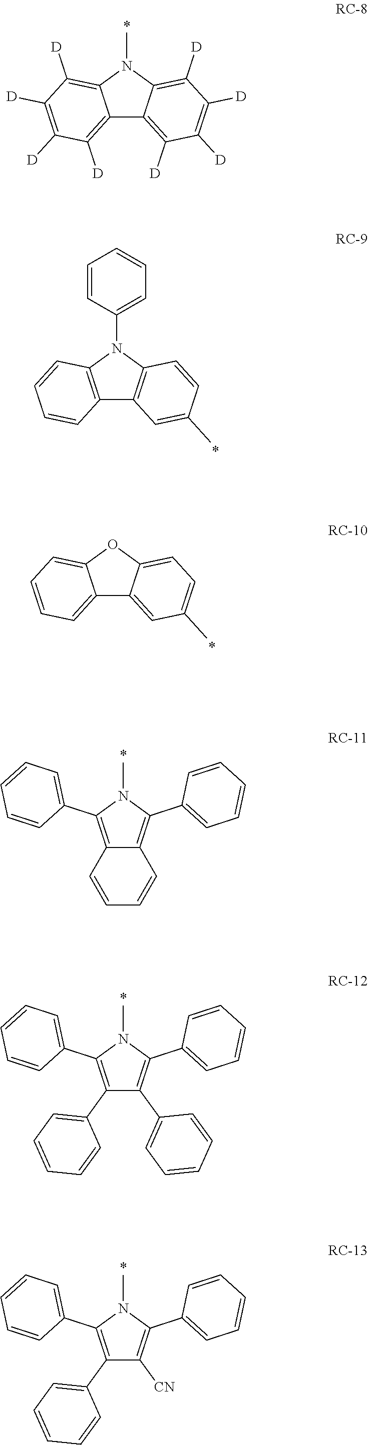 [SMILES: [2H]c1c([2H])c([2H])c2c(c1[2H])c1c([2H])c([2H])c([2H])c([2H])c1n2C ; Cc1ccc2c(c1)c1ccccc1n2-c1ccccc1 ; Cc1ccc2oc3ccccc3c2c1 ; Cn1c(-c2ccccc2)c2ccccc2c1-c1ccccc1 ; Cn1c(-c2ccccc2)c(-c2ccccc2)c(-c2ccccc2)c1-c1ccccc1 ; Cn1c(-c2ccccc2)c(C#N)c(-c2ccccc2)c1-c1ccccc1]

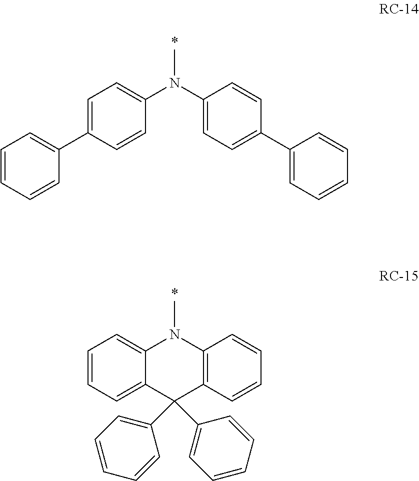 [SMILES: CN(c1ccc(-c2ccccc2)cc1)c1ccc(-c2ccccc2)cc1 ; CN1c2ccccc2C(c2ccccc2)(c2ccccc2)c2ccccc21]

In RC-8, D is a deuterium atom.

In one or more embodiments, in Formula 1, R_{b1} and R_{b2} may each independently be represented by any one selected from among RB-1 to RB-15.

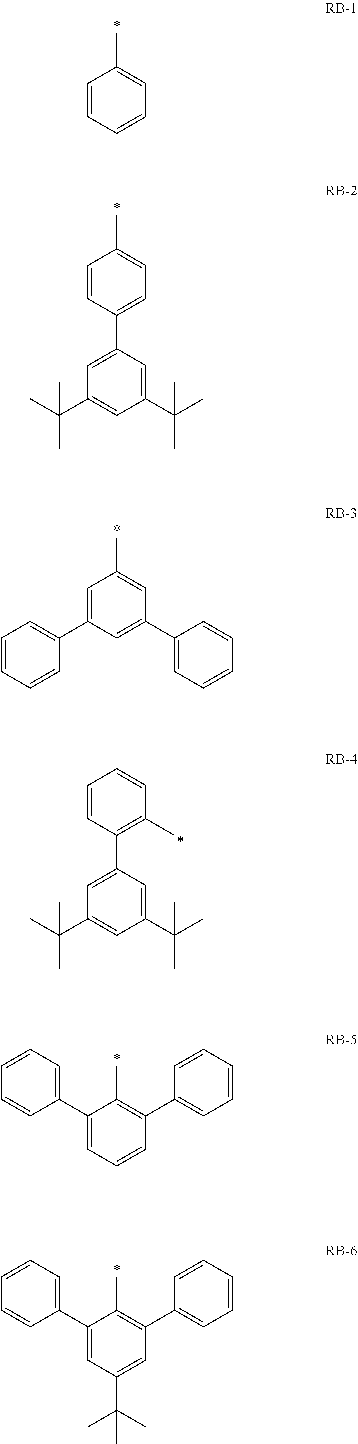

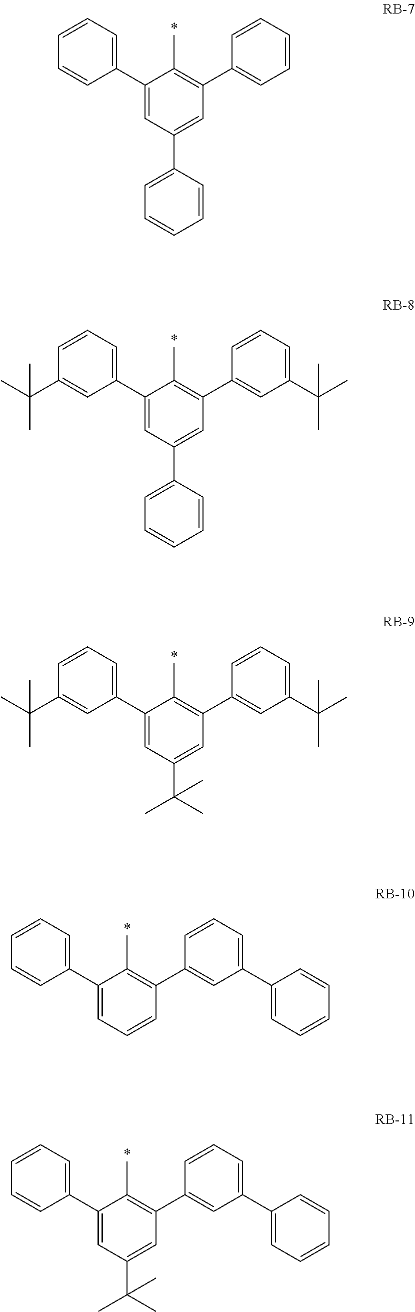

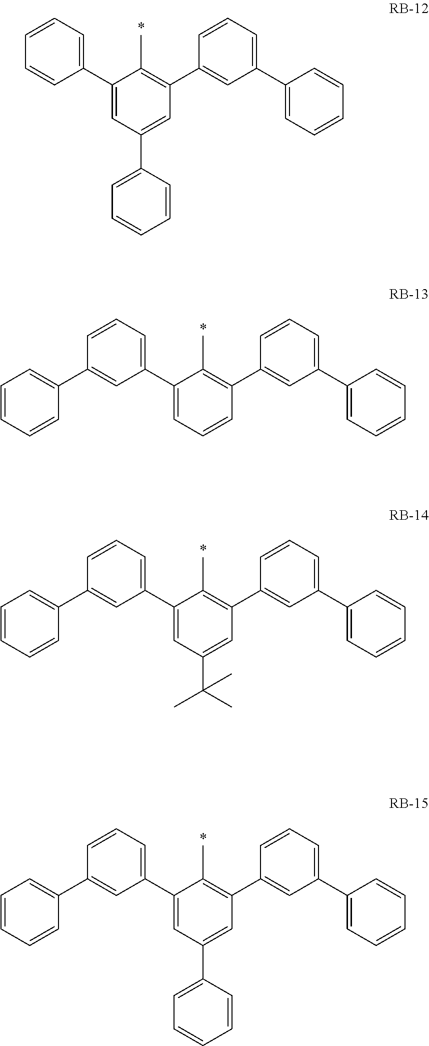

In one or more embodiments of the present disclosure, provided is a fused polycyclic compound represented by Formula 1.

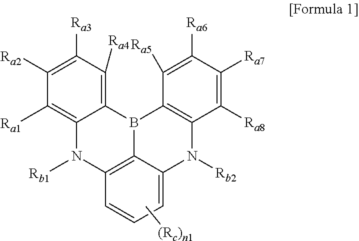

In Formula 1, Rₐ₁ to Rₐ₈ are each independently represented by Formula 2, a hydrogen atom, a deuterium atom, or a substituted or unsubstituted aryl group having 6 to 30 ring-forming carbon atoms, at least one of Rₐ₁ to Rₐ₈ is represented by Formula 2, n1 is an integer of 0 to 3, R_{b1}, R_{b2}, and Re may each independently be a hydrogen atom, a deuterium atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

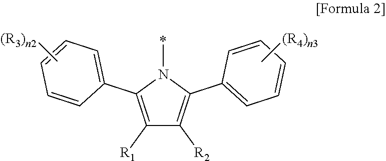

In Formula 2, R₁ and R₂ may each independently be a hydrogen atom, a deuterium atom, a cyano group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring, n2 and n3 may each independently be an integer of 0 to 5, and R₃ and R₄ may each independently be a hydrogen atom, a deuterium atom, a cyano group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms.

### BRIEF DESCRIPTION OF THE DRAWINGS

The accompanying drawings are included to provide a further understanding of the present disclosure, and are incorporated in and constitute a part of this specification. The drawings illustrate example embodiments of the present disclosure and, together with the description, serve to explain principles of the present disclosure.

In the drawings:

FIG. 1 is a plan view showing a display apparatus according to one or more embodiments of the present disclosure;

FIG. 2 is a cross-sectional view showing a portion corresponding to line I-I′ of FIG. 1;

FIG. 3 is a cross-sectional view schematically showing a light emitting device according to one or more embodiments of the present disclosure;

FIG. 4 is a cross-sectional view schematically showing a light emitting device according to one or more embodiments of the present disclosure;

FIG. 5 is a cross-sectional view schematically showing a light emitting device according to one or more embodiments of the present disclosure;

FIG. 6 is a cross-sectional view schematically showing a light emitting device according to one or more embodiments of the present disclosure;

FIG. 7 is a cross-sectional view schematically showing a light emitting device according to one or more embodiments of the present disclosure;

FIG. 8 is a cross-sectional view showing a display apparatus according to one or more embodiments of the present disclosure;

FIG. 9 is a cross-sectional view showing a display apparatus according to one or more embodiments of the present disclosure;

FIG. 10 is a cross-sectional view showing a display apparatus according to one or more embodiments of the present disclosure;

FIG. 11 is a cross-sectional view showing a display apparatus according to one or more embodiments of the present disclosure; and

FIG. 12 is a perspective view showing the inside of a vehicle in which a display apparatus of one or more embodiments of the present disclosure is provided.

### DETAILED DESCRIPTION

The present disclosure may be implemented in one or more suitable modifications and have one or more suitable forms, and specific embodiments are illustrated in the drawings and described in more detail in the text. It is to be understood, however, that the present disclosure is not intended to be limited to the particular forms disclosed, but on the contrary, is intended to cover all modifications, equivalents, and alternatives falling within the spirit and scope of the present disclosure.

In this specification, it will be understood that when an element (or region, layer, portion, and/or the like) is referred to as being “on”, “connected to” or “coupled to” another element, it may be directly provided, connected, or coupled to another element, or intervening elements may be provided therebetween. On the contrary to this, when a layer, a film, a region, or a plate is referred to as being “ ”, “in a lower portion of” another layer, film, region, or plate, it can be not only directly under the layer, film, region, or plate, but intervening layers, films, regions, or plates may also be present. In some embodiments, it will be understood that when a part is referred to as being “on” another part, it can be provided above the other part, or provided under the other part as well. When an element is referred to as being “directly on,” “directly connected to,” or “directly coupled to” another element, there are no intervening elements present.

As used herein, the terms “use,” “using,” and “used” may be considered synonymous with the terms “utilize,” “utilizing,” and “utilized,” respectively.

As used herein, expressions such as “at least one of,” “one of,” and “selected from,” when preceding a list of elements, modify the entire list of elements and do not modify the individual elements of the list. For example, the expressions “at least one of a to c,” “at least one of a, b or c,” and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

When explaining each of drawings, like reference numerals or symbols refer to like elements throughout, and duplicative descriptions thereof may not be provided. In the accompanying drawings, the thickness, the ratio, and the dimension of the elements are exaggerated for effective description of the technical contents. The term “and/or” includes all combinations of one or more of the associated listed elements.

Although the terms first, second, and/or the like, may be utilized to describe one or more suitable elements, these elements should not be limited by these terms. These terms are only utilized to distinguish one element from another element. For example, a first element may be referred to as a second element, and similarly, a second element may also be referred to as a first element without departing from the scope of the present disclosure. The singular forms include the plural forms as well, unless the context clearly indicates otherwise.

The terms such as “below”, “lower”, “above”, “upper” and/or the like, may be utilized herein for the description to describe one element's relationship to another element illustrated in the drawings. It will be understood that the terms have a relative concept and are described on the basis of the orientation depicted in the drawings. It will be understood that the spatially relative terms are intended to encompass different orientations of the device in use or operation in addition to the orientation depicted in the drawings. For example, if the device in the drawings is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The term “may” will be understood to refer to “one or more embodiments of the present disclosure,” some of which include the described element and some of which exclude that element and/or include an alternate element. Similarly, alternative language such as “or” refers to “one or more embodiments of the present disclosure,” each including a corresponding listed item.

It will be understood that the term “include,” “includes,” “including,” “comprise,” “comprises”, “comprising,” have,” “has,” “having,” when utilized in this specification, specifies the presence of stated features, integers, steps, operations, elements, components, or a combination thereof, but does not preclude the presence or addition of one or more other features, integers, steps, operations, elements, components, or combinations thereof.

Unless otherwise defined, all terms (including chemical, technical and scientific terms) utilized herein have the same meaning as commonly understood by one of ordinary skill in the art to which the present disclosure belongs. Also, terms, such as those defined in commonly utilized dictionaries, should be interpreted as having a meaning that is consistent with their meaning in the context of the relevant art and should not be interpreted in an idealized or overly formal sense unless expressly so defined herein.

In this context, “consisting essentially of” means that any additional components will not materially affect the chemical, physical, optical, or electrical properties of the semiconductor film.

Further, in this specification, the phrase “on a plane,” or “plan view,” means viewing a target portion from the top, and the phrase “on a cross-section” means viewing a cross-section formed by vertically cutting a target portion from the side.

### Definitions

In the specification, the term “substituted or unsubstituted” may refer to substituted or unsubstituted with at least one substituent selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. In some embodiments, each of the substituents exemplified herein may be substituted or unsubstituted. For example, a biphenyl group may be interpreted as an aryl group or a phenyl group substituted with a phenyl group.

In the specification, the phrase “bonded to an adjacent group to form a ring” may refer to that a group is bonded to an adjacent group to form a substituted or unsubstituted hydrocarbon ring, or a substituted or unsubstituted heterocycle. The hydrocarbon ring includes an aliphatic hydrocarbon ring and an aromatic hydrocarbon ring. The heterocycle includes an aliphatic heterocycle and an aromatic heterocycle. The hydrocarbon ring and the heterocycle may be monocyclic or polycyclic. In some embodiments, the rings formed by being bonded to each other may be connected to another ring to form a spiro structure.

In the specification, the term “adjacent group” may refer to a substituent substituted for an atom which is directly linked to an atom substituted with a corresponding substituent, another substituent substituted for an atom which is substituted with a corresponding substituent, or a substituent sterically positioned at the nearest position to a corresponding substituent. For example, two methyl groups in 1,2-dimethylbenzene may be interpreted as “adjacent groups” to each other and two ethyl groups in 1,1-diethylcyclopentane may be interpreted as “adjacent groups” to each other. In some embodiments, two methyl groups in 4,5-dimethylphenanthrene may be interpreted as “adjacent groups” to each other.

In the specification, examples of the halogen atom may include a fluorine atom, a chlorine atom, a bromine atom, or an iodine atom.

In the specification, the alkyl group may be linear or branched. The number of carbons in the alkyl group is 1 to 50, 1 to 30, 1 to 20, 1 to 10, or 1 to 6. Examples of the alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, and/or the like, but the embodiment of the present disclosure is not limited thereto.

In the specification, a cycloalkyl group may refer to a cyclic alkyl group. The number of carbons in the cycloalkyl group is 3 to 50, 3 to 30, 3 to 20, or 3 to 10. Examples of the cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, and/or the like, but the embodiment of the present disclosure is not limited thereto.

In the specification, an alkenyl group refers to a hydrocarbon group including at least one carbon double bond in the middle or terminal of an alkyl group having 2 or more carbon atoms. The alkenyl group may be linear or branched. The number of carbon atoms in the alkenyl group is not specifically limited, but is 2 to 30, 2 to 20, or 2 to 10. Examples of the alkenyl group include a vinyl group, a 1-butenyl group, a 1-pentenyl group, a 1,3-butadienyl aryl group, a styrenyl group, a styryl vinyl group, and/or the like, but the embodiment of the present disclosure is not limited thereto.

In the specification, an alkynyl group refers to a hydrocarbon group including at least one carbon triple bond in the middle or terminal of an alkyl group having 2 or more carbon atoms. The alkynyl group may be linear or branched. Although the number of carbon atoms is not specifically limited, it is 2 to 30, 2 to 20, or 2 to 10. Specific examples of the alkynyl group may include an ethynyl group, a propynyl group, and/or the like, but are not limited thereto.

In the specification, the hydrocarbon ring group refers to any functional group or substituent derived from an aliphatic hydrocarbon ring. The hydrocarbon ring group may be a saturated hydrocarbon ring group having 5 to 20 ring-forming carbon atoms.

In the specification, an aryl group refers to any functional group or substituent derived from an aromatic hydrocarbon ring. The aryl group may be a monocyclic aryl group or a polycyclic aryl group. The number of ring-forming carbon atoms in the aryl group may be 6 to 60, 6 to 30, 6 to 20, or 6 to 15. Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, and/or the like, but the embodiment of the present disclosure is not limited thereto.

In the specification, the fluorenyl group may be substituted, and two substituents may be bonded to each other to form a spiro structure. Examples of the substituted fluorenyl group are as follows. However, the embodiment of the present disclosure is not limited thereto.

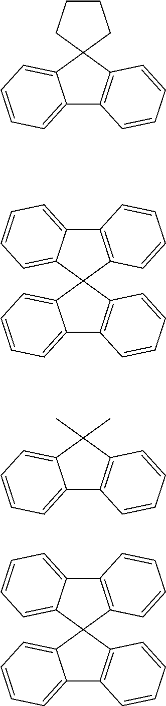

The heterocyclic group herein refers to any functional group or substituent derived from a ring containing at least one of B, O, N, P, Si, or Se as a heteroatom.

The heterocyclic group includes an aliphatic heterocyclic group and an aromatic heterocyclic group. The aromatic heterocyclic group may be a heteroaryl group. The aliphatic heterocycle and the aromatic heterocycle may be monocyclic or polycyclic.

In the specification, the heterocyclic group may contain at least one of B, O, N, P, Si or S as a heteroatom. When the heterocyclic group contains two or more heteroatoms, the two or more heteroatoms may be the same as or different from each other. The heterocyclic group may be a monocyclic heterocyclic group or a polycyclic heterocyclic group, and includes a heteroaryl group. The number of ring-forming carbon atoms in the heterocyclic group may be 2 to 60, 2 to 30, 2 to 20, or 2 to 10.

In the specification, the aliphatic heterocyclic group may include at least one of B, O, N, P, Si, or S as a heteroatom. The number of ring-forming carbon atoms in the aliphatic heterocyclic group may be 2 to 60, 2 to 30, 2 to 20, or 2 to 10. Examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, and/or the like, but the embodiment of the present disclosure is not limited thereto.

In the specification, the heteroaryl group may contain at least one of B, O, N, P, Si, or S as a heteroatom. When the heteroaryl group contains two or more heteroatoms, the two or more heteroatoms may be the same as or different from each other. The heteroaryl group may be a monocyclic heterocyclic group or a polycyclic heterocyclic group. The number of ring-forming carbon atoms in the heteroaryl group may be 2 to 60, 2 to 30, 2 to 20, or 2 to 10. Examples of the heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, an isoindole group, a carbazole group, an N-arylcarbazole group, an N-heteroarylcarbazole group, an N-alkylcarbazole group, a benzoxazole group, a benzimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, and/or the like, but the embodiment of the present disclosure is not limited thereto.

In the specification, the description of the aryl group may be applied to an arylene group except that the arylene group is a divalent group. The description of the heteroaryl group may be applied to a heteroarylene group except that the heteroarylene group is a divalent group.

In the specification, the silyl group includes an alkylsilyl group and an arylsilyl group. Examples of the silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, and/or the like, but the embodiment of the present disclosure is not limited thereto.

In the specification, the number of ring-forming carbon atoms in the carbonyl group is not specifically limited, but may be 1 to 40, 1 to 30, or 1 to 20. For example, the carbonyl group may have the following structures, but the embodiment of the present disclosure is not limited thereto.

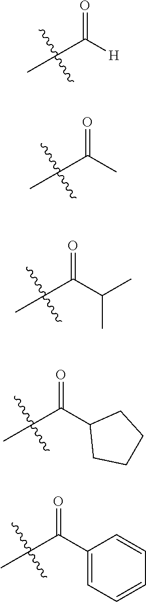

In the specification, the number of carbon atoms in the sulfinyl group and the sulfonyl group is not particularly limited, but may be 1 to 30. The sulfinyl group may include an alkyl sulfinyl group and an aryl sulfinyl group. The sulfonyl group may include an alkyl sulfonyl group and an aryl sulfonyl group.

In the specification, the thio group may include an alkylthio group and an arylthio group. The thio group may refer to that a sulfur atom is bonded to the alkyl group or the aryl group as defined herein. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, but the embodiment of the present disclosure is not limited thereto.

In the specification, an oxy group may refer to that an oxygen atom is bonded to the alkyl group or the aryl group as defined herein. The oxy group may include an alkoxy group and an aryl oxy group. The alkoxy group may be a linear chain, a branched chain or a ring chain. The number of carbon atoms in the alkoxy group is not specifically limited, but may be, for example, 1 to 20 or 1 to 10. Examples of the oxy group may include methoxy, ethoxy, n-propoxy, isopropoxy, butoxy, pentyloxy, hexyloxy, octyloxy, nonyloxy, decyloxy, benzyloxy, and/or the like, but the embodiment of the present disclosure is not limited thereto.

The boron group herein may refer to that a boron atom is bonded to the alkyl group or the aryl group as defined herein. The boron group includes an alkyl boron group and an aryl boron group. Examples of the boron group may include a dimethylboron group, a trimethylboron group, a t-butyldimethylboron group, a diphenylboron group, a phenylboron group, and/or the like, but the embodiment of the present disclosure is not limited thereto.

In the specification, the number of carbon atoms in an amine group is not specifically limited, but may be 1 to 30. The amine group may include an alkyl amine group and an aryl amine group. Examples of the amine group may include a methylamine group, a dimethylamine group, a phenylamine group, a diphenylamine group, a naphthylamine group, a 9-methyl-anthracenylamine group, and/or the like, but the embodiment of the present disclosure is not limited thereto.

In the specification, the alkyl group among an alkylthio group, an alkylsulfoxy group, an alkylaryl group, an alkylamino group, an alkyl boron group, an alkyl silyl group, and an alkyl amine group is the same as the examples of the alkyl group described herein.

In the specification, the aryl group among an aryloxy group, an arylthio group, an arylsulfoxy group, an arylamino group, an arylboron group, an arylsilyl group, an arylamine group is the same as the examples of the aryl group described herein.

In the specification, a direct linkage may refer to a single bond. In the specification, and “ [symbol] ” and “ [symbol] ” refer to a position to be connected.

Hereinafter, embodiments of the present disclosure will be described with reference to the accompanying drawings.

### Display Apparatus

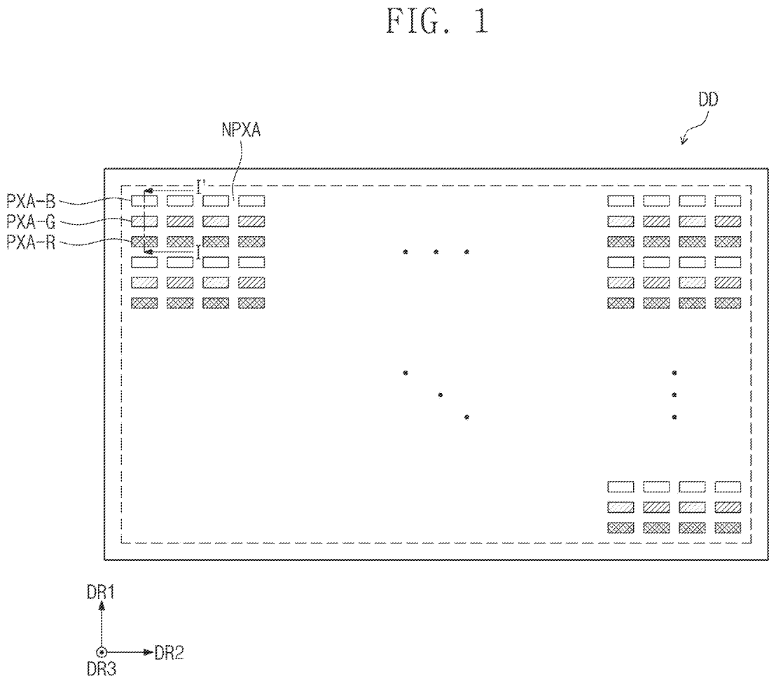

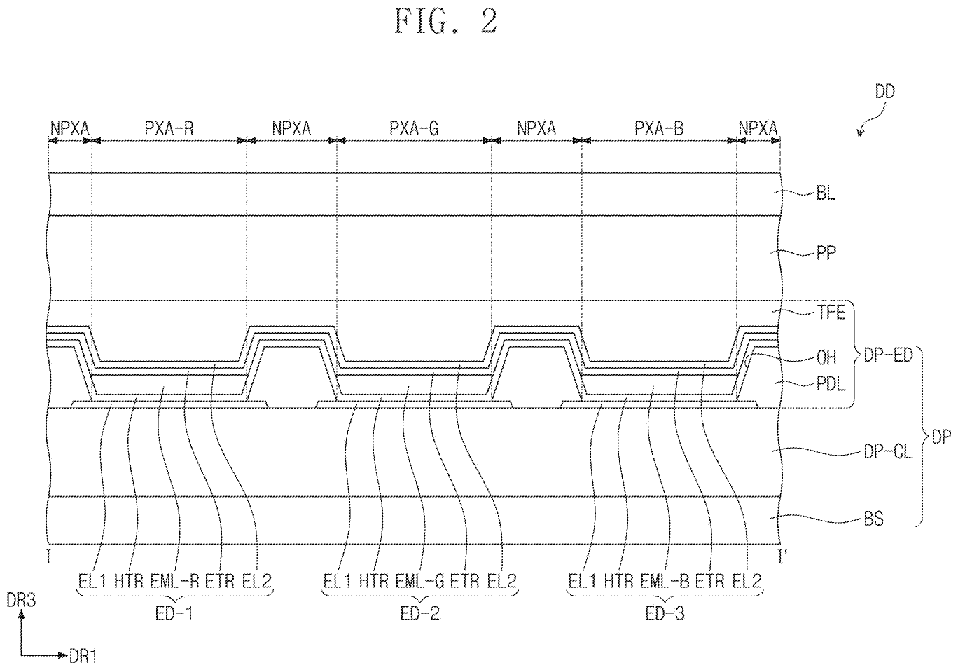

FIG. 1 is a plan view illustrating one or more embodiments of a display apparatus DD. FIG. 2 is a cross-sectional view of the display apparatus DD of the embodiment. FIG. 2 is a cross-sectional view illustrating a part taken along line I-I′ of FIG. 1.

The display apparatus DD may include a display panel DP and an optical layer PP provided on the display panel DP. The display panel DP includes light emitting devices ED-1, ED-2, and ED-3. The display apparatus DD may include a plurality of light emitting devices ED-1, ED-2, and ED-3. The optical layer PP may be provided on the display panel DP to control reflected light in the display panel DP due to external light. The optical layer PP may include, for example, a polarization layer or a color filter layer. In some embodiments, unlike the configuration illustrated in the drawing, the optical layer PP may not be provided from the display apparatus DD of one or more embodiments.

A base substrate BL may be provided on the optical layer PP. The base substrate BL may be a member which provides a base surface on which the optical layer PP provided. The base substrate BL may be a glass substrate, a metal substrate, a plastic substrate, and/or the like. However, the embodiment of the present disclosure is not limited thereto, and the base substrate BL may be an inorganic layer, an organic layer, or a composite material layer. In some embodiments, unlike the configuration illustrated, in one or more embodiments, the base substrate BL may not be provided.

The display apparatus DD according to one or more embodiments may further include a filling layer. The filling layer may be provided between a display device layer DP-ED and the base substrate BL. The filling layer may be an organic material layer. The filling layer may include at least one of an acrylic-based resin, a silicone-based resin, or an epoxy-based resin (i.e., at least one selected from among an acrylic-based resin, a silicone-based resin, and an epoxy-based resin).

The display panel DP may include a base layer BS, a circuit layer DP-CL provided on the base layer BS, and the display device layer DP-ED. The display device layer DP-ED may include a pixel defining film PDL, the light emitting devices ED-1, ED-2, and ED-3 provided between portions of the pixel defining film PDL, and an encapsulation layer TFE provided on the light emitting devices ED-1, ED-2, and ED-3.

The base layer BS may be a member which provides a base surface on which the display device layer DP-ED is provided. The base layer BS may be a glass substrate, a metal substrate, a plastic substrate, and/or the like. However, the embodiment is not limited thereto, and the base layer BS may be an inorganic layer, an organic layer, or a composite material layer.

In one or more embodiments, the circuit layer DP-CL is provided on the base layer BS, and the circuit layer DP-CL may include a plurality of transistors. Each of the transistors may include a control electrode, an input electrode, and an output electrode. For example, the circuit layer DP-CL may include a switching transistor and a driving transistor for driving the light emitting devices ED-1, ED-2, and ED-3 of the display device layer DP-ED.

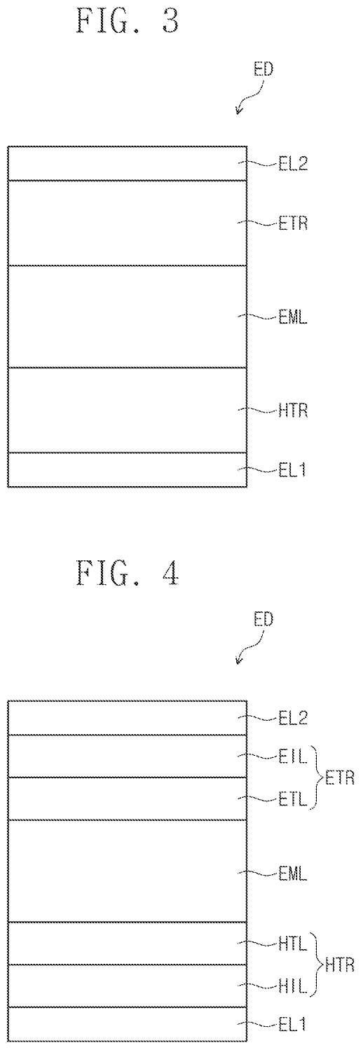

Each of the light emitting devices ED-1, ED-2, and ED-3 may have a structure of each light emitting device ED of one or more embodiments according to FIGS. 3 to 7, as described in more detail elsewhere herein. Each of the light emitting devices ED-1, ED-2, and ED-3 may include a first electrode EL1, a hole transport region HTR, a layer selected from among emission layers EML-R, EML-G, and EML-B, an electron transport region ETR, and a second electrode EL2.

FIG. 2 illustrates one or more embodiments in which the emission layers EML-R, EML-G, and EML-B of the light emitting devices ED-1, ED-2, and ED-3 are provided in openings OH defined in the pixel defining film PDL, and the hole transport region HTR, the electron transport region ETR, and the second electrode EL2 are provided as a common layer in the entire light emitting devices ED-1, ED-2, and ED-3. However, the embodiment of the present disclosure is not limited thereto, and unlike the configuration illustrated in FIG. 2, the hole transport region HTR and the electron transport region ETR in one or more embodiments may be provided by being patterned inside the openings OH defined in the pixel defining film PDL. For example, the hole transport region HTR, the emission layers EML-R, EML-G, and EML-B, and the electron transport region ETR of the light emitting devices ED-1, ED-2, and ED-3 in one or more embodiments may be provided by being patterned in an inkjet printing method.

The encapsulation layer TFE may cover the light emitting devices ED-1, ED-2 and ED-3. The encapsulation layer TFE may seal the display device layer DP-ED. The encapsulation layer TFE may be a thin film encapsulation layer. The encapsulation layer TFE may be formed by laminating one layer or a plurality of layers. The encapsulation layer TFE includes at least one insulation layer. The encapsulation layer TFE according to one or more embodiments may include at least one inorganic film (hereinafter, an encapsulation-inorganic film). The encapsulation layer TFE according to one or more embodiments may also include at least one organic film (hereinafter, an encapsulation-organic film) and at least one encapsulation-inorganic film.

The encapsulation-inorganic film protects the display device layer DP-ED from moisture/oxygen, and the encapsulation-organic film protects the display device layer DP-ED from foreign substances such as dust particles. The encapsulation-inorganic film may include silicon nitride, silicon oxynitride, silicon oxide, titanium oxide, aluminum oxide, and/or the like, but the embodiment of the present disclosure is not particularly limited thereto. The encapsulation-organic film may include an acrylic-based compound, an epoxy-based compound, and/or the like. The encapsulation-organic film may include a photopolymerizable organic material, but the embodiment of the present disclosure is not particularly limited thereto.

The encapsulation layer TFE may be provided on the second electrode EL2 and may be provided filling the opening OH.

Referring to FIGS. 1 and 2, the display apparatus DD may include one or more non-light emitting region(s) NPXA and light emitting regions PXA-R, PXA-G, and PXA-B. The light emitting regions PXA-R, PXA-G, and PXA-B may be regions in which light generated by the respective light emitting devices ED-1, ED-2, and ED-3 is emitted. The light emitting regions PXA-R, PXA-G, and PXA-B may be spaced from each other on a plane.

Each of the light emitting regions PXA-R, PXA-G, and PXA-B may be a region divided by the pixel defining film PDL. The non-light emitting areas NPXA may be areas between the adjacent light emitting areas PXA-R, PXA-G, and PXA-B, which correspond to the pixel defining film PDL. In some embodiments, in the specification, the light emitting regions PXA-R, PXA-G, and PXA-B may respectively correspond to pixels. The pixel defining film PDL may divide the light emitting devices ED-1, ED-2, and ED-3. The emission layers EML-R, EML-G, and EML-B of the light emitting devices ED-1, ED-2, and ED-3 may be provided in openings OH defined in the pixel defining film PDL and separated from each other.

The light emitting regions PXA-R, PXA-G, and PXA-B may be divided into a plurality of groups according to the color of light generated from the light emitting devices ED-1, ED-2, and ED-3. In the display apparatus DD of one or more embodiments illustrated in FIGS. 1 and 2, three light emitting regions PXA-R, PXA-G, and PXA-B, which emit red light, green light, and blue light, respectively, are illustrated as an example. For example, the display apparatus DD of one or more embodiments may include the red light emitting region PXA-R, the green light emitting region PXA-G, and the blue light emitting region PXA-B that are separated from each other.

In the display apparatus DD according to one or more embodiments, the plurality of light emitting devices ED-1, ED-2 and ED-3 may be to emit (e.g., configured to emit) light beams having wavelengths different from each other. For example, in one or more embodiments, the display apparatus DD may include a first light emitting device ED-1 that emits red light, a second light emitting device ED-2 that emits green light, and a third light emitting device ED-3 that emits blue light. For example, the red light emitting region PXA-R, the green light emitting region PXA-G, and the blue light emitting region PXA-B of the display apparatus DD may correspond to the first light emitting device ED-1, the second light emitting device ED-2, and the third light emitting device ED-3, respectively.

However, the embodiment of the present disclosure is not limited thereto, and the first to third light emitting devices ED-1, ED-2, and ED-3 may be to emit (e.g., configured to emit) light beams in substantially the same wavelength range or at least one light emitting device may be to emit (e.g., configured to emit) a light beam in a wavelength range different from the others. For example, the first to third light emitting devices ED-1, ED-2, and ED-3 may all emit blue light.

The light emitting regions PXA-R, PXA-G, and PXA-B in the display apparatus DD according to one or more embodiments may be arranged in a stripe form. Referring to FIG. 1, the plurality of red light emitting regions PXA-R may be arranged with each other along a second directional axis DR2, the plurality of green light emitting regions PXA-G may be arranged with each other along the second directional axis DR2, and the plurality of blue light emitting regions PXA-B may be arranged with each other along the second directional axis DR2. In some embodiments, the red light emitting region PXA-R, the green light emitting region PXA-G, and the blue light emitting region PXA-B may be alternately arranged with each other in this order along a first directional axis DR1.

FIGS. 1 and 2 illustrate that all the light emitting regions PXA-R, PXA-G, and PXA-B have similar area, but the embodiment of the present disclosure is not limited thereto. Thus, the light emitting regions PXA-R, PXA-G, and PXA-B may have different areas from each other according to the wavelength range of the emitted light. In this case, the areas of the light emitting regions PXA-R, PXA-G, and PXA-B may refer to areas when viewed on a plane defined by the first directional axis DR1 and the second directional axis DR2.

In some embodiments, an arrangement form of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in one or more suitable combinations according to the characteristics of display quality required in the display apparatus DD. For example, the arrangement form of the light emitting regions PXA-R, PXA-G, and PXA-B may be a pentile (PENTILE®) arrangement form or a diamond (Diamond Pixel®) arrangement form, (PENTILE® and Diamond Pixel® are registered trademarks owned by Samsung Display Co., Ltd.).

In some embodiments, the areas of the light emitting regions PXA-R, PXA-G, and PXA-B may be different from each other. For example, in one or more embodiments, the area of the green light emitting region PXA-G may be smaller than that of the blue light emitting region PXA-B, but the embodiment of the present disclosure is not limited thereto.

Hereinafter, FIGS. 3 to 7 are cross-sectional views schematically showing a light emitting device according to one or more embodiments. The light emitting device ED according to one or more embodiments may include a first electrode EL1, a hole transport region HTR, an emission layer EML, an electron transport region ETR, and a second electrode EL2.

As illustrated in FIG. 3, the light emitting element ED includes the first electrode EL1, a hole transport region HTR, a light emitting layer EML, an electron transport region ETR, and the second electrode EL2 which are, e.g., sequentially laminated.

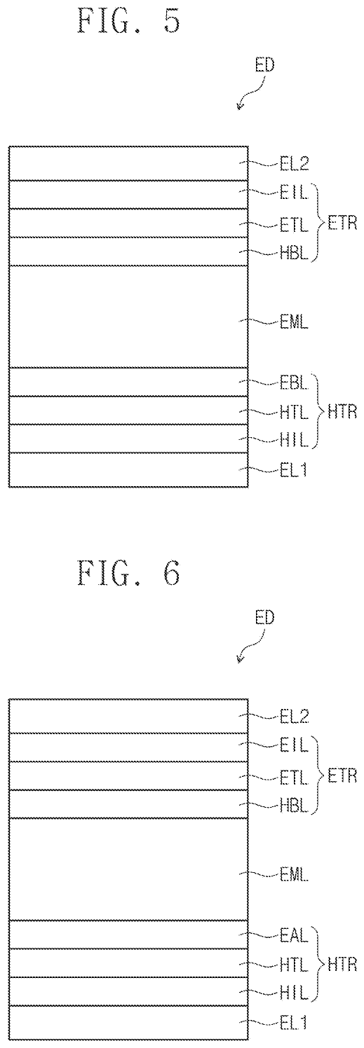

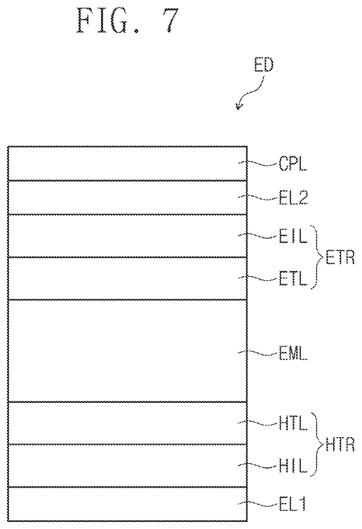

FIG. 4 shows, compared with FIG. 3, a cross-sectional view of a light emitting device ED of one or more embodiments in which the hole transport region HTR includes a hole injection layer HIL and a hole transport layer HTL, and the electron transport region ETR includes an electron injection layer EIL and an electron transport layer ETL. In some embodiments, FIG. 5 shows, compared with FIG. 3, a cross-sectional view of a light emitting device ED according to one or more embodiments in which the hole transport region HTR includes a hole injection layer HIL, a hole transport layer HTL, and an electron blocking layer EBL, and the electron transport region ETR includes an electron injection layer EIL, an electron transport layer ETL, and a hole blocking layer HBL. FIG. 6 shows, compared with FIG. 3, a cross-sectional view of a light emitting device ED according to one or more embodiments in which the hole transport region HTR includes a hole injection layer HIL, a hole transport layer HTL, and an auxiliary emission layer EAL, and the electron transport region ETR includes an electron injection layer EIL, an electron transport layer ETL, and a hole blocking layer HBL. FIG. 7 shows, compared with FIG. 4, a cross-sectional view of a light emitting device ED according to one or more embodiments, in which a capping layer CPL provided on the second electrode EL2 is provided.

The first electrode EL1 has conductivity (e.g., is a conductor). The first electrode EL1 may be formed of a metal material, a metal alloy, or a conductive compound. The first electrode EL1 may be an anode or a cathode. However, the embodiment of the present disclosure is not limited thereto. In some embodiments, the first electrode EL1 may be a pixel electrode. The first electrode EL1 may be a transmissive electrode, a transflective electrode, or a reflective electrode. The first electrode EL1 may include at least one selected from among Ag, Mg, Cu, Al, Pt, Pd, Au, Ni, Nd, Ir, Cr, Li, Ca, LiF, Mo, Ti, W, In, Sn, and Zn, a compound of two or more selected from among these, a mixture of two or more selected from among these, and/or an oxide thereof.

When the first electrode EL1 is the transmissive electrode, the first electrode EL1 may include a transparent metal oxide such as indium tin oxide (ITO), indium zinc oxide (IZO), zinc oxide (ZnO), or indium tin zinc oxide (ITZO). When the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, and/or a compound or mixture thereof (e.g., a mixture of Ag and Mg). In some embodiments, the first electrode EL1 may have a multilayer structure including a reflective film or a transflective film formed of the described materials, and a transparent conductive film formed of ITO, IZO, ZnO, ITZO, and/or the like. For example, the first electrode EL1 may have a three-layer structure of ITO/Ag/ITO, but the embodiment of the present disclosure is not limited thereto. In some embodiments, the embodiment of the present disclosure is not limited thereto, and the first electrode EL1 may include the described metal materials, combinations of at least two metal materials of the described metal materials, oxides of the described metal materials, and/or the like. The thickness of the first electrode EL1 may be from about 700 angstrom (Å) Å to about 10,000 Å. For example, the thickness of the first electrode EL1 may be from about 1,000 Å to about 3,000 Å.

The hole transport region HTR is provided on the first electrode EL1. The hole transport region HTR may include at least one of a hole injection layer HIL, a hole transport layer HTL, an auxiliary emission layer EAL, or an electron blocking layer EBL. The thickness of the hole transport region HTR may be, for example, from about 50 Å to about 15,000 Å.

The hole transport region HTR may have a single layer formed of a single material, a single layer formed of a plurality of different materials, or a multilayer structure including a plurality of layers formed of a plurality of different materials.

For example, the hole transport region HTR may have a single layer structure of the hole injection layer HIL or the hole transport layer HTL, or may have a single layer structure formed of a hole injection material and a hole transport material. In some embodiments, the hole transport region HTR may have a single layer structure formed of a plurality of different materials, or a structure in which a hole injection layer HIL/hole transport layer HTL, a hole injection layer HIL/hole transport layer HTL/auxiliary emission layer EAL, a hole injection layer HIL/auxiliary emission layer EAL, or a hole injection layer HIL/hole transport layer HTL/electron blocking layer EBL are stacked in order from the first electrode EL1, but the embodiment of the present disclosure is not limited thereto.

The hole transport region HTR may be formed utilizing one or more suitable methods such as a vacuum deposition method, a spin coating method, a cast method, a Langmuir-Blodgett (LB) method, an inkjet printing method, a laser printing method, and/or a laser induced thermal imaging (LITI) method.

The hole transport region HTR may include a compound represented by Formula H-1:

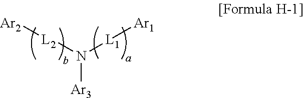

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. a and b may each independently be an integer of 0 to 10. In some embodiments, when a or b is an integer of 2 or greater, a plurality of L₁'s and L₂'s may each independently be a substituted or unsubstituted arylene group having 6 to 30 ring-forming carbon atoms, or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. In some embodiments, in Formula H-1, Ar₃ may be a substituted or unsubstituted aryl group having 6 to 30 ring-forming carbon atoms, or a substituted or unsubstituted heteroaryl group having 2 to 30 ring-forming carbon atoms.

The compound represented by Formula H-1 may be a monoamine compound. In some embodiments, the compound represented by Formula H-1 may be a diamine compound in which at least one among Ar₁ to Ar₃ includes the amine group as a substituent. In some embodiments, the compound represented by Formula H-1 may be a carbazole-based compound including a substituted or unsubstituted carbazole group in at least one of Ar₁ or Ar₂, or a fluorene-based compound including a substituted or unsubstituted fluorene group in at least one of Ar₁ or Ar₂.

The compound represented by Formula H-1 may be represented by any one selected from among the compounds in Compound Group H. However, the compounds listed in Compound Group H are examples, and the compounds represented by Formula H-1 are not limited to those represented by Compound Group H:

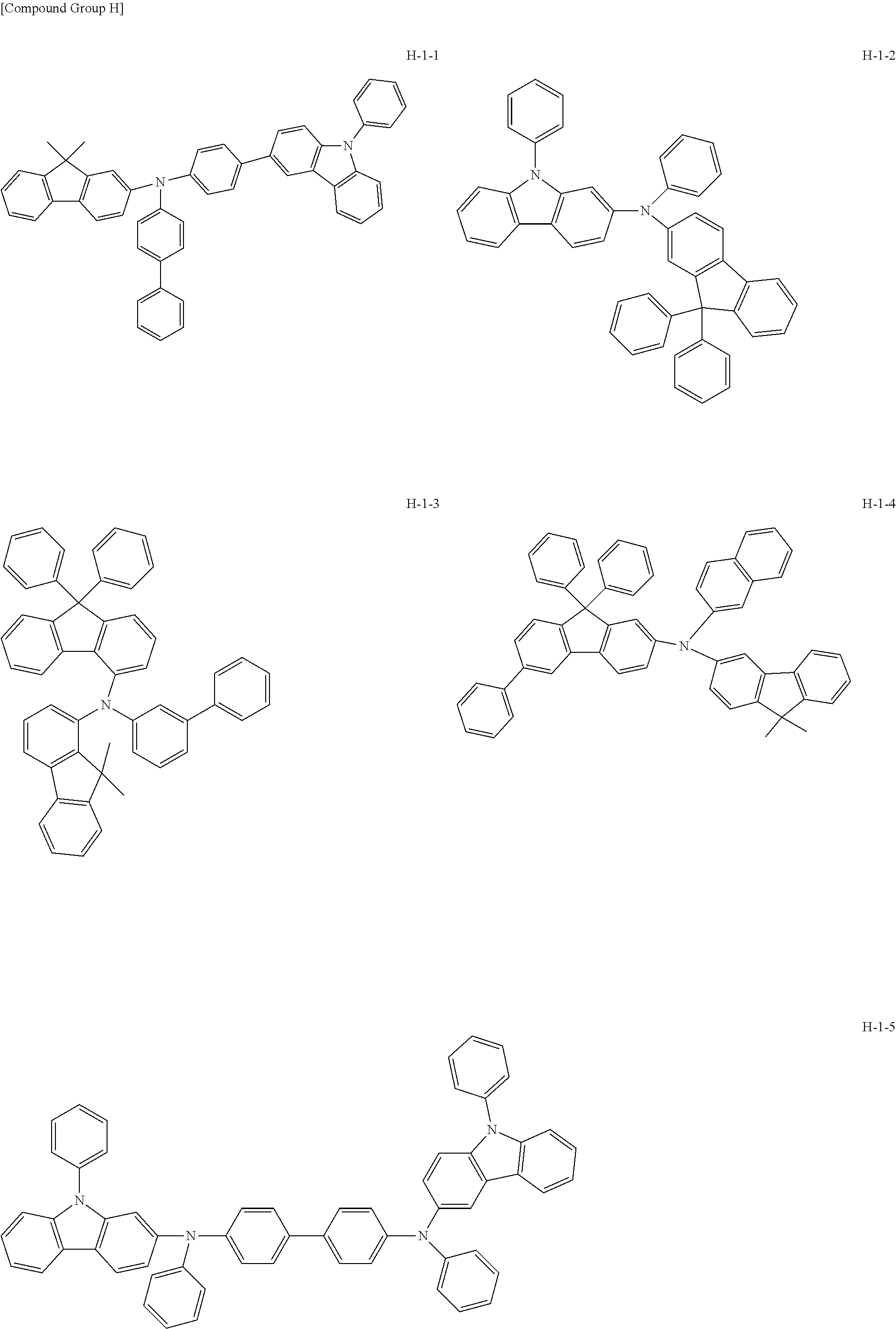 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21 ; CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21 ; c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1]

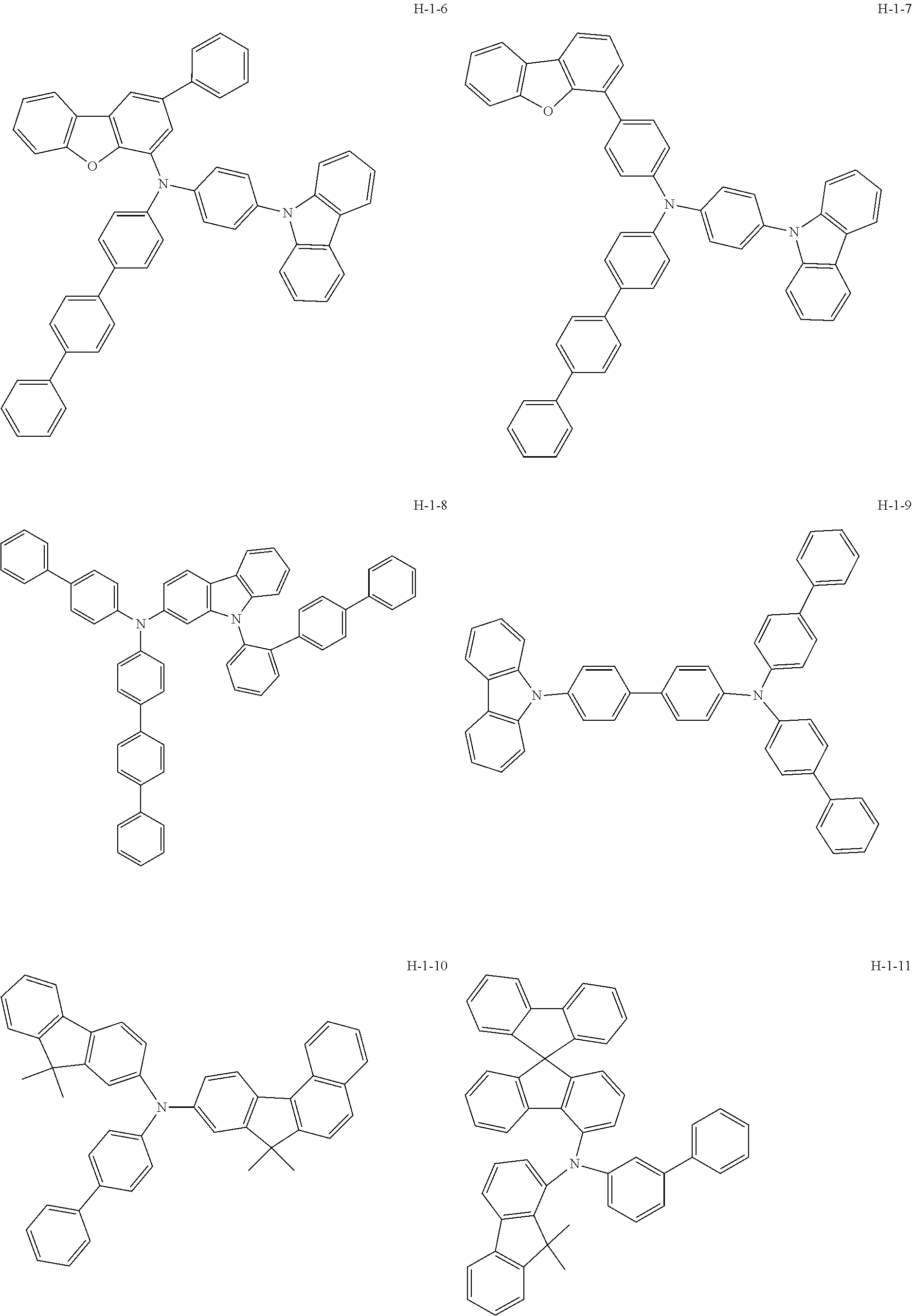

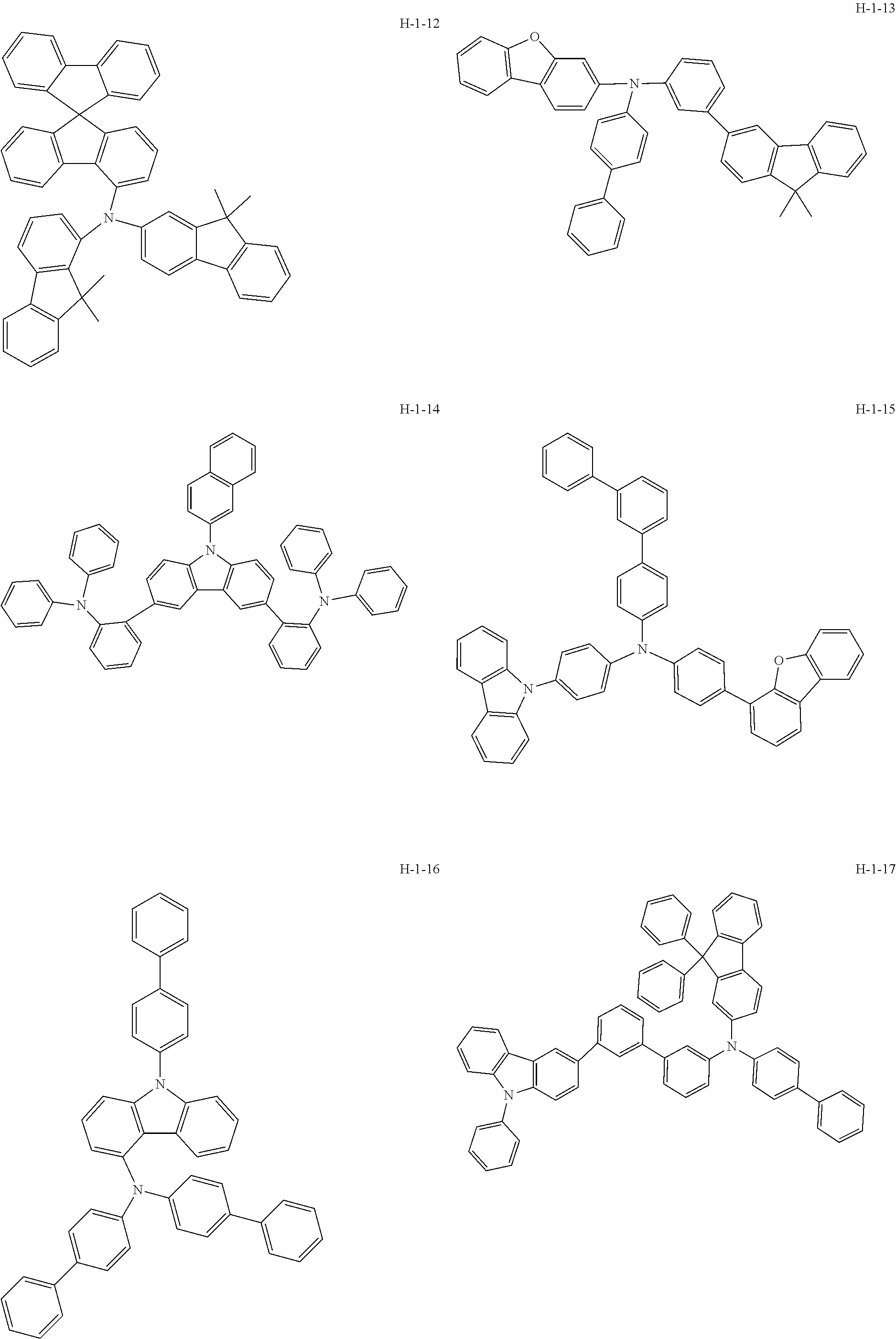

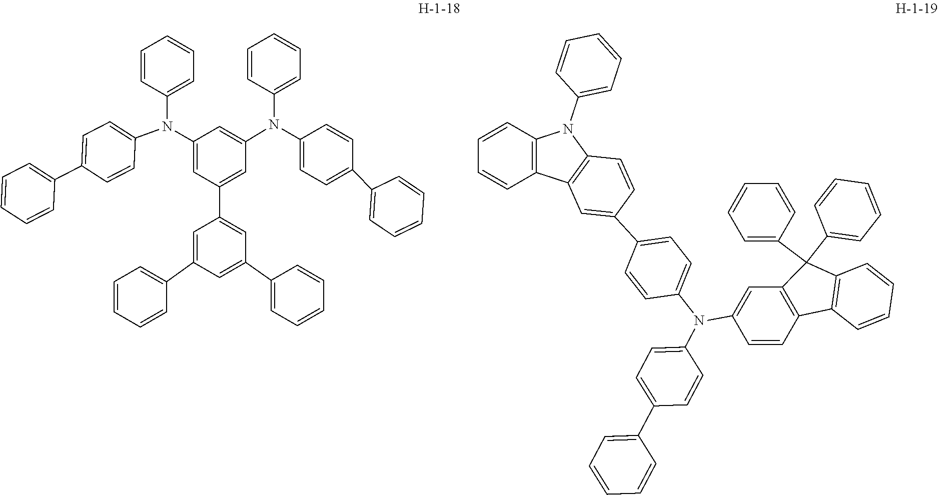 [SMILES: c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include at least one selected from among a phthalocyanine compound such as copper phthalocyanine; N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methyl phenyl)phenylamino] triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCN), and/or the like.

The hole transport region HTR may include at least one selected from among a carbazole-based derivative such as N-phenyl carbazole or polyvinyl carbazole, a fluorene-based derivative, a triphenylamine-based derivative such as N,N′-bis(3-methylphenyl)-N,N′-diphenyl-[1,1-biphenyl]-4,4′-diamine (TPD) or 4,4′,4″-tris(N-carbazolyl)triphenylamine (TCTA), N,N′-di(naphthalene-1-yl)-N,N′-diphenyl-benzidine (NPB), 4,4′-cyclohexylidene bis[N,N-bis(4-methylphenyl]benzenamine](TAPC), 4,4′-bis[N,N′-(3-tolyl)amino]-3,3′-dimethylbiphenyl (HMTPD), 1,3-bis(N-carbazolyl)benzene (mCP), and/or the like.

In some embodiments, the hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), and/or the like.

The hole transport region HTR may include the described compounds of the hole transport region in at least one selected from among a hole injection layer HIL, a hole transport layer HTL, an auxiliary emission layer EAL, and/or an electron blocking layer EBL.

The thickness of the hole transport region HTR may be from about 100 Å to about 10,000 Å, for example, from about 100 Å to about 5,000 Å. When the hole transport region HTR includes the hole injection layer HIL, the hole injection layer HIL may have, for example, a thickness of about 30 Å to about 1,000 Å. When the hole transport region HTR includes the hole transport layer HTL, the hole transport layer HTL may have a thickness of about 250 Å to about 1,000 Å. For example, when the hole transport region HTR includes the electron blocking layer EBL, the electron blocking layer EBL may have a thickness of about 10 Å to about 1,000 Å. When the thicknesses of the hole transport region HTR, the hole injection layer HIL, the hole transport layer HTL and the electron blocking layer EBL satisfy the described ranges, satisfactory hole transport properties may be achieved without a substantial increase in driving voltage.

The hole transport region HTR may further include a charge generating material to increase conductivity in addition to the described materials. The charge generating material may be dispersed uniformly or non-uniformly in the hole transport region HTR. The charge generating material may be, for example, a p-dopant. The p-dopant may include at least one selected from among a halogenated metal compound, a quinone derivative, a metal oxide, or a cyano group-containing compound, but the embodiment of the present disclosure is not limited thereto. For example, the p-dopant may include a metal halide compound such as CuI or RbI, a quinone derivative such as tetracyanoquinodimethane (TCNQ) or 2,3,5,6-tetrafluoro-7,7′,8,8-tetracyanoquinodimethane (F4-TCNQ), a metal oxide such as tungsten oxide or molybdenum oxide, a cyano group-containing compound such as dipyrazino[2,3-f: 2′,3′-h] quinoxaline-2,3,6,7,10,11-hexacarbonitrile (HATCN) or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), and/or the like, but the embodiment of the present disclosure is not limited thereto.

As described herein, the hole transport region HTR may further include at least one of the auxiliary emission layer EAL or the electron blocking layer EBL, in addition to the hole injection layer HIL and the hole transport layer HTL. The auxiliary emission layer EAL may compensate a resonance distance according to the wavelength of light emitted from the emission layer EML and regulate a hole charge balance to increase light emitting efficiency. In some embodiments, the auxiliary emission layer EAL may serve to prevent or reduce electrons from being injected into the hole transport region HTR. Materials which may be included in the hole transport region HTR may be utilized as materials included in the auxiliary emission layer EAL. The electron blocking layer EBL is a layer that serves to prevent or reduce electrons from being injected from the electron transport region ETR to the hole transport region HTR.

In the light emitting device ED of one or more embodiments, the emission layer EML may include at least one selected from among the second to fourth compounds, and the first compound. The second compound may include a fused ring of three rings, which contains a nitrogen atom as a ring-forming atom. The third compound may include a 6-membered ring group containing at least one nitrogen atom as a ring-forming atom. The fourth compound may include an organometallic complex. The second to fourth compounds will be described in more detail later.

Herein, the first compound may be referred to as a fused polycyclic compound of one or more embodiments. The fused polycyclic compound of one or more embodiments may include, as a central structure, a fused ring of five rings, which contains two nitrogen atoms and one boron atom as ring-forming atoms. In the central structure of the fused polycyclic compound of one or more embodiments, a substituted pyrrole group or a substituted isoindole group may be bonded to a carbon atom forming a ring. The substituted pyrrole group and the substituted isoindole group are each substituted with a phenyl group, and may be at a position where a nitrogen atom, which is a ring-forming atom of a pyrrole group and an isoindole group, is bonded to the central structure.

The light emitting device ED of one or more embodiments may include the fused polycyclic compound of one or more embodiments. The fused polycyclic compound of one or more embodiments may be represented by Formula 1.

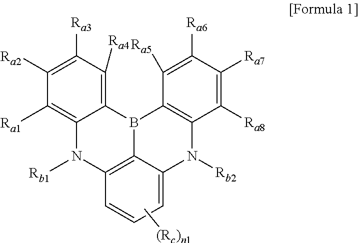

In Formula 1, Rₐ₁ to Rₐ₈ may each independently be represented by Formula 2, a hydrogen atom, a deuterium atom, or a substituted or unsubstituted aryl group having 6 to 30 ring-forming carbon atoms, and at least one of Rₐ₁ to Rₐ₈ is represented by Formula 2. For example, any one selected from among Rₐ₅ to Rₐ₈ may be represented by Formula 2. In some embodiments, any one selected from among Rₐ₁ to Rₐ₄ and any one selected from among Rₐ₅ to Rₐ₈ may each independently be represented by Formula 2.

n1 may be an integer of 0 to 3. When n1 is an integer of 2 or greater, a plurality of R_{c}'s may all be the same or at least one may be different from the others.

R_{b1}, R_{b2}, and Re may each independently be a hydrogen atom, a deuterium atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, n1 may be 1 and, Re may be a substituted or unsubstituted t-butyl group, a substituted or unsubstituted aryl amine group, a substituted or unsubstituted phenyl group, a substituted or unsubstituted pyrrole group, a substituted or unsubstituted isoindole group, a substituted or unsubstituted dibenzofuran group, a substituted or unsubstituted carbazole group, or a substituted or unsubstituted acridine group.

R_{b1} and R_{b2} may each independently be a substituted or unsubstituted phenyl group. In one or more embodiments, R_{b1} and R_{b2} may each independently be represented by any one selected from among RB-1 to RB-15.

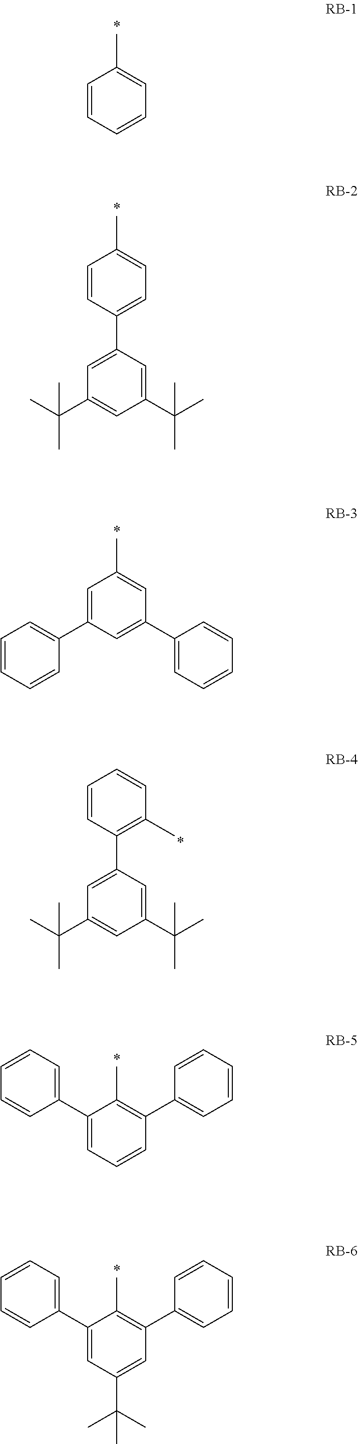

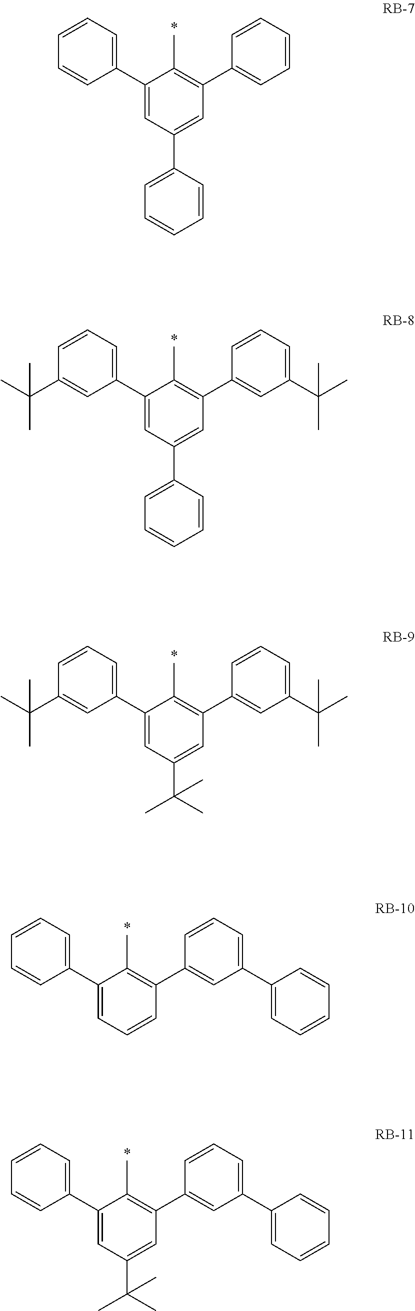

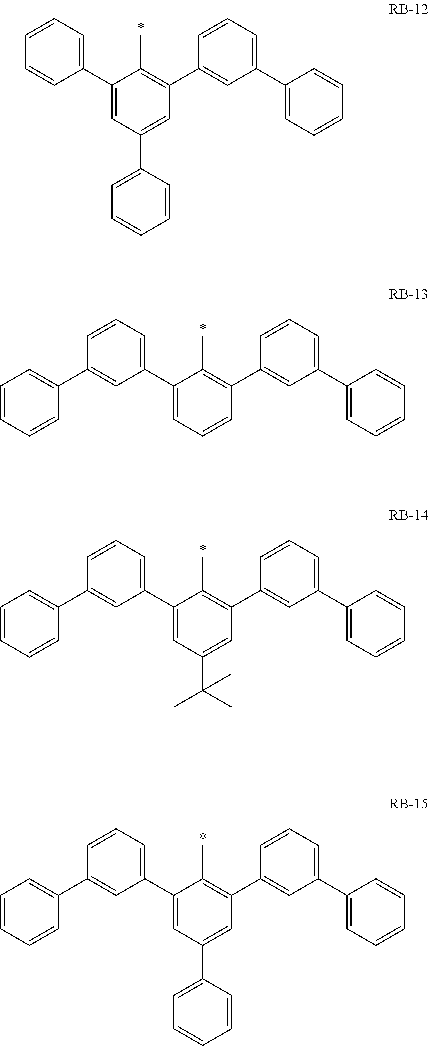

In Formula 1, at least one of Rₐ₁ to Rₐ₈ may be represented by Formula 2. Formula 2 may represent a substituted pyrrole group. In some embodiments, Formula 2 may represent a moiety constituting a substituted isoindole group.

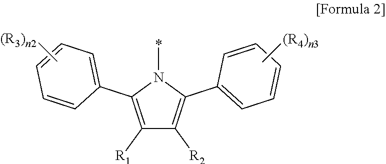

In Formula 2, R₁ and R₂ may each independently be a hydrogen atom, a deuterium atom, a cyano group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring. For example, R₁ and R₂ may each independently be a hydrogen atom, a cyano group, a substituted or unsubstituted methyl group, or a substituted or unsubstituted phenyl group. In some embodiments, R₁ and R₂ may be ethyl groups, and may be bonded to each other to form an isoindole group. R₁ and R₂ may be phenyl groups, and may be bonded to each other to form a dibenzoisoindole group.

n2 and n3 may each independently be an integer of 0 to 5. When n2 is an integer of 2 or greater, a plurality of R₃'s may all be the same or at least one may be different from the others. When n3 is an integer of 2 or greater, a plurality of R₄'s may all be the same or at least one may be different from the others.

R₃ and R₄ may each independently be a hydrogen atom, a deuterium atom, a cyano group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms. For example, R₃ and R₄ may be hydrogen atoms.

In one or more embodiments, Formula 2 may be represented by any one selected from among Formulas 2-1 to 2-6. Formulas 2-1 to 2-6 specifically indicate R₁ to R₄ in Formula 2.

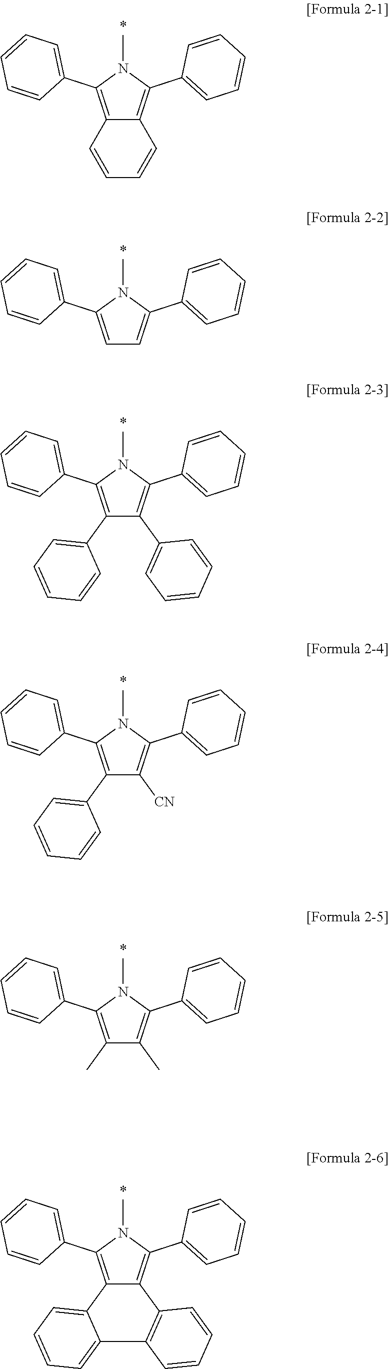 [SMILES: Cn1c(-c2ccccc2)c2ccccc2c1-c1ccccc1 ; Cn1c(-c2ccccc2)ccc1-c1ccccc1 ; Cn1c(-c2ccccc2)c(-c2ccccc2)c(-c2ccccc2)c1-c1ccccc1 ; Cn1c(-c2ccccc2)c(C#N)c(-c2ccccc2)c1-c1ccccc1 ; Cc1c(C)c(-c2ccccc2)n(C)c1-c1ccccc1 ; Cn1c(-c2ccccc2)c2c3ccccc3c3ccccc3c2c1-c1ccccc1]

Formulas 2-1 and 2-6 show cases in which R₁ and R₂ are bonded to each other to form a ring in Formula 2. Formulas 2-2 to 2-5 show cases in which R₁ and R₂ may each independently be a hydrogen atom, an unsubstituted phenyl group, a cyano group, or an unsubstituted methyl group in Formula 2.

In one or more embodiments, Formula 1 may be represented by Formula 1-A1 or Formula 1-A2. Formula 1-A1 shows a case in which Rₐ₂ and Rₐ₇ may each independently be represented by Formula 2 in Formula 1. Formula 1-A2 shows a case in which Rₐ₇ is represented by Formula 2 in Formula 1.

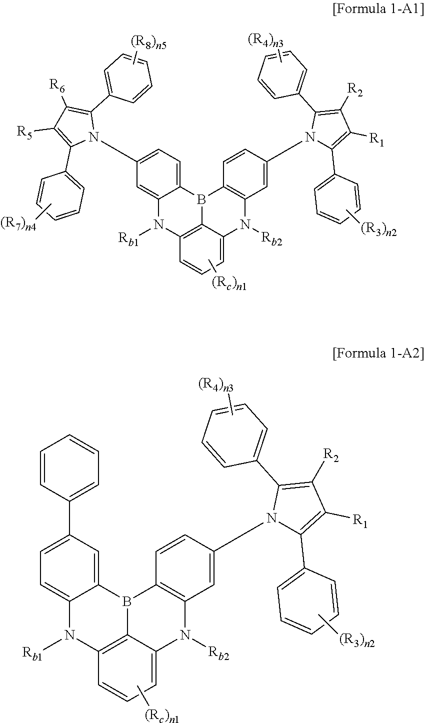

In Formulas 1-A1 and 1-A2, the descriptions of Formulas 1 and 2 may also apply to n1 to n3, R_{b1}, R_{b2}, R_{c}, and R₁ to R₄.

In Formula 1-A1, R₅ and R₆ may each independently be a hydrogen atom, a deuterium atom, a cyano group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring.

n4 and n5 may each independently be an integer of 0 to 5. When n4 is an integer of 2 or greater, a plurality of R₇'s may all be the same or at least one may be different from the others. When n5 is an integer of 2 or greater, a plurality of R₈'s may all be the same or at least one may be different from the others.

R₇ and R₈ may each independently be a hydrogen atom, a deuterium atom, a cyano group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms. For example, R₇ and R₈ may be hydrogen atoms.

In one or more embodiments, Formula 1 may be represented by Formula 1-B. Formula 1-B shows a case in which Rₐ₇ is represented by Formula 2 and R_{b1} and R_{b2} are substituted or unsubstituted phenyl groups in Formula 1.

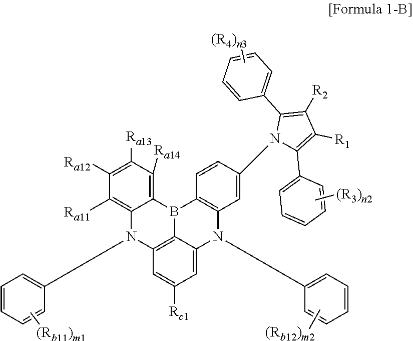

In Formula 1-B, the descriptions of Formula 2 may also apply to n2, n3, and R₁ to R₄.

Rₐ₁₁ to Rₐ₁₄ may each independently be a hydrogen atom, a deuterium atom, or a substituted or unsubstituted aryl group having 6 to 30 ring-forming carbon atoms, or may be represented by Formula 2. For example, Rₐ₁₂ may be represented by Formula 2, and Rₐ₁₁, Rₐ₁₃, and Rₐ₁₄ may be hydrogen atoms. In some embodiments, Rₐ₁₃ may be an unsubstituted phenyl group, and Rₐ₁₁, Rₐ₁₂, and Rₐ₁₄ may be hydrogen atoms.

m1 and m2 may each independently be an integer of 0 to 5. When m1 is an integer of 2 or greater, a plurality of R_{b11}'s may all be the same or at least one may be different from the others. When m2 is an integer of 2 or greater, a plurality of R_{b12}'s may all be the same or at least one may be different from the others.

R_{b11} and R_{b12} may each independently be a hydrogen atom, a deuterium atom, a substituted or unsubstituted alkyl group having 1 to 20 carbon atoms, or a substituted or unsubstituted aryl group having 6 to 30 ring-forming carbon atoms. R_{b11} and R_{b12} may each independently be represented by any one selected from among RB-1 to RB-15 as described herein.

R_{c1} may be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. R_{c1} may be a substituted or unsubstituted t-butyl group, a substituted or unsubstituted aryl amine group, a substituted or unsubstituted phenyl group, a substituted or unsubstituted pyrrole group, a substituted or unsubstituted isoindole group, a substituted or unsubstituted dibenzofuran group, a substituted or unsubstituted carbazole group, or a substituted or unsubstituted acridine group.

R_{c1} may be represented by any one selected from among RC-1 to RC-15. RC-1 represents an unsubstituted t-butyl group, and RC-2 represents an unsubstituted phenyl group. RC-3 to RC-6 represent substituted phenyl groups, and RC-7 to RC-9 represent substituted carbazole groups. RC-10 represents an unsubstituted dibenzofuran group, and RC-11 represents a substituted isoindole group. RC-12 and RC-13 represent substituted pyrrole groups, and RC-14 represent substituted or unsubstituted aryl amine groups. RC-15 represents a substituted acridine group. In RC-8, D is a deuterium atom.

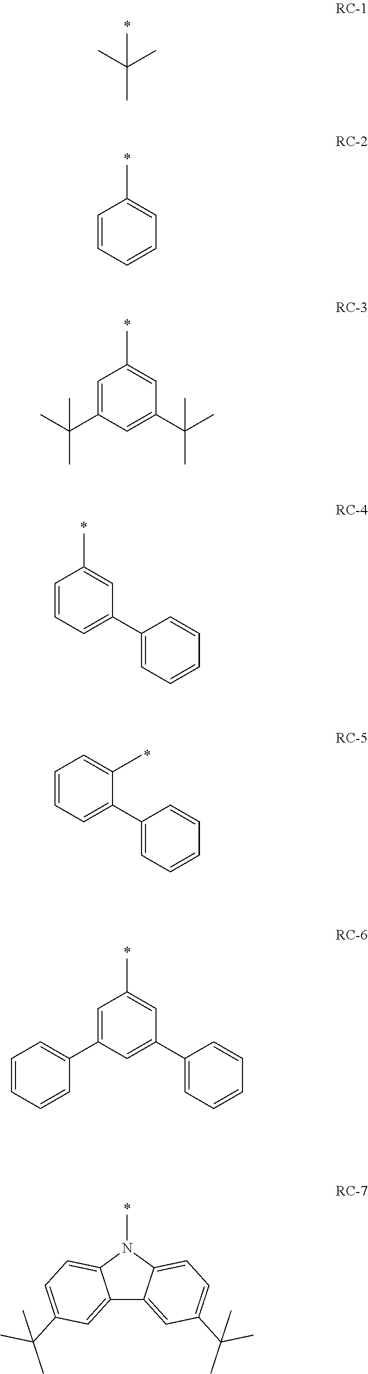

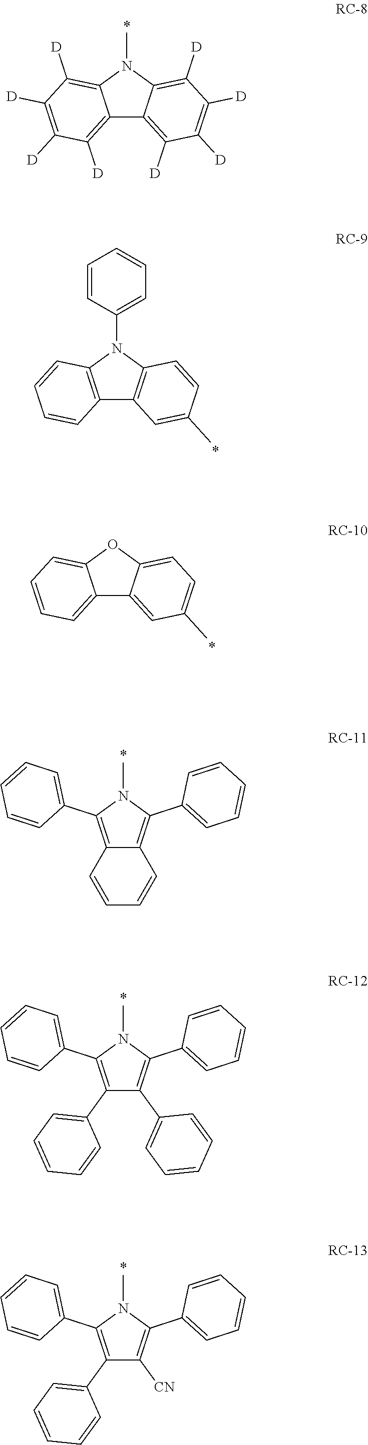 [SMILES: [2H]c1c([2H])c([2H])c2c(c1[2H])c1c([2H])c([2H])c([2H])c([2H])c1n2C ; Cc1ccc2c(c1)c1ccccc1n2-c1ccccc1 ; Cc1ccc2oc3ccccc3c2c1 ; Cn1c(-c2ccccc2)c2ccccc2c1-c1ccccc1 ; Cn1c(-c2ccccc2)c(-c2ccccc2)c(-c2ccccc2)c1-c1ccccc1 ; Cn1c(-c2ccccc2)c(C#N)c(-c2ccccc2)c1-c1ccccc1]

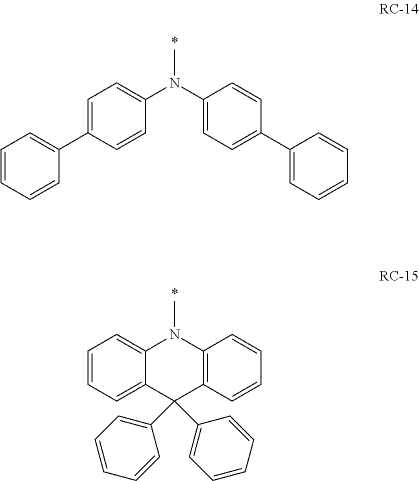 [SMILES: CN(c1ccc(-c2ccccc2)cc1)c1ccc(-c2ccccc2)cc1 ; CN1c2ccccc2C(c2ccccc2)(c2ccccc2)c2ccccc21]

In one or more embodiments, Formula 1-B may be represented by Formula 1-B1 or Formula 1-B2. Formulas 1-B1 and 1-B2 specifically indicate m1, m2, R_{b11} and R_{b12} in Formula 1-B.

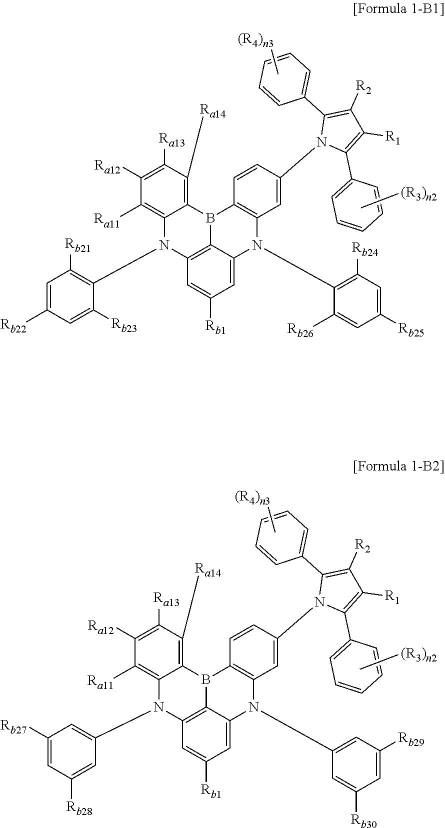

In Formulas 1-B1 and 1-B2, the descriptions of Formula 1-B may also apply to n2, n3, R₁ to R₄, Rₐ₁₁ to Rₐ₁₄, and R_{c1}. R_{b21} to R_{b30} may each independently be a hydrogen atom, a deuterium atom, a substituted or unsubstituted t-butyl group, or a substituted or unsubstituted phenyl group.

For example, in Formula 1-B1, at least one selected from among R_{b21} to R_{b23} and at least one selected from among R_{b24} to R_{b26} may each independently be a substituted or unsubstituted t-butyl group or a substituted or unsubstituted phenyl group. In Formula 1-B2, at least one selected from R_{b27} and/or R_{b28} and at least one selected from among R_{b29} and/or R_{b30} may each independently be a substituted or unsubstituted t-butyl group or a substituted or unsubstituted phenyl group.

The fused polycyclic compound of one or more embodiments may be represented by any one selected from among compounds of Compound Group 1. The light emitting device ED of one or more embodiments may include at least one selected from among the compounds from Compound Group 1. In Compound Group 1, D is a deuterium atom.

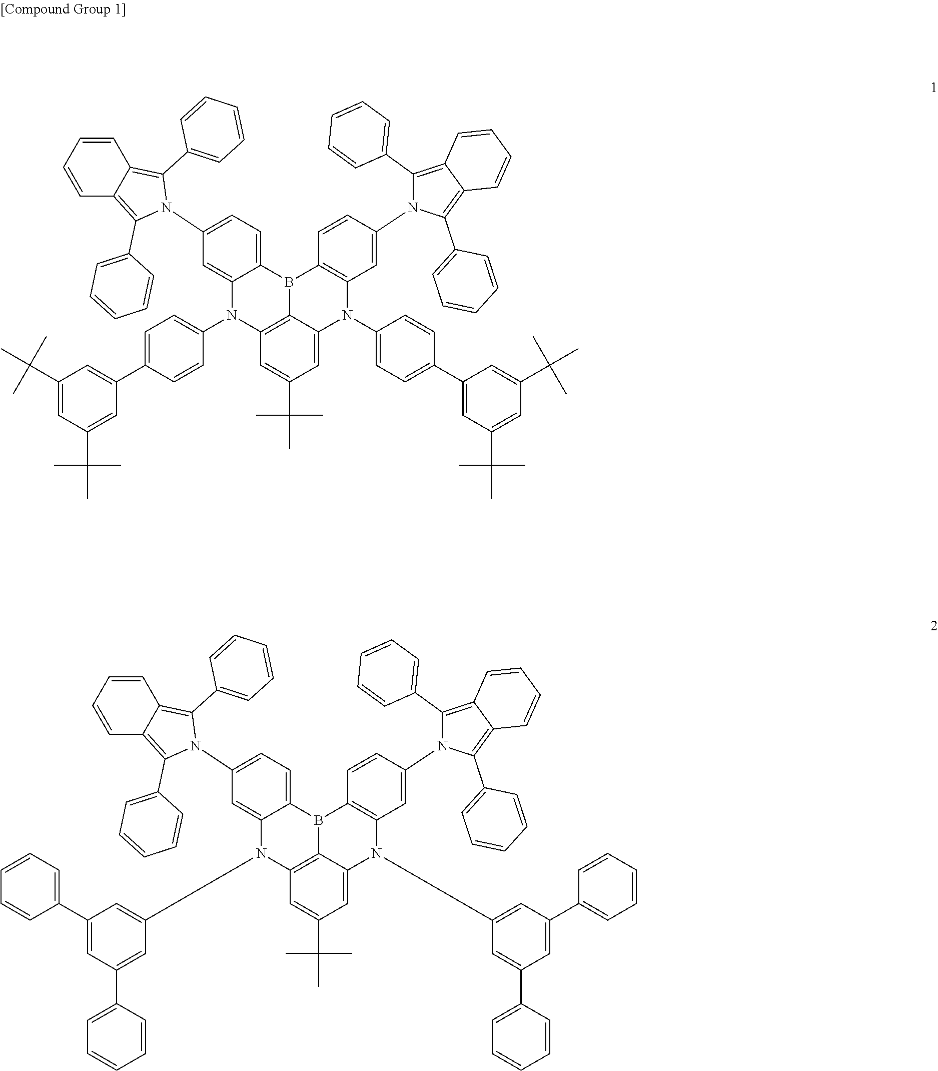 [SMILES: CC(C)(C)c1cc(-c2ccc(N3c4cc(-n5c(-c6ccccc6)c6ccccc6c5-c5ccccc5)ccc4B4c5ccc(-n6c(-c7ccccc7)c7ccccc7c6-c6ccccc6)cc5N(c5ccc(-c6cc(C(C)(C)C)cc(C(C)(C)C)c6)cc5)c5cc(C(C)(C)C)cc3c54)cc2)cc(C(C)(C)C)c1 ; CC(C)(C)c1cc2c3c(c1)N(c1cc(-c4ccccc4)cc(-c4ccccc4)c1)c1cc(-n4c(-c5ccccc5)c5ccccc5c4-c4ccccc4)ccc1B3c1ccc(-n3c(-c4ccccc4)c4ccccc4c3-c3ccccc3)cc1N2c1cc(-c2ccccc2)cc(-c2ccccc2)c1]

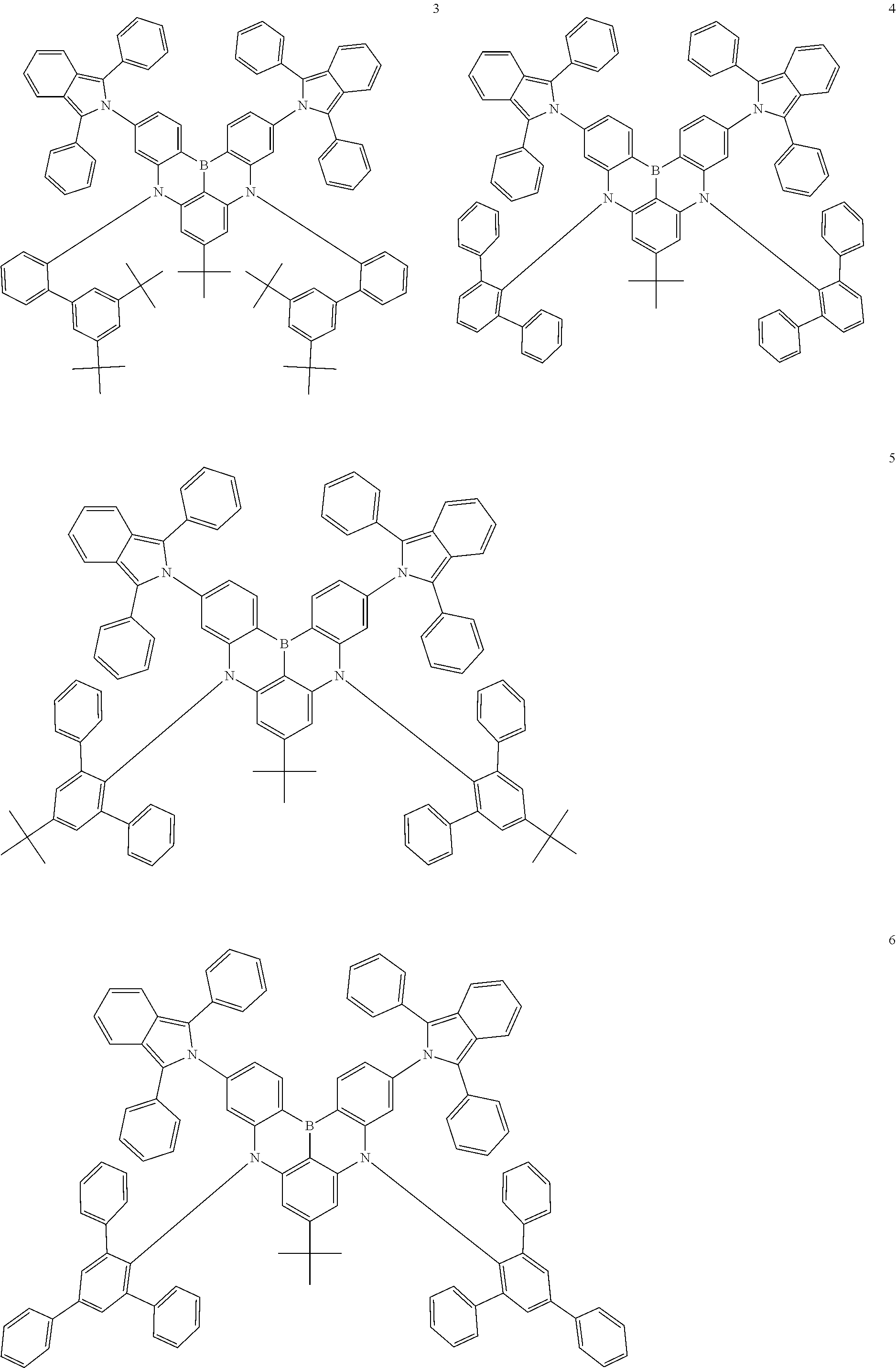

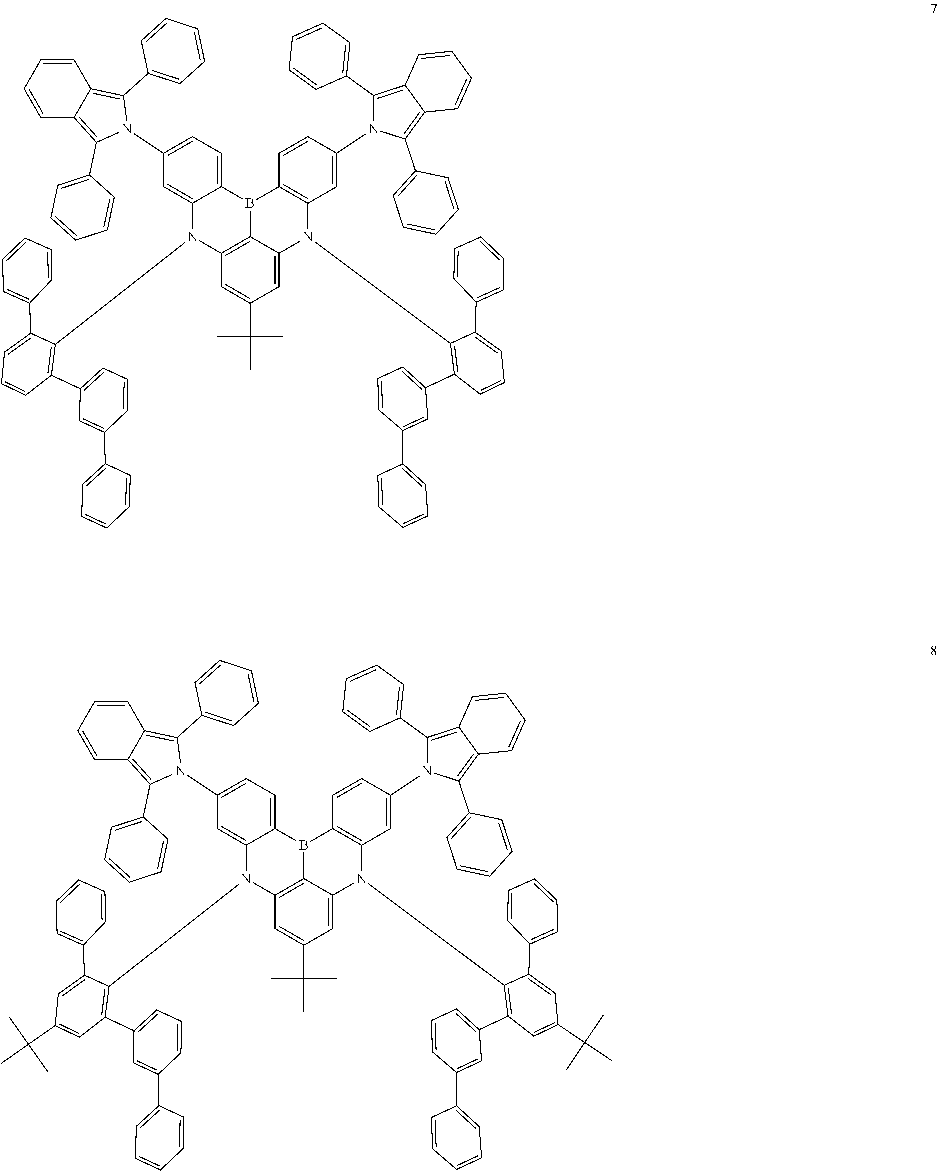 [SMILES: CC(C)(C)c1cc2c3c(c1)N(c1c(-c4ccccc4)cccc1-c1cccc(-c4ccccc4)c1)c1cc(-n4c(-c5ccccc5)c5ccccc5c4-c4ccccc4)ccc1B3c1ccc(-n3c(-c4ccccc4)c4ccccc4c3-c3ccccc3)cc1N2c1c(-c2ccccc2)cccc1-c1cccc(-c2ccccc2)c1 ; CC(C)(C)c1cc(-c2ccccc2)c(N2c3cc(-n4c(-c5ccccc5)c5ccccc5c4-c4ccccc4)ccc3B3c4ccc(-n5c(-c6ccccc6)c6ccccc6c5-c5ccccc5)cc4N(c4c(-c5ccccc5)cc(C(C)(C)C)cc4-c4cccc(-c5ccccc5)c4)c4cc(C(C)(C)C)cc2c43)c(-c2cccc(-c3ccccc3)c2)c1]

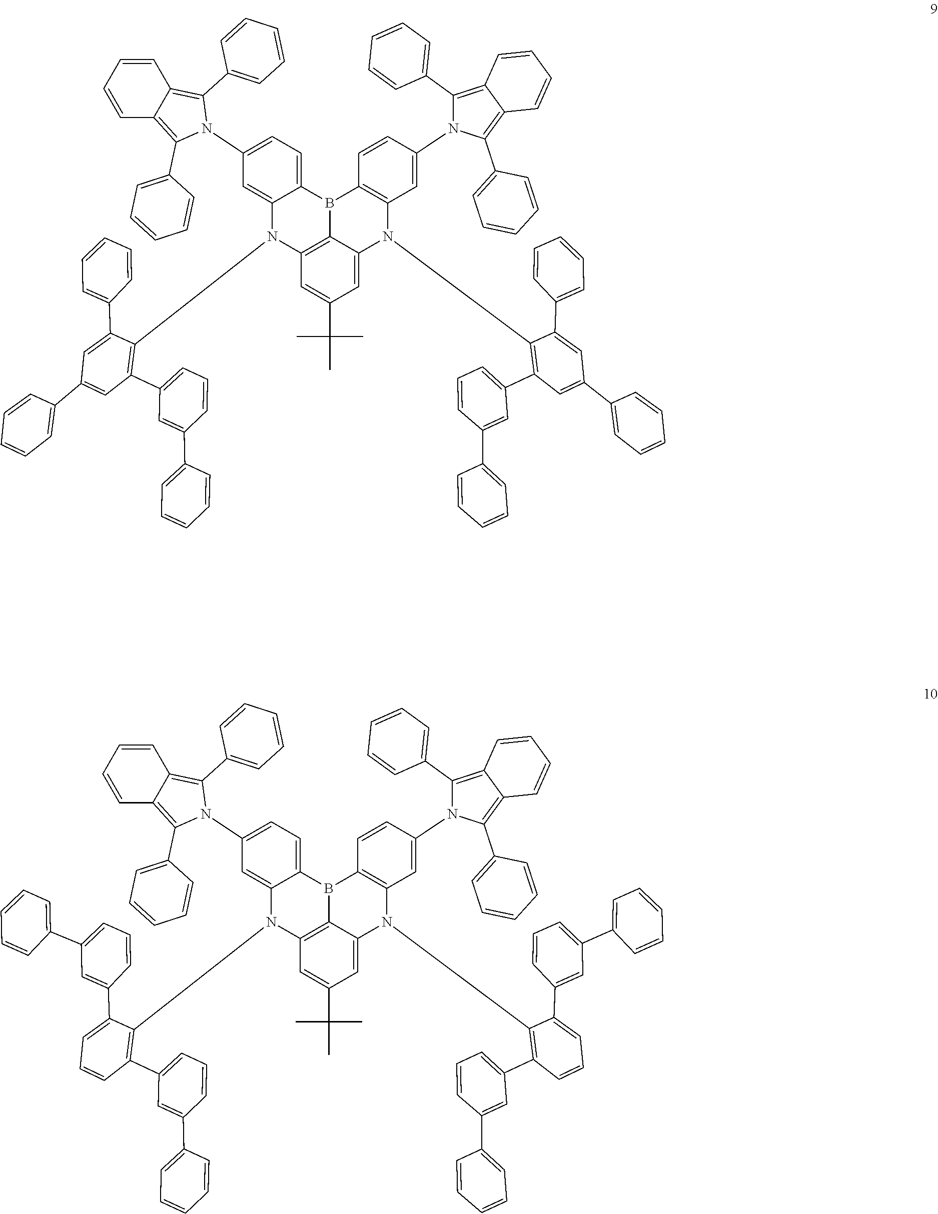 [SMILES: CC(C)(C)c1cc2c3c(c1)N(c1c(-c4ccccc4)cc(-c4ccccc4)cc1-c1cccc(-c4ccccc4)c1)c1cc(-n4c(-c5ccccc5)c5ccccc5c4-c4ccccc4)ccc1B3c1ccc(-n3c(-c4ccccc4)c4ccccc4c3-c3ccccc3)cc1N2c1c(-c2ccccc2)cc(-c2ccccc2)cc1-c1cccc(-c2ccccc2)c1 ; CC(C)(C)c1cc2c3c(c1)N(c1c(-c4cccc(-c5ccccc5)c4)cccc1-c1cccc(-c4ccccc4)c1)c1cc(-n4c(-c5ccccc5)c5ccccc5c4-c4ccccc4)ccc1B3c1ccc(-n3c(-c4ccccc4)c4ccccc4c3-c3ccccc3)cc1N2c1c(-c2cccc(-c3ccccc3)c2)cccc1-c1cccc(-c2ccccc2)c1]

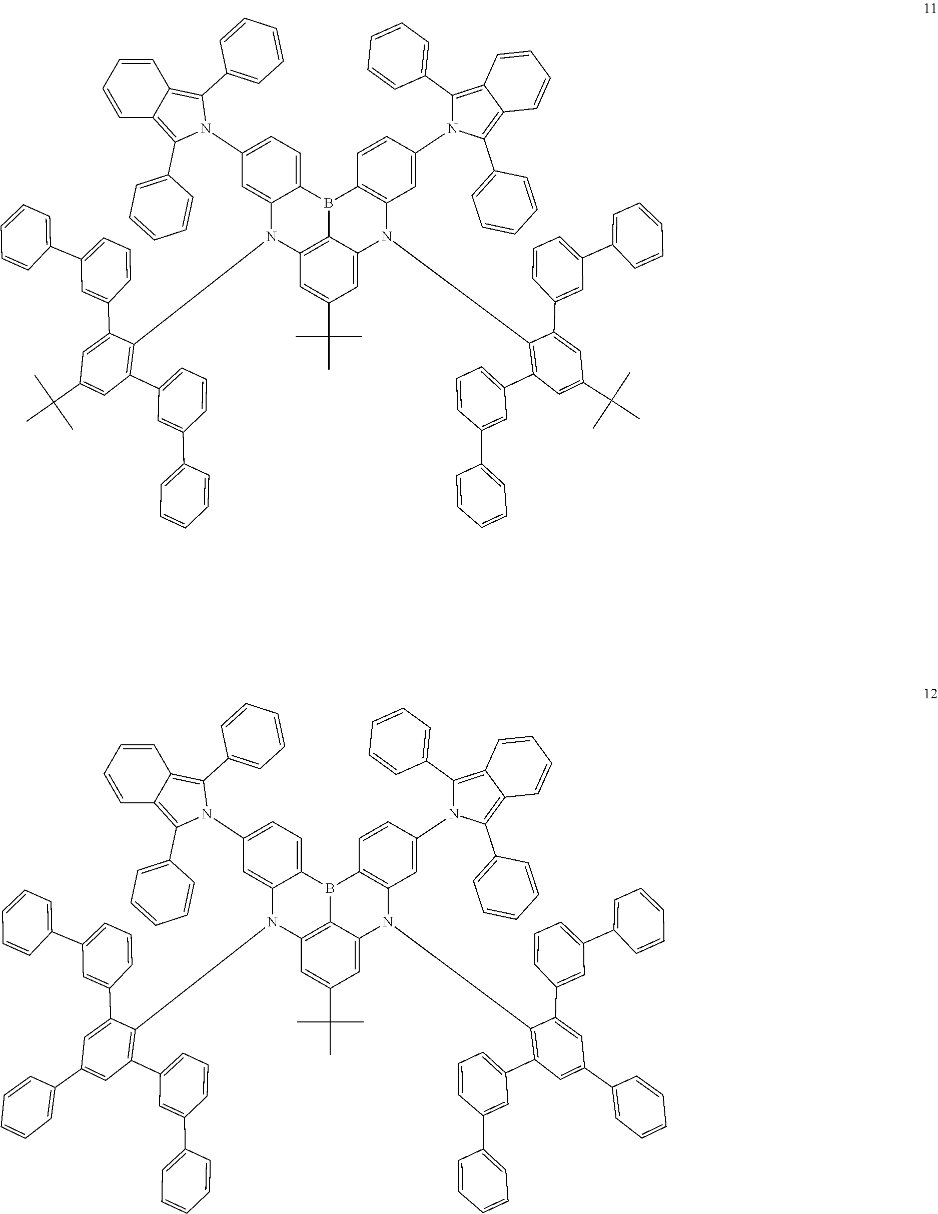 [SMILES: CC(C)(C)c1cc(-c2cccc(-c3ccccc3)c2)c(N2c3cc(-n4c(-c5ccccc5)c5ccccc5c4-c4ccccc4)ccc3B3c4ccc(-n5c(-c6ccccc6)c6ccccc6c5-c5ccccc5)cc4N(c4c(-c5cccc(-c6ccccc6)c5)cc(C(C)(C)C)cc4-c4cccc(-c5ccccc5)c4)c4cc(C(C)(C)C)cc2c43)c(-c2cccc(-c3ccccc3)c2)c1 ; CC(C)(C)c1cc2c3c(c1)N(c1c(-c4cccc(-c5ccccc5)c4)cc(-c4ccccc4)cc1-c1cccc(-c4ccccc4)c1)c1cc(-n4c(-c5ccccc5)c5ccccc5c4-c4ccccc4)ccc1B3c1ccc(-n3c(-c4ccccc4)c4ccccc4c3-c3ccccc3)cc1N2c1c(-c2cccc(-c3ccccc3)c2)cc(-c2ccccc2)cc1-c1cccc(-c2ccccc2)c1]

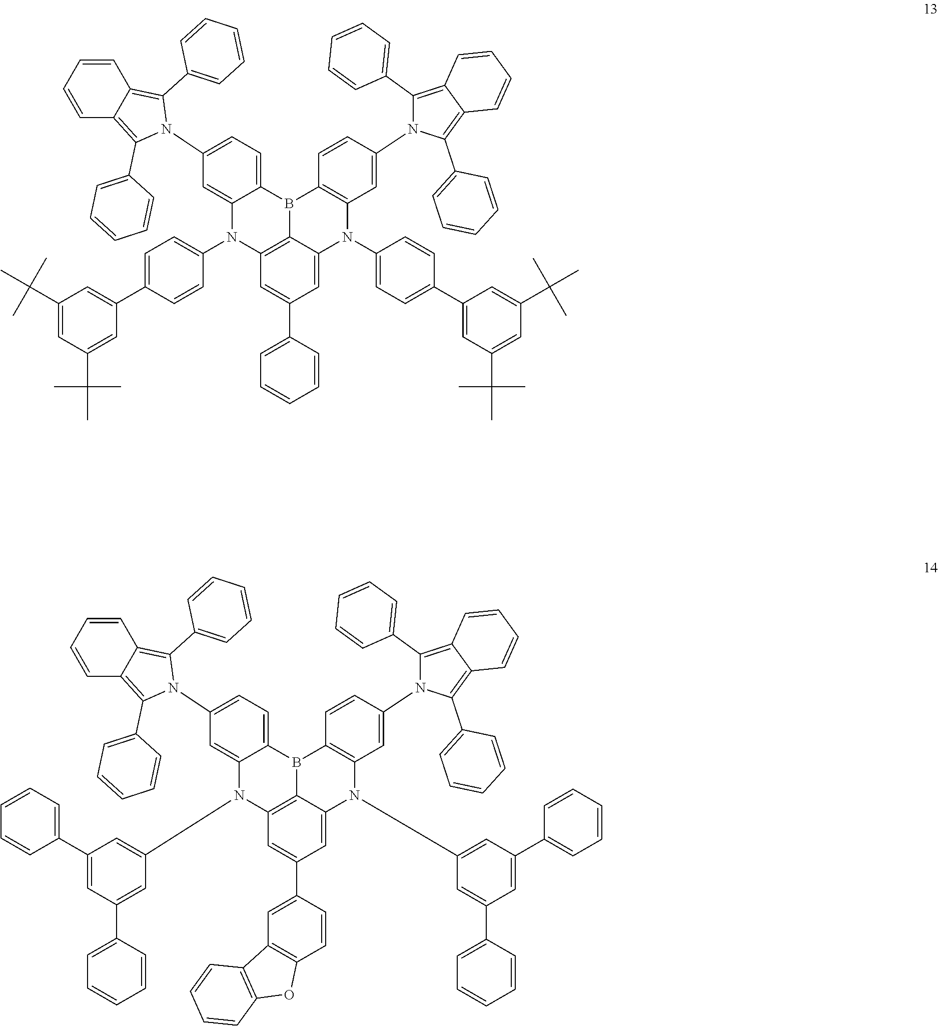 [SMILES: CC(C)(C)c1cc(-c2ccc(N3c4cc(-n5c(-c6ccccc6)c6ccccc6c5-c5ccccc5)ccc4B4c5ccc(-n6c(-c7ccccc7)c7ccccc7c6-c6ccccc6)cc5N(c5ccc(-c6cc(C(C)(C)C)cc(C(C)(C)C)c6)cc5)c5cc(-c6ccccc6)cc3c54)cc2)cc(C(C)(C)C)c1 ; c1ccc(-c2cc(-c3ccccc3)cc(N3c4cc(-n5c(-c6ccccc6)c6ccccc6c5-c5ccccc5)ccc4B4c5ccc(-n6c(-c7ccccc7)c7ccccc7c6-c6ccccc6)cc5N(c5cc(-c6ccccc6)cc(-c6ccccc6)c5)c5cc(-c6ccc7oc8ccccc8c7c6)cc3c54)c2)cc1]

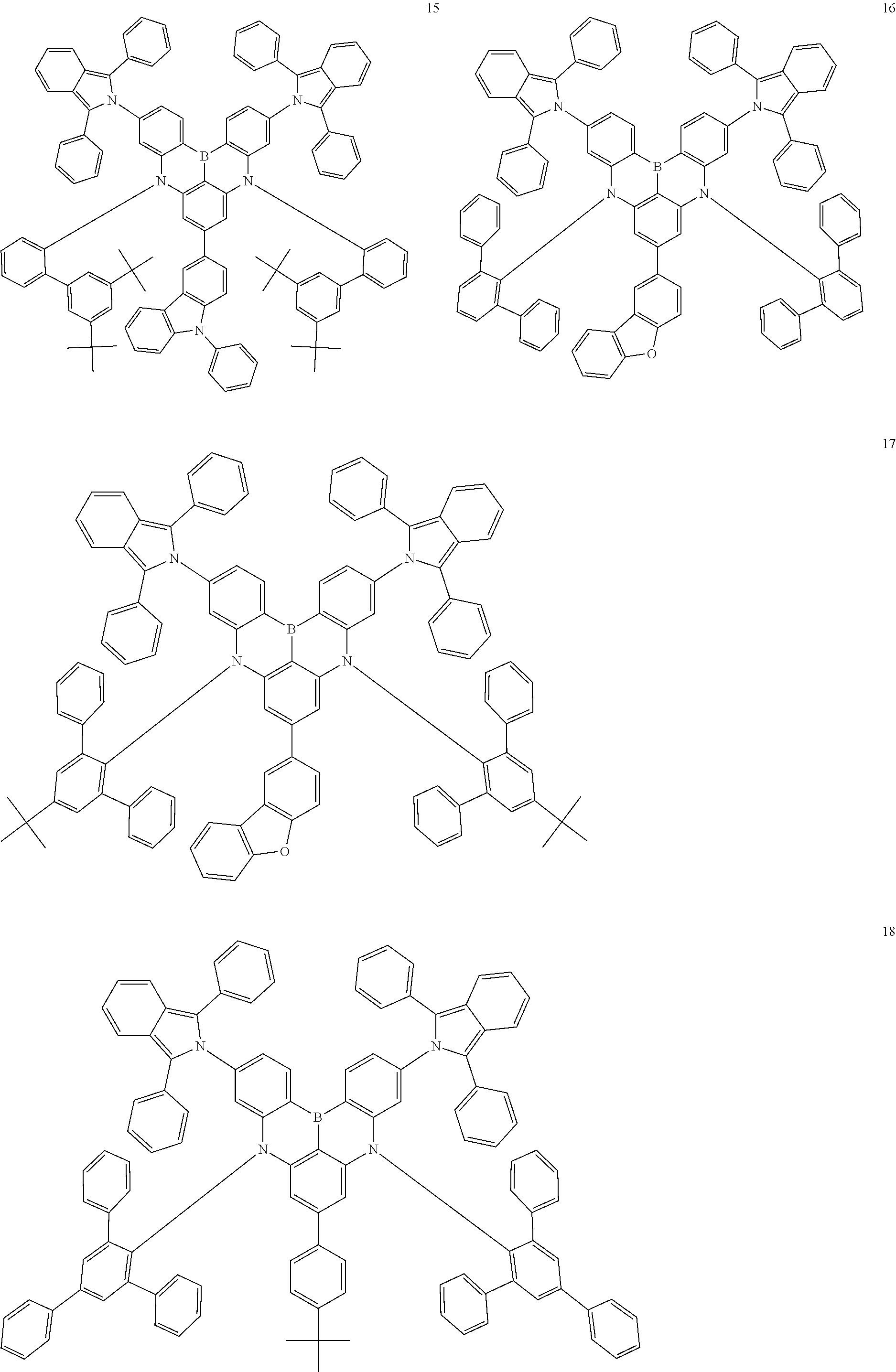

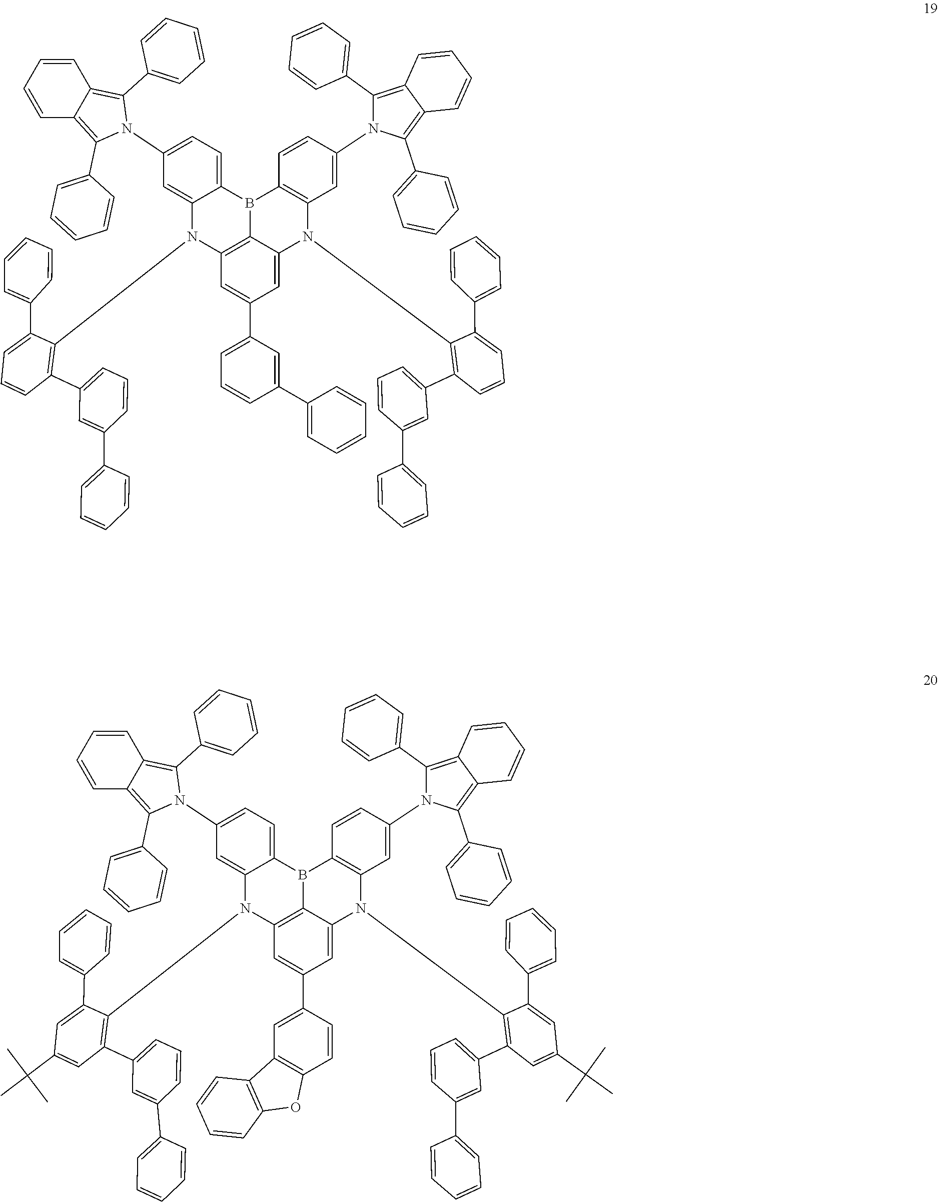 [SMILES: c1ccc(-c2cccc(-c3cc4c5c(c3)N(c3c(-c6ccccc6)cccc3-c3cccc(-c6ccccc6)c3)c3cc(-n6c(-c7ccccc7)c7ccccc7c6-c6ccccc6)ccc3B5c3ccc(-n5c(-c6ccccc6)c6ccccc6c5-c5ccccc5)cc3N4c3c(-c4ccccc4)cccc3-c3cccc(-c4ccccc4)c3)c2)cc1 ; CC(C)(C)c1cc(-c2ccccc2)c(N2c3cc(-n4c(-c5ccccc5)c5ccccc5c4-c4ccccc4)ccc3B3c4ccc(-n5c(-c6ccccc6)c6ccccc6c5-c5ccccc5)cc4N(c4c(-c5ccccc5)cc(C(C)(C)C)cc4-c4cccc(-c5ccccc5)c4)c4cc(-c5ccc6oc7ccccc7c6c5)cc2c43)c(-c2cccc(-c3ccccc3)c2)c1]

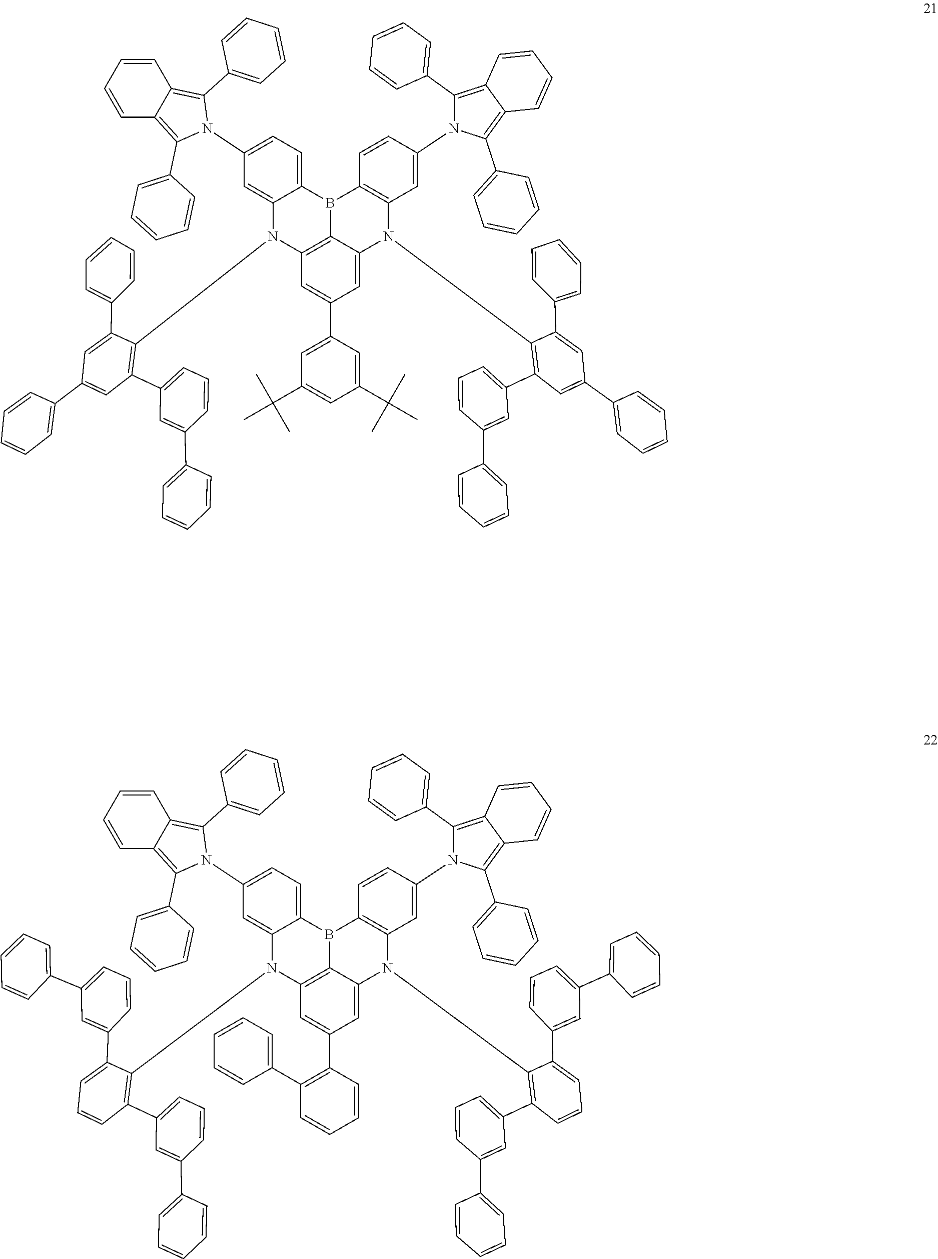 [SMILES: CC(C)(C)c1cc(-c2cc3c4c(c2)N(c2c(-c5ccccc5)cc(-c5ccccc5)cc2-c2cccc(-c5ccccc5)c2)c2cc(-n5c(-c6ccccc6)c6ccccc6c5-c5ccccc5)ccc2B4c2ccc(-n4c(-c5ccccc5)c5ccccc5c4-c4ccccc4)cc2N3c2c(-c3ccccc3)cc(-c3ccccc3)cc2-c2cccc(-c3ccccc3)c2)cc(C(C)(C)C)c1 ; c1ccc(-c2cccc(-c3cccc(-c4cccc(-c5ccccc5)c4)c3N3c4cc(-n5c(-c6ccccc6)c6ccccc6c5-c5ccccc5)ccc4B4c5ccc(-n6c(-c7ccccc7)c7ccccc7c6-c6ccccc6)cc5N(c5c(-c6cccc(-c7ccccc7)c6)cccc5-c5cccc(-c6ccccc6)c5)c5cc(-c6ccccc6-c6ccccc6)cc3c54)c2)cc1]

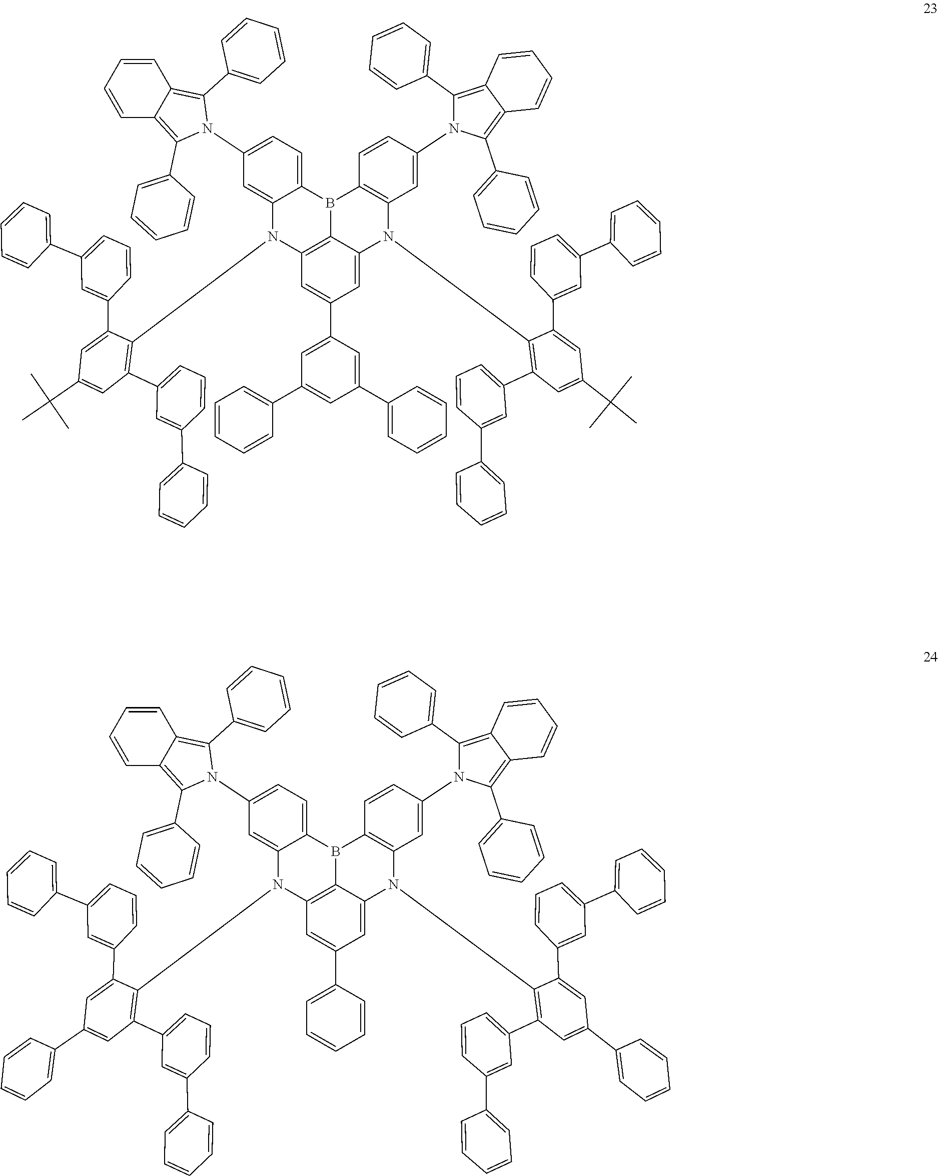

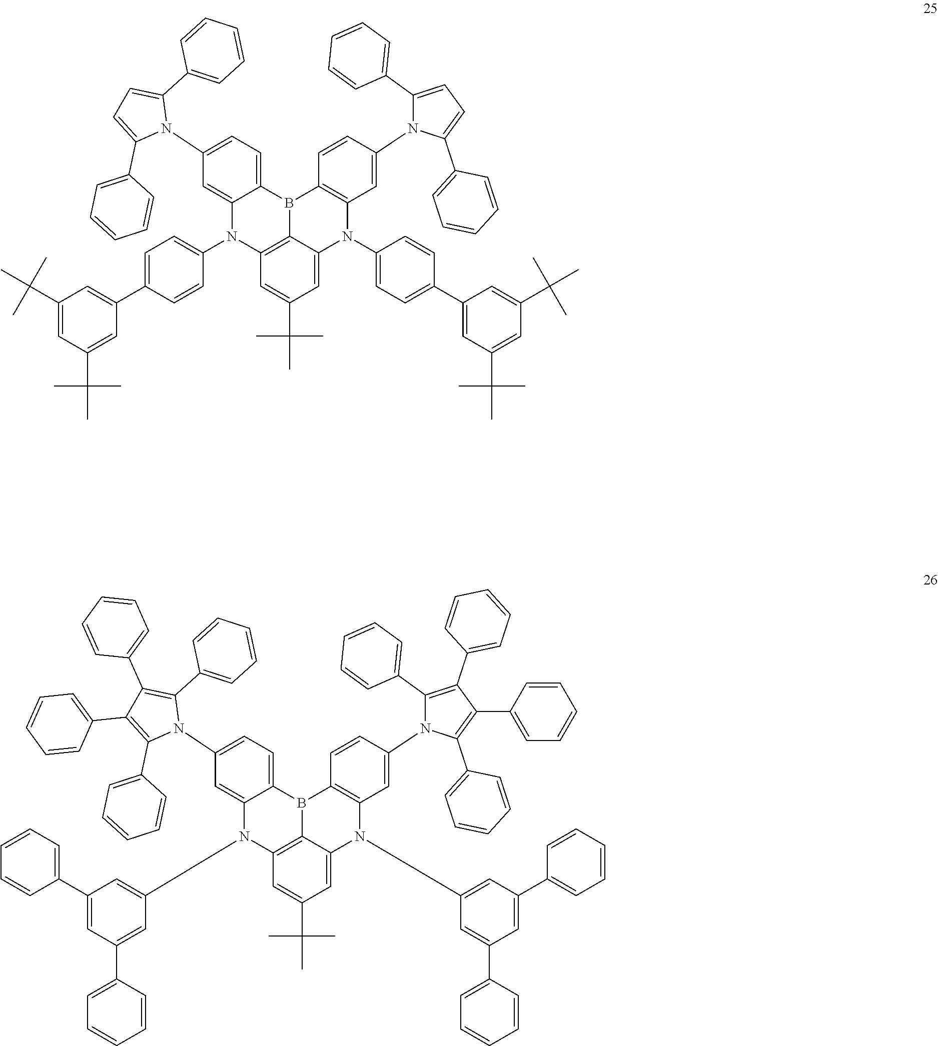 [SMILES: CC(C)(C)c1cc(-c2ccc(N3c4cc(-n5c(-c6ccccc6)ccc5-c5ccccc5)ccc4B4c5ccc(-n6c(-c7ccccc7)ccc6-c6ccccc6)cc5N(c5ccc(-c6cc(C(C)(C)C)cc(C(C)(C)C)c6)cc5)c5cc(C(C)(C)C)cc3c54)cc2)cc(C(C)(C)C)c1 ; CC(C)(C)c1cc2c3c(c1)N(c1cc(-c4ccccc4)cc(-c4ccccc4)c1)c1cc(-n4c(-c5ccccc5)c(-c5ccccc5)c(-c5ccccc5)c4-c4ccccc4)ccc1B3c1ccc(-n3c(-c4ccccc4)c(-c4ccccc4)c(-c4ccccc4)c3-c3ccccc3)cc1N2c1cc(-c2ccccc2)cc(-c2ccccc2)c1]

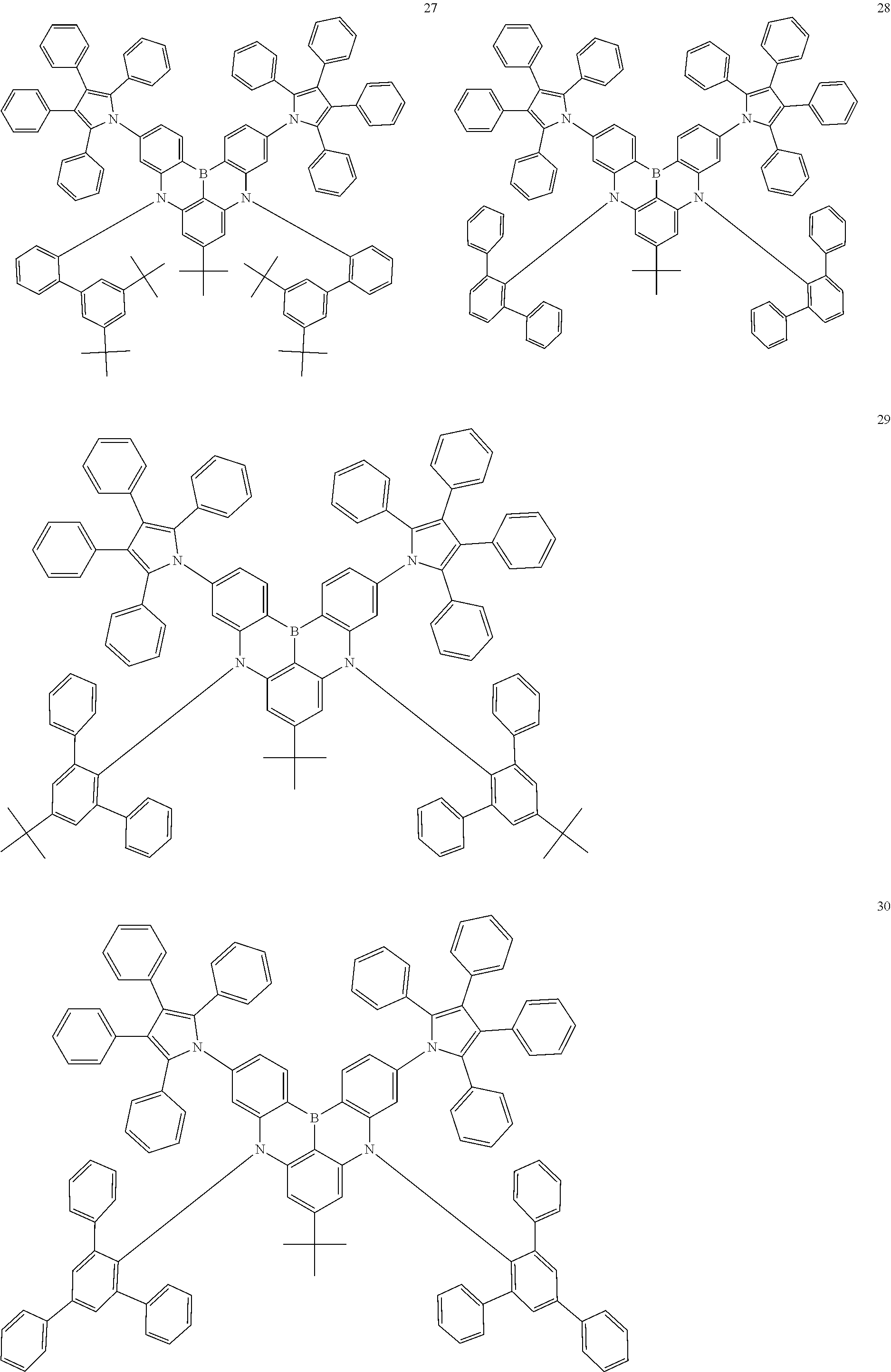

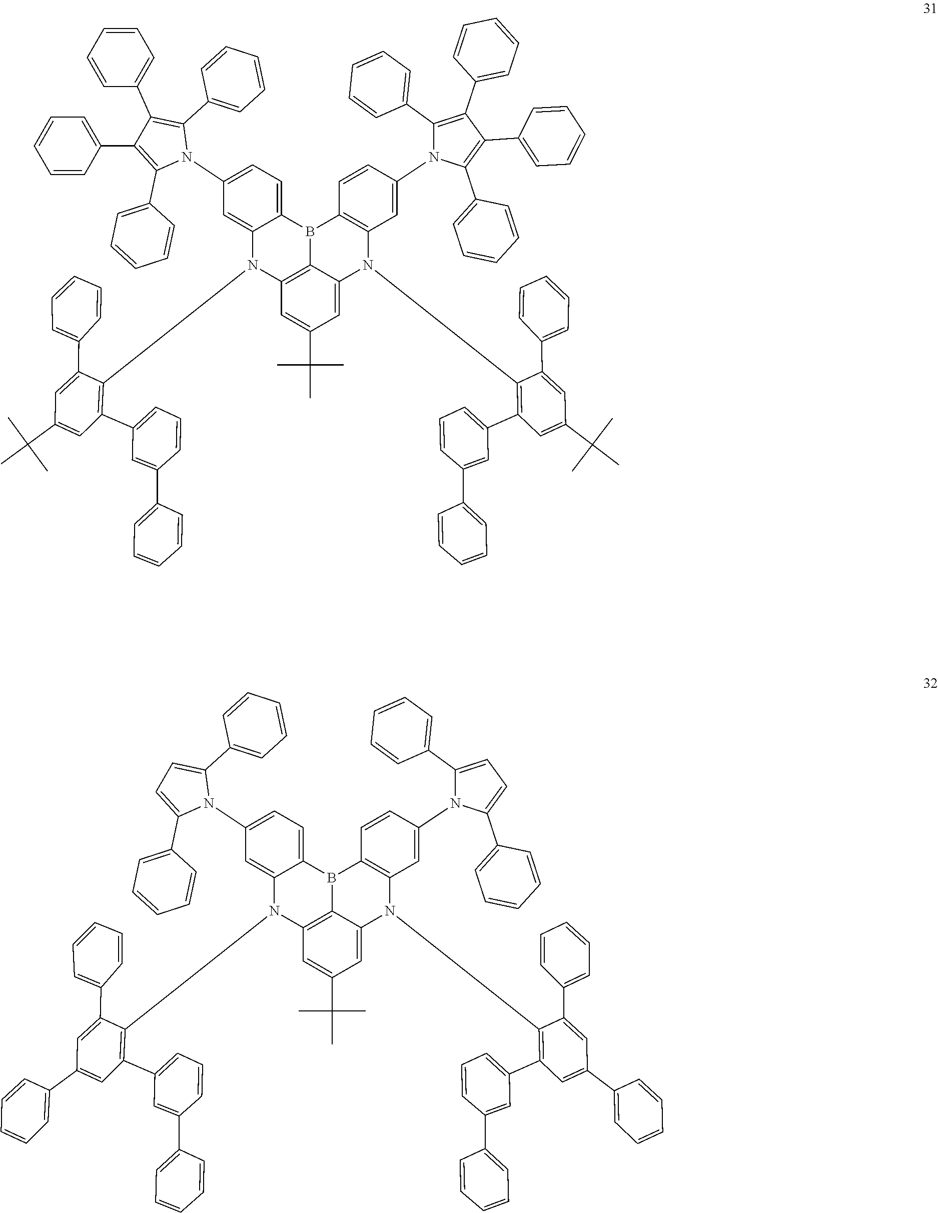 [SMILES: CC(C)(C)c1cc(-c2ccccc2)c(N2c3cc(-n4c(-c5ccccc5)c(-c5ccccc5)c(-c5ccccc5)c4-c4ccccc4)ccc3B3c4ccc(-n5c(-c6ccccc6)c(-c6ccccc6)c(-c6ccccc6)c5-c5ccccc5)cc4N(c4c(-c5ccccc5)cc(C(C)(C)C)cc4-c4cccc(-c5ccccc5)c4)c4cc(C(C)(C)C)cc2c43)c(-c2cccc(-c3ccccc3)c2)c1 ; CC(C)(C)c1cc2c3c(c1)N(c1c(-c4ccccc4)cc(-c4ccccc4)cc1-c1cccc(-c4ccccc4)c1)c1cc(-n4c(-c5ccccc5)ccc4-c4ccccc4)ccc1B3c1ccc(-n3c(-c4ccccc4)ccc3-c3ccccc3)cc1N2c1c(-c2ccccc2)cc(-c2ccccc2)cc1-c1cccc(-c2ccccc2)c1]

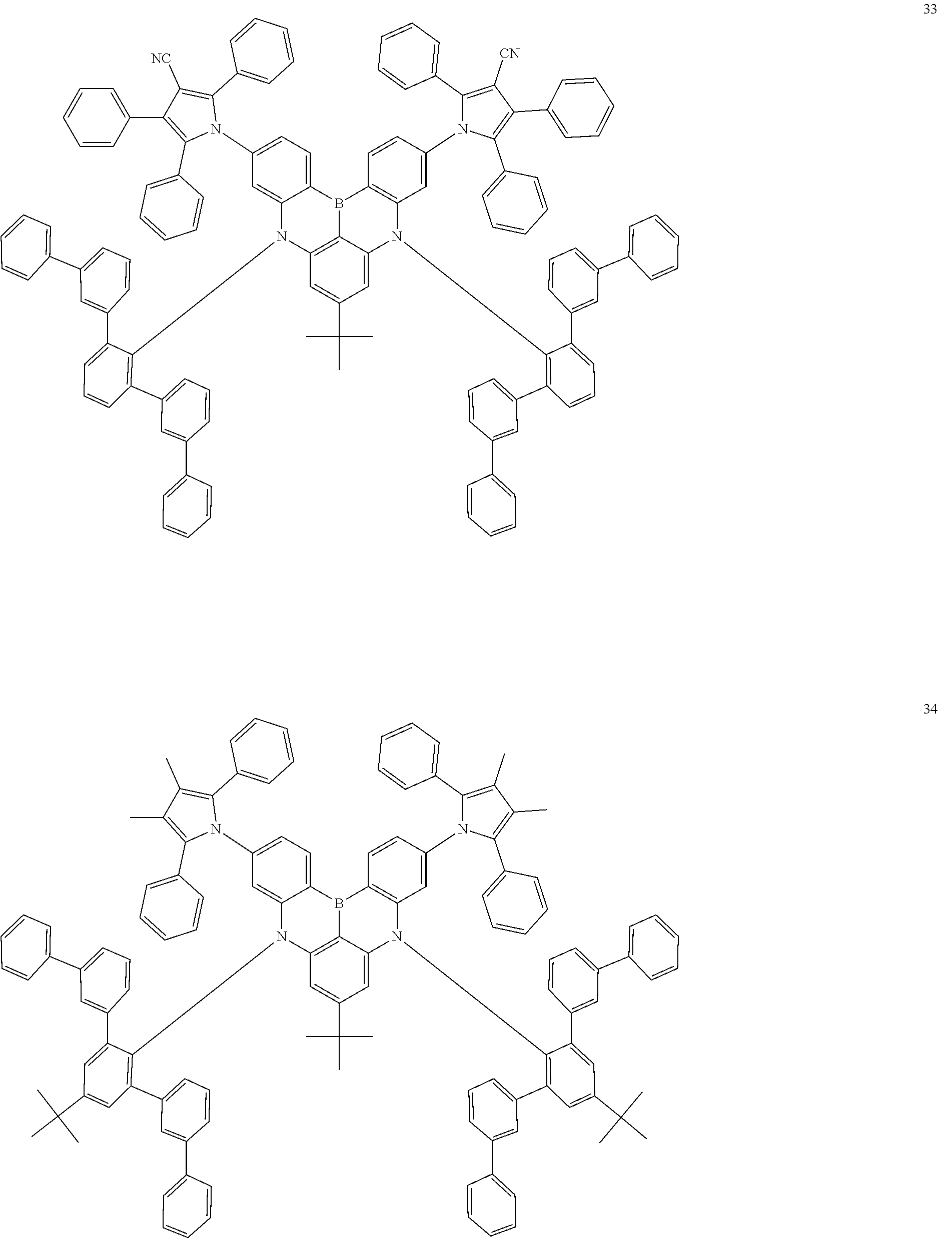 [SMILES: CC(C)(C)c1cc2c3c(c1)N(c1c(-c4cccc(-c5ccccc5)c4)cccc1-c1cccc(-c4ccccc4)c1)c1cc(-n4c(-c5ccccc5)c(C#N)c(-c5ccccc5)c4-c4ccccc4)ccc1B3c1ccc(-n3c(-c4ccccc4)c(C#N)c(-c4ccccc4)c3-c3ccccc3)cc1N2c1c(-c2cccc(-c3ccccc3)c2)cccc1-c1cccc(-c2ccccc2)c1 ; Cc1c(C)c(-c2ccccc2)n(-c2ccc3c(c2)N(c2c(-c4cccc(-c5ccccc5)c4)cc(C(C)(C)C)cc2-c2cccc(-c4ccccc4)c2)c2cc(C(C)(C)C)cc4c2B3c2ccc(-n3c(-c5ccccc5)c(C)c(C)c3-c3ccccc3)cc2N4c2c(-c3cccc(-c4ccccc4)c3)cc(C(C)(C)C)cc2-c2cccc(-c3ccccc3)c2)c1-c1ccccc1]

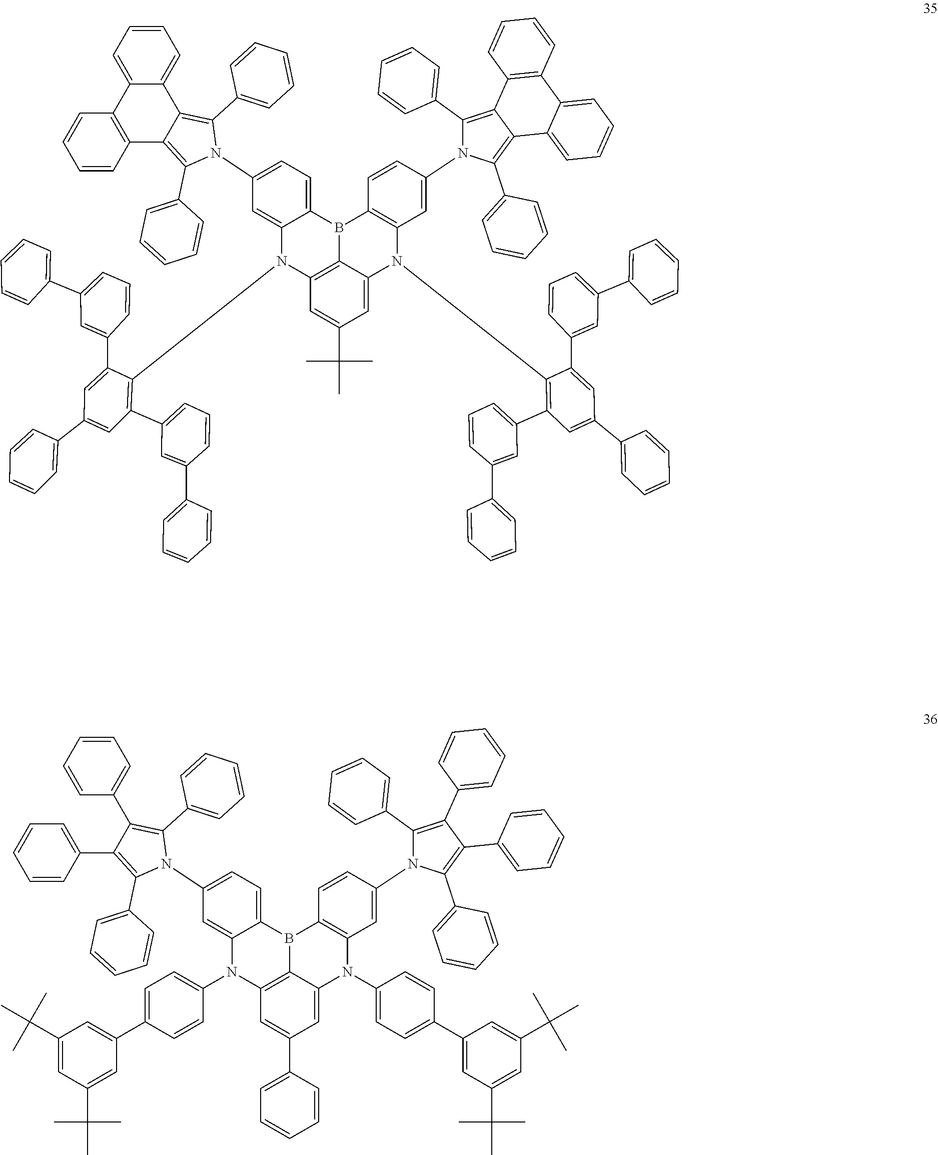 [SMILES: CC(C)(C)c1cc2c3c(c1)N(c1c(-c4cccc(-c5ccccc5)c4)cc(-c4ccccc4)cc1-c1cccc(-c4ccccc4)c1)c1cc(-n4c(-c5ccccc5)c5c6ccccc6c6ccccc6c5c4-c4ccccc4)ccc1B3c1ccc(-n3c(-c4ccccc4)c4c5ccccc5c5ccccc5c4c3-c3ccccc3)cc1N2c1c(-c2cccc(-c3ccccc3)c2)cc(-c2ccccc2)cc1-c1cccc(-c2ccccc2)c1 ; CC(C)(C)c1cc(-c2ccc(N3c4cc(-n5c(-c6ccccc6)c(-c6ccccc6)c(-c6ccccc6)c5-c5ccccc5)ccc4B4c5ccc(-n6c(-c7ccccc7)c(-c7ccccc7)c(-c7ccccc7)c6-c6ccccc6)cc5N(c5ccc(-c6cc(C(C)(C)C)cc(C(C)(C)C)c6)cc5)c5cc(-c6ccccc6)cc3c54)cc2)cc(C(C)(C)C)c1]

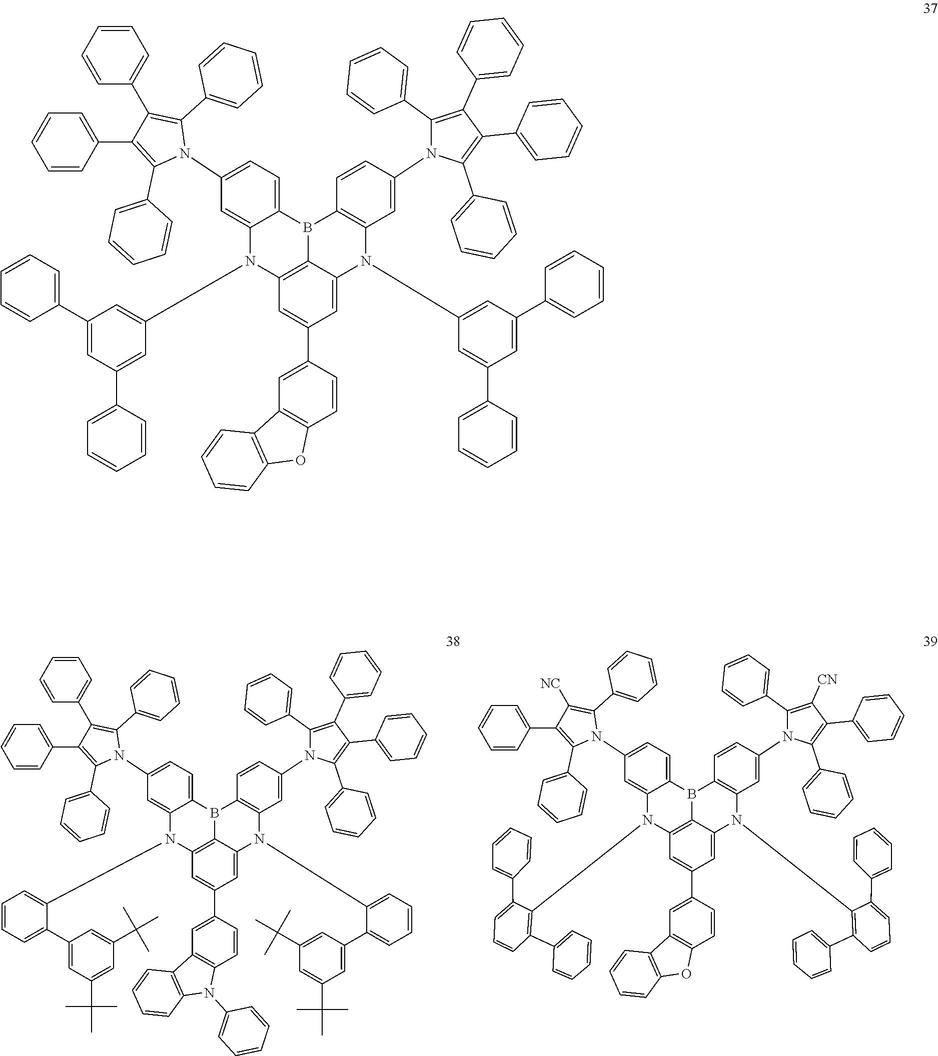

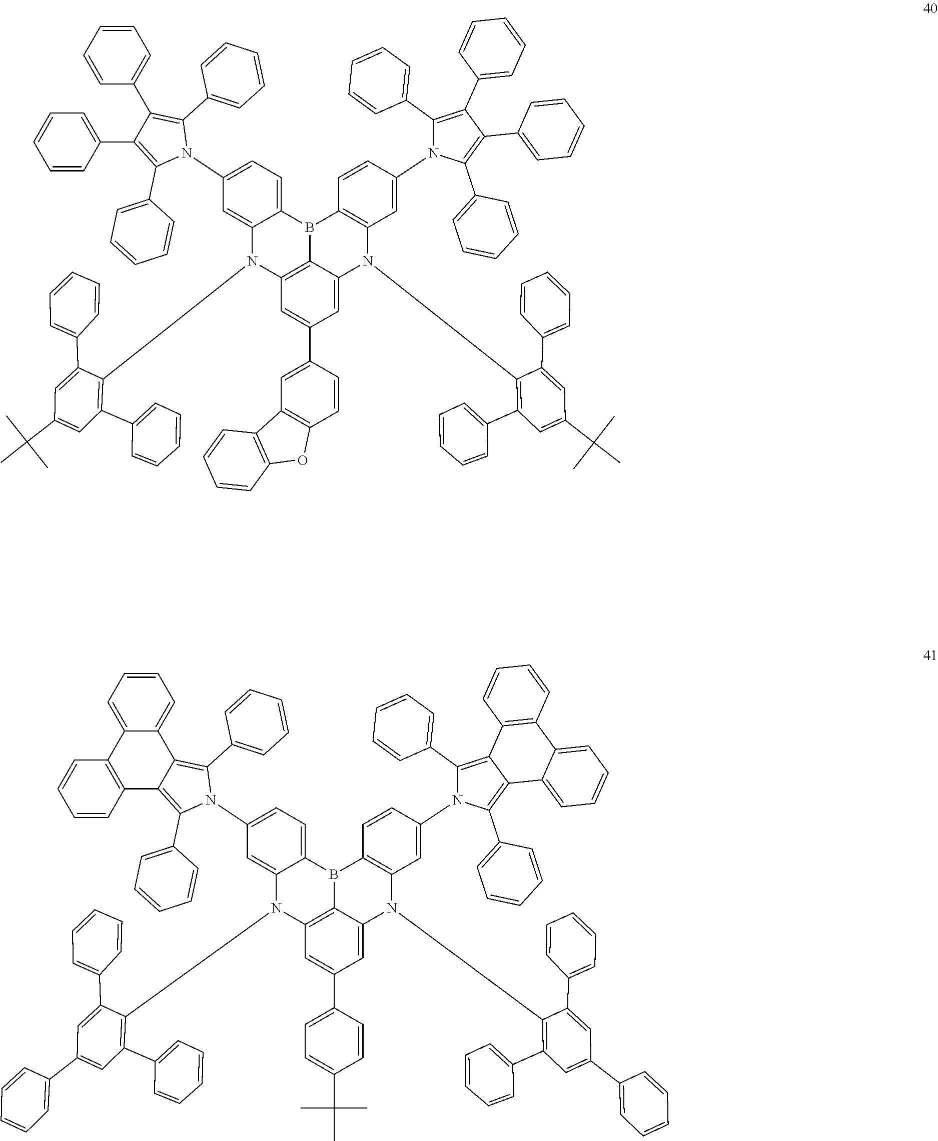 [SMILES: CC(C)(C)c1cc(-c2ccccc2)c(N2c3cc(-n4c(-c5ccccc5)c(-c5ccccc5)c(-c5ccccc5)c4-c4ccccc4)ccc3B3c4ccc(-n5c(-c6ccccc6)c(-c6ccccc6)c(-c6ccccc6)c5-c5ccccc5)cc4N(c4c(-c5ccccc5)cc(C(C)(C)C)cc4-c4ccccc4)c4cc(-c5ccc6oc7ccccc7c6c5)cc2c43)c(-c2ccccc2)c1 ; CC(C)(C)c1ccc(-c2cc3c4c(c2)N(c2c(-c5ccccc5)cc(-c5ccccc5)cc2-c2ccccc2)c2cc(-n5c(-c6ccccc6)c6c7ccccc7c7ccccc7c6c5-c5ccccc5)ccc2B4c2ccc(-n4c(-c5ccccc5)c5c6ccccc6c6ccccc6c5c4-c4ccccc4)cc2N3c2c(-c3ccccc3)cc(-c3ccccc3)cc2-c2ccccc2)cc1]

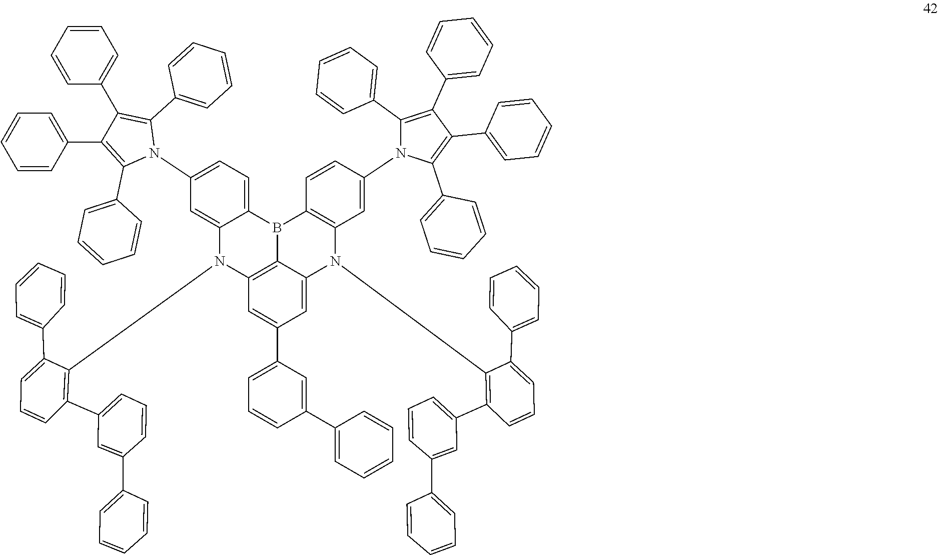 [SMILES: c1ccc(-c2cccc(-c3cc4c5c(c3)N(c3c(-c6ccccc6)cccc3-c3cccc(-c6ccccc6)c3)c3cc(-n6c(-c7ccccc7)c(-c7ccccc7)c(-c7ccccc7)c6-c6ccccc6)ccc3B5c3ccc(-n5c(-c6ccccc6)c(-c6ccccc6)c(-c6ccccc6)c5-c5ccccc5)cc3N4c3c(-c4ccccc4)cccc3-c3cccc(-c4ccccc4)c3)c2)cc1]

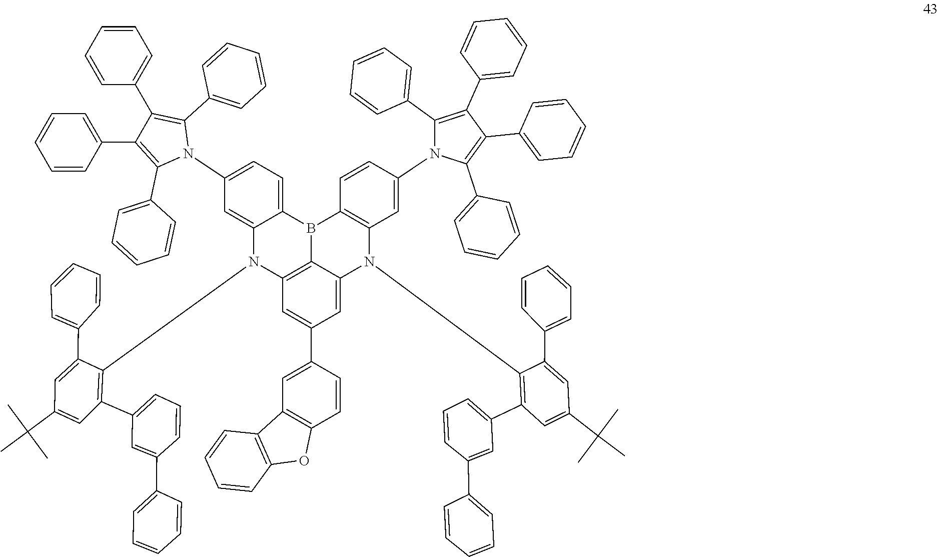 [SMILES: CC(C)(C)c1cc(-c2ccccc2)c(N2c3cc(-n4c(-c5ccccc5)c(-c5ccccc5)c(-c5ccccc5)c4-c4ccccc4)ccc3B3c4ccc(-n5c(-c6ccccc6)c(-c6ccccc6)c(-c6ccccc6)c5-c5ccccc5)cc4N(c4c(-c5ccccc5)cc(C(C)(C)C)cc4-c4cccc(-c5ccccc5)c4)c4cc(-c5ccc6oc7ccccc7c6c5)cc2c43)c(-c2cccc(-c3ccccc3)c2)c1]

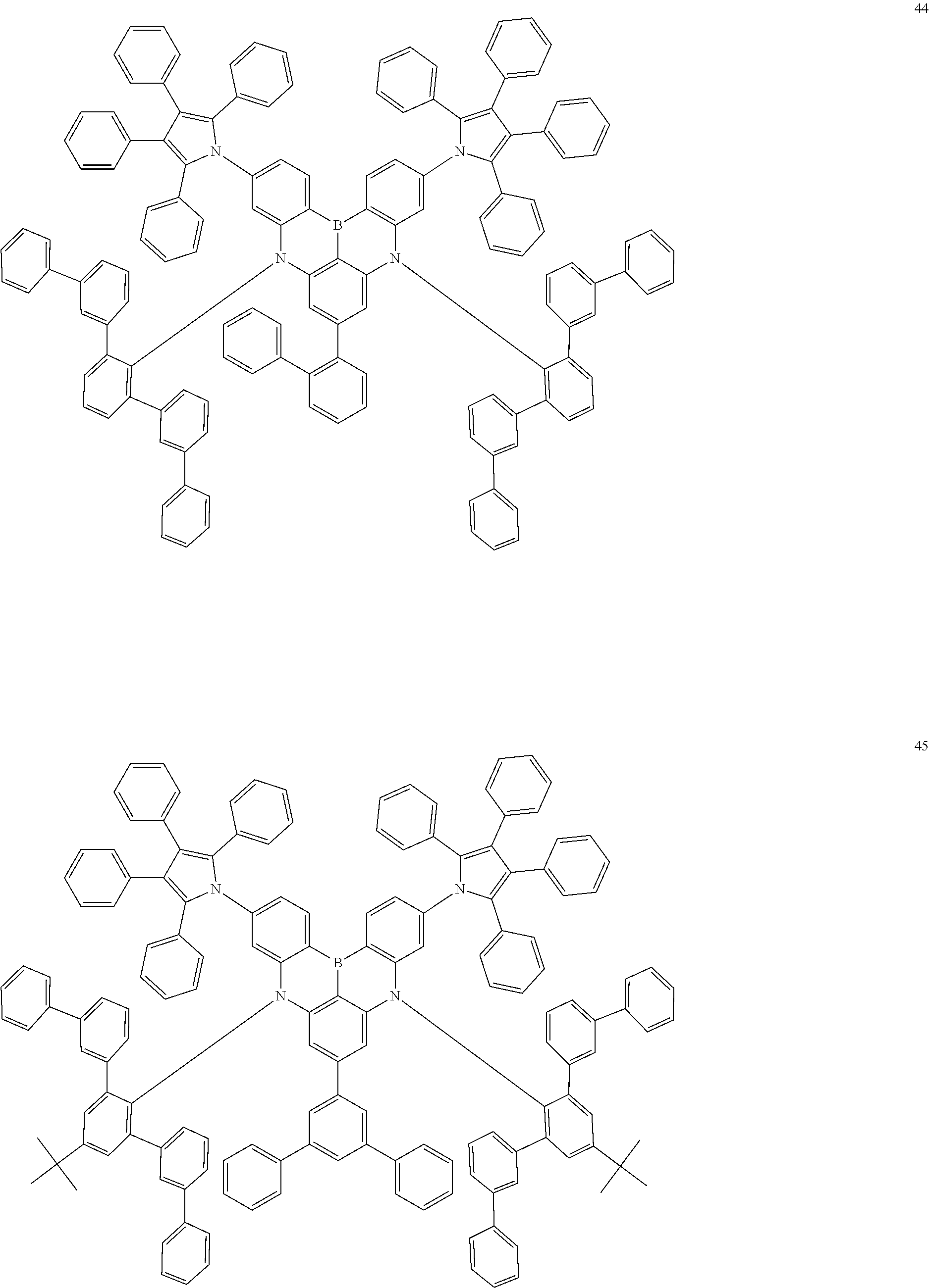

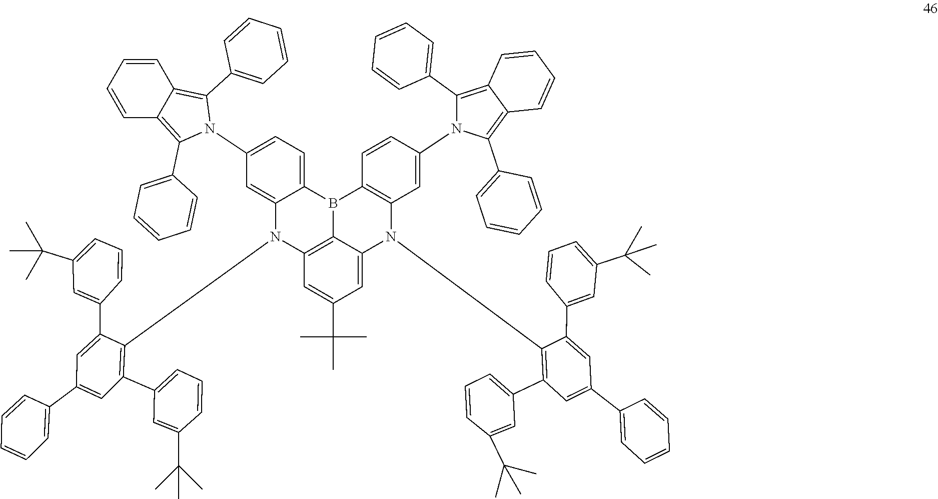 [SMILES: CC(C)(C)c1cccc(-c2cc(-c3ccccc3)cc(-c3cccc(C(C)(C)C)c3)c2N2c3cc(-n4c(-c5ccccc5)c5ccccc5c4-c4ccccc4)ccc3B3c4ccc(-n5c(-c6ccccc6)c6ccccc6c5-c5ccccc5)cc4N(c4c(-c5cccc(C(C)(C)C)c5)cc(-c5ccccc5)cc4-c4cccc(C(C)(C)C)c4)c4cc(C(C)(C)C)cc2c43)c1]

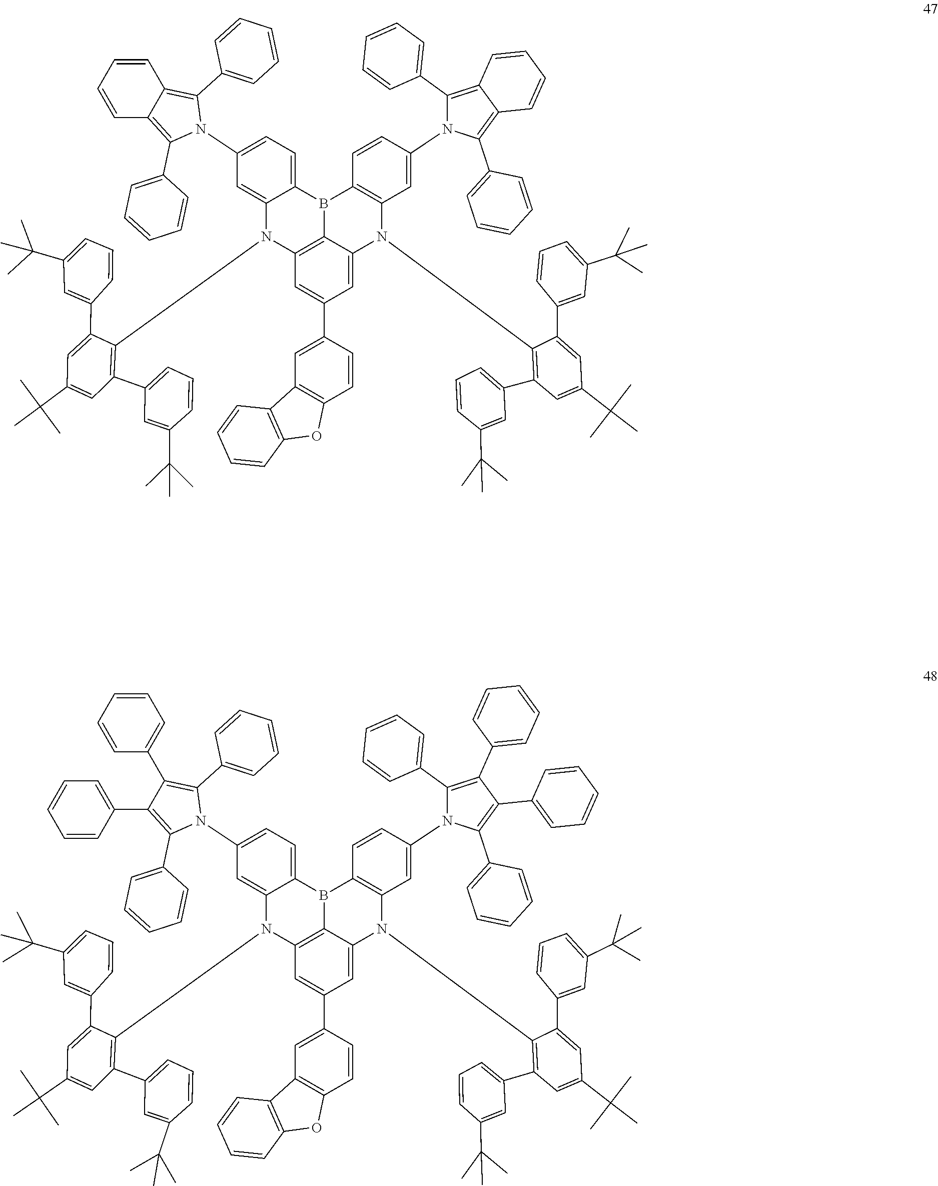

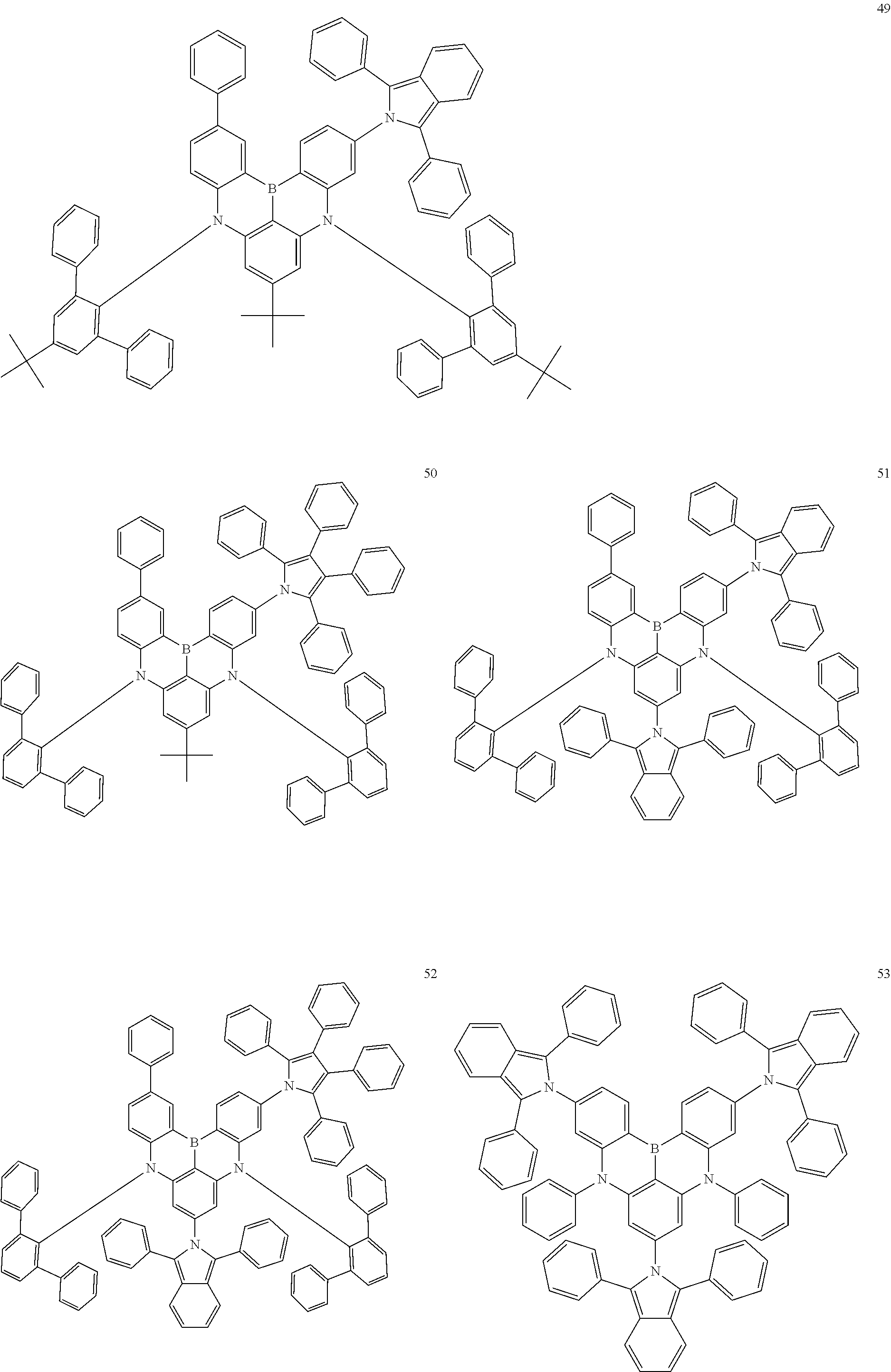

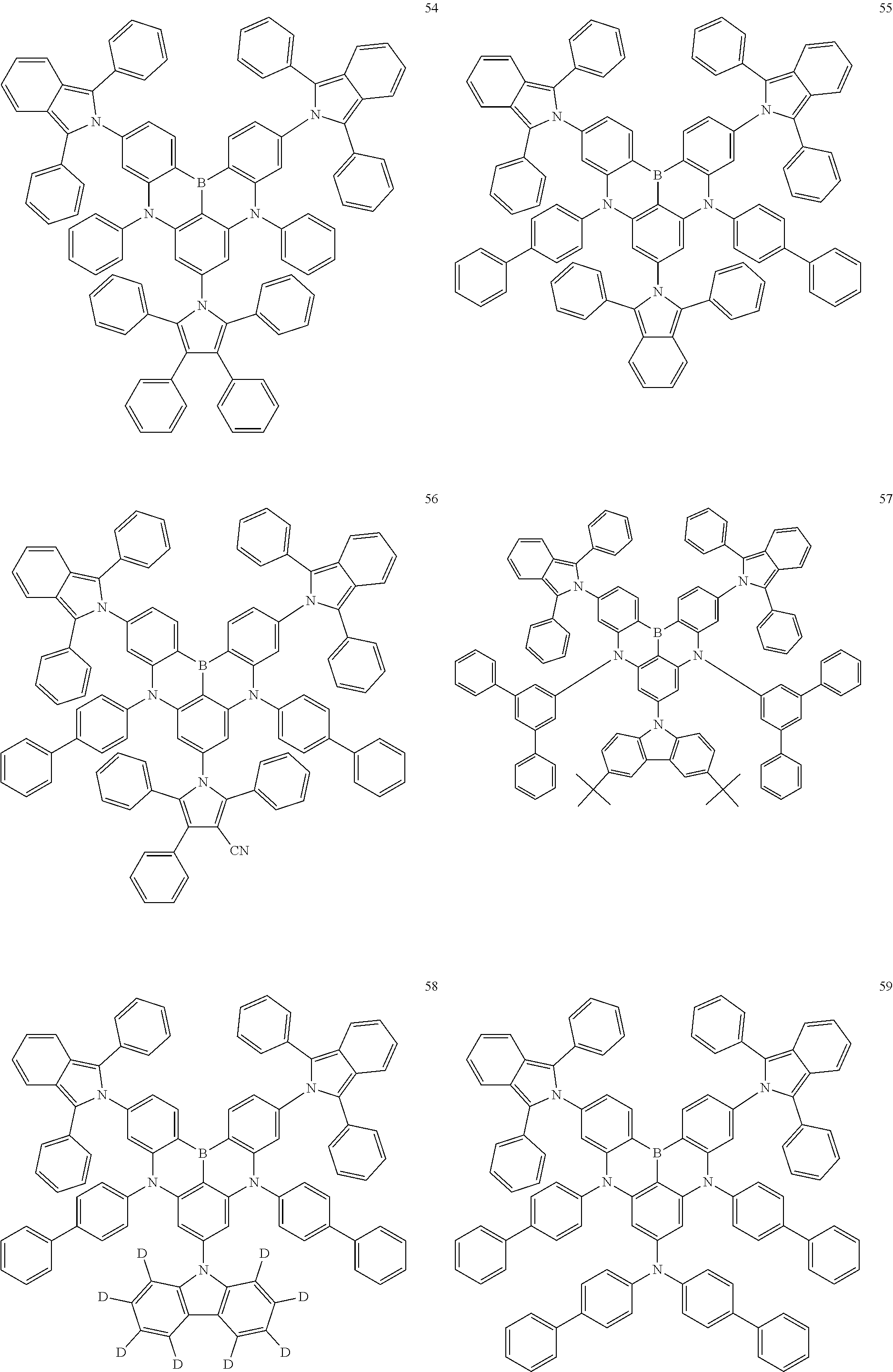

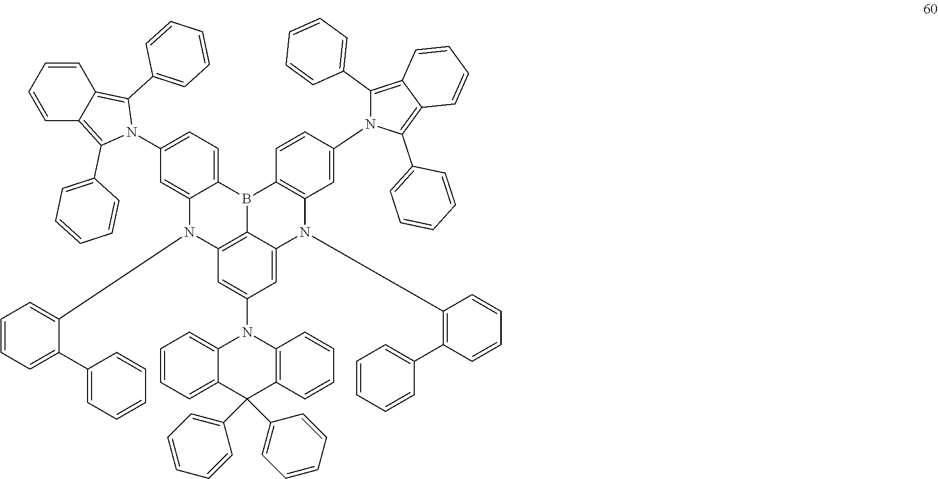 [SMILES: c1ccc(-c2ccccc2N2c3cc(-n4c(-c5ccccc5)c5ccccc5c4-c4ccccc4)ccc3B3c4ccc(-n5c(-c6ccccc6)c6ccccc6c5-c5ccccc5)cc4N(c4ccccc4-c4ccccc4)c4cc(N5c6ccccc6C(c6ccccc6)(c6ccccc6)c6ccccc65)cc2c43)cc1]

The fused polycyclic compound of one or more embodiments may include, as a central structure, a fused ring of five rings, which contains two nitrogen atoms and one boron atom as ring-forming atoms, and may include a pyrrole group or an isoindole group directly bonded to a core structure. The pyrrole group and isoindole group may be bonded to be positioned para to a boron atom to shield the central structure. In some embodiments, the fused polycyclic compound of one or more embodiments may include a bulky substituent bonded to two nitrogen atoms to shield the central structure. The fused polycyclic compound of one or more embodiments may be in the form of a sphere in which the pyrrole group, the isoindole group, and the bulky substituent shield the central structure.

The compound 4 represents, as an example, the fused polycyclic compound of one or more embodiments. In the compound 4, TP1 to TP6 and ID1 to ID8 are indicated for convenience of description.

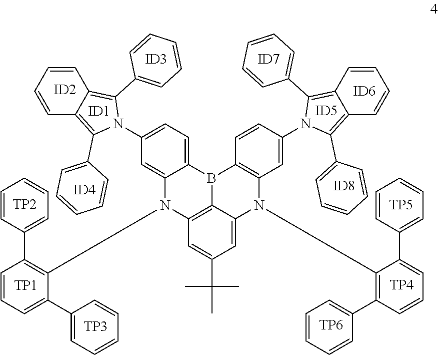

In terms of the three-dimensional structure of a compound, the fused ring of five rings which is the central structure, has a planar structure, and a first terphenyl group formed of TP1 to TP3 ring groups may be tilted at a set or predetermined angle with respect to the fused ring of five rings. A second terphenyl group formed of TP4 to TP6 ring groups may be tilted at a set or predetermined angle with respect to the fused ring of five rings. The first and second terphenyl groups may be bulky substituents. A first isoindole group formed of ID1 to ID4 ring groups may be tilted at a set or predetermined angle with respect to the fused ring of five rings, and a second isoindole group formed of ID5 to ID8 ring groups may be tilted at a set or predetermined angle with respect to the fused ring of five rings. The first terphenyl group, the second terphenyl group, the first isoindole group, and the second isoindole group may shield the fused ring of five rings in different directions, and may sterically shield the fused ring of five rings in four directions.

The fused polycyclic compound of one or more embodiments may be a multiple resonance (MR) type or kind dopant. The pyrrole group and the isoindole group are bonded to be positioned para to a boron atom, and accordingly, the fused polycyclic compound may have improved charge transfer properties, and may thus be an MR type or kind dopant having enhanced multiple resonance. The pyrrole group and the isoindole group may be an electron donating group (EDG). Accordingly, electrons are supplied to the vacant p-orbital of the boron atom, and the boron atom may be chemically stabilized (e.g., less chemically reactive). Therefore, the fused polycyclic compound of one or more embodiments may exhibit excellent or suitable material stability.

In the fused polycyclic compound of one or more embodiments, the fused ring of five rings, which is the central structure, is a portion of multiple resonance where energy is absorbed or light emitting-related transitions take place, and as the fused ring of five rings is shielded, nonradiative decay may be reduced. The fused polycyclic compound of one or more embodiments includes a terphenyl group and a pyrrole (or isoindole) group to improve the flatness of the fused ring of five rings, and accordingly, side effects caused by intermolecular interactions may be prevented or reduced. The fused polycyclic compound of one or more embodiments includes a terphenyl group and a pyrrole group (or isoindole group) to increase intermolecular distance, and accordingly, Dexter energy transfer may be prevented or reduced. The pyrrole group and the isoindole group regulate the highest occupied molecular orbital (HOMO) energy level of the fused polycyclic compound, and may thus prevent or reduce an excessive increase in triplet excitons. Accordingly, a light emitting device including the fused polycyclic compound of one or more embodiments may exhibit high efficiency and long service life.

In some embodiments, the Dexter energy transition increases the concentration of triplet excitons. The triplet excitons are present in an excited state for a long period of time to cause decomposition of a compound, and generate an amount of relatively high-energy hot excitons through triplet-triplet annihilation (TTA) to cause a decrease in service life of a light emitting device. In some embodiments, the triplet-triplet annihilation (TTA) causes nonradiative decay of a light emitting material, resulting in reduced efficiency of a light emitting device. For example, the excessive increase in triplet excitons deteriorates the service life and efficiency of the light emitting device.

The emission layer EML may be a delayed fluorescence emission layer including a host and a dopant. To be more specific, the emission layer EML may be to emit (e.g., be configured to emit) light of thermally activated delayed fluorescence (TADF). The fused polycyclic compound of one or more embodiments may be an MR type or kind thermally activated delayed fluorescence dopant.

The emission layer EML may include the fused polycyclic compound of one or more embodiments as a dopant. The fused polycyclic compound of one or more embodiments may be a thermally activated delayed fluorescence material. The fused polycyclic compound may be to emit (e.g., be configured to emit) blue light, and have a central emission wavelength in a wavelength range of about 430 nm to about 490 nm.

In one or more embodiments, the emission layer EML may include the fused polycyclic compound of one or more embodiments, and include at least one selected from among the second compound to fourth compound. In one or more embodiments, the emission layer EML may include a second compound represented by Formula HT-1. For example, the second compound may be utilized as a hole transporting host material of the emission layer EML.

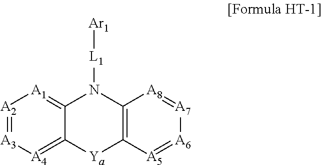

In Formula HT-1, A₁ to A8 may each independently be N or CR₅₁. For example, all of A₁ to A₈ may be CR₅₁. In some embodiments, any one among A₁ to A₈ may be N, and the rest may be CR₅₁.

In Formula HT-1, L₁ may be a direct linkage, a substituted or unsubstituted arylene group having 6 to 30 ring-forming carbon atoms, or a substituted or unsubstituted heteroarylene group having 2 to 30 ring-forming carbon atoms. For example, L₁ may be a direct linkage, a substituted or unsubstituted phenylene group, a substituted or unsubstituted divalent biphenyl group, or a substituted or unsubstituted divalent carbazole group, and/or the like, but the embodiment of the present disclosure is not limited thereto.

In Formula HT-1, Yₐ may be a direct linkage, CR₅₂R₅₃, or SiR₅₄R₅₅. For example, it may refer to that the two benzene rings linked to the nitrogen atom in Formula HT-1 are linked via a direct linkage,

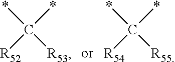

In Formula HT-1, when Yₐ is a direct linkage, the second compound represented by Formula HT-1 may include a carbazole moiety.

In Formula HT-1, Ar₁ may be a substituted or unsubstituted aryl group having 6 to 30 ring-forming carbon atoms, or a substituted or unsubstituted heteroaryl group having 2 to 30 ring-forming carbon atoms. For example, Ar₁ may be a substituted or unsubstituted carbazole group, a substituted or unsubstituted dibenzofuran group, a substituted or unsubstituted dibenzothiophene group, a substituted or unsubstituted biphenyl group, and/or the like, but the embodiment of the present disclosure is not limited thereto.

In Formula HT-1, R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms. In some embodiments, each of R₅₁ to R₅₅ may be bonded to an adjacent group to form a ring. For example, R₅₁ to R₅₅ may each independently be a hydrogen atom or a deuterium atom. R₅₁ to R₅₅ may each independently be an unsubstituted methyl group or an unsubstituted phenyl group.

In one or more embodiments, the second compound represented by Formula HT-1 may be represented by any one selected from among the compounds represented by Compound Group 2. The emission layer EML may include at least one selected from among the compounds represented by Compound Group 2 as a hole transporting host material.

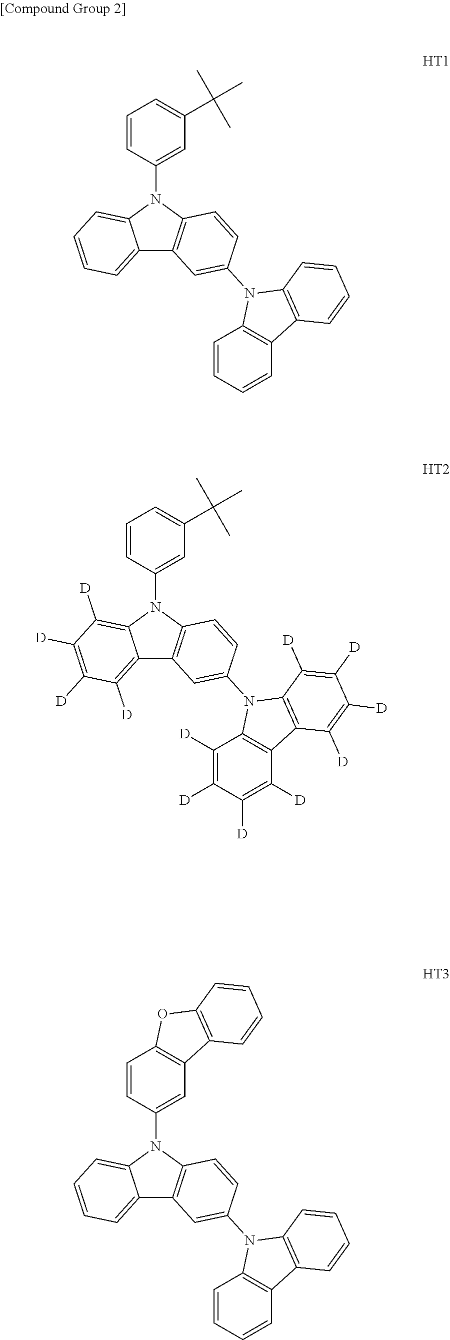 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

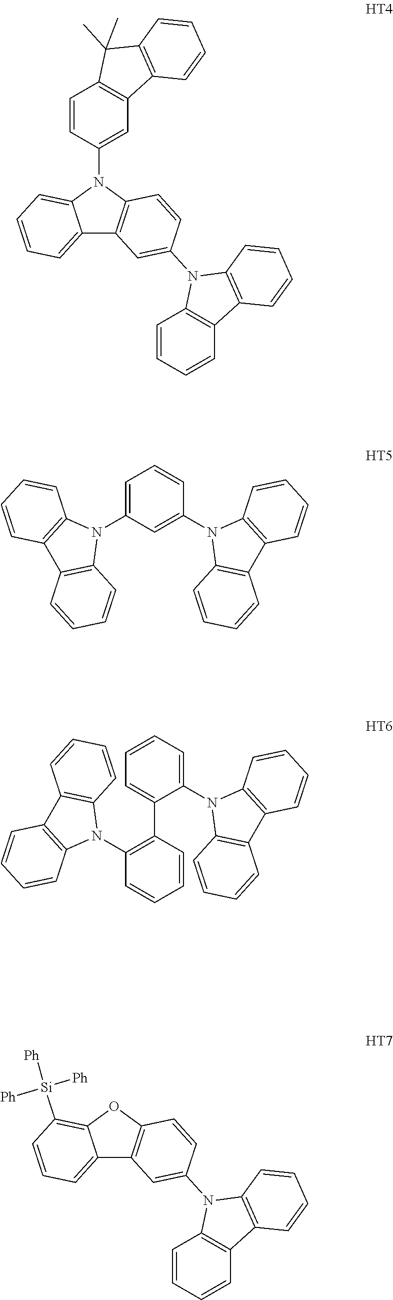 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1]

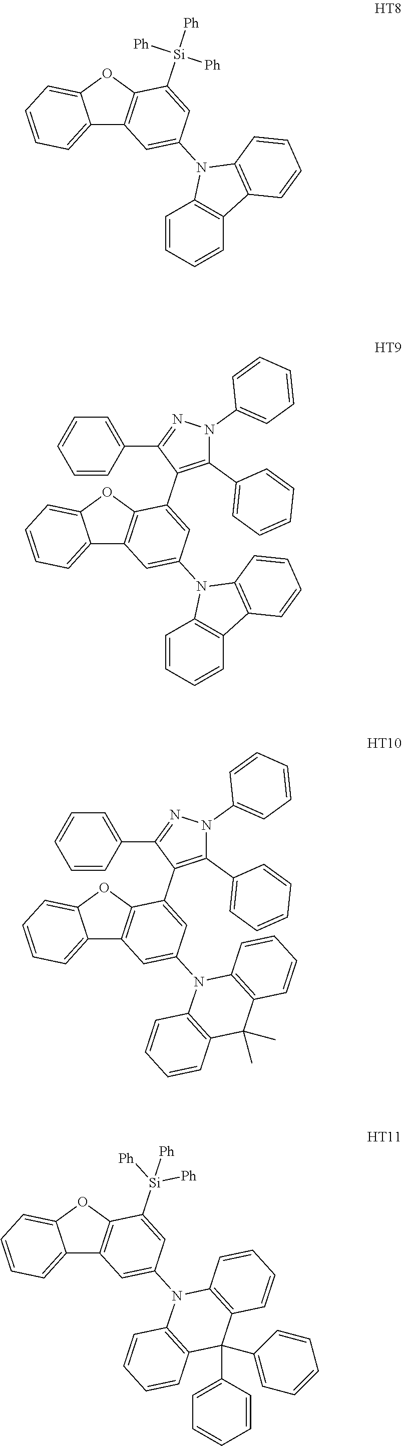 [SMILES: c1ccc([Si](c2ccccc2)(c2ccccc2)c2cc(-n3c4ccccc4c4ccccc43)cc3c2oc2ccccc23)cc1 ; c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1]

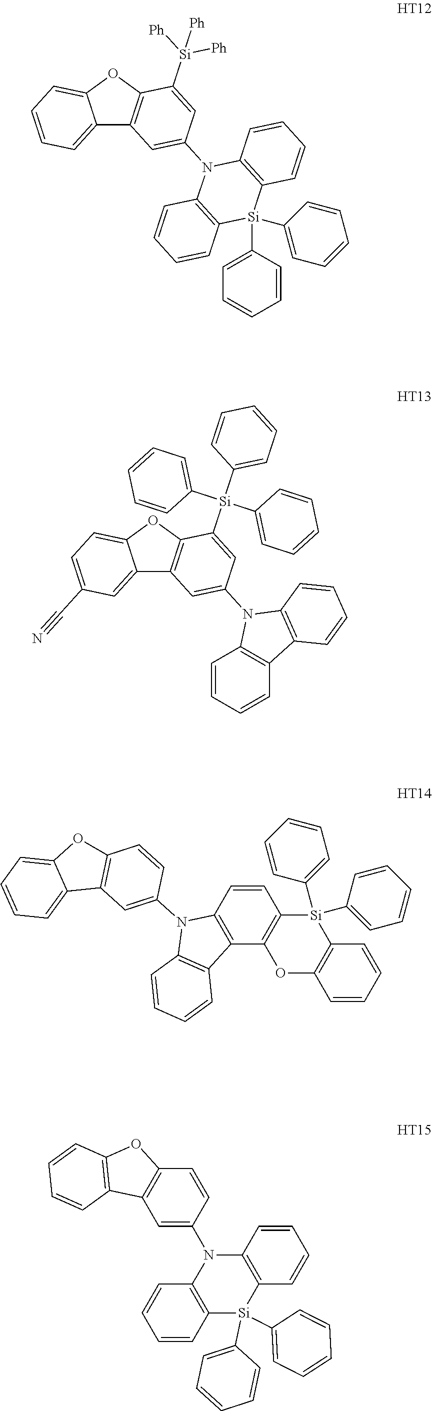 [SMILES: c1ccc([Si]2(c3ccccc3)c3ccccc3N(c3cc([Si](c4ccccc4)(c4ccccc4)c4ccccc4)c4oc5ccccc5c4c3)c3ccccc32)cc1 ; N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3N(c3ccc4oc5ccccc5c4c3)c3ccccc32)cc1]

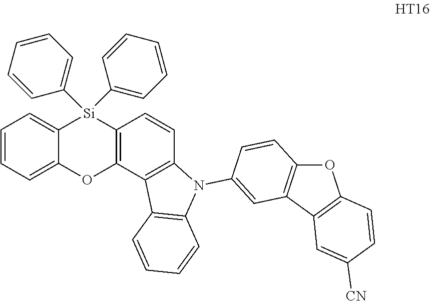 [SMILES: N#Cc1ccc2oc3ccc(-n4c5ccccc5c5c6c(ccc54)[Si](c4ccccc4)(c4ccccc4)c4ccccc4O6)cc3c2c1]

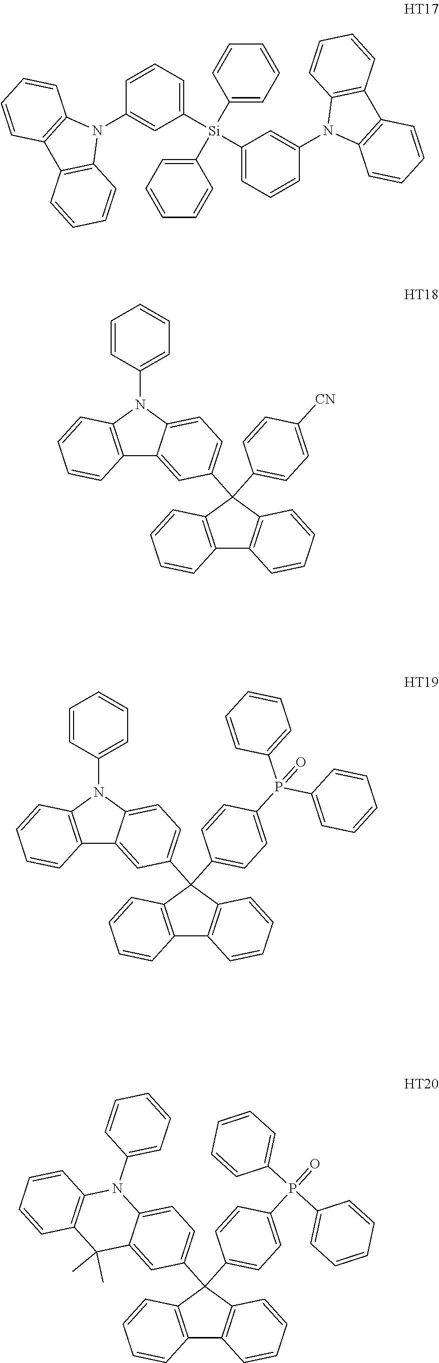 [SMILES: c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1 ; O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21]

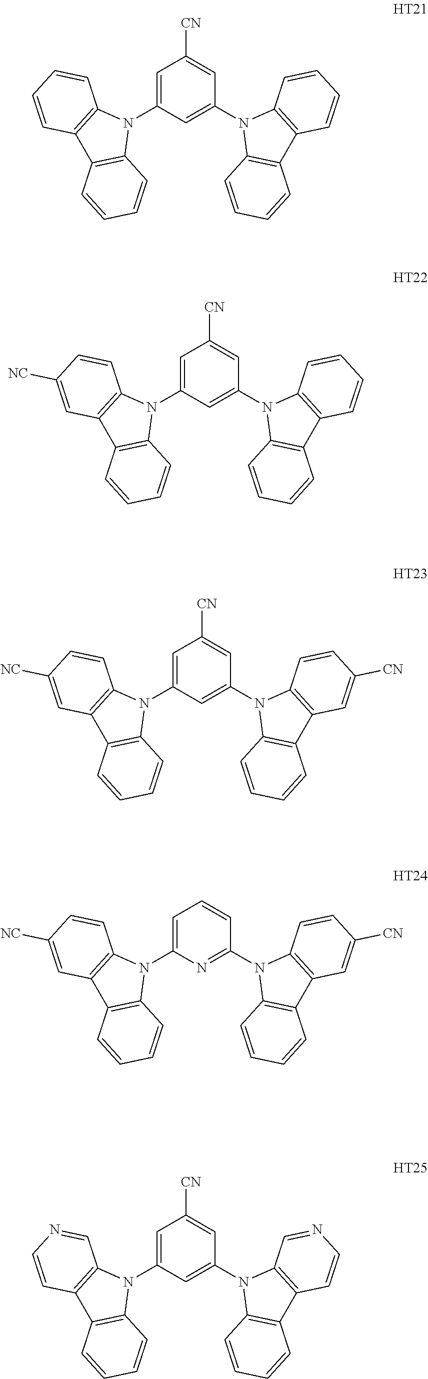 [SMILES: N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1 ; N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1 ; N#Cc1cc(-n2c3ccccc3c3ccncc32)cc(-n2c3ccccc3c3ccncc32)c1]

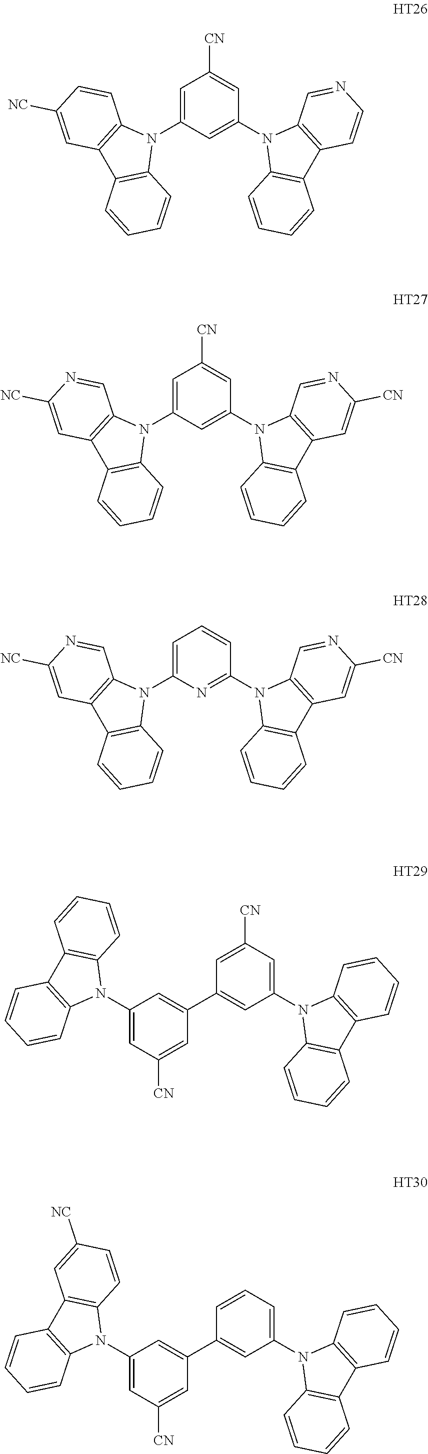 [SMILES: N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1 ; N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1]

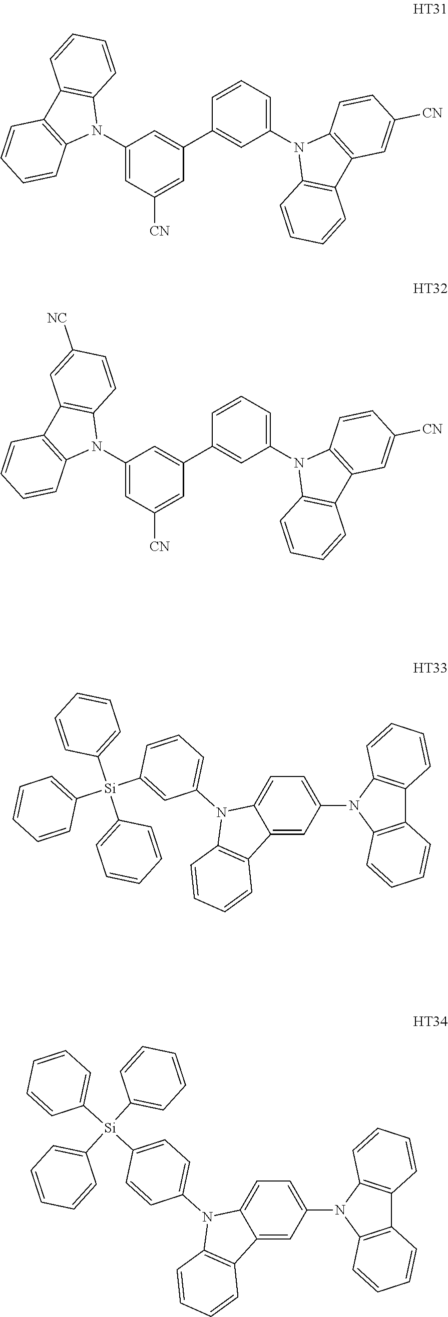 [SMILES: N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1 ; c1ccc([Si](c2ccccc2)(c2ccccc2)c2cccc(-n3c4ccccc4c4cc(-n5c6ccccc6c6ccccc65)ccc43)c2)cc1 ; c1ccc([Si](c2ccccc2)(c2ccccc2)c2ccc(-n3c4ccccc4c4cc(-n5c6ccccc6c6ccccc65)ccc43)cc2)cc1]

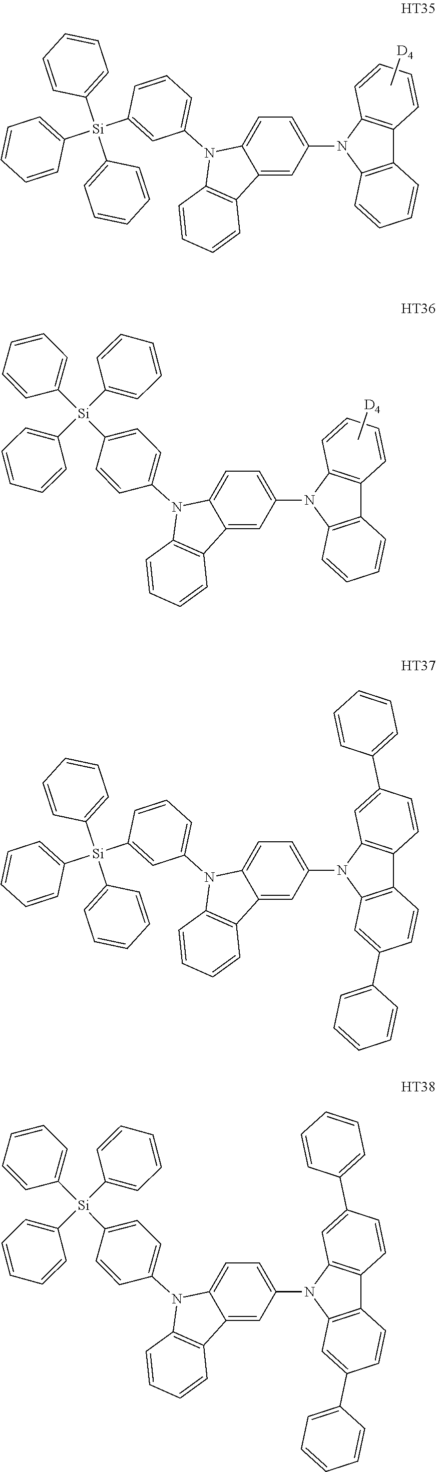

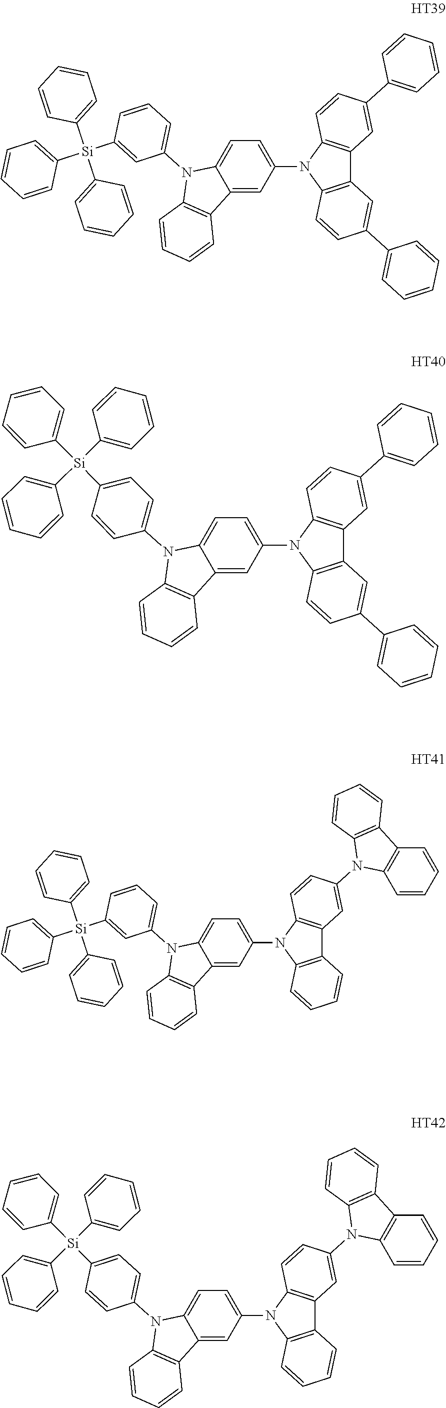 [SMILES: c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1]

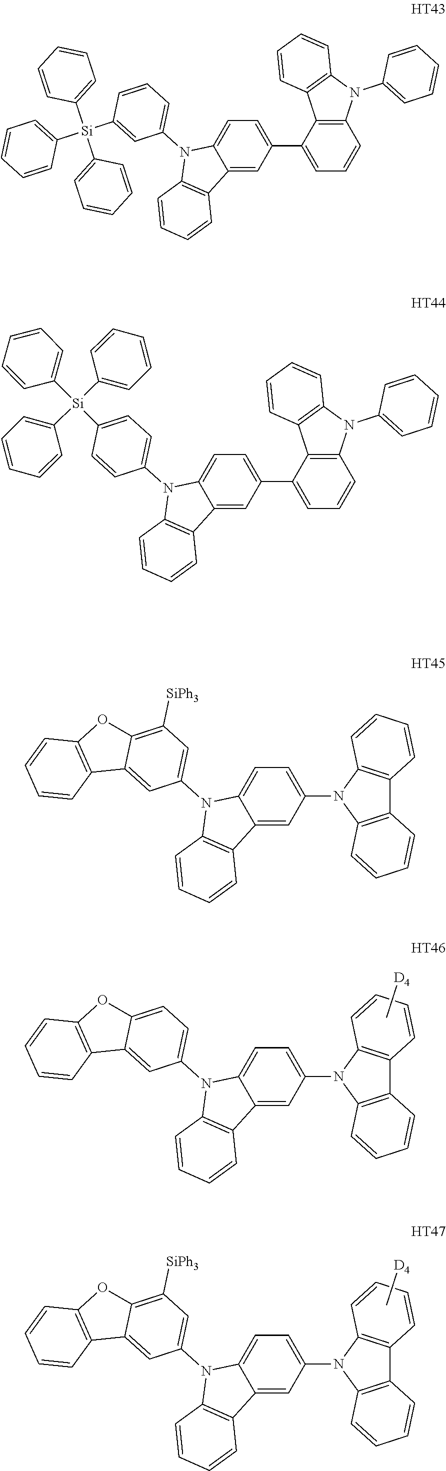

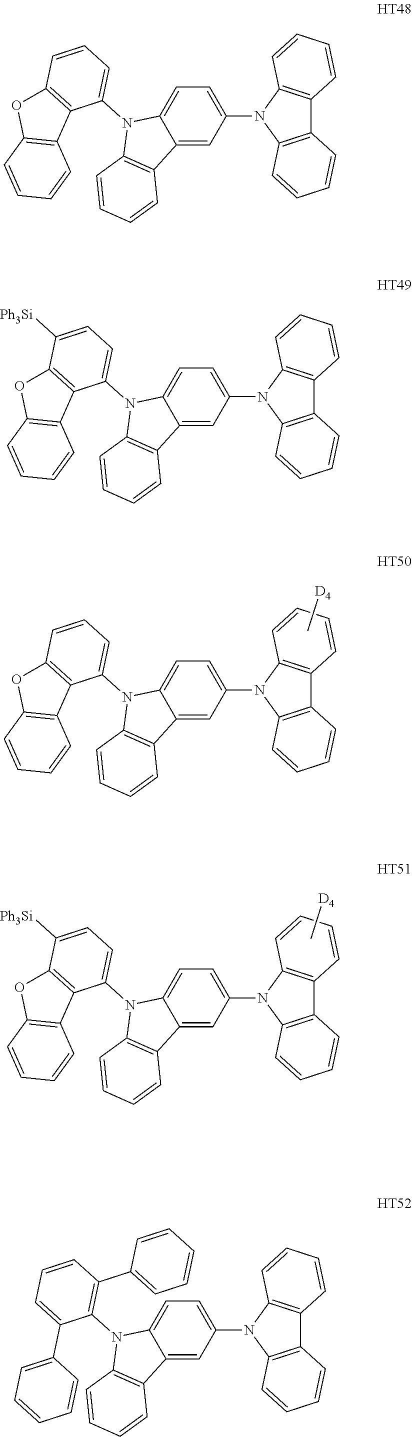

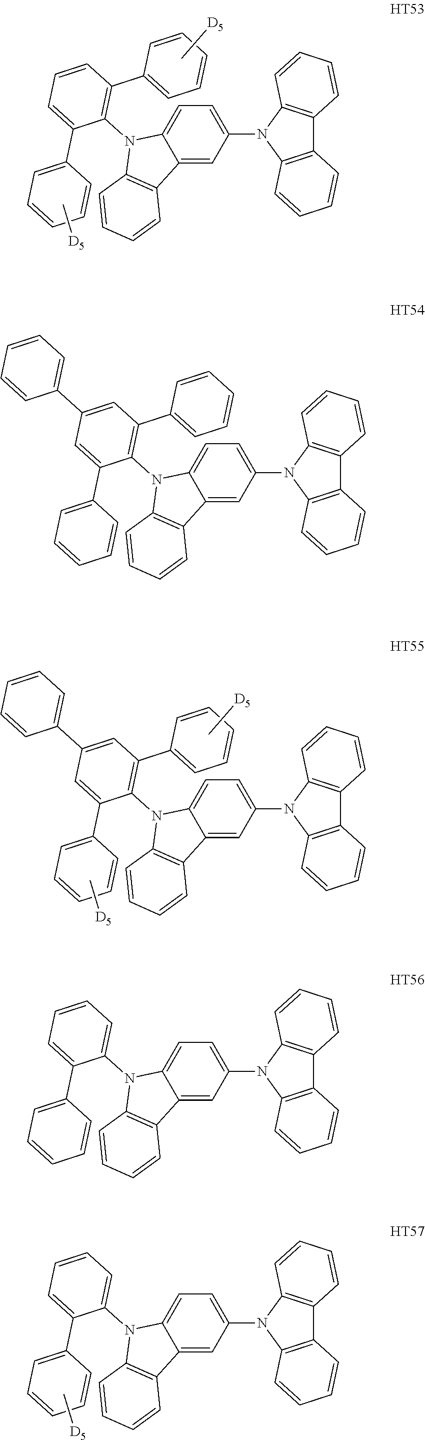

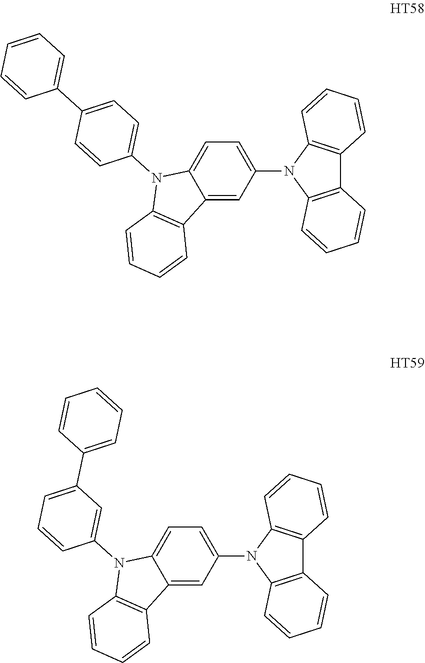 [SMILES: c1ccc(-c2ccc(-n3c4ccccc4c4cc(-n5c6ccccc6c6ccccc65)ccc43)cc2)cc1 ; c1ccc(-c2cccc(-n3c4ccccc4c4cc(-n5c6ccccc6c6ccccc65)ccc43)c2)cc1]

In embodiment compounds presented in Compound Group 2, “D” may refer to a deuterium atom, and “Ph” may refer to a substituted or unsubstituted phenyl group. For example, in embodiment compounds presented in Compound Group 2, “Ph” may refer to an unsubstituted phenyl group.

In one or more embodiments, the emission layer EML may include the third compound represented by Formula ET-1. For example, the third compound may be utilized as an electron transport host material for the emission layer EML.

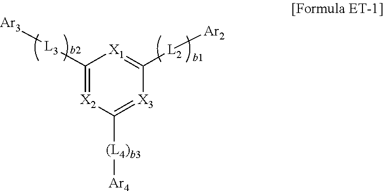

In Formula ET-1, X₁ to X₃ may each independently be N or CR₅₆ and at least one among X₁ to X₃ is N. For example, any one among X₁ to X₃ may be N, and the rest may each independently be CR₅₆. In this case, the third compound represented by Formula ET-1 may include a pyridine moiety. In some embodiments, two among X₁ to X₃ may be N, and the other one may be CR₅₆. In this case, the third compound represented by Formula ET-1 may include a pyrimidine moiety. In some embodiments, X₁ to X₃ may all be N. In this case, the third compound represented by Formula ET-1 may include a triazine moiety.

In Formula ET-1, R₅₆ may each independently be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms.

In Formula ET-1, b1 to b3 may each independently be an integer of 0 to 10.

In Formula ET-1, Ar₂ to Ar₄ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Ar₂ to Ar₄ may each independently be a substituted or unsubstituted phenyl group, or a substituted or unsubstituted carbazole group.

In Formula ET-1, L₂ to L₄ may each independently be a direct linkage, a substituted or unsubstituted arylene group having 6 to 30 ring-forming carbon atoms, or a substituted or unsubstituted heteroarylene group having 2 to 30 ring-forming carbon atoms. In some embodiments, when b1 to b3 are integers of 2 or greater, L₂ to L₄ may each independently be a substituted or unsubstituted arylene group having 6 to 30 ring-forming carbon atoms, or a substituted or unsubstituted heteroarylene group having 2 to 30 ring-forming carbon atoms.

In one or more embodiments, the third compound may be represented by any one selected from among compounds in Compound Group 3. The light emitting device ED of one or more embodiments may include any one selected from among the compounds in Compound Group 3.

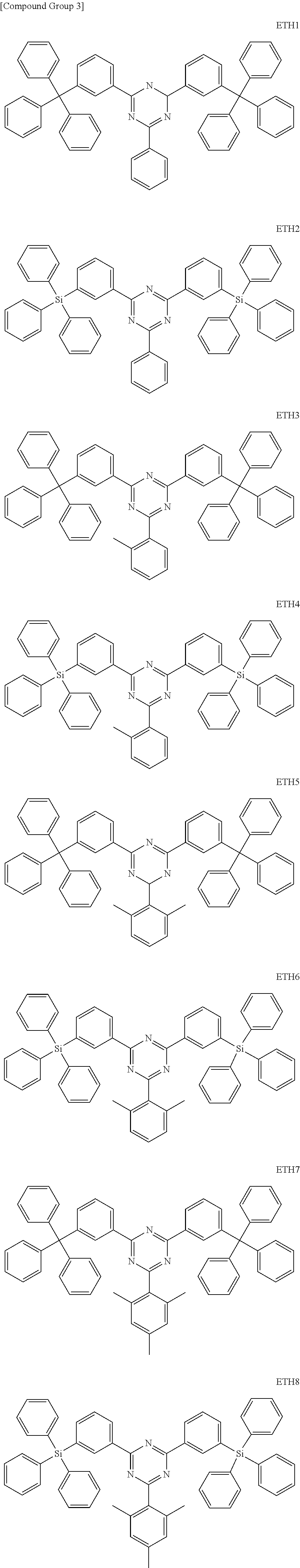

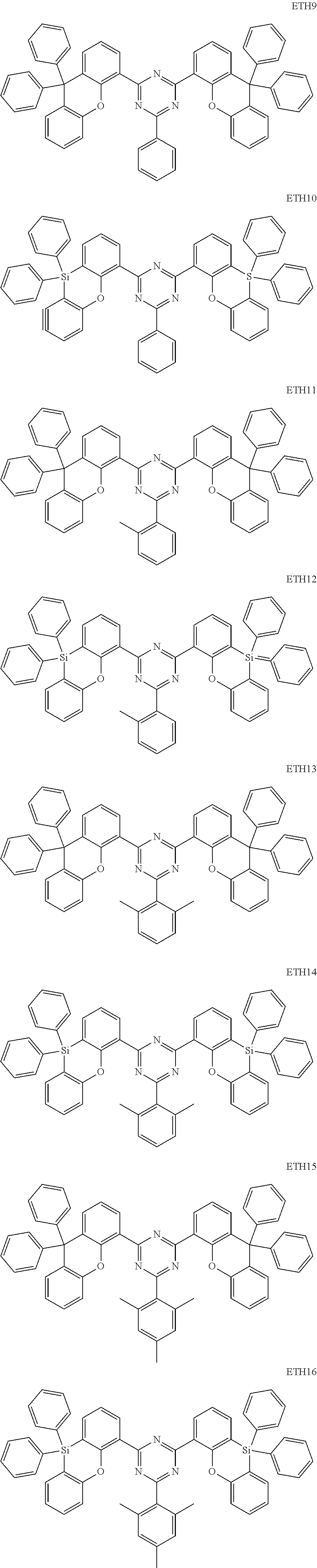

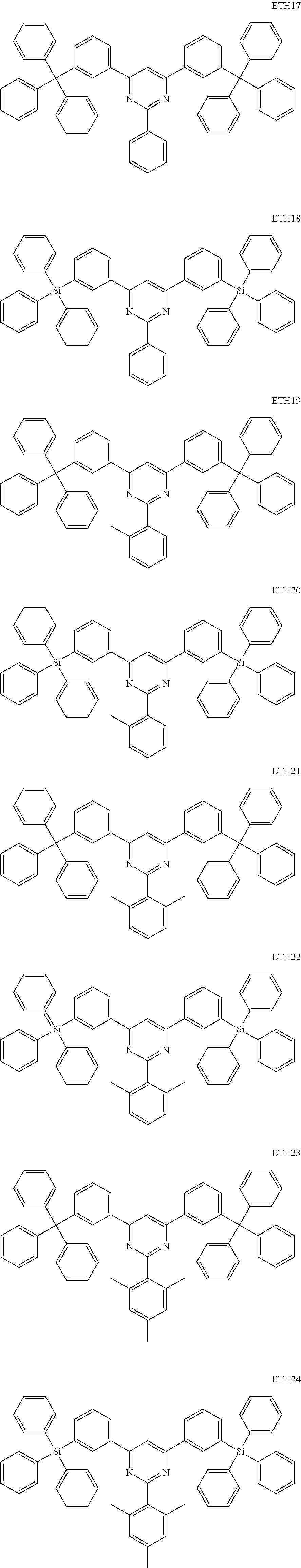

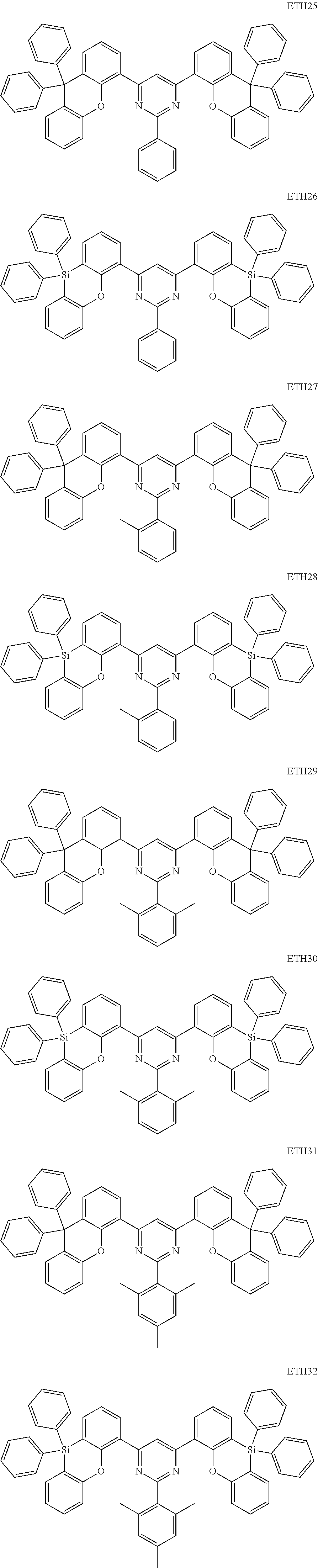

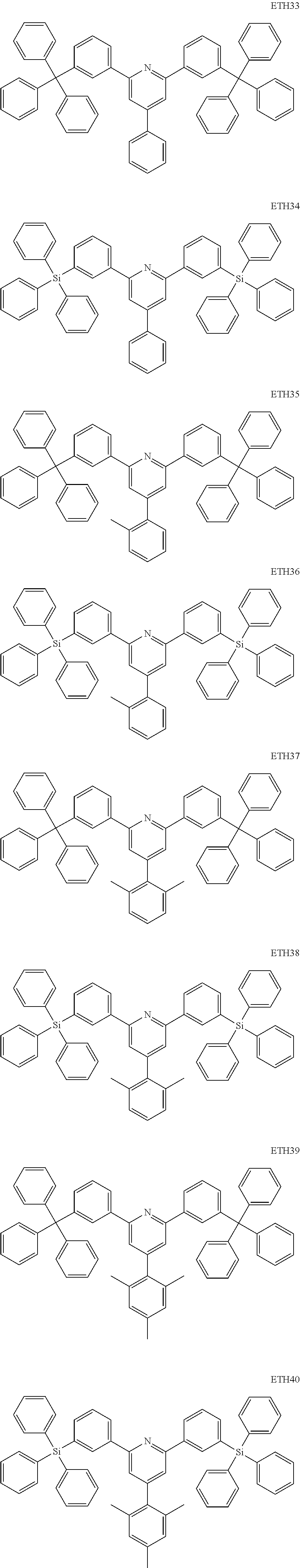

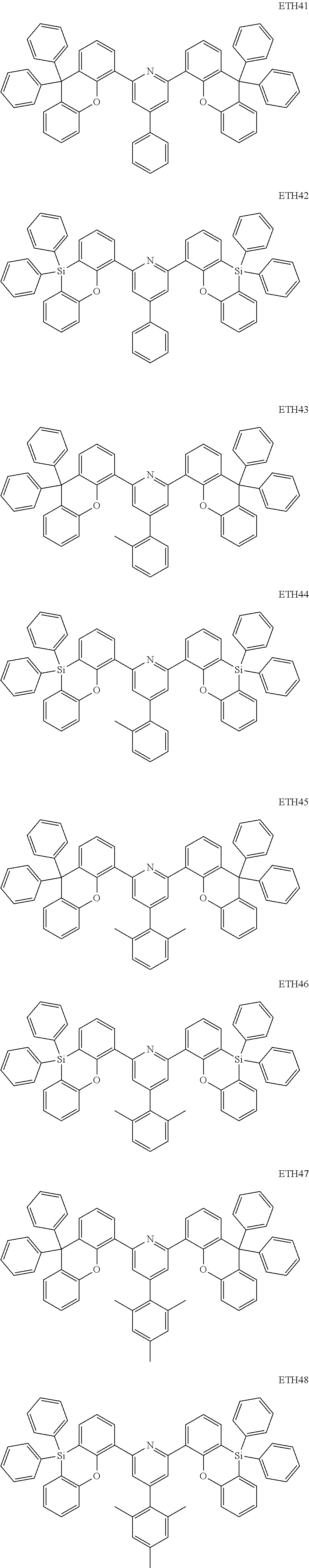

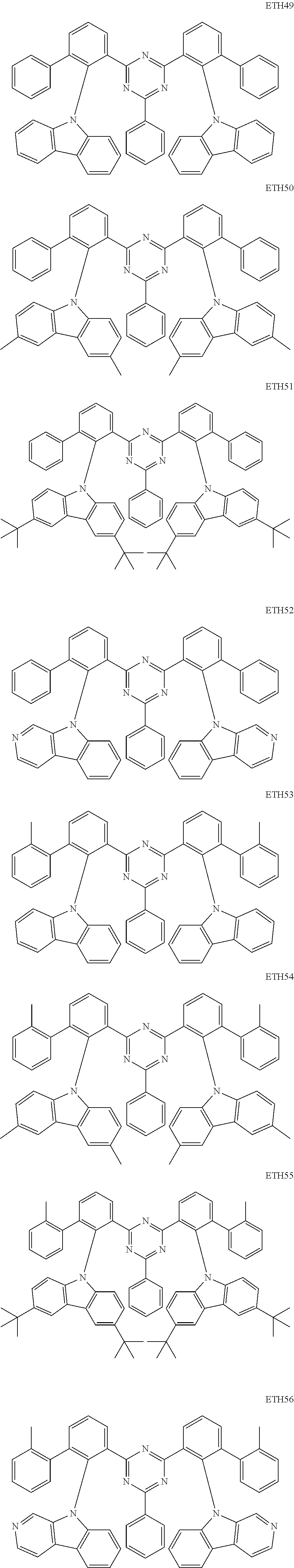

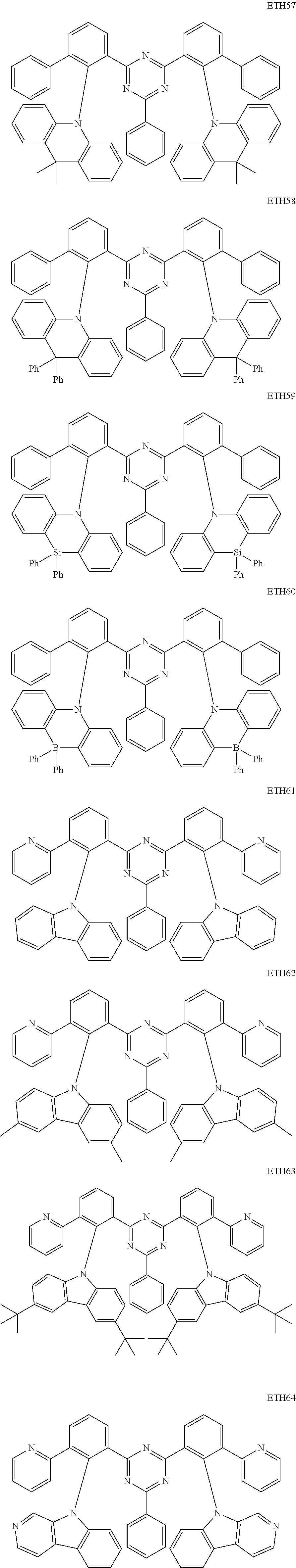

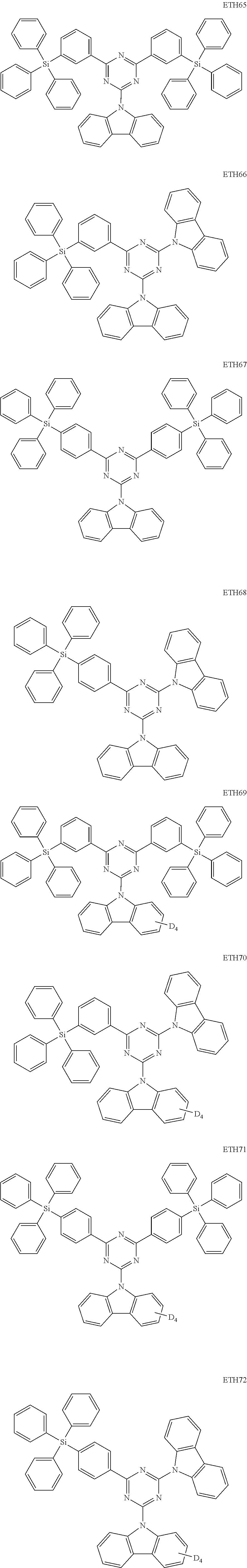

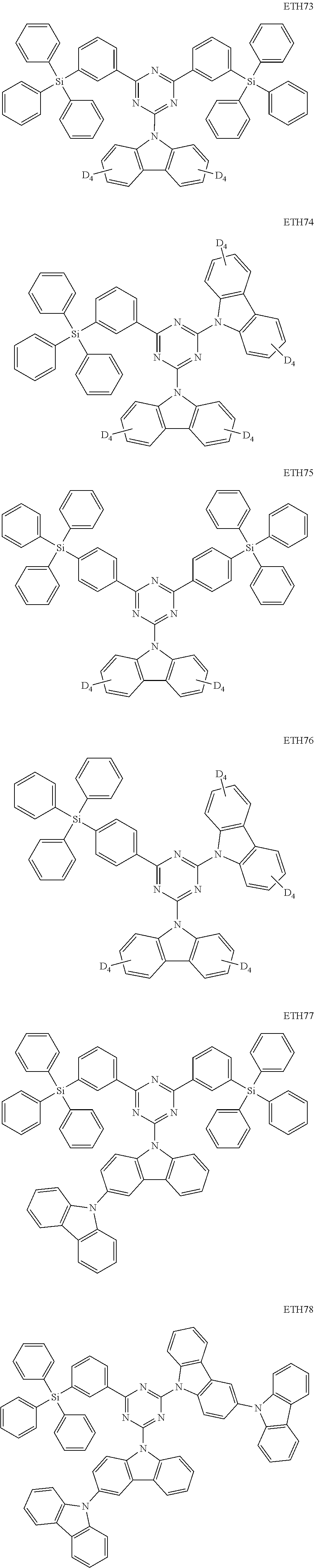

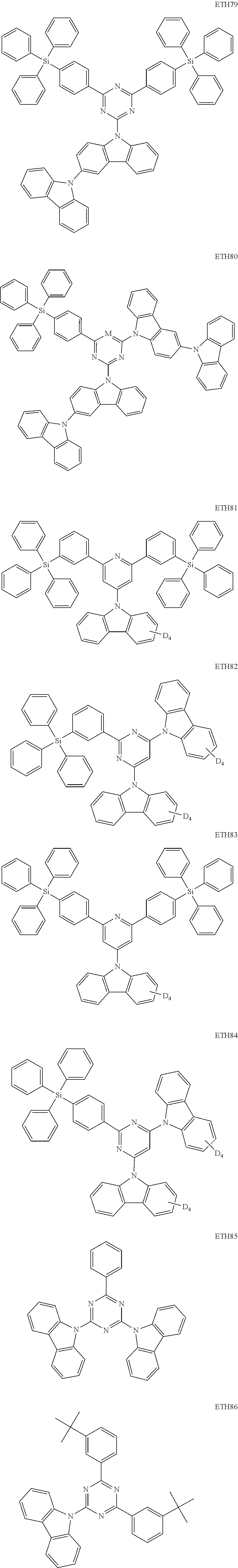

In the embodiment compounds presented in Compound Group 3, “D” refers to a deuterium atom and “Ph” refers to an unsubstituted phenyl group.

The emission layer EML may include the second compound and/or the third compound, and the second compound and/or the third compound may form an exciplex. In the emission layer EML, an exciplex may be formed by the hole transport host and the electron transport host. In this case, a triplet energy of the exciplex formed by the hole transporting host and the electron transporting host may correspond to the difference between a lowest unoccupied molecular orbital (LUMO) energy level of the electron transporting host and a highest occupied molecular orbital (HOMO) energy level of the hole transporting host.

For example, the absolute value of the triplet energy (T1) of the exciplex formed by the hole transporting host and the electron transporting host may be about 2.4 electron volt (eV) to about 3.0 eV. In some embodiments, the triplet energy of the exciplex may be a value smaller than an energy gap of each host material. The exciplex may have a triplet energy of about 3.0 eV or less that is an energy gap between the hole transporting host and the electron transporting host.

In one or more embodiments, the emission layer EML may include a fourth compound in addition to the first compound to the third compound as described herein. The fourth compound may be utilized as a phosphorescent sensitizer of the emission layer EML. The energy may be transferred from the fourth compound to the first compound, thereby emitting light.

For example, the emission layer EML may include, as the fourth compound, an organometallic complex containing platinum (Pt) as a central metal atom and ligands linked to the central metal atom. The emission layer EML in the light emitting device ED of one or more embodiments may include, as the fourth compound, a compound represented by Formula D-1:

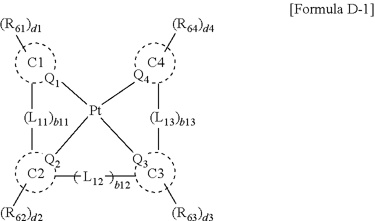

In Formula D-1, Q₁ to 04 may each independently be C or N. In Formula D-1, C1 to 04 may each independently be a substituted or unsubstituted hydrocarbon ring having 5 to 30 ring-forming carbon atoms, or a substituted or unsubstituted heterocycle having 2 to 30 ring-forming carbon atoms.

In Formula D-1, L₁₁ to L₁₃ may each independently be a direct linkage,

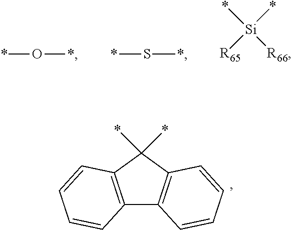

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms. In L₁₁ to L₁₃, “ [symbol] ” refers to a part linked to C1 to C4.

In Formula D-1, b11 to b13 may each independently be 0 or 1. When b11 is 0, C1 and C2 may not be linked to each other. When b12 is 0, C2 and C3 may not be linked to each other. When b13 is 0, C3 and C4 may not be linked to each other.

In Formula D-1, R₆₁ to R₆₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms. In some embodiments, each of R₆₁ to R₆₆ may be bonded to an adjacent group to form a ring. R₆₁ to R₆₆ may each independently be a substituted or unsubstituted methyl group, or a substituted or unsubstituted t-butyl group.

In Formula D-1, d1 to d4 may each independently be an integer of 0 to 4. In Formula D-1, when each of d1 to d4 is 0, the fourth compound may not be substituted with each of R₆₁ to R₆₄. The case where each of d1 to d4 is 4 and the R₆₁'s to R₆₄'s are each hydrogen atoms may be the same as the case where each of d1 to d4 is 0. When each of d1 to d4 is an integer of 2 or more, a plurality of the R₆₁'s to R₆₄'s may each be the same or at least one among the plurality of the R₆₁'s to R₆₄'s may be different from the others.

In Formula D-1, C1 to C4 may each independently be a substituted or unsubstituted hydrocarbon ring or a substituted or unsubstituted heterocycle represented by any one selected from among C-1 to C-4:

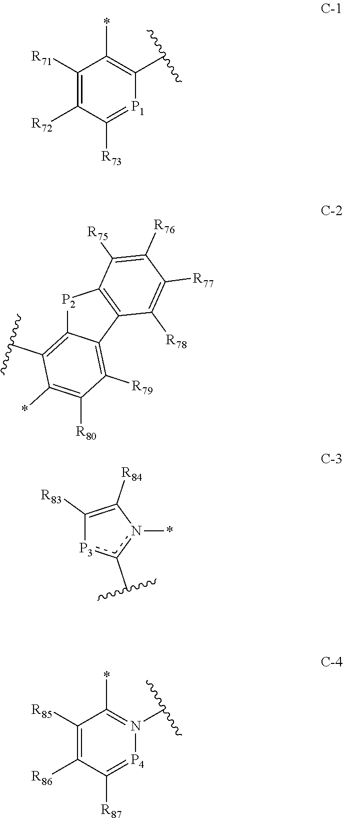

In C-1 to C-4, P₁ may be C—* or CR₇₄, P₂ may be N—* or NR₈₁, P₃ may be N—* or NR₈₂, and P₄ may be C—* or CR₈₈. R₇₁ to R₈₈ may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring.

In some embodiments, in C-1 to C-4,

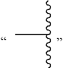

corresponds to a part linked to Pt that is a central metal atom, and “ [symbol] ” corresponds to a part linked to a neighboring cyclic group (C1 to C4) or a linker (L₁₁ to L₁₃).

The emission layer EML of one or more embodiments may include the first compound, which is a fused polycyclic compound, and at least one selected from among the second to fourth compounds. For example, the emission layer EML may include the first compound, the second compound, and the third compound. In the emission layer EML, the second compound and the third compound may form an exciplex, and the energy may be transferred from the exciplex to the first compound, thereby emitting light.

In some embodiments, the emission layer EML may include the first compound, the second compound, the third compound, and the fourth compound. In the emission layer EML, the second compound and the third compound may form an exciplex, and the energy may be transferred from the exciplex to the fourth compound and the first compound, thereby emitting light. In one or more embodiments, the fourth compound may be a sensitizer. The fourth compound included in the emission layer EML in the light emitting device ED of one or more embodiments may serve as a sensitizer to deliver energy from the host to the first compound that is a light emitting dopant. For example, the fourth compound serving as an auxiliary dopant accelerates energy delivery to the first compound that is a light emitting dopant, thereby increasing the emission ratio of the first compound. Therefore, the emission layer EML of one or more embodiments may improve luminous efficiency. In some embodiments, when the energy delivery to the first compound is increased, an exciton formed in the emission layer EML is not accumulated inside the emission layer EML and emits light rapidly, and thus deterioration of the light emitting device may be reduced. Therefore, the service life of the light emitting device ED of one or more embodiments may increase.

The light emitting device ED of one or more embodiments may include all of the first compound, the second compound, the third compound, and the fourth compound, and the emission layer EML may include the combination of two host materials and two dopant materials. In the light emitting device ED of one or more embodiments, the emission layer EML may concurrently (e.g., simultaneously) include the second compound and the third compound, which are two different hosts, the first compound that emits a delayed fluorescence, and the fourth compound including an organometallic complex, thereby exhibiting excellent or suitable luminous efficiency characteristics.

In one or more embodiments, the fourth compound represented by Formula D-1 may be represented by at least one selected from among the compounds represented by Compound Group 4. The emission layer EML may include at least one selected from among the compounds represented by Compound Group 4 as a sensitizer material.

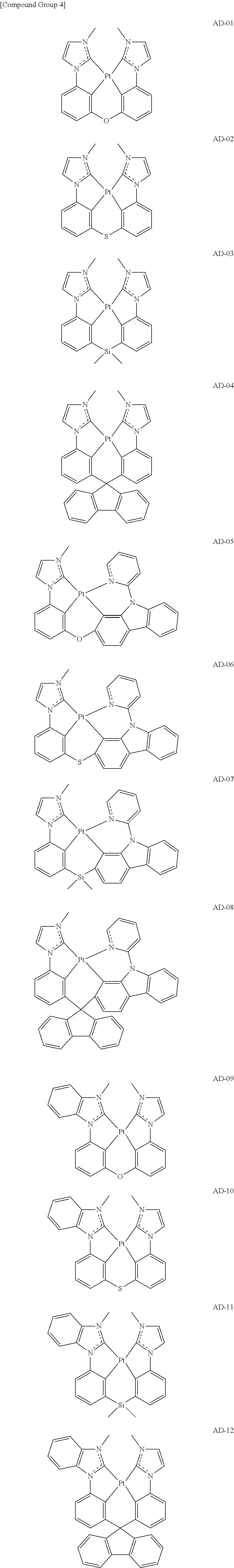

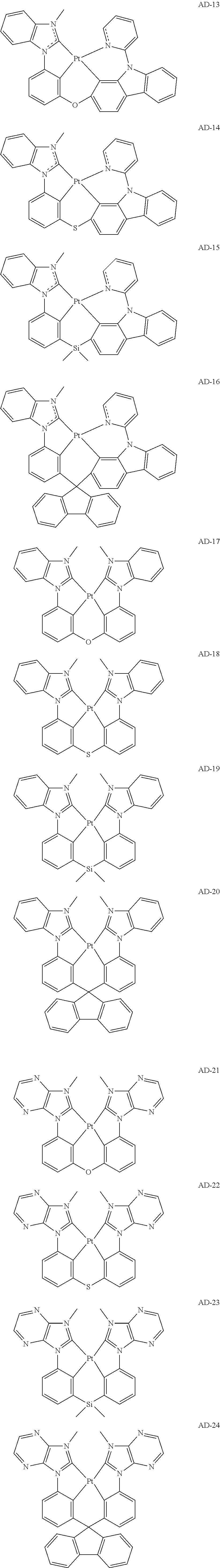

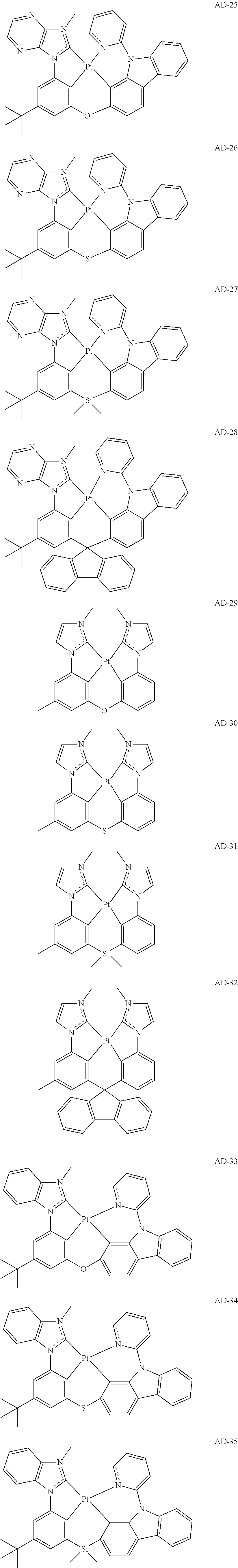

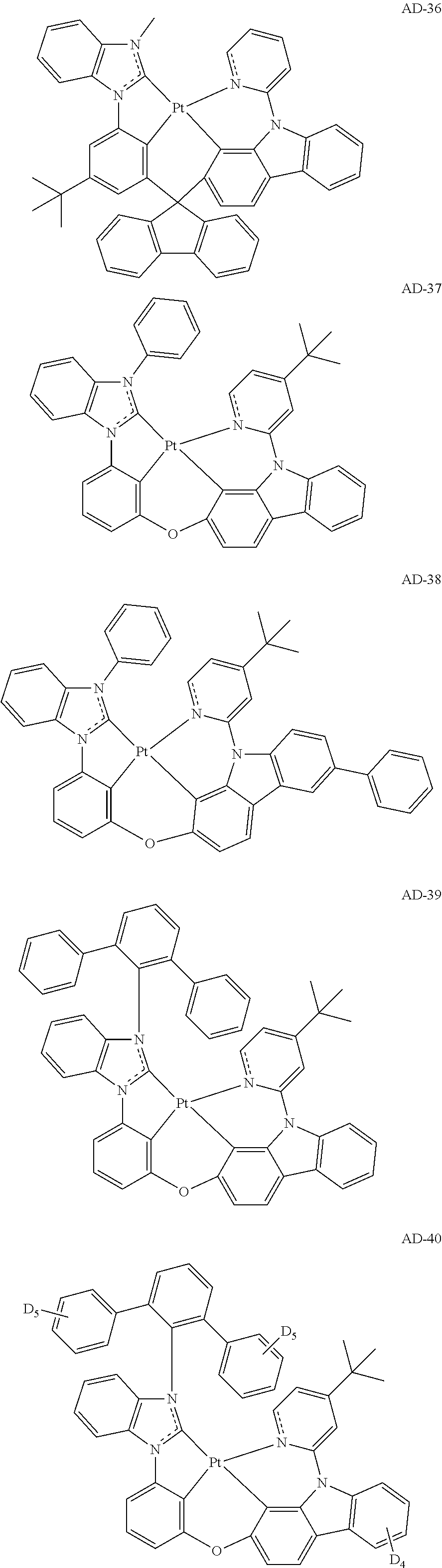

In the embodiment compounds presented in Compound Group 4, “D” refers to a deuterium atom.

When the emission layer EML in the light emitting device ED of one or more embodiments includes all of the first compound, the second compound, and the third compound, with respect to the total weight of the first compound, the second compound, and the third compound, the content (e.g., amount) of the first compound may be about 0.1 wt % to about 5 wt %. However, the embodiment of the present disclosure is not limited thereto. When the content (e.g., amount) of the first compound satisfy the described proportion, the energy transfer from the second compound and the third compound to the first compound may increase, and thus the luminous efficiency and device service life may increase.

The contents of the second compound and the third compound in the emission layer EML may comprise the entirety of the emission layer EML (e.g., be the rest) excluding the weight of the first compound. For example, the contents of the second compound and the third compound in the emission layer EML may be about 65 wt % to about 95 wt % with respect to the total weight of the first compound, the second compound, and the third compound.

In the total weight of the second compound and the third compound, the weight ratio of the second compound and the third compound may be about 3:7 to about 7:3.

When the contents of the second compound and the third compound satisfy the described ratio, one or more charge balance characteristic(s) in the emission layer EML may be (e.g., are) improved, and thus the luminous efficiency and device service life may increase. When the contents of the second compound and the third compound deviate from the described ratio range, a charge balance in the emission layer EML is lost (e.g., decreased or broken), and thus the luminous efficiency may be reduced and the device may be easily deteriorated.

When the emission layer EML includes the fourth compound, the content (e.g., amount) of the fourth compound in the emission layer EML may be about 10 wt % to about 30 wt % with respect to the total weight of the first compound, the second compound, the third compound, and the fourth compound. However, the embodiment of the present disclosure is not limited thereto. When the content (e.g., amount) of the fourth compound satisfies the described content (e.g., amount), the energy delivery from the host to the first compound which is a light emitting dopant may be increased, thereby a luminous ratio may be improved, and thus the luminous efficiency of the emission layer EML may be improved. When the first compound, the second compound, the third compound, and the fourth compound included in the emission layer EML satisfy the described content (e.g., amount) ratio range, excellent or suitable luminous efficiency and long service life may be achieved.

The emission layer EML is provided on the hole transport region HTR. The emission layer EML may have a thickness of, for example, about 100 Å to about 1,000 Å or about 100 Å to about 300 Å. The emission layer EML may have a single layer formed of a single material, a single layer formed of a plurality of different materials, or a multilayer structure having a plurality of layers formed of a plurality of different materials.

In the light emitting device ED of one or more embodiments, the emission layer EML may include an anthracene derivative, a pyrene derivative, a fluoranthene derivative, a chrysene derivative, a dehydrobenzanthracene derivative, or a triphenylene derivative. For example, the emission layer EML may include the anthracene derivative or the pyrene derivative.

In each light emitting device ED of embodiments illustrated in FIGS. 3 to 7, the emission layer EML may further include a suitable host and dopant besides the described host and dopant, and for example the emission layer EML may include a compound represented by Formula E-1. The compound represented by Formula E-1 may be utilized as a fluorescent host material.

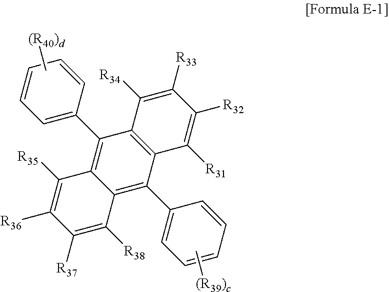

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. In some embodiments, R₃₁ to R₄₀ may be bonded to an adjacent group to form a saturated hydrocarbon ring or an unsaturated hydrocarbon ring, a saturated heterocycle, or an unsaturated heterocycle.

In Formula E-1, c and d may each independently be an integer of 0 to 5.

Formula E-1 may be represented by any one among Compound E1 to Compound E19:

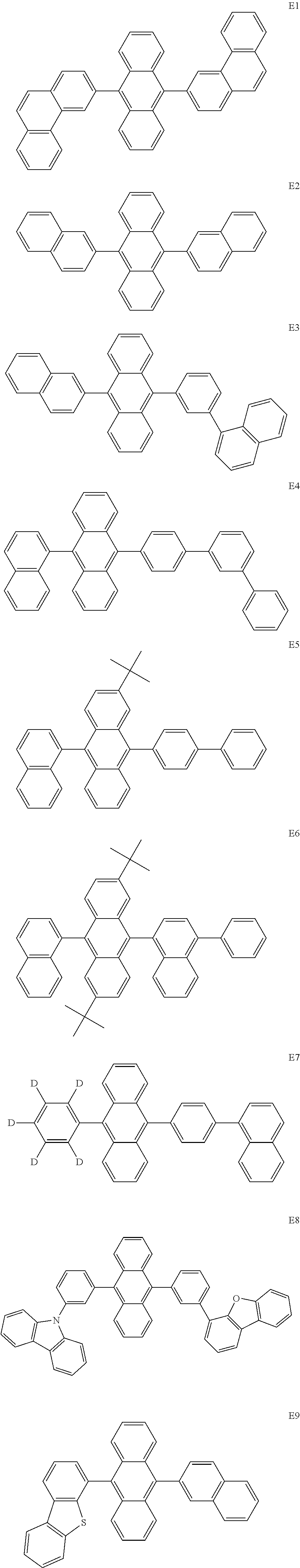

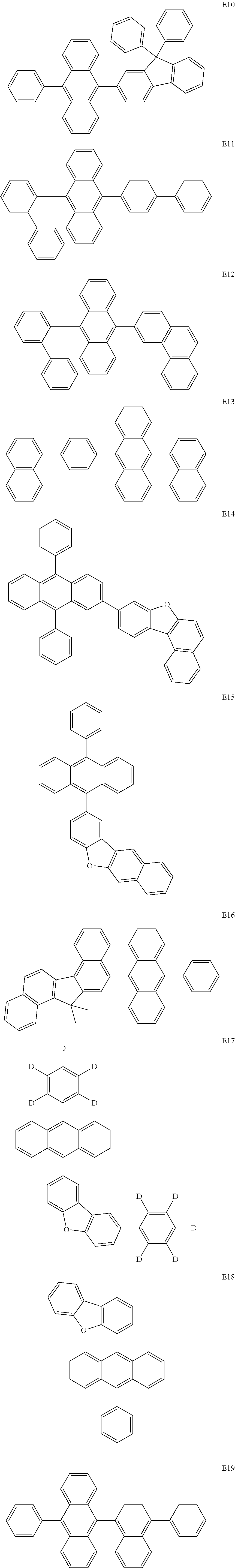

In one or more embodiments, the emission layer EML may include a compound represented by Formula E-2a or Formula E-2b. The compound represented by Formula E-2a or Formula E-2b may be utilized as a phosphorescent host material.

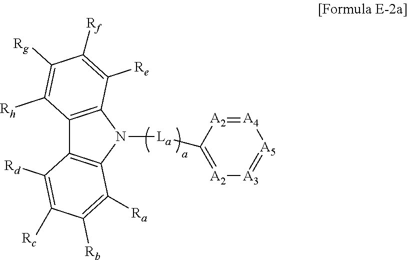

In Formula E-2a, a may be an integer of 0 to 10, and La may be a direct linkage, a substituted or unsubstituted arylene group having 6 to 30 ring-forming carbon atoms, or a substituted or unsubstituted heteroarylene group having 2 to 30 ring-forming carbon atoms. In some embodiments, when a is an integer of 2 or greater, a plurality of La's may each independently be a substituted or unsubstituted arylene group having 6 to 30 ring-forming carbon atoms, or a substituted or unsubstituted heteroarylene group having 2 to 30 ring-forming carbon atoms.

In some embodiments, in Formula E-2a, A₁ to A₅ may each independently be N or CRᵢ. Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. Rₐ to Rᵢ may be bonded to an adjacent group to form a hydrocarbon ring or a heterocycle containing N, O, S, and/or the like, as a ring-forming atom.

In some embodiments, in Formula E-2a, two or three selected from among A₁ to A₅ may be N, and the rest (e.g., others) may be CRI.

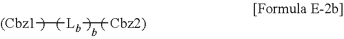

In Formula E-2b, Cbz1 and Cbz2 may each independently be an unsubstituted carbazole group, or a carbazole group substituted with an aryl group having 6 to 30 ring-forming carbon atoms. L_{b} is a direct linkage, a substituted or unsubstituted arylene group having 6 to 30 ring-forming carbon atoms, or a substituted or unsubstituted heteroarylene group having 2 to 30 ring-forming carbon atoms. In some embodiments, b is an integer of 0 to 10, and when b is an integer of 2 or more, a plurality of L_{b}'s may each independently be a substituted or unsubstituted arylene group having 6 to 30 ring-forming carbon atoms, or a substituted or unsubstituted heteroarylene group having 2 to 30 ring-forming carbon atoms.

The compound represented by Formula E-2a or Formula E-2b may be represented by any one among the compounds of Compound Group E-2. However, the compounds listed in Compound Group E-2 are example, and the compound represented by Formula E-2a or Formula E-2b is not limited to those represented in Compound Group E-2.

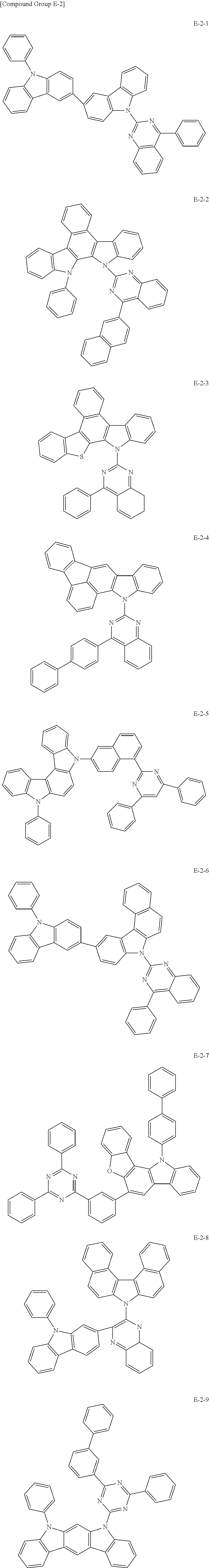

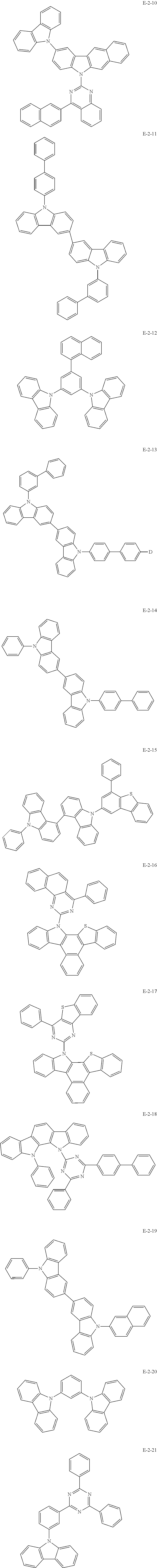

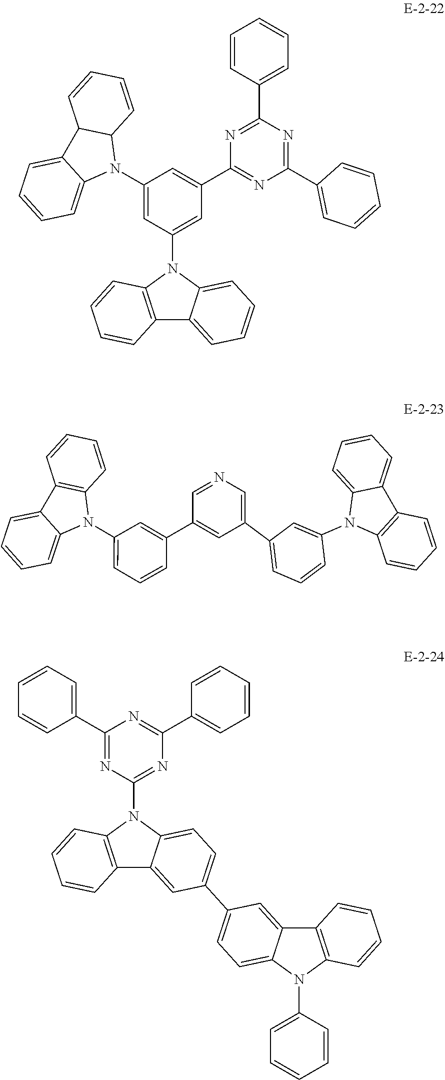 [SMILES: C1=CC2c3ccccc3N(c3cc(-c4nc(-c5ccccc5)nc(-c5ccccc5)n4)cc(-n4c5ccccc5c5ccccc54)c3)C2C=C1 ; c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may include the compound represented by Formula M-a. The compound represented by Formula M-a may be utilized as a phosphorescent dopant material.

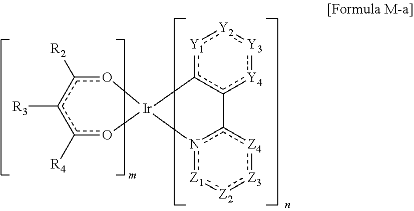

In Formula M-a, Y₁ to Y₄ and Z₁ to Z₄ may each independently be CR₁ or N, R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. In Formula M-a, m is 0 or 1, and n is 2 or 3. In Formula M-a, when m is 0, n is 3, and when m is 1, n is 2.

The compound represented by Formula M-a may be utilized as a phosphorescent dopant.

The compound represented by Formula M-a may be represented by any one selected from among Compound M-a1 to Compound M-a25. However, Compounds M-a1 to M-a25 are examples, and the compound represented by Formula M-a is not limited to those represented by Compounds M-a1 to M-a25.

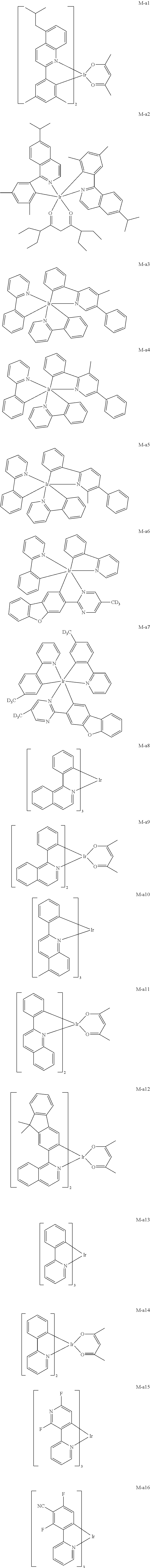

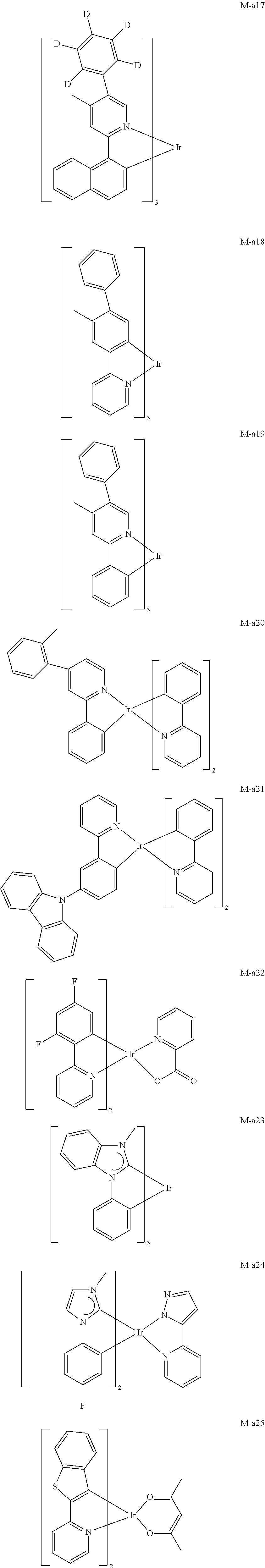

The emission layer EML may include a compound represented by any one selected from among Formula F-a to Formula F-c. The compound represented by Formula F-a to Formula F-c may be utilized as a fluorescene dopant material.

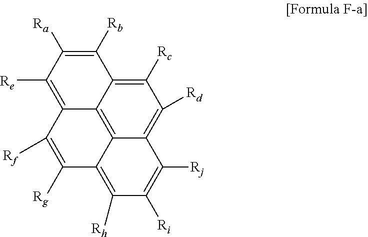

In Formula F-a, two selected from among Rₐ to Rⱼ may each independently be substituted with *—NAr₁Ar₂. The others, which are not substituted with *—NAr₁Ar₂ among Rₐ to Rⱼ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In *—NAr₁Ar₂, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. For example, at least one of Ar₁ or Ar₂ may be a heteroaryl group containing O or S as a ring-forming atom.

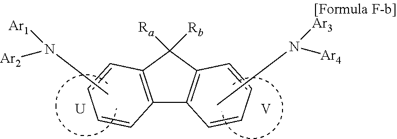

In Formula F-b, Rₐ and R_{b} may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. Ar₁ to Ar₄ may each independently be a substituted or unsubstituted aryl group having 6 to 30 ring-forming carbon atoms, or a substituted or unsubstituted heteroaryl group having 2 to 30 ring-forming carbon atoms.

In Formula F-b, U and V may each independently be a substituted or unsubstituted hydrocarbon ring having 5 to 30 ring-forming carbon atoms, or a substituted or unsubstituted heterocycle having 2 to 30 ring-forming carbon atoms. At least one selected from among Ar₁ to Ar₄ may be a heteroaryl group containing O or S as a ring-forming atom.

In Formula F-b, the number of rings represented by U and V may each independently be 0 or 1. For example, in Formula F-b, it refers to that when the number of U or V is 1, one ring constitutes a fused ring at a portion indicated by U or V, and when the number of U or V is 0, a ring indicated by U or V does not exist. For example, when the number of U is 0 and the number of V is 1, or when the number of U is 1 and the number of V is 0, the fused ring having a fluorene core in Formula F-b may be a cyclic compound having four rings. In some embodiments, when each number of U and V is 0, the fused ring in Formula F-b may be a cyclic compound having three rings. In some embodiments, when each number of U and V is 1, the fused ring having a fluorene core in Formula F-b may be a cyclic compound having five rings.

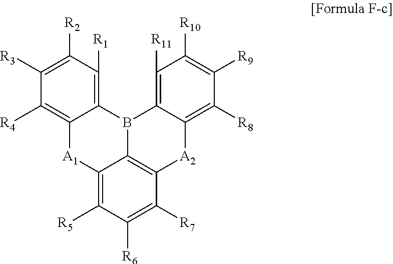

In Formula F-c, A₁ and A₂ may each independently be O, S, Se, or NRₘ, and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring.

In Formula F-c, A₁ and A₂ may each independently be bonded to substituents of an adjacent ring to form a fused ring. For example, when A₁ and A₂ may each independently be NRₘ, A₁ may be bonded to R₄ or R₅ to form a ring. In some embodiments, A₂ may be bonded to R₇ or R₈ to form a ring.

In one or more embodiments, the emission layer EML may further include, as a suitable dopant material, at least one selected from among a styryl derivative (e.g., 1,4-bis[2-(3-N-ethylcarbazolyl)vinyl]benzene (BCzVB), 4-(di-p-tolylamino)-4′-[(di-p-tolylamino)styryl]stilbene (DPAVB), and N-(4-((E)-2-(6-((E)-4-(diphenylamino)styryl)naphthalen-2-yl)vinyl)phenyl)-N-phenylbenzenamine (N-BDAVBi), 4,4′-bis[2-(4-(N,N-diphenylamino)phenyl)vinyl]biphenyl (DPAVBi), perylene and a derivative thereof (e.g., 2,5,8,11-tetra-t-butylperylene (TBP)), pyrene and a derivative thereof (e.g., 1,1-dipyrene, 1,4-dipyrenylbenzene, 1,4-bis(N,N-diphenylamino)pyrene), and/or the like.

The emission layer EML may further include a suitable phosphorescence dopant material. For example, a metal complex containing iridium (Ir), platinum (Pt), osmium (Os), aurum (Au), titanium (Ti), zirconium (Zr), hafnium (Hf), europium (Eu), terbium (Tb), or thulium (Tm) may be utilized as a phosphorescent dopant. For example, iridium(III) bis(4,6-difluorophenylpyridinato-N,C2) (Firpic), bis(2,4-difluorophenylpyridinato)-tetrakis(1-pyrazolyl)borate iridium(III) (Fir6), or platinum octaethyl porphyrin (PtOEP) may be utilized as a phosphorescent dopant. However, the embodiment of the present disclosure is not limited thereto.

The emission layer EML may include a quantum dot material. The core of a quantum dot may be selected from among a Group II-VI compound, a Group I-II-VI compound, a Group II-IV-VI compound, a Group I-II-IV-VI compound, a Group II-IV-V compound, a Group III-VI compound, a Group I-III-VI element, a Group III-V compound, a Group III-II-V compound, a Group IV-VI compound, a Group IV element, a Group IV compound, and a combination thereof.

The Group II-VI compound may be selected from the group consisting of a binary compound selected from the group consisting of CdSe, CdTe, CdS, ZnS, ZnSe, ZnTe, ZnO, HgS, HgSe, HgTe, MgSe, MgS, and a mixture thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, and a mixture thereof.

In some embodiments, the Group II-VI compound may further include a Group I metal and/or a Group IV element. The Group I-II-VI compound may be selected from among CuSnS and/or CuZnS, and the Group II-IV-VI compound may be selected from among ZnSnS and/or the like. The Group I-II-IV-VI compound may be selected from among quaternary compounds selected from the group consisting of Cu₂ZnSnS₂, Cu₂ZnSnS₄, Cu₂ZnSnSe₄, Ag₂ZnSnS₂, and a mixture thereof.

The Group II-IV-V compound may be selected from among a ternary compound selected from the group consisting of ZnSnP, ZnSnP₂, ZnSnAs₂, ZnGeP₂, ZnGeAs₂, CdSnP₂, and CdGeP₂ and a mixture thereof.

The Group III-VI compound may include a binary compound such as GaS, Ga₂S₃, GaSe, Ga₂Se₃, GaTe, InTe, InS, InSe, In₂S₃, and/or In₂Se₃, a ternary compound such as InGaS₃ and/or InGaSe₃, or any combination thereof.

The Group I-III-VI compound may be selected from among a ternary compound selected from the group consisting of AgInS, AgInS₂, CuInS, CuInS₂, AgGaS₂, CuGaS₂ CuGaO₂, AgGaO₂, AgAlO₂, and/or a mixture thereof, and/or a quaternary compound such as AgInGaS₂ and/or CuInGaS₂.

The Group III-V compound may be selected from the group consisting of a binary compound selected from the group consisting of GaN, GaP, GaAs, GaSb, AlN, AlP, AlAs, AlSb, InN, InP, InAs, InSb, and a mixture thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof, and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof. In some embodiments, the Group III-V compound may further include a Group II metal. For example, InZnP, and/or the like may be selected as a Group III-II-V compound.

The Group IV-VI compound may be selected from the group consisting of a binary compound selected from the group consisting of SnS, SnSe, SnTe, PbS, PbSe, PbTe, and a mixture thereof, a ternary compound selected from the group consisting of SnSeS, SnSeTe, SnSTe, PbSeS, PbSeTe, PbSTe, SnPbS, SnPbSe, SnPbTe, and a mixture thereof, and a quaternary compound selected from the group consisting of SnPbSSe, SnPbSeTe, SnPbSTe, and a mixture thereof. The Group IV element may be selected from the group consisting of Si, Ge, and a mixture thereof. The Group IV compound may be a binary compound selected from the group consisting of SiC, SiGe, and a mixture thereof.

Each element included in the multi-element compound such as the binary compound, ternary compound, and quaternary compound may be present in particle form, e.g., as particles, at a substantially uniform concentration or a non-substantially uniform concentration. For example, the formula as disclosed herein indicates the types (kinds) of elements included in a compound, and element ratios in the compound may be different. For example, AgInGaS₂ may indicate AgInₓGa₁₋ₓS₂ (x is a real number between 0 and 1).

In some embodiments, the quantum dot may have a single structure having a substantially uniform concentration of each element included in the corresponding quantum dot or a dual structure of a core-shell. For example, materials included in the core may be different from materials included in the shell. Examples of the shell of the quantum dot may be a metal or non-metal oxide, a semiconductor compound, and/or a combination thereof.

For example, the metal or non-metal oxide may be a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and/or NiO, or a ternary compound such as MgAl₂O₄, CoFe₂O₄, NiFe₂O₄, and/or CoMn₂O₄, but the embodiment of the present disclosure is not limited thereto.

In some embodiments, the semiconductor compound may be, for example, CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and/or the like, but the embodiment of the present disclosure is not limited thereto.

Each element included in the multi-element compound such as the binary compound and/or the ternary compound may be present in particle form, e.g., as particles at a substantially uniform concentration or a non-substantially uniform concentration. For example, the formula as disclosed herein indicates the types (kinds) of elements included in a compound, and element ratios in the compound may be different.

The quantum dot may have, in an emission wavelength spectrum, a full width of half maximum (FWHM) of about 45 nanometer (nm) or less, about 40 nm or less, or about 30 nm or less, and in this range, the color purity or the color reproducibility may be improved. In some embodiments, light emitted through the quantum dot is emitted in all directions, and thus a wide viewing angle may be improved, (e.g., the size or width of the viewing angle may be enhanced or increased).

In some embodiments, the form of a quantum dot is not particularly limited as long as it is a form commonly utilized in the art, but more specifically, a quantum dot in the form of spherical, pyramidal, multi-arm, and/or cubic nanoparticles, nanotubes, nanowires, nanofibers, nanoplatelets, and/or the like may be utilized.

As the size of the quantum dot or the ratio of elements in the quantum dot compound is regulated, the energy band gap may be accordingly controlled or selected to obtain light of one or more suitable wavelengths from the quantum dot emission layer. Therefore, by utilizing the quantum dots as described herein (utilizing quantum dots of different sizes or having different element ratios in the quantum dot compound), a light emitting device emitting light of one or more suitable wavelengths may be obtained. For example, the size of the quantum dots or the ratio of elements in the quantum dot compound may be regulated to emit red, green, and/or blue light. In some embodiments, the quantum dots may be configured to emit white light by combining light of one or more suitable colors.

In each of the light emitting devices ED of embodiments illustrated in FIGS. 3 to 7, the electron transport region ETR is provided on the emission layer EML. The electron transport region ETR may include at least one selected from among the hole blocking layer HBL, the electron transport layer ETL, and/or the electron injection layer EIL, but the embodiment of the present disclosure is not limited thereto.

The electron transport region ETR may have a single layer formed of a single material, a single layer formed of a plurality of different materials, or a multilayer structure including a plurality of layers formed of a plurality of different materials.

For example, the electron transport region ETR may have a single layer structure of the electron injection layer EIL or the electron transport layer ETL, and may have a single layer structure formed of an electron injection material and an electron transport material. In some embodiments, the electron transport region ETR may have a single layer structure formed of a plurality of different materials, or may have a structure in which an electron transport layer ETL/electron injection layer EIL, a hole blocking layer HBL/electron transport layer ETL/electron injection layer EIL are stacked in order from the emission layer EML, but the embodiment of the present disclosure is not limited thereto. The electron transport region ETR may have a thickness, for example, from about 1,000 Å to about 1,500 Å.

The electron transport region ETR may be formed utilizing one or more suitable methods such as a vacuum deposition method, a spin coating method, a cast method, a Langmuir-Blodgett (LB) method, an inkjet printing method, a laser printing method, and/or a laser induced thermal imaging (LITI) method.

The electron transport region ETR may include a compound represented by Formula ET-2:

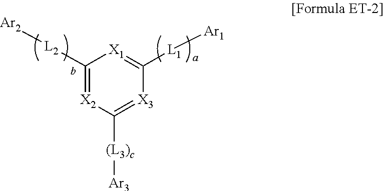

In Formula ET-2, at least one among X₁ to X₃ is N, and the rest are CRₐ. Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-2, a to c may each independently be an integer of 0 to 10. In Formula ET-2, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. In some embodiments, when a to c may each independently be an integer of 2 or more, L₁ to L₃ may each independently be a substituted or unsubstituted arylene group having 6 to 30 ring-forming carbon atoms, or a substituted or unsubstituted heteroarylene group having 2 to 30 ring-forming carbon atoms.

The electron transport region ETR may include an anthracene-based compound. However, the embodiment of the present disclosure is not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,08)-(1,1′-biphenyl-4-olato)aluminum (BAlq), beryllium bis(benzoquinolin-10-olate) (Bebq₂), 9,10-di(naphthalene-2-yl)anthracene (ADN), 1,3-bis[3,5-di(pyridin-3-yl)phenyl]benzene (BmPyPhB), and/or a mixture thereof.

The electron transport region ETR may include at least one selected from among Compound ET1 to Compound ET36:

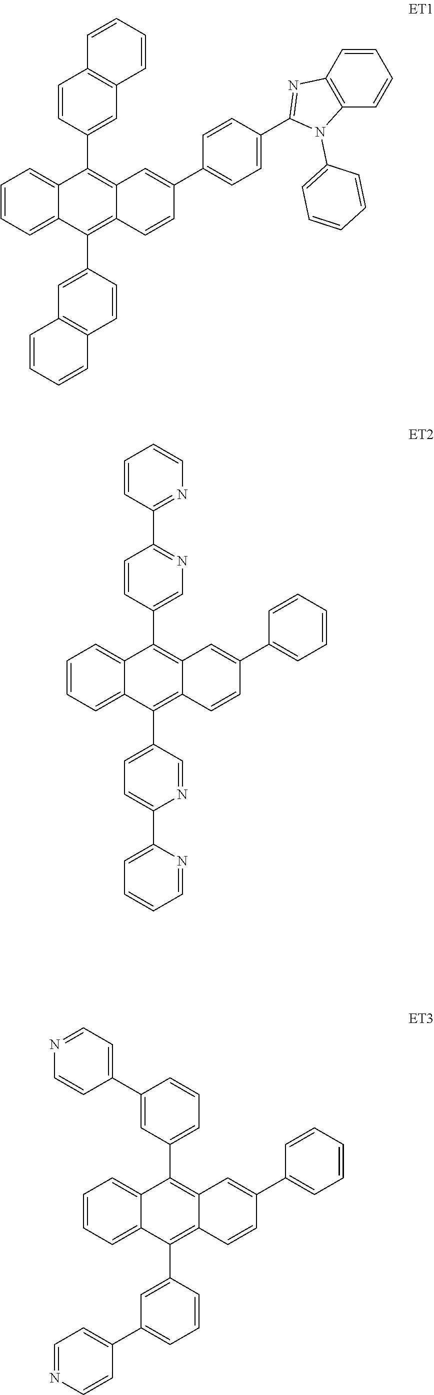 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

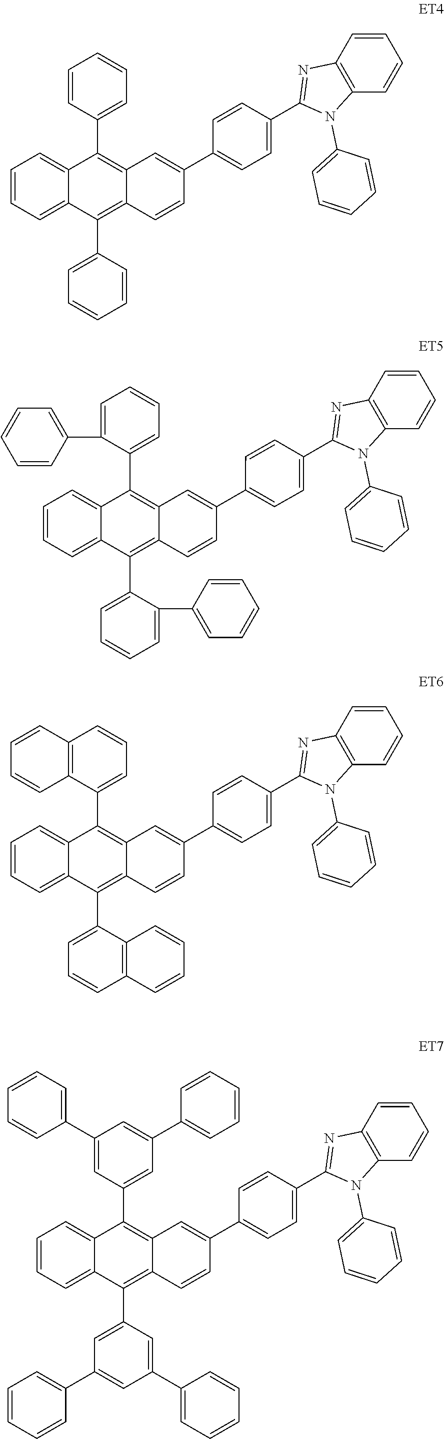 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

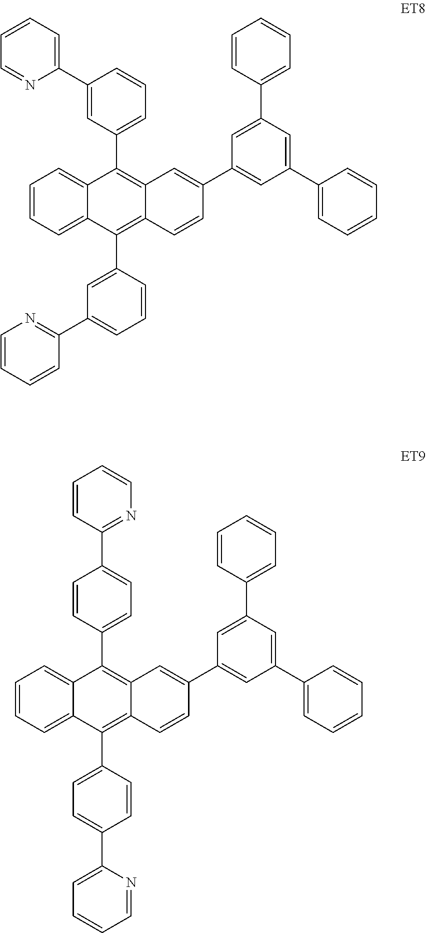 [SMILES: c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

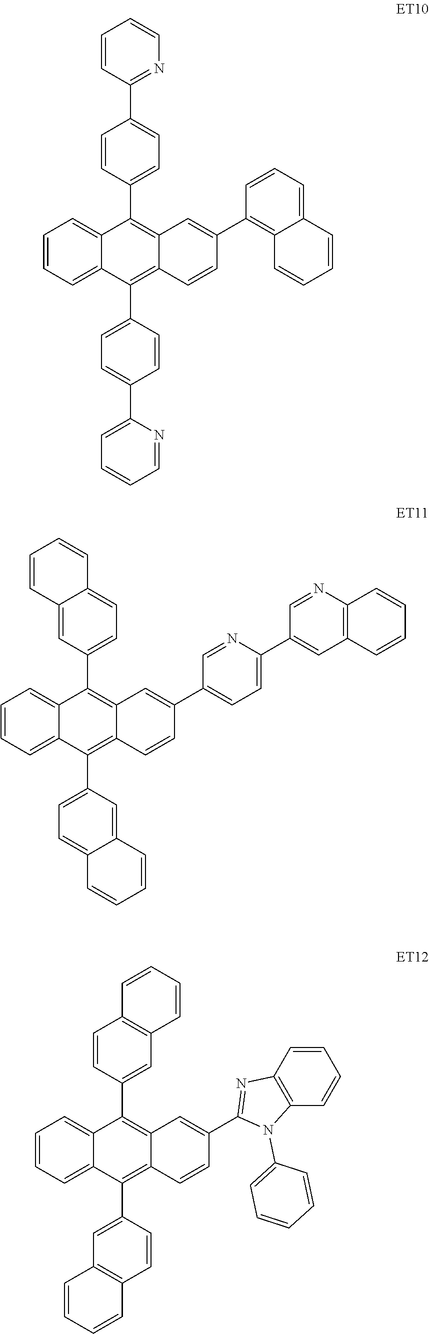 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

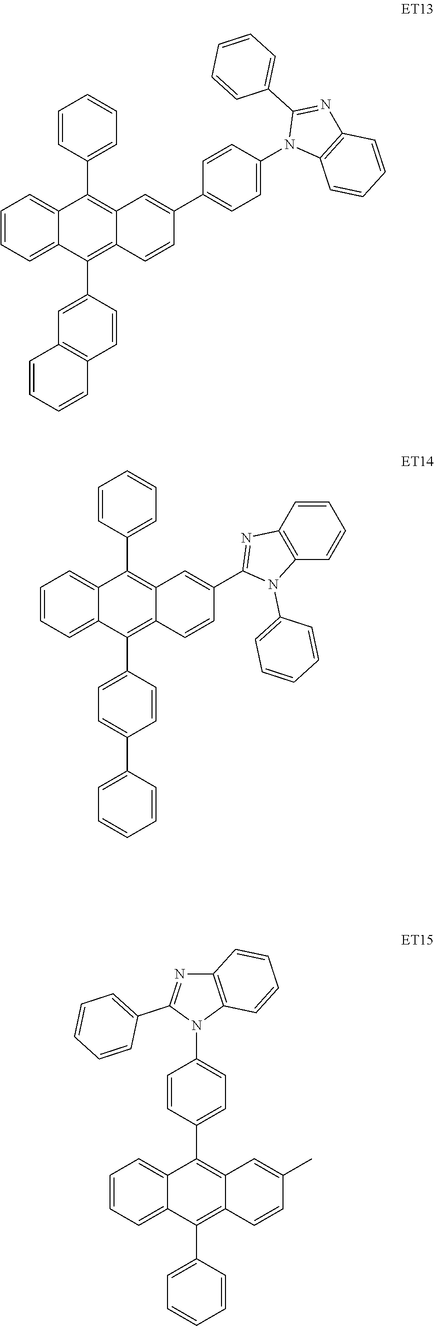 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

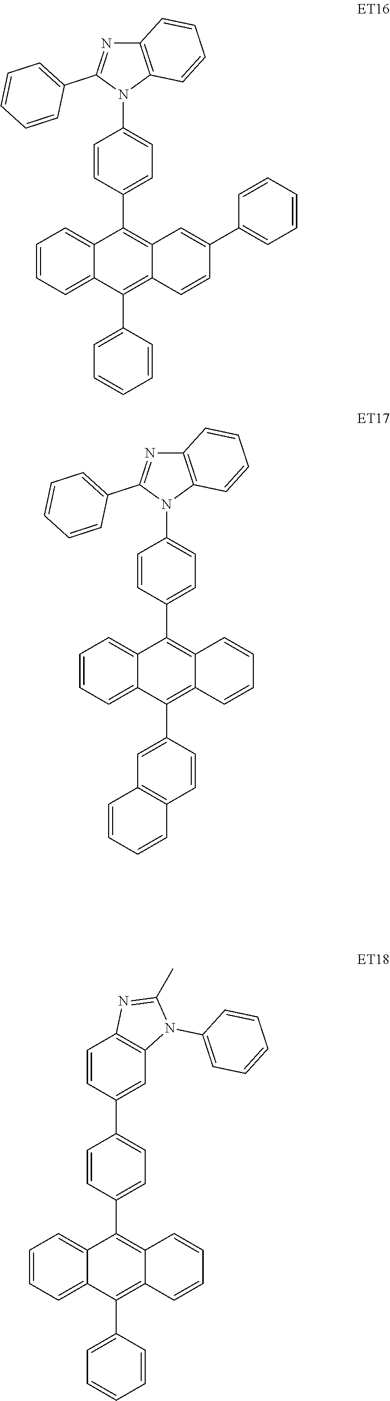 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

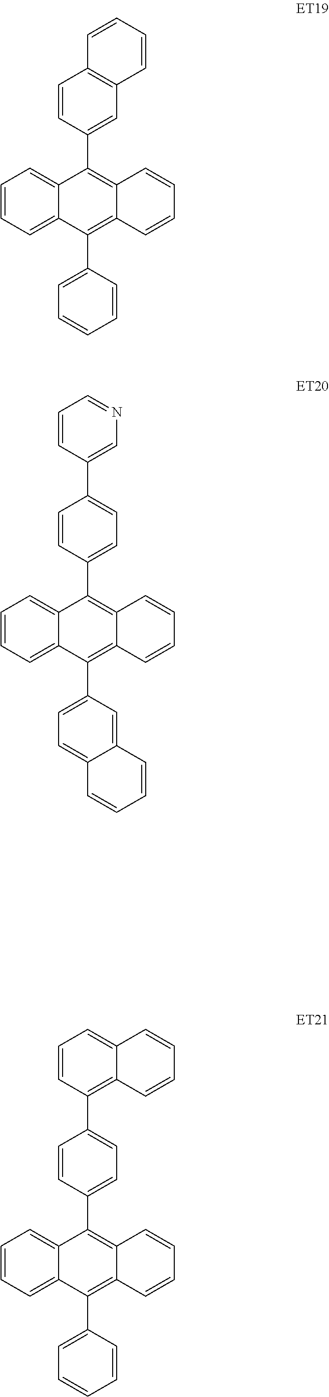

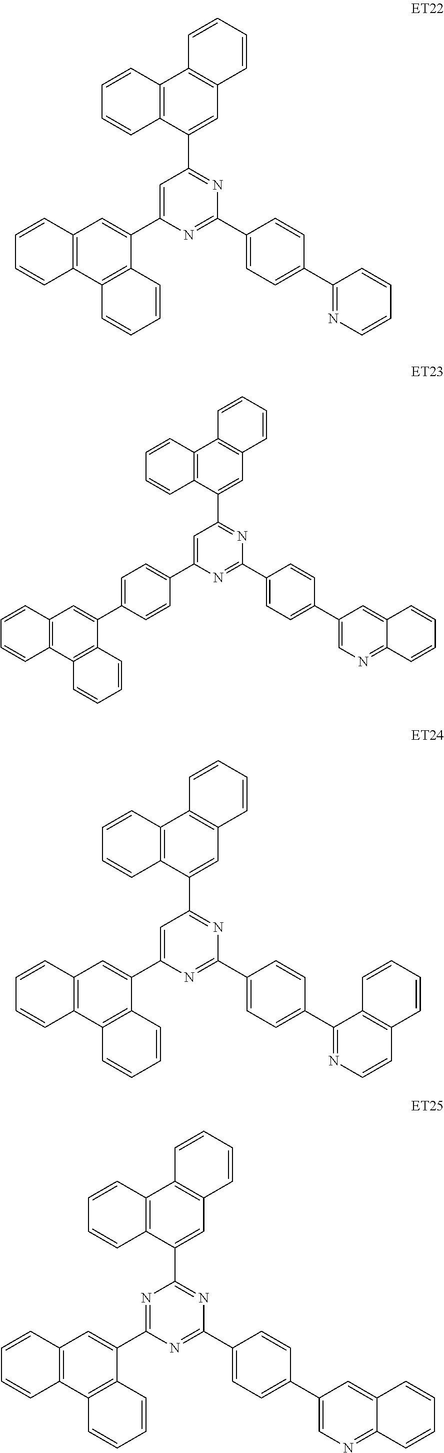 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1]

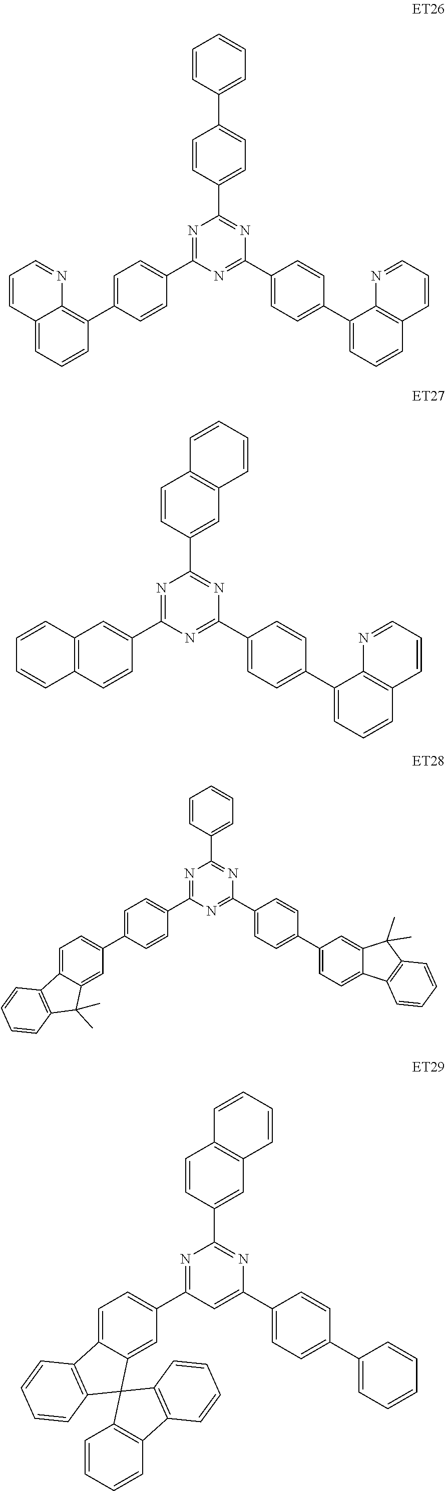 [SMILES: c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1]

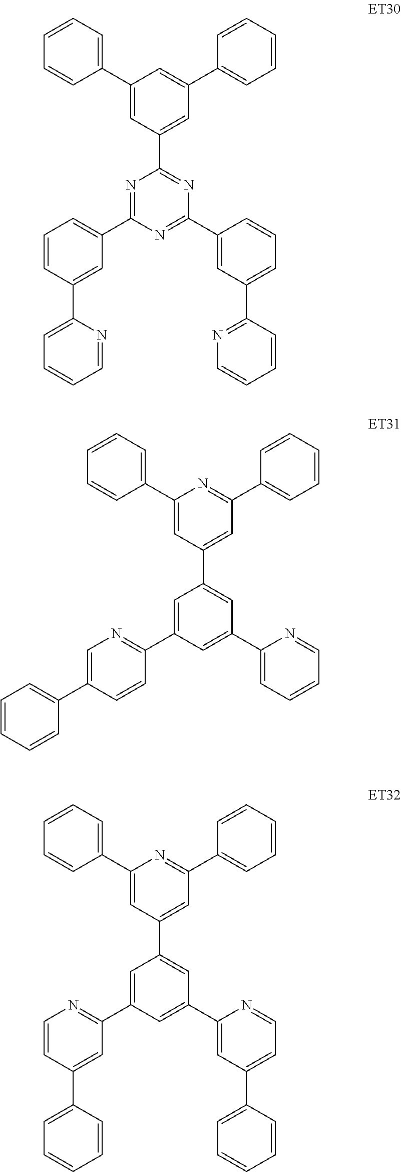 [SMILES: c1ccc(-c2cc(-c3ccccc3)cc(-c3nc(-c4cccc(-c5ccccn5)c4)nc(-c4cccc(-c5ccccn5)c4)n3)c2)cc1 ; c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1]

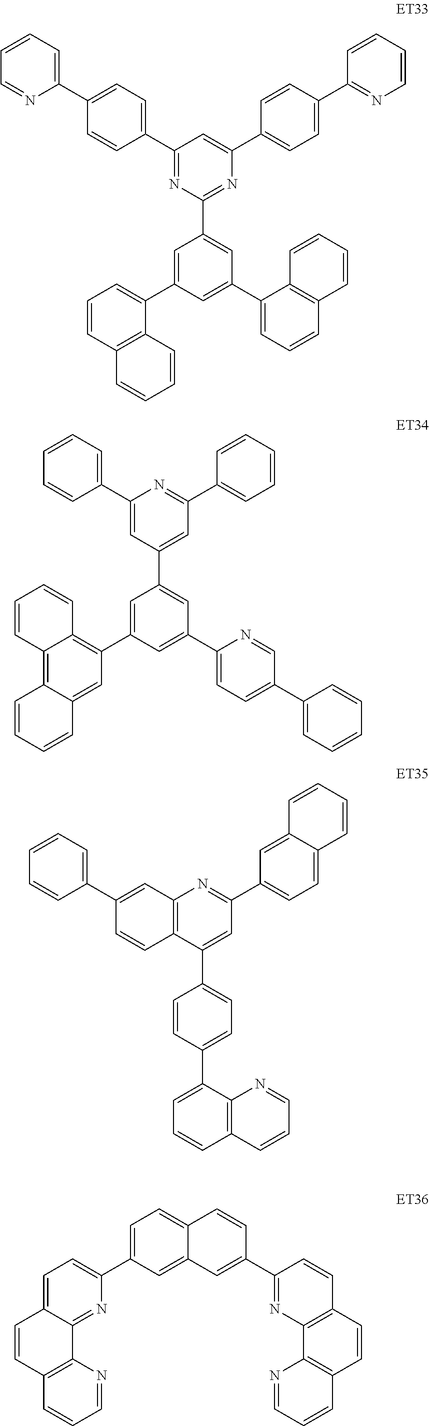

In some embodiments, the electron transport region ETR may include a metal halide such as LiF, NaCl, CsF, RbCl, RbI, CuI, and/or KI, a lanthanide metal such as Yb, and/or a co-deposited material of the metal halide and the lanthanide metal. For example, the electron transport region ETR may include KI:Yb, RbI:Yb, LiF:Yb, and/or the like, as a co-deposited material. In some embodiments, the electron transport region ETR may be formed utilizing a metal oxide such as Li₂O and/or BaO, and/or 8-hydroxyl-lithium quinolate (Liq), and/or the like, but the embodiment of the present disclosure is not limited thereto. The electron transport region ETR may also be formed of a mixture material of an electron transport material and an insulating organometallic salt. The organometallic salt may be a material having an energy band gap of about 4 eV or more. For example, the organometallic salt may include, for example, a metal acetate, a metal benzoate, a metal acetoacetate, a metal acetylacetonate, and/or a metal stearate.

The electron transport region ETR may further include at least one selected from among 2,9-dimethyl-4,7-diphenyl-1,10-phenanthroline (BCP), diphenyl(4-(triphenylsilyl)phenyl)phosphine oxide (TSPO1), and/or 4,7-diphenyl-1,10-phenanthroline (Bphen) in addition to the described materials, but the embodiment of the present disclosure is not limited thereto.

The electron transport region ETR may include the described compounds of the hole transport region in at least one of the electron injection layer EIL, the electron transport layer ETL, or the hole blocking layer HBL.

When the electron transport region ETR includes the electron transport layer ETL, the electron transport layer ETL may have a thickness of about 100 Å to about 1,000 Å, for example, about 150 Å to about 500 Å. When the thickness of the electron transport layer ETL satisfies the aforementioned range, satisfactory electron transport characteristics may be obtained without a substantial increase in driving voltage. When the electron transport region ETR includes the electron injection layer EIL, the electron injection layer EIL may have a thickness of about 1 Å to about 100 Å, for example, about 3 Å to about 90 Å. When the thickness of the electron injection layer EIL satisfies the described range, satisfactory electron injection characteristics may be obtained without a substantial increase in driving voltage.

The second electrode EL2 is provided on the electron transport region ETR. The second electrode EL2 may be a common electrode. The second electrode EL2 may be a cathode or an anode, but the embodiment of the present disclosure is not limited thereto. For example, when the first electrode EL1 is an anode, the second electrode EL2 may be a cathode, and when the first electrode EL1 is a cathode, the second electrode EL2 may be an anode.

The second electrode EL2 may be a transmissive electrode, a transflective electrode, or a reflective electrode. When the second electrode EL2 is the transmissive electrode, the second electrode EL2 may be formed of a transparent metal oxide, for example, indium tin oxide (ITO), indium zinc oxide (IZO), zinc oxide (ZnO), indium tin zinc oxide (ITZO), and/or the like.

When the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, or a compound or mixture thereof (e.g., AgMg, AgYb, or MgYb). In some embodiments, the second electrode EL2 may have a multilayer structure including a reflective film or a transflective film formed of the described materials, and a transparent conductive film formed of ITO, IZO, ZnO, ITZO, and/or the like For example, the second electrode EL2 may include one or more selected from the described metal materials, combinations of at least two metal materials of the described metal materials, oxides of the described metal materials, and/or the like.

In some embodiments, the second electrode EL2 may be connected with an auxiliary electrode. When the second electrode EL2 is connected with the auxiliary electrode, the resistance of the second electrode EL2 may be decreased.

In some embodiments, a capping layer CPL may further be provided on the second electrode EL2 of the light emitting device ED of one or more embodiments. The capping layer CPL may include a multilayer or a single layer.

In one or more embodiments, the capping layer CPL may be an organic layer or an inorganic layer. For example, when the capping layer CPL contains an inorganic material, the inorganic material may include an alkaline metal compound (e.g., LiF), an alkaline earth metal compound (e.g., MgF₂), SiON, SiNₓ, SiO_{y}, and/or the like.

For example, when the capping layer CPL includes an organic material, the organic material may include α-NPD, NPB, TPD, m-MTDATA, Alq₃, CuPc, N4,N4,N4′,N4′-tetra(biphenyl-4-yl)biphenyl-4,4′-diamine (TPD15), 4,4′,4″-tris(carbazol-9-yl)triphenylamine (TCTA), and/or the like, an epoxy resin, and/or acrylate such as methacrylate. However, the embodiment of the present disclosure is not limited thereto, and the capping layer CPL may include at least one selected from among Compounds P1 to P5:

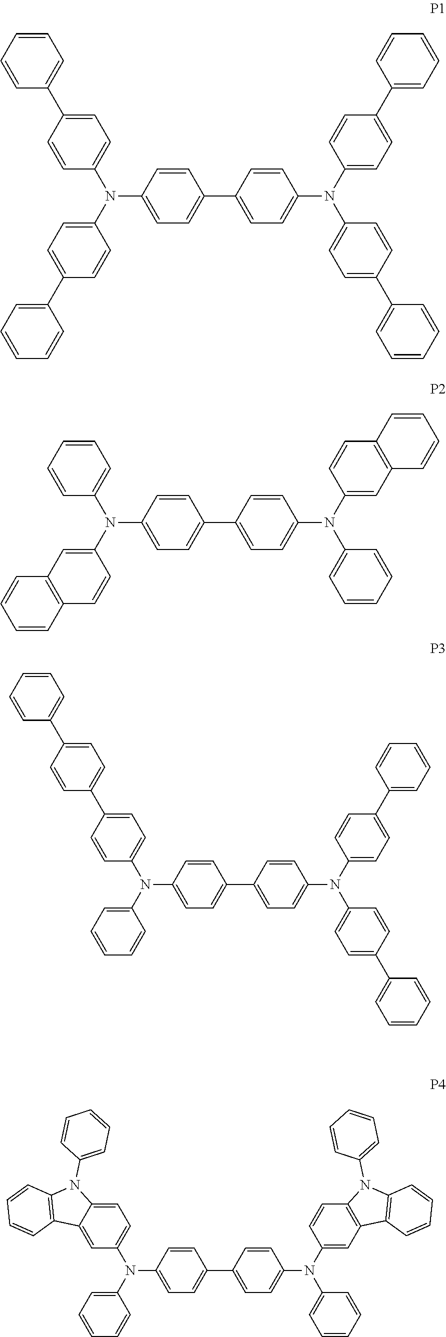 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

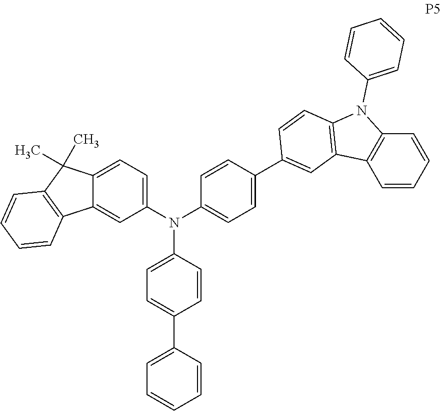 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21]

In some embodiments, the refractive index of the capping layer CPL may be about 1.6 or more. For example, the refractive index of the capping layer CPL may be about 1.6 or more with respect to light in a wavelength range of about 550 nm to about 660 nm.

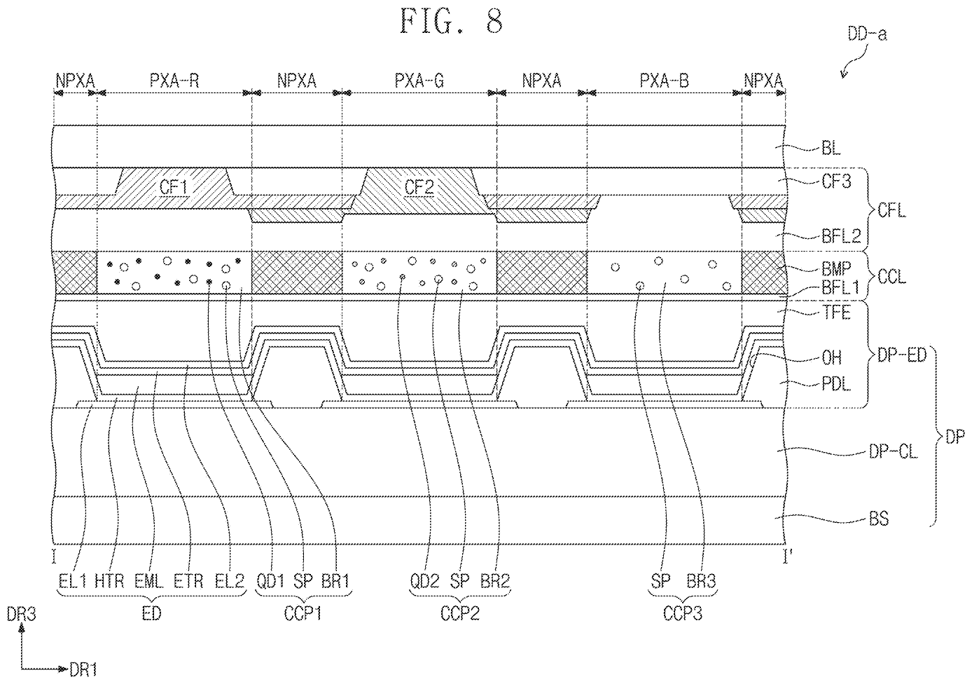

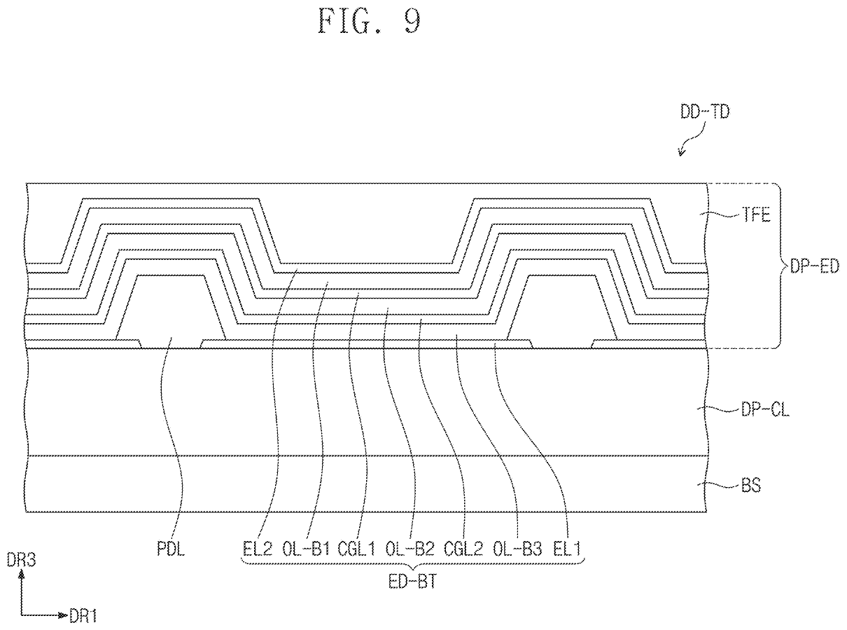

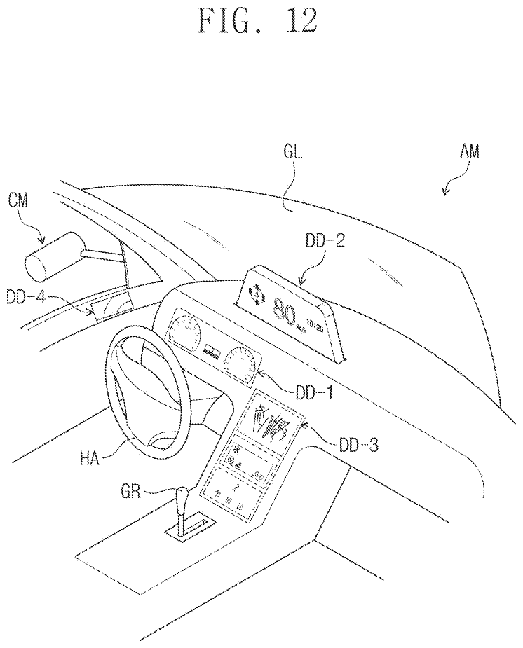

FIGS. 8 to 11 are each a cross-sectional view of a display apparatus according to one or more embodiments. Hereinafter, in the description of the display apparatus according to one or more embodiments with reference to FIGS. 8 and 11, content (e.g., amount) overlapping the one described herein with reference to FIGS. 1 to 7 will not be described again, and, instead, the differences will be mainly described, (e.g., in more detail).

Referring to FIG. 8, a display apparatus DD-a according to one or more embodiments may include a display panel DP having a display device layer DP-ED, a light control layer CCL provided on the display panel DP, and a color filter layer CFL.

In one or more embodiments shown in FIG. 8, the display panel DP may include a base layer BS, a circuit layer DP-CL provided on the base layer BS, and a display device layer DP-ED, and the display device layer DP-ED may include a light emitting device ED.

The light emitting device ED may include a first electrode EL1, a hole transport region HTR provided on the first electrode EL1, an emission layer EML provided on the hole transport region HTR, an electron transport region ETR provided on the emission layer EML, and a second electrode EL2 provided on the electron transport region ETR. In some embodiments, a structure of the light emitting device ED shown in FIG. 8 may be the same as the structure of the light emitting device of FIGS. 3 to 7 described herein. The light emitting device ED shown in FIG. 8 may include the fused polycyclic compound of one or more embodiments and at least one of the second to fourth compounds. Accordingly, the light emitting device ED may exhibit high efficiency and long service life.

Referring to FIG. 8, the emission layer EML may be provided in an opening OH defined in a pixel defining film PDL. For example, the emission layer EML which is divided by the pixel defining film PDL and provided corresponding to each light emitting regions PXA-R, PXA-G, and PXA-B may be to emit (e.g., configured to emit) light in substantially the same wavelength range. In the display apparatus DD-a of one or more embodiments, the emission layer EML may be to emit (e.g., configured to emit) blue light. In some embodiments, unlike the configuration illustrated, in one or more embodiments, the emission layer EML may be provided as a common layer in the entire light emitting regions PXA-R, PXA-G, and PXA-B.

The light control layer CCL may be provided on the display panel DP. The light control layer CCL may include a light conversion body. The light conversion body may be a quantum dot, a phosphor, and/or the like. The light conversion body may be to emit (e.g., configured to emit) provided light by converting the wavelength thereof.

For example, the light control layer CCL may a layer containing the quantum dot or a layer containing the phosphor.

The light control layer CCL may include a plurality of light control parts CCP1, CCP2 and CCP3. The light control parts CCP1, CCP2, and CCP3 may be spaced apart from each other.

Referring to FIG. 8, divided patterns BMP may be provided between the light control parts CCP1, CCP2 and CCP3 which are spaced apart from each other, but the embodiment of the present disclosure is not limited thereto. FIG. 8 illustrates that the divided patterns BMP do not overlap the light control parts CCP1, CCP2 and CCP3, but at least a portion of the edges of the light control parts CCP1, CCP2 and CCP3 may overlap the divided patterns BMP.

The light control layer CCL may include a first light control part CCP1 containing a first quantum dot QD1 which converts first color light provided from the light emitting device ED into second color light, a second light control part CCP2 containing a second quantum dot QD2 which converts the first color light into third color light, and a third light control part CCP3 which transmits the first color light.

In one or more embodiments, the first light control part CCP1 may provide red light that is the second color light, and the second light control part CCP2 may provide green light that is the third color light. The third light control part CCP3 may provide blue light by transmitting the blue light that is the first color light provided from the light emitting device ED. For example, the first quantum dot QD1 may be a red quantum dot, and the second quantum dot QD2 may be a green quantum dot. The same as described herein may be applied with respect to the quantum dots QD1 and QD2.

In some embodiments, the light control layer CCL may further include a scatterer SP. The first light control part CCP1 may include the first quantum dot QD1 and the scatterer SP, the second light control part CCP2 may include the second quantum dot QD2 and the scatterer SP, and the third light control part CCP3 may not include (e.g., may exclude) any quantum dot but include the scatterer SP.

The scatterer SP may be inorganic particles. For example, the scatterer SP may include at least one selected from among TiO₂, ZnO, Al₂O₃, SiO₂, or hollow sphere silica. The scatterer SP may include any one selected from among TiO₂, ZnO, Al₂O₃, SiO₂, and hollow sphere silica, or may be a mixture of at least two materials selected from among TiO₂, ZnO, Al₂O₃, SiO₂, and hollow sphere silica.

The first light control part CCP1, the second light control part CCP2, and the third light control part CCP3 include base resins BR1, BR2, and BR3 (respectively) in which the quantum dots QD1 and QD2 and the scatterer SP may be dispersed. In one or more embodiments, the first light control part CCP1 may include the first quantum dot QD1 and the scatterer SP dispersed in a first base resin BR1, the second light control part CCP2 may include the second quantum dot QD2 and the scatterer SP dispersed in a second base resin BR2, and the third light control part CCP3 may include the scatterer SP dispersed in a third base resin BR3.

The base resins BR1, BR2, and BR3 are each a composition (e.g., media) in which the quantum dots QD1 and QD2 and the scatterer SP are dispersed, and may be formed of one or more suitable resin compositions, which may be generally referred to as a binder. For example, the base resins BR1, BR2, and BR3 may be acrylic-based resins, urethane-based resins, silicone-based resins, epoxy-based resins, and/or the like. The base resins BR1, BR2, and BR3 may be transparent resins. In one or more embodiments, the first base resin BR1, the second base resin BR2, and the third base resin BR3 may be the same as or different from each other.

The light control layer CCL may include a barrier layer BFL1. The barrier layer BFL1 may serve to prevent or reduce the penetration of moisture and/or oxygen (hereinafter, referred to as ‘moisture/oxygen’). The barrier layer BFL1 may block or reduce the light control parts CCP1, CCP2 and CCP3 from being exposed to moisture/oxygen. In some embodiments, the barrier layer BFL1 may cover the light control parts CCP1, CCP2, and CCP3. In some embodiments, the barrier layer BFL2 may be provided between the light control parts CCP1, CCP2, and CCP3 and the color filter layer CFL.

The barrier layers BFL1 and BFL2 may include at least one inorganic layer. For example, the barrier layers BFL1 and BFL2 may include an inorganic material. For example, the barrier layers BFL1 and BFL2 may include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, and/or a metal thin film which secures a transmittance, and/or the like. In some embodiments, the barrier layers BFL1 and BFL2 may further include an organic film. The barrier layers BFL1 and BFL2 may be formed of a single layer or a plurality of layers.

In the display apparatus DD-a of one or more embodiments, the color filter layer CFL may be provided on the light control layer CCL. For example, the color filter layer CFL may be directly provided on the light control layer CCL. In this case, the barrier layer BFL2 may not be provided.

The color filter layer CFL may include color filters CF1, CF2, and CF3. The color filter layer CFL may include a first filter CF1 configured to transmit the second color light, a second filter CF2 configured to transmit the third color light, and a third filter CF3 configured to transmit the first color light. For example, the first filter CF1 may be a red filter, the second filter CF2 may be a green filter, and the third filter CF3 may be a blue filter. The filters CF1, CF2, and CF3 each may include a polymeric photosensitive resin and a pigment or dye. The first filter CF1 may include a red pigment or dye, the second filter CF2 may include a green pigment or dye, and the third filter CF3 may include a blue pigment or dye.

In some embodiments, the embodiment of the present disclosure is not limited thereto, and the third filter CF3 may not include (e.g., may exclude) a pigment or dye. The third filter CF3 may include a polymeric photosensitive resin and may not include a (e.g., may exclude any) pigment or dye. The third filter CF3 may be transparent. The third filter CF3 may be formed of a transparent photosensitive resin.

In one or more embodiments, the first filter CF1 and the second filter CF2 may be a yellow filter. The first filter CF1 and the second filter CF2 may not be separated but be provided as one filter.

In one or more embodiments, the color filter layer CFL may further include a light shielding part. The light shielding part may be a black matrix. The light shielding part may include an organic light shielding material or an inorganic light shielding material containing a black pigment or dye. The light shielding part may prevent or reduce light leakage, and may separate boundaries between the adjacent filters CF1, CF2, and CF3. Also, the light shielding part may be formed of a blue filter.

The first to third filters CF1, CF2, and CF3 may be provided corresponding to the red light emitting region PXA-R, the green light emitting region PXA-G, and the blue light emitting region PXA-B, respectively.

A base substrate BL may be provided on the color filter layer CFL. The base substrate BL may be a member which provides a base surface in which the color filter layer CFL, the light control layer CCL, and/or the like are provided. The base substrate BL may be a glass substrate, a metal substrate, a plastic substrate, and/or the like. However, the embodiment of the present disclosure is not limited thereto, and the base substrate BL may be an inorganic layer, an organic layer, or a composite material layer. In some embodiments, unlike the configuration illustrated, in one or more embodiments, the base substrate BL may not be provided.

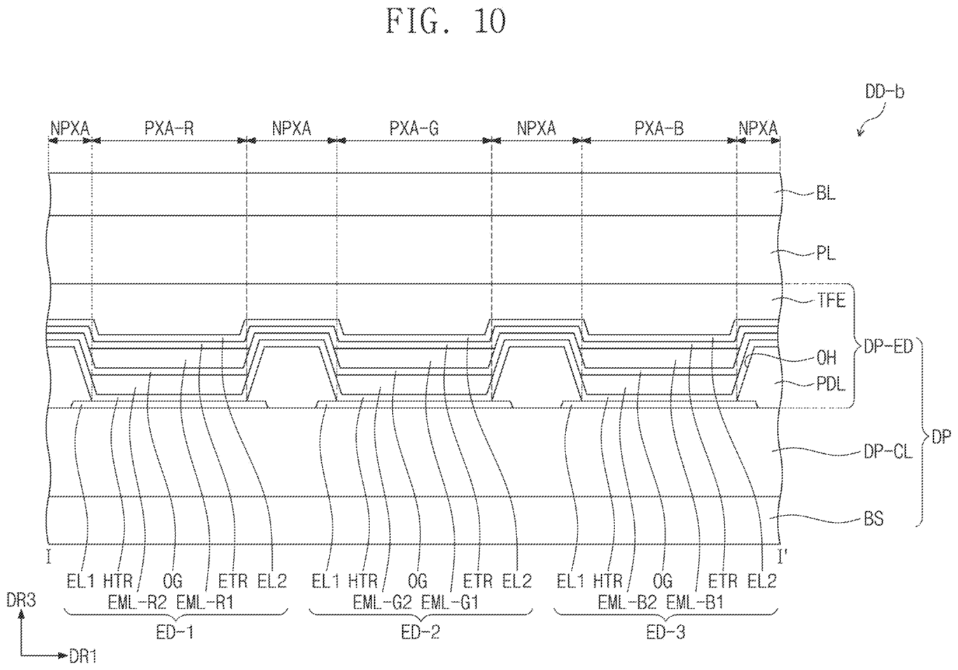

FIG. 9 is a cross-sectional view showing a portion of a display apparatus according to one or more embodiments. In a display apparatus DD-TD of one or more embodiments, a light emitting device ED-BT may include a plurality of light emitting structures OL-B1, OL-B2, and OL-B3. At least one of the plurality of light emitting structures OL-B1, OL-B2, and OL-B3 may include the fused polycyclic compound of one or more embodiments and at least one of the second to fourth compounds. Accordingly, the light emitting device ED-BT may exhibit high efficiency and long service life.

The light emitting device ED-BT may include a first electrode EL1 and a second electrode EL2 which face each other, and the plurality of light emitting structures OL-B1, OL-B2, and OL-B3 sequentially stacked in the thickness direction between the first electrode EL1 and the second electrode EL2. The light emitting structures OL-B1, OL-B2, and OL-B3 each may include an emission layer EML (FIG. 8) and a hole transport region HTR and an electron transport region ETR provided with the emission layer EML (FIG. 8) located therebetween. For example, the light emitting device ED-BT included in the display apparatus DD-TD of one or more embodiments may be a light emitting device having a tandem structure and including a plurality of emission layers.

In one or more embodiments illustrated in FIG. 9, all light beams respectively emitted from the light emitting structures OL-B1, OL-B2, and OL-B3 may be blue light. However, the embodiment of the present disclosure is not limited thereto, and the light beams respectively emitted from the light emitting structures OL-B1, OL-B2, and OL-B3 may have wavelength ranges different from each other. For example, the light emitting device ED-BT including the plurality of light emitting structures OL-B1, OL-B2, and OL-B3 which emit light beams having wavelength ranges different from each other may be to emit (e.g., configured to emit) white light.

Charge generation layers CGL1 and CGL2 may be respectively provided between two of the neighboring light emitting structures OL-B1, OL-B2, and OL-B3.

The charge generation layers CGL1 and CGL2 may include a p-type or kind charge generation layer (p-charge generation layer) and/or an n-type or kind charge generation layer (n-charge generation layer).

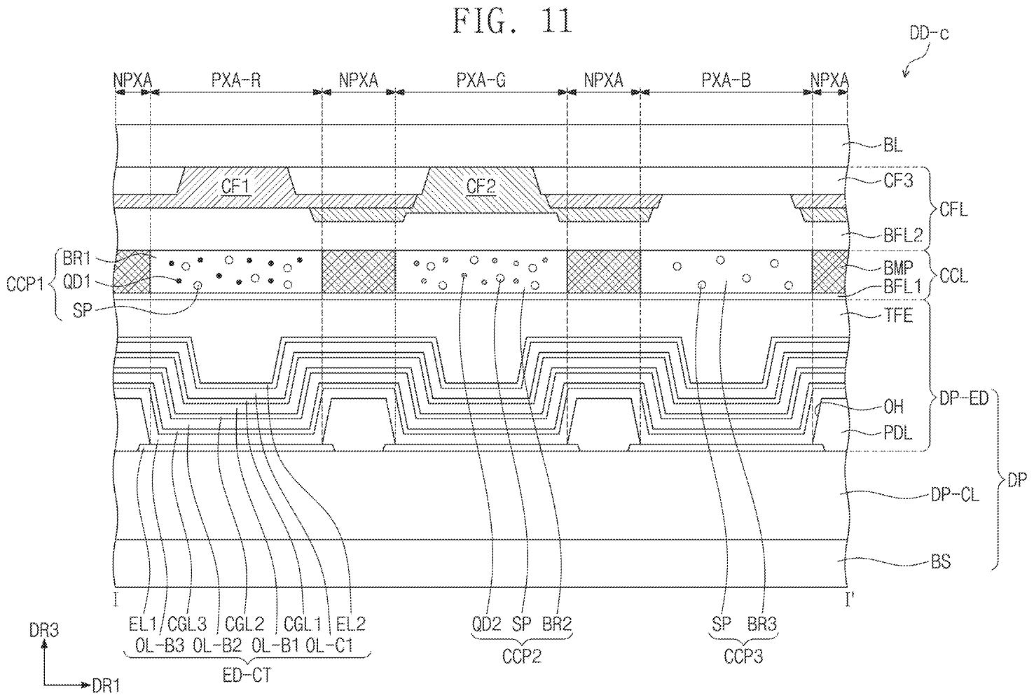

Referring to FIG. 10, a display apparatus DD-b according to one or more embodiments may include light emitting devices ED-1, ED-2, and ED-3 in which two emission layers are stacked. At least one of the light emitting devices ED-1, ED-2, or ED-3 may include the fused polycyclic compound of one or more embodiments and at least one of the second to fourth compounds. Accordingly, the light emitting device ED-BT may exhibit high efficiency and long service life.

Compared with the display apparatus DD of one or more embodiments illustrated in FIG. 2, one or more embodiments illustrated in FIG. 10 has a difference in that the first to third light emitting devices ED-1, ED-2, and ED-3 each include two emission layers stacked in the thickness direction. In each of the first to third light emitting devices ED-1, ED-2, and ED-3, the two emission layers may be to emit light in substantially the same wavelength region.

The first light emitting device ED-1 may include a first red emission layer EML-R1 and a second red emission layer EML-R2. The second light emitting device ED-2 may include a first green emission layer EML-G1 and a second green emission layer EML-G2. In some embodiments, the third light emitting device ED-3 may include a first blue emission layer EML-B1 and a second blue emission layer EML-B2. An emission auxiliary part OG may be provided between the first red emission layer EML-R1 and the second red emission layer EML-R2, between the first green emission layer EML-G1 and the second green emission layer EML-G2, and between the first blue emission layer EML-B1 and the second blue emission layer EML-B2.

The emission auxiliary part OG may include a single layer or a multilayer. The emission auxiliary part OG may include a charge generation layer. More specifically, the emission auxiliary part OG may include an electron transport region, a charge generation layer, and a hole transport region that are sequentially stacked. The emission auxiliary part OG may be provided as a common layer in the whole of the first to third light emitting devices ED-1, ED-2, and ED-3. However, the embodiment of the present disclosure is not limited thereto, and the emission auxiliary part OG may be provided by being patterned within the openings OH defined in the pixel defining film PDL.

The first red emission layer EML-R1, the first green emission layer EML-G1, and the first blue emission layer EML-B1 may be provided between the emission auxiliary part OG and the electron transport region ETR. The second red emission layer EML-R2, the second green emission layer EML-G2, and the second blue emission layer EML-B2 may be provided between the hole transport region HTR and the emission auxiliary part OG.

For example, the first light emitting device ED-1 may include the first electrode EL1, the hole transport region HTR, the second red emission layer EML-R2, the emission auxiliary part OG, the first red emission layer EML-R1, the electron transport region ETR, and the second electrode EL2 that are sequentially stacked. The second light emitting device ED-2 may include the first electrode EL1, the hole transport region HTR, the second green emission layer EML-G2, the emission auxiliary part OG, the first green emission layer EML-G1, the electron transport region ETR, and the second electrode EL2 that are sequentially stacked. The third light emitting device ED-3 may include the first electrode EL1, the hole transport region HTR, the second blue emission layer EML-B2, the emission auxiliary part OG, the first blue emission layer EML-B1, the electron transport region ETR, and the second electrode EL2 that are sequentially stacked.

In some embodiments, an optical auxiliary layer PL may be provided on the display device layer DP-ED. The optical auxiliary layer PL may include a polarizing layer. The optical auxiliary layer PL may be provided on the display panel DP and control reflected light in the display panel DP due to external light. Unlike the configuration illustrated, the optical auxiliary layer PL in the display apparatus according to one or more embodiments may not be provided.

Unlike FIGS. 9 and 10, the display apparatus DD-c of FIG. 11 is illustrated to include four light emitting structures OL-B1, OL-B2, OL-B3, and OL-C1. The light emitting device ED-BT may include the first electrode EL1 and the second electrode EL2 facing each other, and the first to fourth light emitting structures L-B1, OL-B2, OL-B3, and OL-C1 sequentially stacked in a thickness direction between the first electrode EL1 and the second electrode EL2. At least one of the first to fourth light emitting structures OL-B1, OL-B2, OL-B3, or OL-C1 may include the fused polycyclic compound of one or more embodiments and at least one of the second to fourth compounds. Accordingly, the light emitting device ED-BT may exhibit high efficiency and long service life.

Charge generation layers CGL1, CGL2, and CGL3 may be provided between the first to fourth light emitting structures OL-B1, OL-B2, OL-B3, and OL-C1. Among the four light emitting structures, the first to third light emitting structures OL-B1, OL-B2, and OL-B3 may be to emit (e.g., configured to emit) blue light, and the fourth light emitting structure OL-C1 may be to emit (e.g., configured to emit) green light. However, the embodiment of the present disclosure is not limited thereto, and the first to fourth light emitting structures OL-B1, OL-B2, OL-B3, and OL-C1 may be to emit (e.g., configured to emit) light beams in different wavelength regions. The charge generation layers CGL1, CGL2, and CGL3 provided between adjacent light emitting structures OL-B1, OL-B2, OL-B3, and OL-C1 may include a p-type or kind charge generation layer (p-charge generation layer) and/or an n-type or kind charge generation layer (n-charge generation layer).

In one or more embodiments, the electronic apparatus may include a display apparatus including a plurality of light emitting devices, and a control part which controls the display apparatus. The electronic apparatus of one or more embodiments may be a device that is activated according to an electrical signal. The electronic apparatus may include display apparatuses of one or more suitable embodiments. For example, the electronic apparatus may include not only large-sized electronic apparatuses such as a television set, a monitor, or an outdoor billboard but also include small- and medium-sized electronic apparatuses such as a personal computer, a laptop computer, a personal digital terminal, a display apparatus for a vehicle, a game console, a portable electronic device, or a camera.

FIG. 12 is a view illustrating a vehicle AM in which first to fourth display apparatuses DD-1, DD-2, DD-3, and DD-4 are provided. At least one among the first to fourth display apparatuses DD-1, DD-2, DD-3, and DD-4 may include the same configuration as the display apparatuses DD, DD-TD, DD-a, DD-b, and DD-c as described with reference to FIGS. 1, and 2, and 8 to 11.

FIG. 12 illustrates a vehicle AM, but this is an example, and the first to fourth display apparatuses DD-1, DD-2, DD-3, and DD-4 may be provided in another transportation refers to such as bicycles, motorcycles, trains, ships, and airplanes. In some embodiments, at least one among the first to fourth display apparatuses DD-1, DD-2, DD-3, and DD-4 including the same configuration as the display apparatuses DD, DD-TD, DD-a, DD-b, and DD-c of one or more embodiments may be employed in a personal computer, a laptop computer, a personal digital terminal, a game console, a portable electronic device, a television, a monitor, an outdoor billboard, and/or the like. In some embodiments, these are merely provided as embodiments, and thus may be employed in other electronic apparatuses unless departing from the present disclosure.

At least one of the first to fourth display apparatus DD-1, DD-2, DD-3, or DD-4 may include the light emitting device ED described with reference to FIGS. 3 to 7. At least one of the first to fourth display apparatus DD-1, DD-2, DD-3, or DD-4 may include the fused polycyclic compound of one or more embodiments and at least one of the second to fourth compounds. Accordingly, the first to fourth display apparatus DD-1, DD-2, DD-3, or DD-4 including the fused polycyclic compound of one or more embodiments and at least one of the second to fourth compounds may exhibit improved display efficiency and display service life.

Referring to FIG. 12, the vehicle AM may include a steering wheel HA and a gear GR for driving the vehicle AM. In some embodiments, the vehicle AM may include a front window GL provided so as to face the driver.

The first display apparatus DD-1 may be provided in a first region overlapping the steering wheel HA. For example, the first display apparatus DD-1 may be a digital cluster which displays first information of the vehicle AM. The first information may include a first scale which indicates a driving speed of the vehicle AM, a second scale which indicates an engine speed (that is, revolutions per minute (RPM)), an image which indicates a fuel state, and/or the like. A first scale and a second scale may be indicated as a digital image.

The second display apparatus DD-2 may be provided in a second region facing the driver's seat and overlapping the front window GL. The driver's seat may be a seat in which the steering wheel HA is provided. For example, the second display apparatus DD-2 may be a head up display (HUD) which displays second information of the vehicle AM. The second display apparatus DD-2 may be optically transparent. The second information may include digital numbers which indicate a driving speed, and may further include information such as the current time. Unlike the configuration illustrated, the second information of the second display apparatus DD-2 may be projected to the front window GL to be displayed.

The third display apparatus DD-3 may be provided in a third region adjacent to the gear GR. For example, the third display apparatus DD-3 may be provided between the driver's seat and the passenger seat and may be a center information display (CID) for a vehicle for displaying third information. The passenger seat may be a seat spaced apart from the driver's seat with the gear GR provided therebetween. The third information may include information about traffic (e.g., navigation information), playing music or radio or a video (or an image), temperatures inside the vehicle AM, and/or the like.

The fourth display apparatus DD-4 may be spaced apart from the steering wheel HA and the gear GR, and may be provided in a fourth region adjacent to the side of the vehicle AM. For example, the fourth display apparatus DD-4 may be a digital side-view mirror which displays fourth information. The fourth display apparatus DD-4 may display an image outside the vehicle AM taken by a camera module CM provided outside the vehicle AM. The fourth information may include an image outside the vehicle AM.

The described first to fourth information may be examples, and the first to fourth display apparatuses DD-1, DD-2, DD-3, and DD-4 may further display information about the inside and outside of the vehicle AM. The first to fourth information may include different information. However, the embodiment of the present disclosure is not limited thereto, and a part of the first to fourth information may include the same information as one another.

Terms such as “substantially,” “about,” and “approximately” are used as relative terms and not as terms of degree, and are intended to account for the inherent deviations in measured or calculated values that would be recognized by those of ordinary skill in the art. They may be inclusive of the stated value and an acceptable range of deviation as determined by one of ordinary skill in the art, considering the limitations and error associated with measurement of that quantity. For example, “about” may refer to one or more standard deviations, or ±30%, 20%, 10%, 5% of the stated value.

Numerical ranges disclosed herein include and are intended to disclose all subsumed sub-ranges of the same numerical precision. For example, a range of “1.0 to 10.0” includes all subranges having a minimum value equal to or greater than 1.0 and a maximum value equal to or less than 10.0, such as, for example, 2.4 to 7.6. Applicant therefore reserves the right to amend this specification, including the claims, to expressly recite any sub-range subsumed within the ranges expressly recited herein.

The light emitting device, light emitting element, and/or any other relevant devices or components according to embodiments of the present disclosure described herein may be implemented utilizing any suitable hardware, firmware (e.g., an application-specific integrated circuit), software, or a combination of software, firmware, and hardware. For example, the various components of the light emitting device and/or light emitting element may be formed on one integrated circuit (IC) chip or on separate IC chips. Further, the various components of the light emitting device and/or light emitting element may be implemented on a flexible printed circuit film, a tape carrier package (TCP), a printed circuit board (PCB), or formed on one substrate. Further, the various components of the device and/or element may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

In the present disclosure, when particles are spherical, “diameter” indicates an average particle diameter, and when the particles are non-spherical, the “diameter” indicates a major axis length. The diameter (or size) of the particles may be measured by particle size analysis, dynamic light scattering, scanning electron microscopy, and/or transmission electron microscope photography. When the size of the particles is measured utilizing a particle size analyzer, the average particle diameter (or size) may be referred to as D50. The term “D50” as utilized herein refers to the average diameter (or size) of particles whose cumulative volume corresponds to 50 vol % in the particle size distribution (e.g., cumulative distribution), and refers to the value of the particle size corresponding to 50% from the smallest particle when the total number of particles is 100% in the distribution curve accumulated in the order of the smallest particle size to the largest particle size. Particle size analysis may be performed with a HORIBA LA-950 laser particle size analyzer.

Hereinafter, with reference to Examples and Comparative Examples, a fused polycyclic compound and a light emitting device of one or more embodiments of the present disclosure will be specifically described. In some embodiments, Examples are shown only for the understanding of the present disclosure, and the scope of the present disclosure is not limited thereto.

### EXAMPLES

### 1. Synthesis of Fused Polycyclic Compounds of Examples

A process of synthesizing fused polycyclic compounds according to one or more embodiments of the present disclosure will be described in more detail by presenting a process of synthesizing Compounds 4, 8, 17, 38, 54, and 58 as an example. In some embodiments, a process of synthesizing fused polycyclic compounds, which will be described hereinafter, is provided as an example, and thus a process of synthesizing compounds according to one or more embodiments of the present disclosure is not limited to the Examples.

### (1) Synthesis of Fused Polycyclic Compound 4

Fused polycyclic Compound 4 according to one or more embodiments may be synthesized by, for example, a process of Reaction Formula 1.

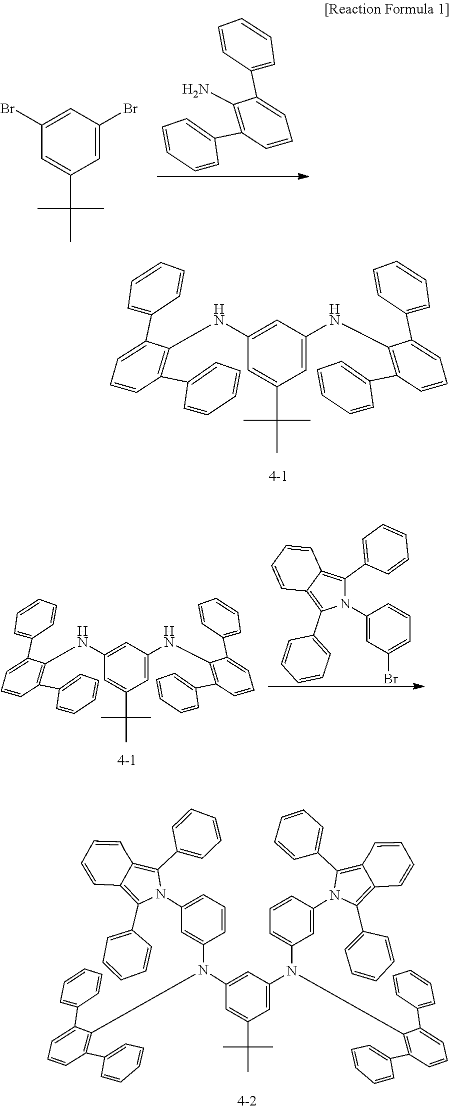

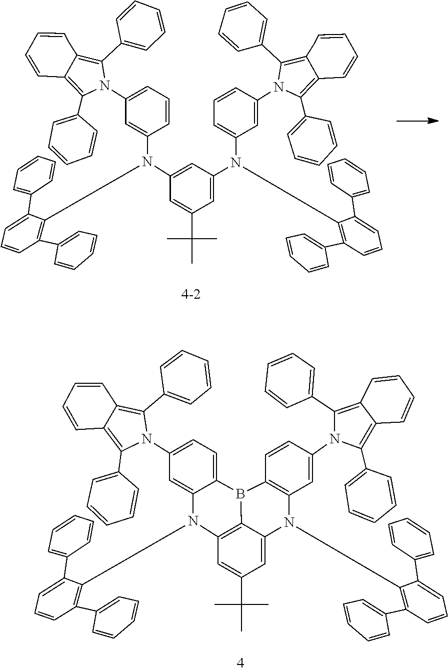 [SMILES: CC(C)(C)c1cc(N(c2cccc(-n3c(-c4ccccc4)c4c(c3-c3ccccc3)CC=CC=C4)c2)c2c(-c3ccccc3)cccc2-c2ccccc2)cc(N(c2cccc(-n3c(-c4ccccc4)c4c(c3-c3ccccc3)CC=CC=C4)c2)c2c(-c3ccccc3)cccc2-c2ccccc2)c1 ; CC(C)(C)c1cc2c3c(c1)N(c1c(-c4ccccc4)cccc1-c1ccccc1)c1cc(-n4c(-c5ccccc5)c5ccccc5c4-c4ccccc4)ccc1B3c1ccc(-n3c(-c4ccccc4)c4ccccc4c3-c3ccccc3)cc1N2c1c(-c2ccccc2)cccc1-c1ccccc1]

### Synthesis of Intermediate 4-1

1,3-dibromo-5-(tert-butyl)benzene (1 eq), [1,1′:3′,1″-terphenyl]-2′-amine (2 eq), tris(dibenzylideneacetone)dipalladium(0) (0.05 eq), tri-tert-butylphosphine (0.1 eq), and sodium tert-butoxide (3 eq) were dissolved in toluene and then stirred at 110° C. for 24 hours. The solution was cooled, diluted with ethyl acetate and then washed three times with water, and separated to obtain an organic layer. The obtained organic layer was dried over MgSO₄ and then dried under reduced pressure. The resulting product was purified through column chromatography with methylene chloride (MC) and n-hexane to obtain Intermediate 4-1. (Yield: 72%)

### Synthesis of Intermediate 4-2

Intermediate 4-1 (1 eq), 2-(3-bromophenyl)-1,3-diphenyl-2H-isoindole (3 eq), tris(dibenzylideneacetone)dipalladium(0) (0.15 eq), tri-tert-butylphosphine (0.3 eq), and sodium tert-butoxide (3 eq) were dissolved in o-xylene and then stirred at 140° C. for 60 hours. The solution was cooled, diluted with ethyl acetate and then washed three times with water, and separated to obtain an organic layer. The obtained organic layer was dried over MgSO₄ and then dried under reduced pressure. The resulting product was purified through column chromatography with MC and n-hexane to obtain Intermediate 4-2. (Yield: 27%)

### Synthesis of Compound 4

Intermediate 4-2 (1 eq) was dissolved in ortho dichlorobenzene, and cooled to 0° C., and then BBr₃ (4 eq) was slowly injected thereto in a nitrogen atmosphere. After completion of adding dropwise, the temperature was raised to 180° C. and the mixture was stirred for 48 hours. After cooling, triethylamine was slowly added dropwise to a flask containing the reactants to terminate the reaction, and ethyl alcohol was added to the reactants to cause precipitation and a solid was obtained therefrom by filtration. The obtained solid was purified through column chromatography with MC and n-hexane and then recrystallized utilizing toluene and acetone to obtain Compound 4. (Yield: 5%)

### (2) Synthesis of Fused Polycyclic Compound 8

Fused polycyclic Compound 8 according to one or more embodiments may be synthesized by, for example, a process of Reaction Formula 2.

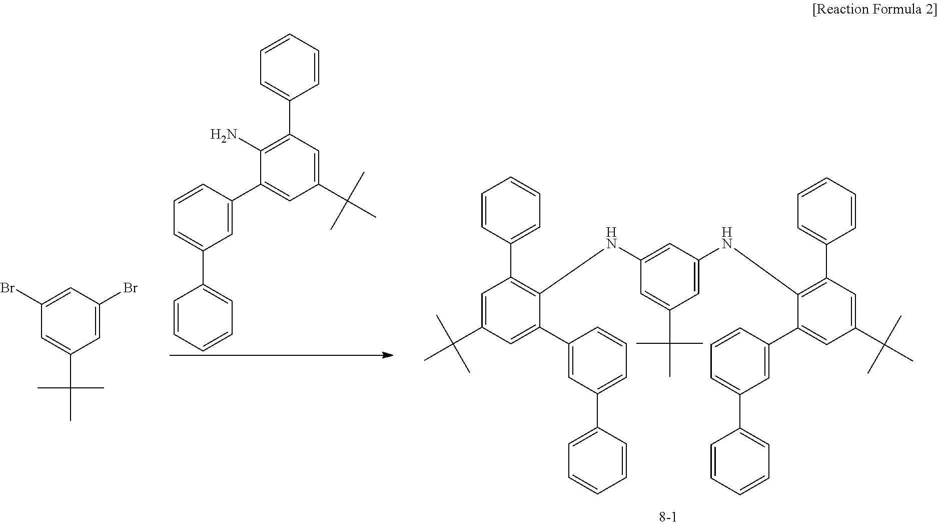 [SMILES: CC(C)(C)c1cc(Br)cc(Br)c1 ; CC(C)(C)c1cc(-c2ccccc2)c(N)c(-c2cccc(-c3ccccc3)c2)c1 ; CC(C)(C)c1cc(Nc2c(-c3ccccc3)cc(C(C)(C)C)cc2-c2cccc(-c3ccccc3)c2)cc(Nc2c(-c3ccccc3)cc(C(C)(C)C)cc2-c2cccc(-c3ccccc3)c2)c1]

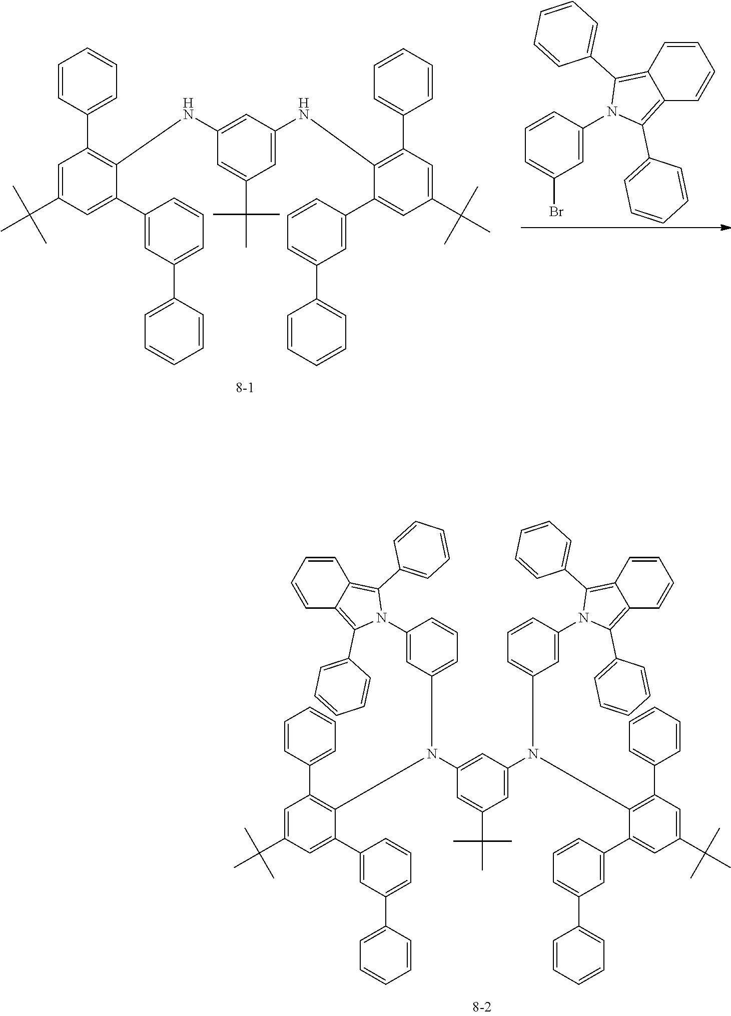

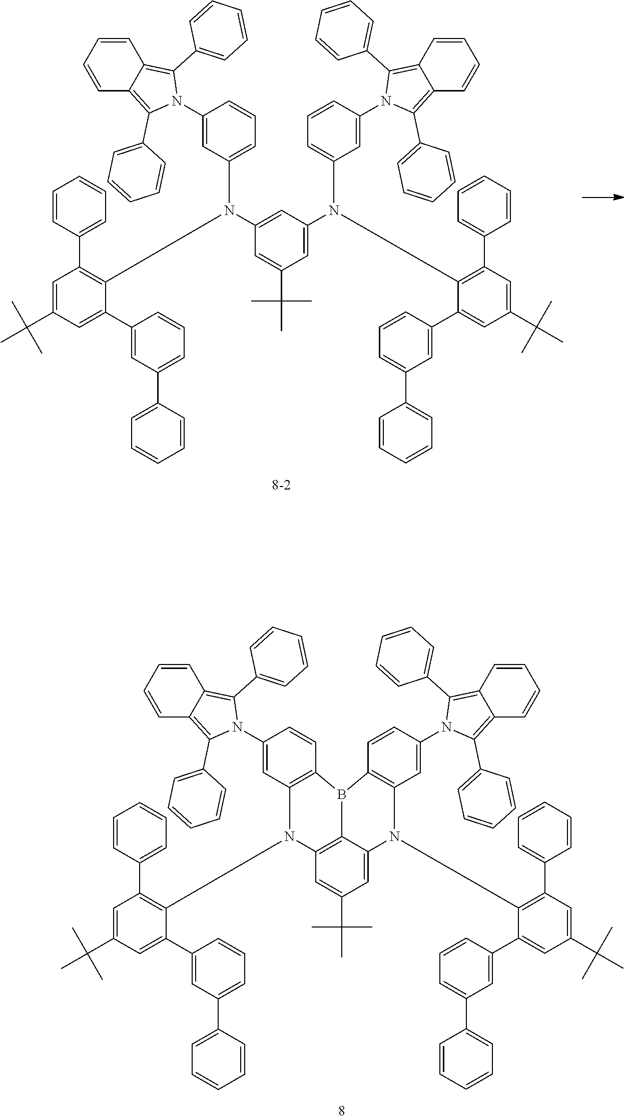

### Synthesis of Intermediate 8-1

1,3-dibromo-5-(tert-butyl)benzene (1 eq), 5′-(tert-butyl)-[1,1′:3′,1″:3″,1′″-quaterphenyl]-2′-amine (2 eq), tris(dibenzylideneacetone)dipalladium(0) (0.05 eq), tri-tert-butylphosphine (0.1 eq), and sodium tert-butoxide (3 eq) were dissolved in toluene and then stirred at 120° C. for 12 hours. The mixture was cooled, diluted with ethyl acetate and then washed three times with water, and separated to obtain an organic layer. The obtained organic layer was dried over MgSO₄ and then dried under reduced pressure. The resulting product was purified through column chromatography with MC and n-hexane to obtain Intermediate 8-1. (Yield: 67%)

### Synthesis of Intermediate 8-2

Intermediate 8-1 (1 eq), 2-(3-bromophenyl)-1,3-diphenyl-2H-isoindole (4 eq), tris(dibenzylideneacetone)dipalladium(0) (0.15 eq), tri-tert-butylphosphine (0.3 eq), and sodium tert-butoxide (3 eq) were dissolved in o-xylene and then stirred at 150° C. for 60 hours. The mixture was cooled, diluted with ethyl acetate and then washed three times with water, and separated to obtain an organic layer. The obtained organic layer was dried over MgSO₄ and then dried under reduced pressure. The resulting product was purified through column chromatography with MC and n-hexane to obtain Intermediate 8-2. (Yield: 31%)

### Synthesis of Compound 8

Intermediate 8-2 (1 eq) was dissolved in ortho dichlorobenzene, and cooled to 0° C., and then BBr₃ (3 eq) was slowly injected thereto in a nitrogen atmosphere. After completion of adding dropwise, the temperature was raised to 180° C. and the mixture was stirred for 24 hours. After cooling, triethylamine was slowly added dropwise to a flask containing the reactants to terminate the reaction, and ethyl alcohol was added to the reactants to cause precipitation and a solid was obtained therefrom by filtration. The obtained solid was purified through column chromatography with MC and n-hexane and then recrystallized utilizing toluene and acetone to obtain Compound 8. (Yield: 4%)

### (3) Synthesis of Fused Polycyclic Compound 17

Fused polycyclic Compound 17 according to one or more embodiments may be synthesized by, for example, a process of Reaction Formula 3.

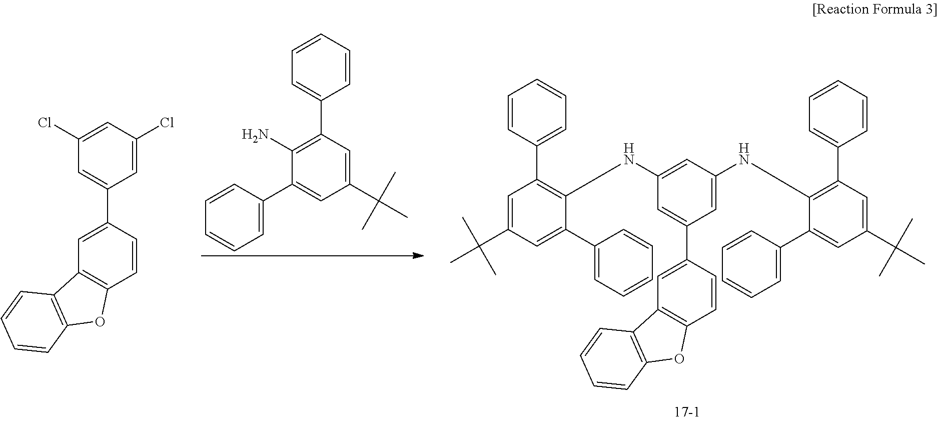 [SMILES: Clc1cc(Cl)cc(-c2ccc3oc4ccccc4c3c2)c1 ; CC(C)(C)c1cc(-c2ccccc2)c(N)c(-c2ccccc2)c1 ; CC(C)(C)c1cc(-c2ccccc2)c(Nc2cc(Nc3c(-c4ccccc4)cc(C(C)(C)C)cc3-c3ccccc3)cc(-c3ccc4oc5ccccc5c4c3)c2)c(-c2ccccc2)c1]

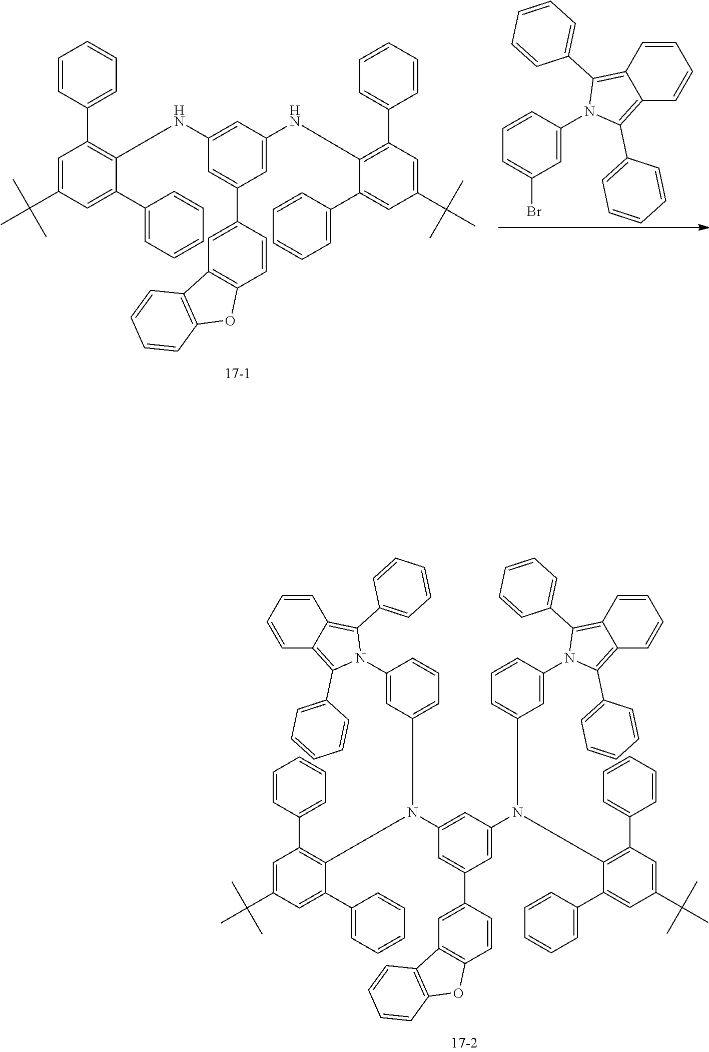

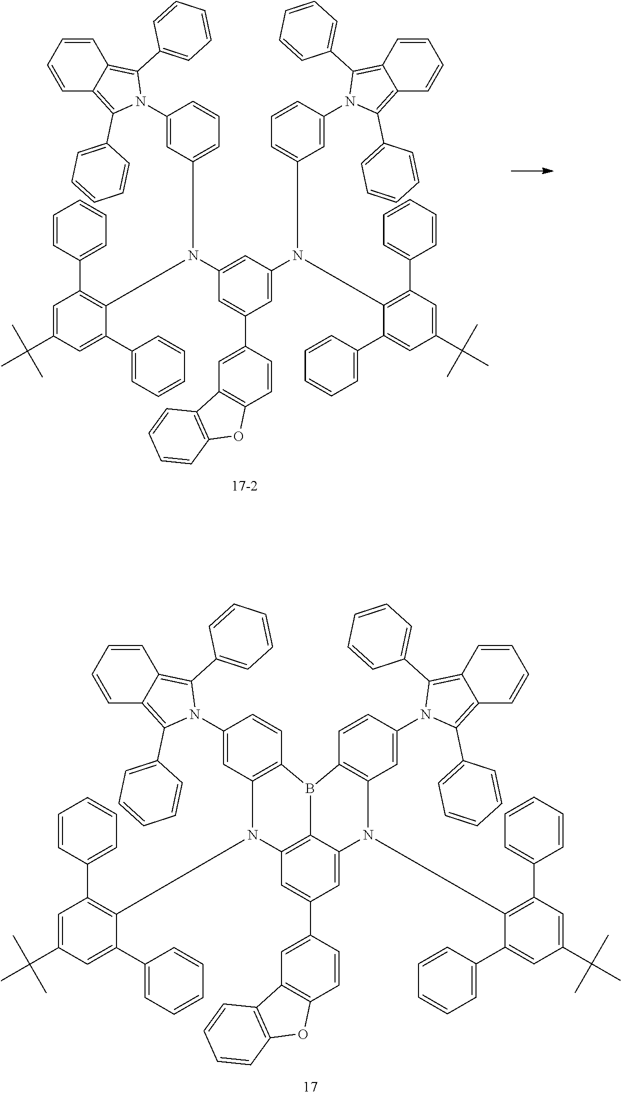

### Synthesis of Intermediate 17-1

2-(3,5-dichlorophenyl)dibenzo[b,d]furan (1 eq), 5′-(tert-butyl)-[1,1′:3′,1″-terphenyl]-2′-amine (2 eq), tris(dibenzylideneacetone)dipalladium(0) (0.05 eq), tri-tert-butylphosphine (0.1 eq), and sodium tert-butoxide (3 eq) were dissolved in toluene and then stirred at 110° C. for 12 hours. The mixture was cooled, diluted with ethyl acetate and then washed three times with water, and separated to obtain an organic layer. The obtained organic layer was dried over MgSO₄ and then dried under reduced pressure. The resulting product was purified through column chromatography with MC and n-hexane to obtain Intermediate 17-1. (Yield: 71%)

### Synthesis of Intermediate 17-2

Intermediate 17-1 (1 eq), 2-(3-bromophenyl)-1,3-diphenyl-2H-isoindole (4 eq), tris(dibenzylideneacetone)dipalladium(0) (0.15 eq), tri-tert-butylphosphine (0.3 eq), and sodium tert-butoxide (3 eq) were dissolved in o-xylene and then stirred at 150° C. for 60 hours. The mixture was cooled, diluted with ethyl acetate and then washed three times with water, and separated to obtain an organic layer. The obtained organic layer was dried over MgSO₄ and then dried under reduced pressure. The resulting product was purified through column chromatography with MC and n-hexane to obtain Intermediate 17-2. (Yield: 37%)

### Synthesis of Compound 17

Intermediate 17-2 (1 eq) was dissolved in ortho dichlorobenzene, and cooled to 0° C., and then BBr₃ (3 eq) was slowly injected thereto in a nitrogen atmosphere. After completion of adding dropwise, the temperature was raised to 180° C. and the mixture was stirred for 24 hours. After cooling, triethylamine was slowly added dropwise to a flask containing the reactants to terminate the reaction, and ethyl alcohol was added to the reactants to cause precipitation and a solid was obtained therefrom by filtration. The obtained solid was purified through column chromatography with MC and n-hexane and then recrystallized utilizing toluene and acetone to obtain Compound 17. (Yield: 5%)

### (4) Synthesis of Fused Polycyclic Compound 38

Fused polycyclic Compound 38 according to one or more embodiments may be synthesized by, for example, a process of Reaction Formula 4.

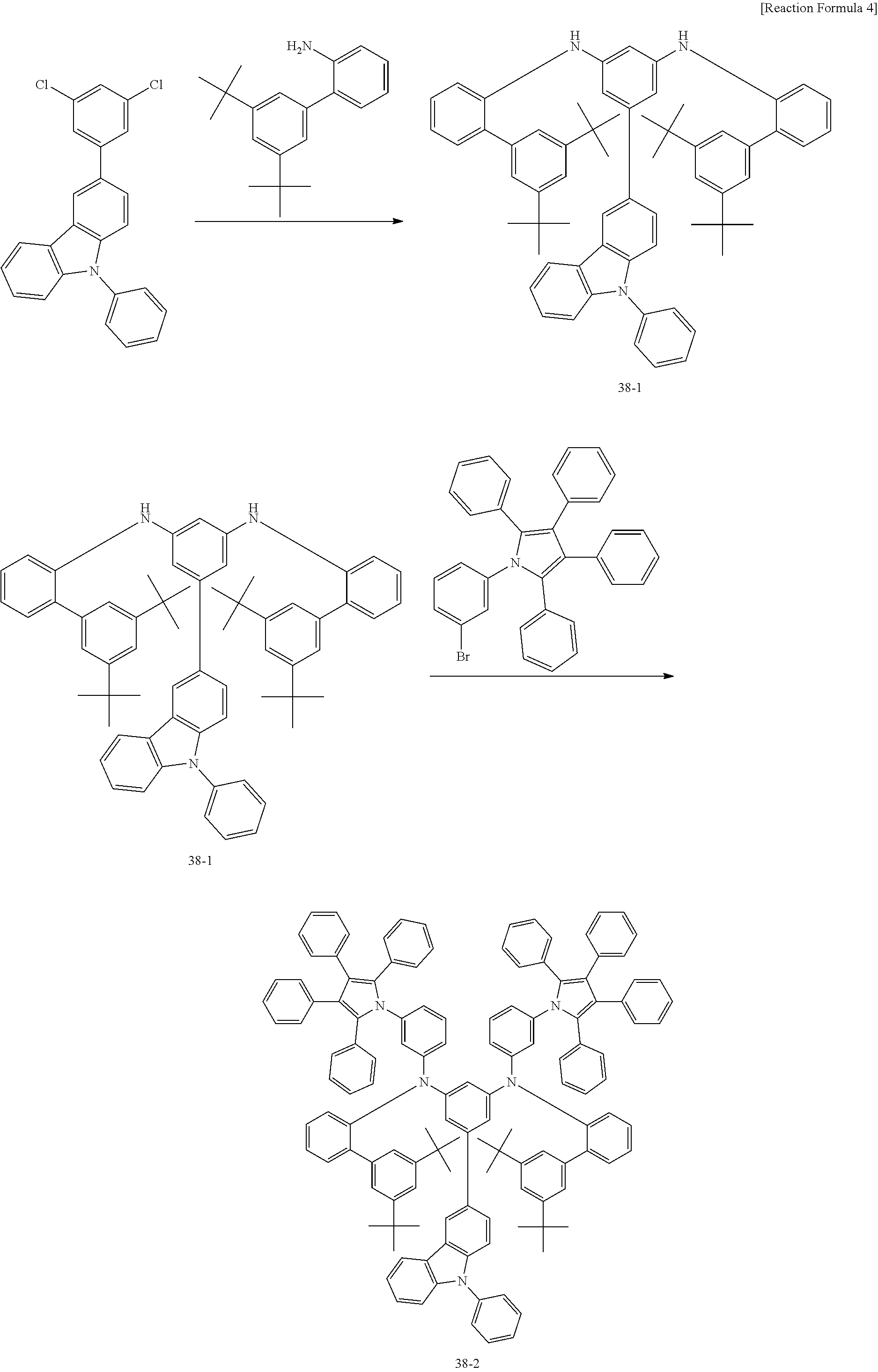

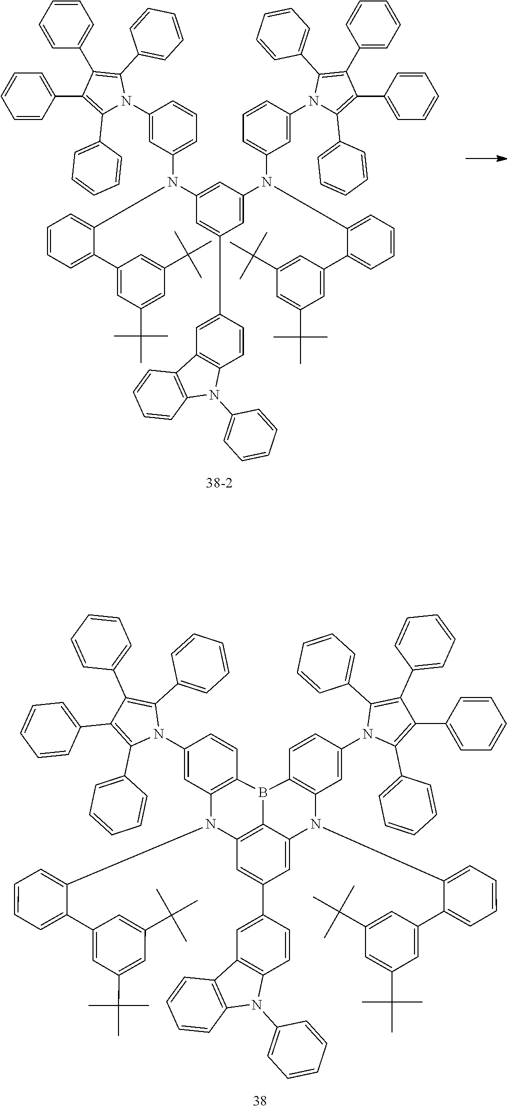 [SMILES: CC(C)(C)c1cc(-c2ccccc2N(c2cc(-c3ccc4c(c3)c3ccccc3n4-c3ccccc3)cc(N(c3cccc(-n4c(-c5ccccc5)c(-c5ccccc5)c(-c5ccccc5)c4-c4ccccc4)c3)c3ccccc3-c3cc(C(C)(C)C)cc(C(C)(C)C)c3)c2)c2cccc(-n3c(-c4ccccc4)c(-c4ccccc4)c(-c4ccccc4)c3-c3ccccc3)c2)cc(C(C)(C)C)c1 ; CC(C)(C)c1cc(-c2ccccc2N2c3cc(-n4c(-c5ccccc5)c(-c5ccccc5)c(-c5ccccc5)c4-c4ccccc4)ccc3B3c4ccc(-n5c(-c6ccccc6)c(-c6ccccc6)c(-c6ccccc6)c5-c5ccccc5)cc4N(c4ccccc4-c4cc(C(C)(C)C)cc(C(C)(C)C)c4)c4cc(-c5ccc6c(c5)c5ccccc5n6-c5ccccc5)cc2c43)cc(C(C)(C)C)c1]

### Synthesis of Intermediate 38-1

3-(3,5-dichlorophenyl)-9-phenyl-9H-carbazole (1 eq), 3′,5′-di-tert-butyl-[1,1′-biphenyl]-2-amine (2.1 eq), tris(dibenzylideneacetone)dipalladium(0) (0.05 eq), tri-tert-butylphosphine (0.1 eq), and sodium tert-butoxide (3 eq) were dissolved in toluene and then stirred at 100° C. for 12 hours. The mixture was cooled, diluted with ethyl acetate and then washed three times with water, and separated to obtain an organic layer. The obtained organic layer was dried over MgSO₄ and then dried under reduced pressure. The resulting product was purified through column chromatography with MC and n-hexane to obtain Intermediate 38-1. (Yield: 76%)

### Synthesis of Intermediate 38-2

Intermediate 38-1 (1 eq), 1-(3-bromophenyl)-2,3,4,5-tetraphenyl-1H-pyrrole (2.1 eq), tris(dibenzylideneacetone)dipalladium(0) (0.05 eq), tri-tert-butylphosphine (0.1 eq), and sodium tert-butoxide (3 eq) were dissolved in toluene and then stirred at 100° C. for 12 hours. The mixture was cooled, diluted with ethyl acetate and then washed three times with water, and separated to obtain an organic layer. The obtained organic layer was dried over MgSO₄ and then dried under reduced pressure. The resulting product was purified through column chromatography with MC and n-hexane to obtain Intermediate 38-2. (Yield: 66%)

### Synthesis of Compound 38

Intermediate 38-2 (1 eq) was dissolved in ortho dichlorobenzene, and cooled to 0° C., and then BBr₃ (3 eq) was slowly injected thereto in a nitrogen atmosphere. After completion of adding dropwise, the temperature was raised to 180° C. and the mixture was stirred for 24 hours. After cooling, triethylamine was slowly added dropwise to a flask containing the reactants to terminate the reaction, and ethyl alcohol was added to the reactants to cause precipitation and a solid was obtained therefrom by filtration. The obtained solid was purified through column chromatography with MC and n-hexane and then recrystallized utilizing toluene and acetone to obtain Compound 38. (Yield: 3%)

### (5) Synthesis of Fused Polycyclic Compound 54

Fused polycyclic Compound 54 according to one or more embodiments may be synthesized by, for example, a process of Reaction Formula 5.

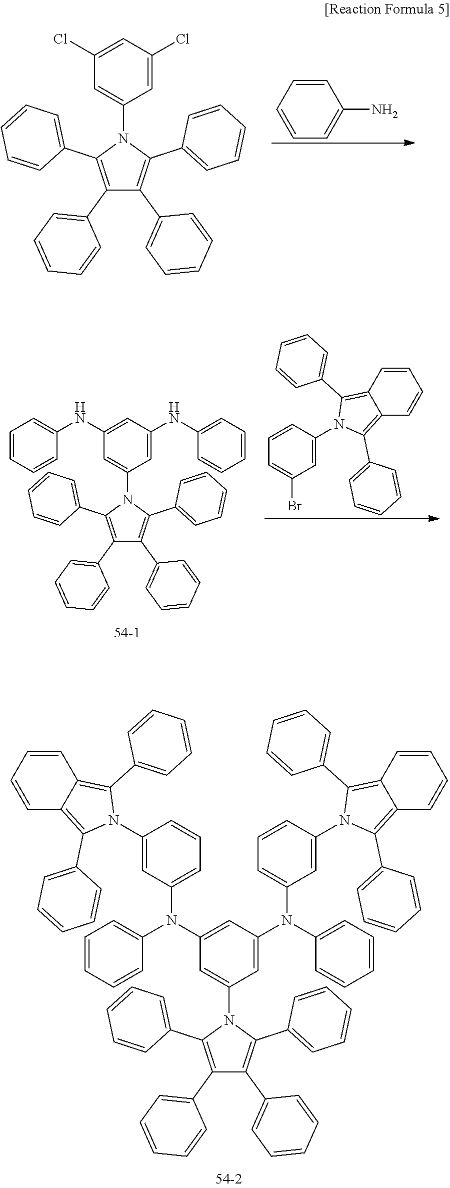

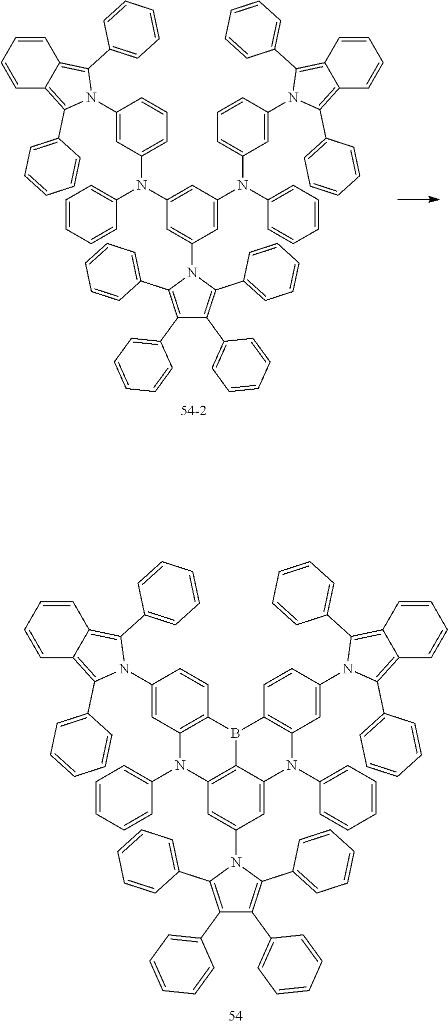 [SMILES: c1ccc(-c2c(-c3ccccc3)c(-c3ccccc3)n(-c3cc(N(c4ccccc4)c4cccc(-n5c(-c6ccccc6)c6ccccc6c5-c5ccccc5)c4)cc(N(c4ccccc4)c4cccc(-n5c(-c6ccccc6)c6ccccc6c5-c5ccccc5)c4)c3)c2-c2ccccc2)cc1 ; c1ccc(-c2c(-c3ccccc3)c(-c3ccccc3)n(-c3cc4c5c(c3)N(c3ccccc3)c3cc(-n6c(-c7ccccc7)c7ccccc7c6-c6ccccc6)ccc3B5c3ccc(-n5c(-c6ccccc6)c6ccccc6c5-c5ccccc5)cc3N4c3ccccc3)c2-c2ccccc2)cc1]

### Synthesis of Intermediate 54-1

1-(3,5-dichlorophenyl)-2,3,4,5-tetraphenyl-1H-pyrrole (1 eq), aniline (2.5 eq), tris(dibenzylideneacetone)dipalladium(0) (0.05 eq), tri-tert-butylphosphine (0.1 eq), and sodium tert-butoxide (3 eq) were dissolved in toluene and then stirred at 100° C. for 12 hours. The mixture was cooled, diluted with ethyl acetate and then washed three times with water, and separated to obtain an organic layer. The obtained organic layer was dried over MgSO₄ and then dried under reduced pressure. The resulting product was purified through column chromatography with MC and n-hexane to obtain Intermediate 54-1. (Yield: 86%)

### Synthesis of Intermediate 54-2

Intermediate 54-1 (1 eq), 2-(3-bromophenyl)-1,3-diphenyl-2H-isoindole (2.5 eq), tris(dibenzylideneacetone)dipalladium(0) (0.05 eq), tri-tert-butylphosphine (0.1 eq), and sodium tert-butoxide (3 eq) were dissolved in toluene and then stirred at 100° C. for 12 hours. The mixture was cooled, diluted with ethyl acetate and then washed three times with water, and separated to obtain an organic layer. The obtained organic layer was dried over MgSO₄ and then dried under reduced pressure. The resulting product was purified through column chromatography with MC and n-hexane to obtain Intermediate 54-2. (Yield: 42%)

### Synthesis of Compound 54

Intermediate 54-2 (1 eq) was dissolved in ortho dichlorobenzene, and cooled to 0° C., and then BBr₃ (3 eq) was slowly injected thereto in a nitrogen atmosphere. After completion of adding dropwise, the temperature was raised to 180° C. and the mixture was stirred for 24 hours. After cooling, triethylamine was slowly added dropwise to a flask containing the reactants to terminate the reaction, and ethyl alcohol was added to the reactants to cause precipitation and a solid was obtained therefrom by filtration. The obtained solid was purified through column chromatography with MC and n-hexane and then recrystallized utilizing toluene and acetone to obtain Compound 54. (Yield: 6%)

### (6) Synthesis of Fused Polycyclic Compound 58

Fused polycyclic Compound 58 according to one or more embodiments may be synthesized by, for example, a process of Reaction Formula 6.

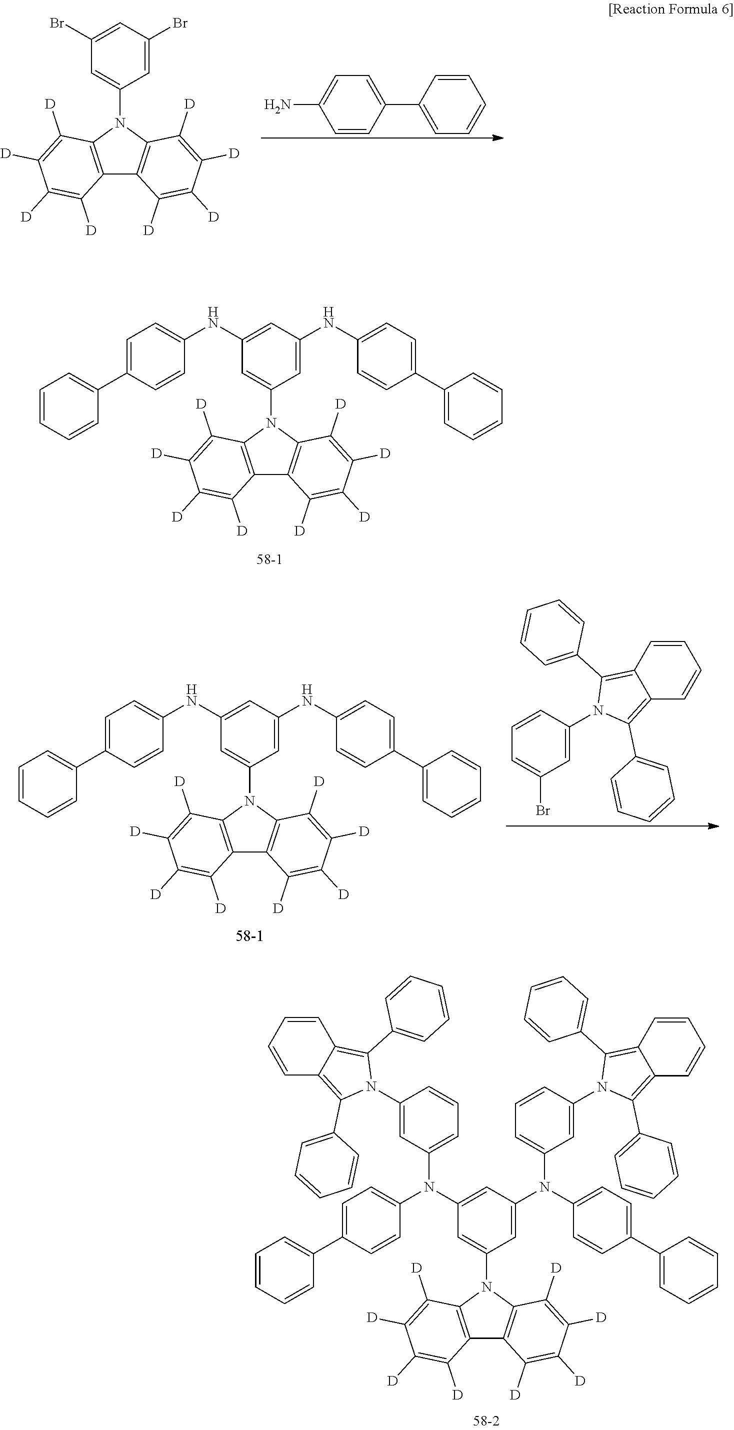

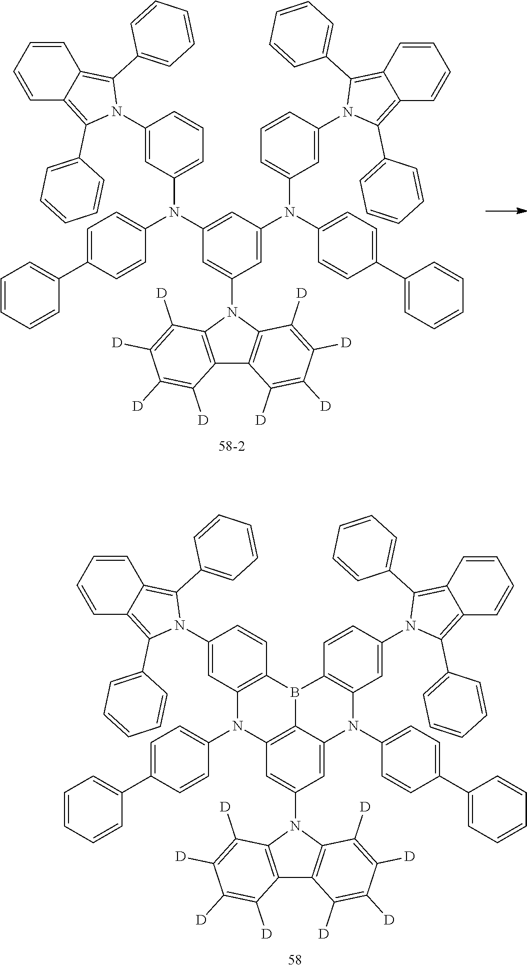 [SMILES: [2H]c1c([2H])c([2H])c2c(c1[2H])c1c([2H])c([2H])c([2H])c([2H])c1n2-c1cc(N(c2ccc(-c3ccccc3)cc2)c2cccc(-n3c(-c4ccccc4)c4ccccc4c3-c3ccccc3)c2)cc(N(c2ccc(-c3ccccc3)cc2)c2cccc(-n3c(-c4ccccc4)c4ccccc4c3-c3ccccc3)c2)c1 ; [2H]c1c([2H])c([2H])c2c(c1[2H])c1c([2H])c([2H])c([2H])c([2H])c1n2-c1cc2c3c(c1)N(c1ccc(-c4ccccc4)cc1)c1cc(-n4c(-c5ccccc5)c5ccccc5c4-c4ccccc4)ccc1B3c1ccc(-n3c(-c4ccccc4)c4ccccc4c3-c3ccccc3)cc1N2c1ccc(-c2ccccc2)cc1]

### Synthesis of Intermediate 58-1

9-(3,5-dibromophenyl)-9H-carbazole-1,2,3,4,5,6,7,8-d8 (1 eq), [1,1′-biphenyl]-4-amine (2.2 eq), tris(dibenzylideneacetone)dipalladium(0) (0.05 eq), tri-tert-butylphosphine (0.1 eq), and sodium tert-butoxide (3 eq) were dissolved in toluene and then stirred at 100° C. for 12 hours. The mixture was cooled, diluted with ethyl acetate and then washed three times with water, and separated to obtain an organic layer. The obtained organic layer was dried over MgSO₄ and then dried under reduced pressure. The resulting product was purified through column chromatography with MC and n-hexane to obtain Intermediate 58-1. (Yield: 82%)

### Synthesis of Intermediate 58-2

Intermediate 58-2 (1 eq), 2-(3-bromophenyl)-1,3-diphenyl-2H-isoindole (2.5 eq), tris(dibenzylideneacetone)dipalladium(0) (0.05 eq), tri-tert-butylphosphine (0.1 eq), and sodium tert-butoxide (3 eq) were dissolved in toluene and then stirred at 100° C. for 12 hours. The mixture was cooled, diluted with ethyl acetate and then washed three times with water, and separated to obtain an organic layer. The obtained organic layer was dried over MgSO₄ and then dried under reduced pressure. The resulting product was purified through column chromatography with MC and n-hexane to obtain Intermediate 58-2. (Yield: 42%)

### Synthesis of Compound 58

Intermediate 58-2 (1 eq) was dissolved in ortho dichlorobenzene, and cooled to 0° C., and then BBr₃ (3 eq) was slowly injected thereto in a nitrogen atmosphere. After completion of adding dropwise, the temperature was raised to 180° C. and the mixture was stirred for 24 hours. After cooling, triethylamine was slowly added dropwise to a flask containing the reactants to terminate the reaction, and ethyl alcohol was added to the reactants to cause precipitation and a solid was obtained therefrom by filtration. The obtained solid was purified through column chromatography with MC and n-hexane and then recrystallized utilizing toluene and acetone to obtain Compound 58. (Yield: 6%)

### 2. Preparation and Evaluation of Light Emitting Devices

### (1) Preparation of Light Emitting Devices

Light emitting devices including fused polycyclic compounds according to one or more embodiments or Comparative Example Compounds were prepared through a method. Light emitting devices of Examples 1 to 6 (LED1 to LED6) were prepared utilizing Compounds 4, 8, 17, 38, 54, and 58, which are fused polycyclic compounds of one or more embodiments, as dopant materials of emission layers. Light emitting devices of Comparative Examples 1 to 2 (CE1 and CE2) were prepared utilizing Comparative Example Compounds CX1 and CX2 as dopant materials for emission layers.

As an anode, a glass substrate having an ITO electrode (Corning, 15 ohm per square centimeter (Ω/cm²), 1200 angstrom (Å)) formed thereon was cut to a size of about 50 millimeter (mm)×50 mm×0.7 mm, subjected to ultrasonic cleaning utilizing isopropyl alcohol and pure water each for 5 minutes, and ultraviolet irradiation for 30 minutes, and then exposed to ozone for cleaning to be mounted on a vacuum deposition apparatus.

On the anode, a hole injection layer having a thickness of 300 Å was formed through the deposition of NPD, and on the hole injection layer, a hole transport layer having a thickness of 200 Å was formed through the deposition of compound H-1-1. On the hole transport layer, an auxiliary emission layer having a thickness of 100 Å was formed through the deposition of CzSi.

On the auxiliary emission layer, an emission layer having a thickness of 200 Å was formed through the co-deposition of a host mixture, a phosphorescent sensitizer, and a dopant in a weight ratio of 85:14:1. As for the host mixture, compound HT35 which is a hole transporting host and compound ETH66 which is an electron transporting host were provided in a weight ratio of 5:5. Compound AD-38 was utilized as a phosphorescent sensitizer material. As a dopant material, one selected from among Example Compounds 4, 8, 17, 38, 54, and 58, or one selected from among Comparative Example Compounds CX1 and CX2 was utilized.

On the emission layer, a hole blocking layer having a thickness of 200 Å was formed through the deposition of HBL-1, and on the hole blocking layer, an electron transport layer having a thickness of 310 Å was formed through the deposition of a mixed layer of CNNPTRZ:LiQ (in a weight ratio 4.0:6.0). On the electron transport layer, an electron injection layer having a thickness of 15 Å was formed through the deposition of Yb, and on the electron injection layer, a cathode having a thickness of 800 Å was formed through the deposition of Mg, thereby preparing a light emitting device.

### Materials Utilized for Preparation of Light Emitting Devices

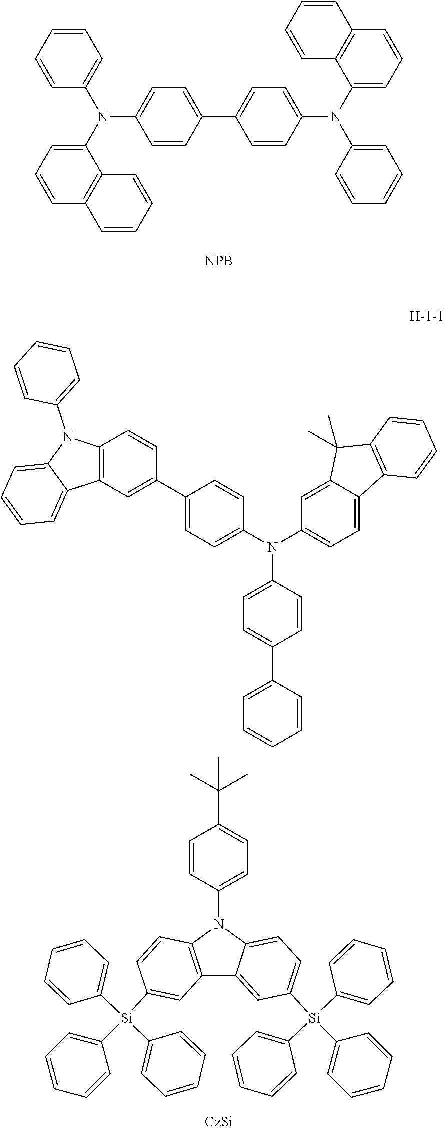

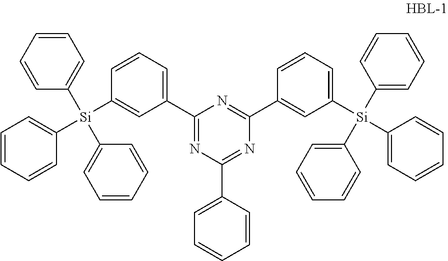 [SMILES: c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1]

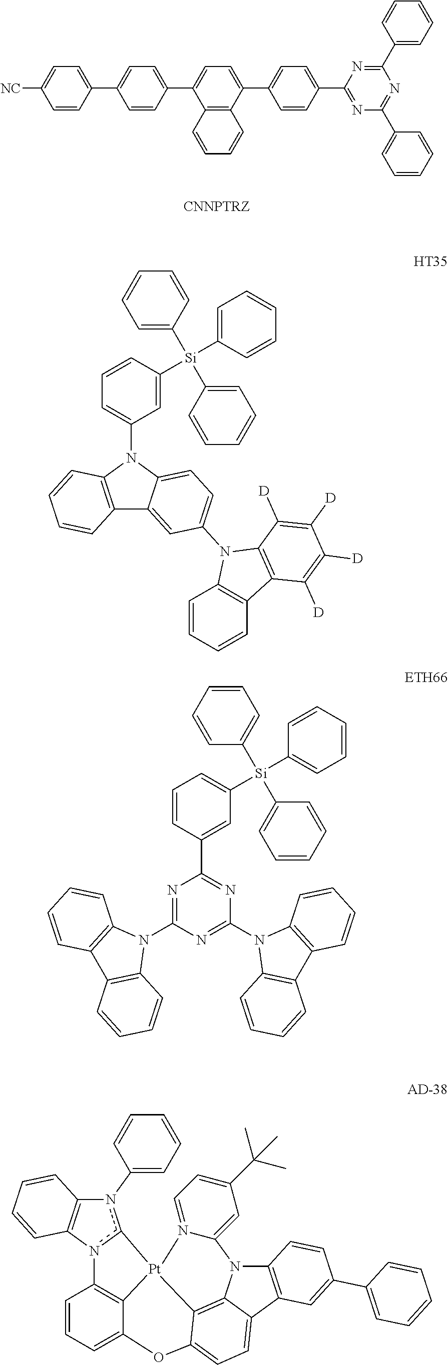

### Example Compounds

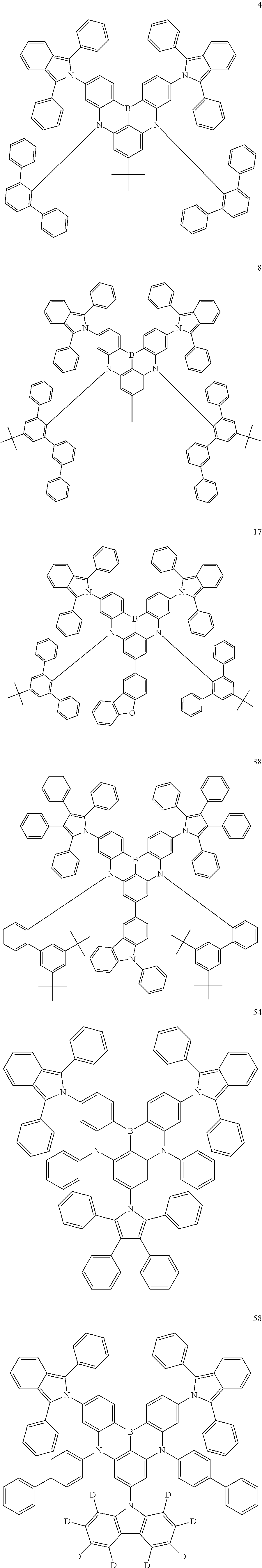

### Comparative Example Compounds

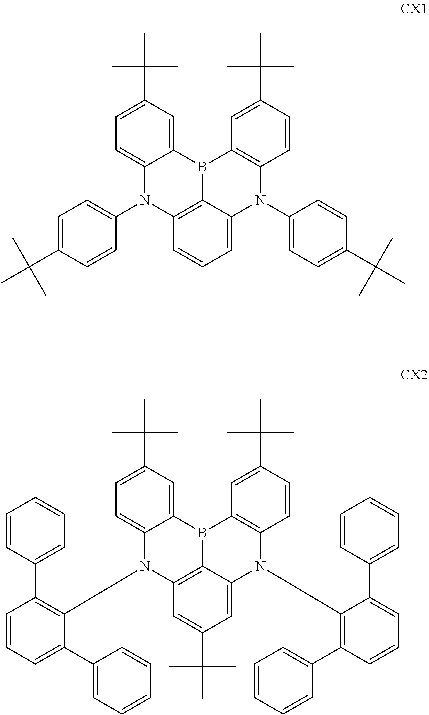 [SMILES: CC(C)(C)c1ccc(N2c3ccc(C(C)(C)C)cc3B3c4cc(C(C)(C)C)ccc4N(c4ccc(C(C)(C)C)cc4)c4cccc2c43)cc1 ; CC(C)(C)c1ccc2c(c1)B1c3cc(C(C)(C)C)ccc3N(c3c(-c4ccccc4)cccc3-c3ccccc3)c3cc(C(C)(C)C)cc(c31)N2c1c(-c2ccccc2)cccc1-c1ccccc1]

### (2) Evaluation of Light Emitting Devices

Table 1 shows evaluation results of the light emitting devices of the Examples and the Comparative Examples. In the light emitting devices of Examples 1 to 6 (LED1 to LED6) and Comparative Examples 1 to 2 (CE1 and CE2), at a current density of 1000 candela per square meter (cd/m²), the driving voltage (V), light emitting efficiency (candela per ampere (cd/A)), and light emitting wavelength were each determined utilizing Keithley MU 236 and a luminance meter PR650. As for service life (i.e., lifespan), time taken for luminance to decrease to 95% with respect to an initial luminance was determined, and relative values are shown with respect to the light emitting devices of Comparative Example 1. The devices listed in Table 1 included a host mixture of compounds HT35 and ETH66 in a weight ratio of 5:5, and Compound AD-38 as a phosphorescent sensitizer material, as described in “Preparation of light emitting devices,” Section (2)(1).

TABLE 1

| | | | Light | Light | |
|---|---|---|---|---|---|
| | Dopant | Driving | emitting | emitting | |
| Example | Compound | voltage | Efficiency | Wavelength | Lifespan |
| ID | ID | (V) | (cd/A) | (nm) | (T95) |
| LED1 | 4 | 4.4 | 26.1 | 461 | 5.6 |
| LED2 | 8 | 4.4 | 25.4 | 461 | 5.9 |
| LED3 | 17 | 4.5 | 25.3 | 461 | 5.5 |
| LED4 | 38 | 4.7 | 24.9 | 461 | 5.2 |
| LED5 | 54 | 4.9 | 23.1 | 458 | 4.4 |
| LED6 | 58 | 4.8 | 24.5 | 457 | 4.1 |
| CE1 | CX1 | 5.4 | 18.1 | 467 | 1.0 |
| CE2 | CX2 | 5.1 | 21.1 | 462 | 3.2 |

Referring to Table 1, it is seen that, compared to the light emitting devices of Comparative Examples 1 and 2 (CE1 and CE2), the light emitting devices of Examples to 6 (LED1 to LED6) had excellent or suitable light emitting efficiency and service life. In some embodiments, it is seen that, compared to the light emitting device of Comparative Examples 1 and 2, the light emitting devices of Examples 1 to 6 had reduced driving voltage. The light emitting devices of Examples 1 to 6 include Compounds 4, 8, 17, 38, 54, and 58, which are fused polycyclic compounds according to one or more embodiments. Compounds 4, 8, 17, 38, 54, and 58 include a fused ring of five rings as a central structure, and have a pyrrole group or an isoindole group bonded to the fused ring of five rings. The pyrrole group and the isoindole group shield the fused ring of five rings, and may thus improve the stability of materials and prevent or reduce side effects caused by intermolecular interactions. Accordingly, a light emitting device including the fused polycyclic compound according to one or more embodiments may exhibit high efficiency and long service life.

Referring to Table 1, it is seen that the light emitting devices of Comparative Examples 1 and 2, and Examples 1 to 6 emitted light having an emission wavelength of about 430 nm to about 490 nm. The light emitting devices of Comparative Examples 1 and 2, and Examples 1 to 6 had a central emission wavelength in a wavelength range of about 430 nm to about 490 nm.

The light emitting device of Comparative Example 1 (CE1) included Comparative Example Compound CX1, which does not contain a pyrrole group and an isoindole group. The light emitting device of Comparative Example 2 (CE2) included Comparative Example Compound CX2, which does not contain a pyrrole group and an isoindole group. Accordingly, the light emitting device of Comparative Examples 1 and 2 exhibited relatively short service life (i.e., lifespan) and low efficiency.

In the light emitting device according to one or more embodiments, the emission later may include the fused polycyclic compound according to one or more embodiments. The fused polycyclic compound according to one or more embodiments may include, as a central structure, a fused ring of five rings, which contains two nitrogen atoms and one boron atom as ring-forming atoms, and may have a pyrrole group or an isoindole group directly bonded to the fused ring of five rings. The pyrrole group and the isoindole group shield the central structure, and the fused polycyclic compound of one or more embodiments may thus improve the stability of materials and prevent or reduce side effects caused by intermolecular interactions. Accordingly, a light emitting device including the fused polycyclic compound of one or more embodiments may exhibit high efficiency and long service life.

A light emitting device of one or more embodiments includes a fused polycyclic compound according to one or more embodiments, and may thus exhibit high efficiency and long service life.

A fused polycyclic compound according to one or more embodiments may contribute to greater light efficiency and long service life of a light emitting device.

Although the present disclosure has been described with reference to a preferred embodiment of the present disclosure, it will be understood that the present disclosure should not be limited to these preferred embodiments but one or more suitable changes and modifications may be made by those skilled in the art without departing from the spirit and scope of the present disclosure as set forth in the following claims and equivalents thereof.

Accordingly, the technical scope of the present disclosure is not intended to be limited to the contents set forth in the detailed description of the specification, but is intended to be defined by the appended claims and equivalents thereof.

What is claimed is:

1. A light emitting device comprising:
a first electrode;
a second electrode on the first electrode; and
an emission layer between the first electrode and the second electrode,
wherein the emission layer comprises:
a first compound represented by Formula 1; and
at least one of a second compound represented by Formula HT-1, a third compound represented by Formula ET-1, or a fourth compound represented by Formula D-1: 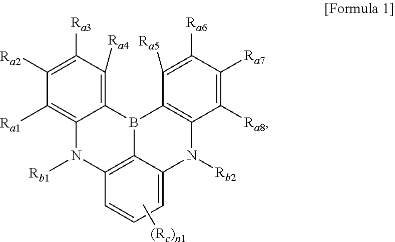
wherein in Formula 1,
Rₐ₁ to Rₐ₈ are each independently represented by Formula 2, a hydrogen atom, a deuterium atom, or a substituted or unsubstituted aryl group having 6 to 30 ring-forming carbon atoms,
at least one of Rₐ₁ to Rₐ₈ is represented by Formula 2,
n1 is an integer of 0 to 3, and
R_{b1}, R_{b2}, and R_{c} are each independently a hydrogen atom, a deuterium atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, 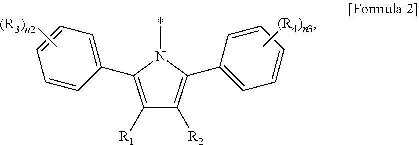
wherein in Formula 2,
R₁ and R₂ are each independently a hydrogen atom, a deuterium atom, a cyano group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring,
n2 and n3 are each independently an integer of 0 to 5, and
R₃ and R₄ are each independently a hydrogen atom, a deuterium atom, a cyano group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, 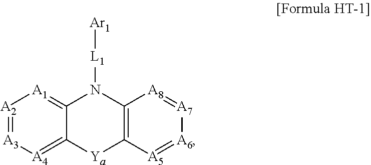
wherein in Formula HT-1,
A₁ to A₈ are each independently N or CR₅₁,
L₁ is a direct linkage, a substituted or unsubstituted arylene group having 6 to 30 ring-forming carbon atoms, or a substituted or unsubstituted heteroarylene group having 2 to 30 ring-forming carbon atoms,
Yₐ is a direct linkage, CR₅₂R₅₃, or SiR₅₄R₅₅,
Ar₁ is a substituted or unsubstituted aryl group having 6 to 30 ring-forming carbon atoms, or a substituted or unsubstituted heteroaryl group having 2 to 30 ring-forming carbon atoms, and
R₅₁ to R₅₅ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 ring-forming carbon atoms, a substituted or unsubstituted aryl group having 6 to 60 ring-forming carbon atoms, or a substituted or unsubstituted heteroaryl group having 2 to 60 ring-forming carbon atoms, and/or bonded to an adjacent group to form a ring, 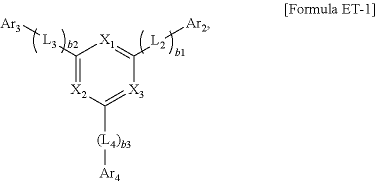
wherein in Formula ET-1,
X₁ to X₃ are each independently N or CR₅₆,
at least one of X₁ to X₃ is N,
R₅₆ are each independently a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms,
b1 to b3 are each independently an integer of 0 to 10,
Ar₂ to Ar₄ are each independently a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and
L₂ to L₄ are each independently a direct linkage, a substituted or unsubstituted arylene group having 6 to 30 ring-forming carbon atoms, or a substituted or unsubstituted heteroarylene group having 2 to 30 ring-forming carbon atoms, and 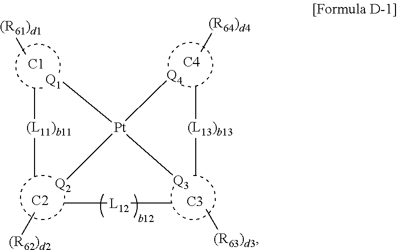
wherein in Formula D-1,
Q₁ to Q₄ are each independently C or N,
C1 to C4 are each independently a substituted or unsubstituted hydrocarbon ring having 5 to 30 ring-forming carbon atoms, or a substituted or unsubstituted heterocycle having 2 to 30 ring-forming carbon atoms,
L₁₁ to L₁₃ are each independently a direct linkage, *—O—*, *—S—*, 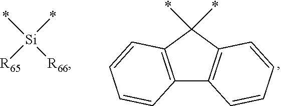
a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms,
b11 to b13 are each independently 0 or 1,
R₆₁ to R₆₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 ring-forming carbon atoms, a substituted or unsubstituted aryl group having 6 to 60 ring-forming carbon atoms, or a substituted or unsubstituted heteroaryl group having 2 to 60 ring-forming carbon atoms, and
d1 to d4 are each independently an integer of 0 to 4.

2. The light emitting device of claim 1, wherein the emission layer is configured to emit delayed fluorescence.

3. The light emitting device of claim 1, wherein the emission layer is configured to emit light having a central emission wavelength of about 430 nm to about 490 nm.

4. The light emitting device of claim 1, wherein Formula 1 is represented by Formula 1-A1 or Formula 1-A2: 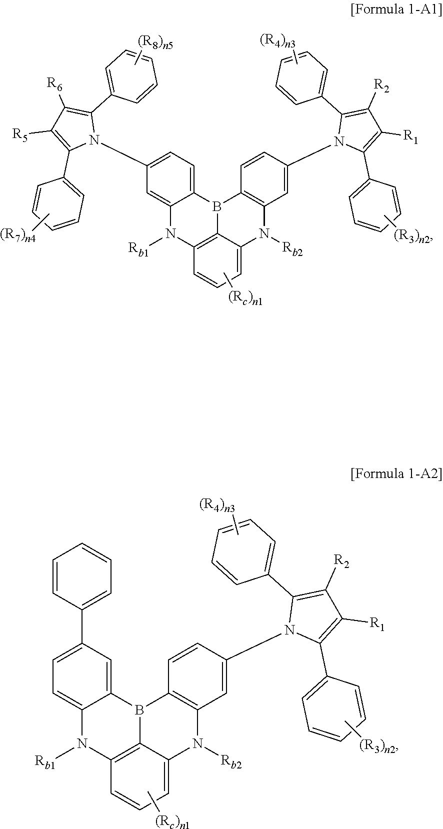
wherein in Formula 1-A1,
R₅ and R₆ are each independently a hydrogen atom, a deuterium atom, a cyano group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring,
n4 and n5 are each independently an integer of 0 to 5, and
R₇ and R₈ are each independently a hydrogen atom, a deuterium atom, a cyano group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and
wherein in Formulas 1-A1 and 1-A2,
n1 to n3, R_{b1}, R_{b2}, R_{c}, and R₁ to R₄ are as defined in Formulas 1 and 2.

5. The light emitting device of claim 1, wherein Formula 2 is represented by any one selected from among Formulas 2-1 to 2-6:

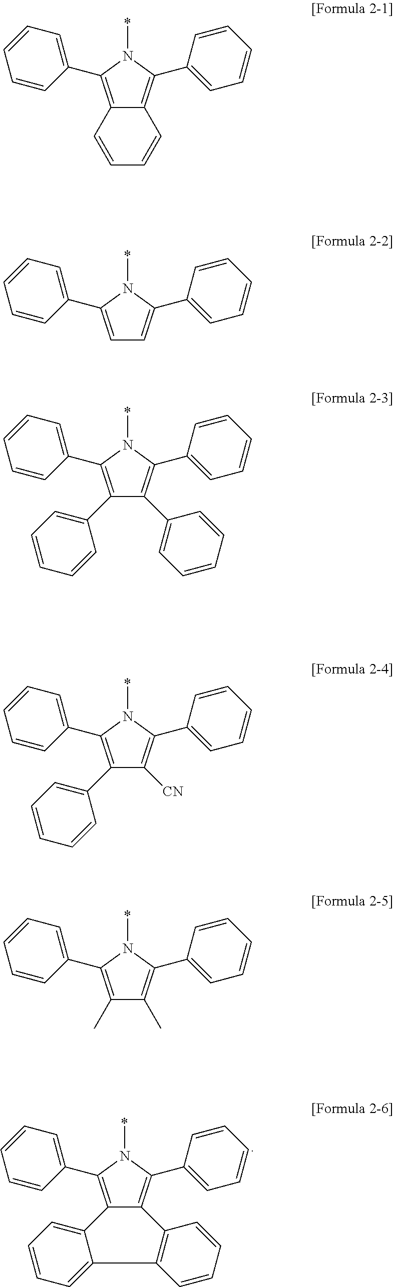 [SMILES: *n1c(-c2ccccc2)c2ccccc2c1-c1ccccc1 ; *n1c(-c2ccccc2)ccc1-c1ccccc1 ; *n1c(-c2ccccc2)c(-c2ccccc2)c(-c2ccccc2)c1-c1ccccc1 ; *n1c(-c2ccccc2)c(C#N)c(-c2ccccc2)c1-c1ccccc1 ; *n1c(-c2ccccc2)c(C)c(C)c1-c1ccccc1 ; *n1c(-c2ccccc2)c2c3ccccc3c3ccccc3c2c1-c1ccccc1]

6. The light emitting device of claim 1, wherein Formula 1 is represented by Formula 1-B: 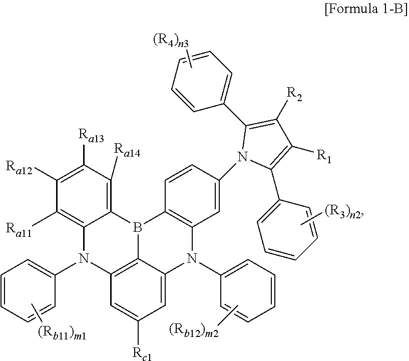
and
wherein in Formula 1-B,
Rₐ₁₁ to Rₐ₁₄ are each independently a hydrogen atom, a deuterium atom, or a substituted or unsubstituted aryl group having 6 to 30 ring-forming carbon atoms, or represented by Formula 2,
m1 and m2 are each independently an integer of 0 to 5,
R_{b11} and R_{b12} are each independently a hydrogen atom, a deuterium atom, a substituted or unsubstituted alkyl group having 1 to 20 carbon atoms, or a substituted or unsubstituted aryl group having 6 to 30 ring-forming carbon atoms,
R_{c1} is a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and
n2, n3, and R₁ to R₄ are as defined in Formula 2.

7. The light emitting device of claim 6, wherein Formula 1-B is represented by Formula 1-B1 or Formula 1-B2: 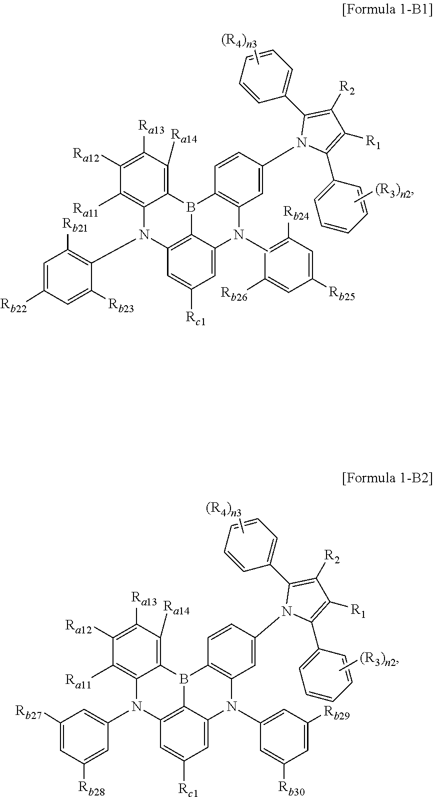
and
wherein in Formulas 1-B1 and 1-B2,
R_{b21} to R_{b30} are each independently a hydrogen atom, a deuterium atom, a substituted or unsubstituted t-butyl group, or a substituted or unsubstituted phenyl group, and
n2, n3, R₁ to R₄, Rₐ₁₁ to Rₐ₁₄, and R_{c1} are as defined in Formula 1-B.

8. The light emitting device of claim 6, wherein in Formula 1-B, R_{c1} is a substituted or unsubstituted t-butyl group, a substituted or unsubstituted aryl amine group, a substituted or unsubstituted phenyl group, a substituted or unsubstituted pyrrole group, a substituted or unsubstituted isoindole group, a substituted or unsubstituted dibenzofuran group, a substituted or unsubstituted carbazole group, or a substituted or unsubstituted acridine group.

9. The light emitting device of claim 6, wherein in Formula 1-B, R_{c1} is represented by any one selected from among RC-1 to RC-15: 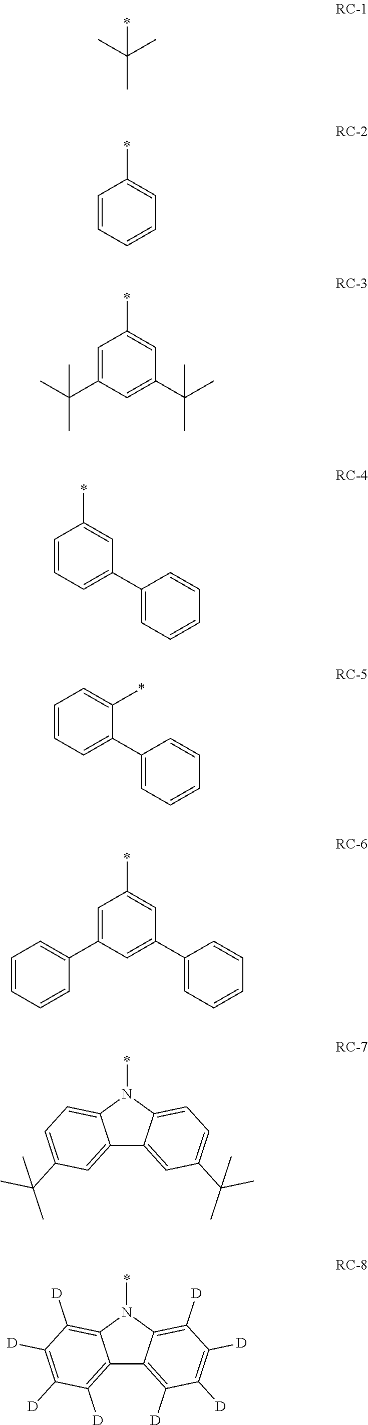 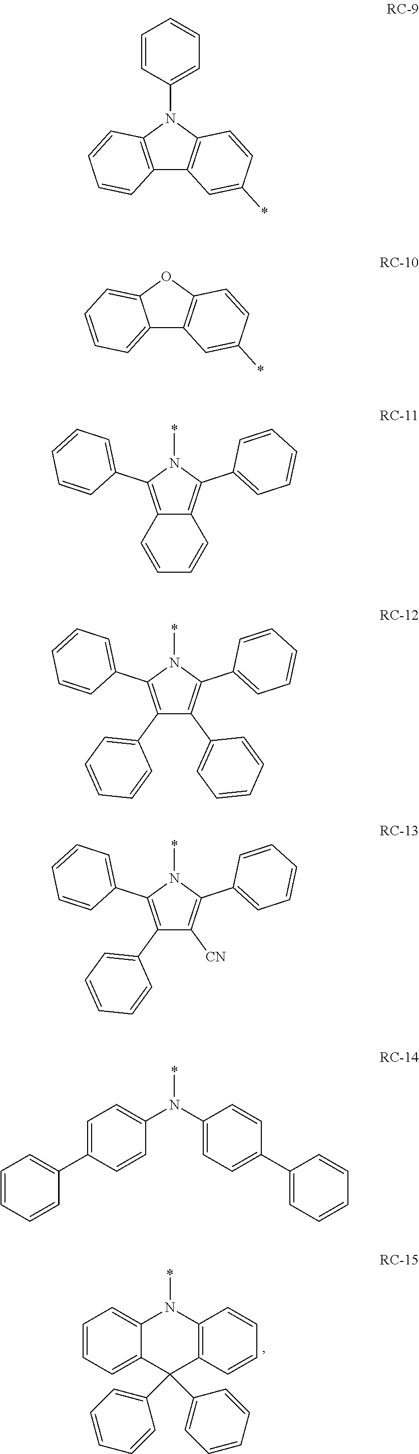
and
wherein in RC-8, D is a deuterium atom.

10. The light emitting device of claim 1, wherein in Formula 1, R_{b1} and R_{b2} are each independently represented by any one selected from among RB-1 to RB-15:

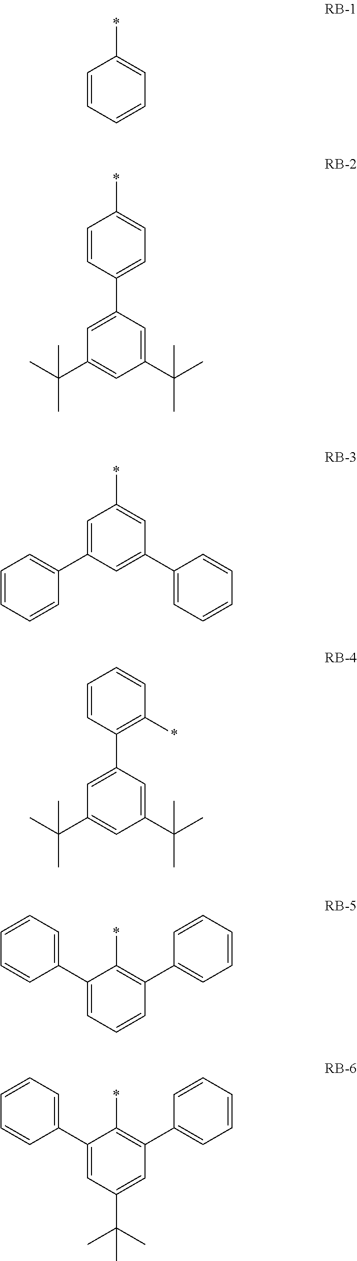

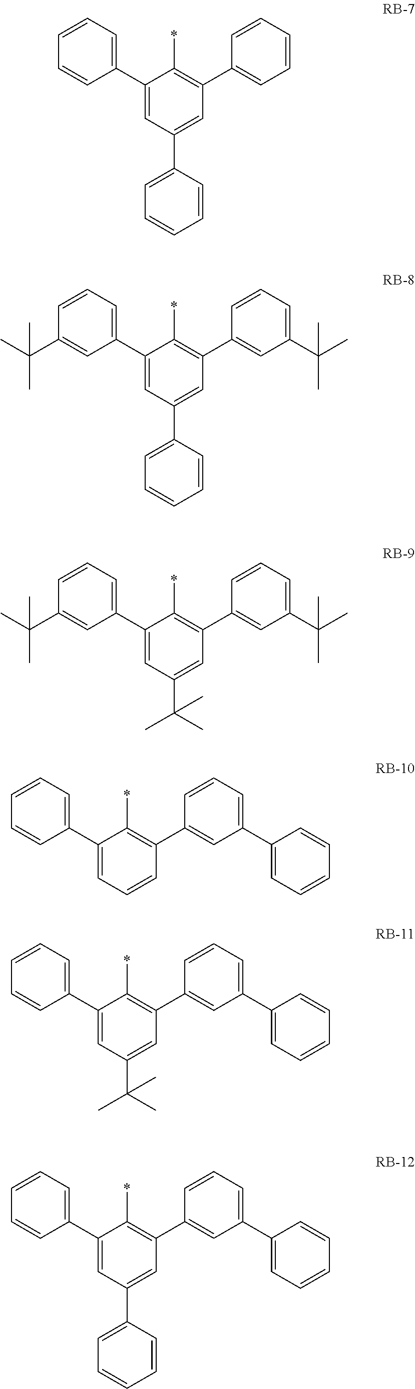

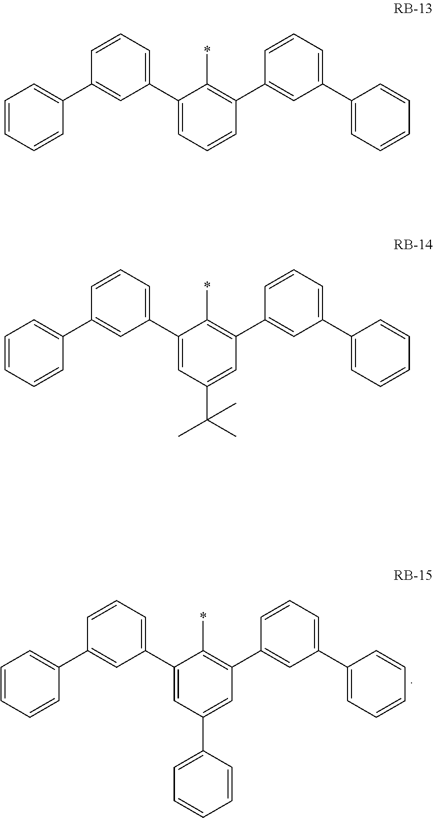 [SMILES: *c1c(-c2cccc(-c3ccccc3)c2)cccc1-c1cccc(-c2ccccc2)c1 ; *c1c(-c2cccc(-c3ccccc3)c2)cc(C(C)(C)C)cc1-c1cccc(-c2ccccc2)c1 ; *c1c(-c2cccc(-c3ccccc3)c2)cc(-c2ccccc2)cc1-c1cccc(-c2ccccc2)c1]

11. The light emitting device of claim 1, wherein the first compound is represented by any one selected from among Compound Group 1: 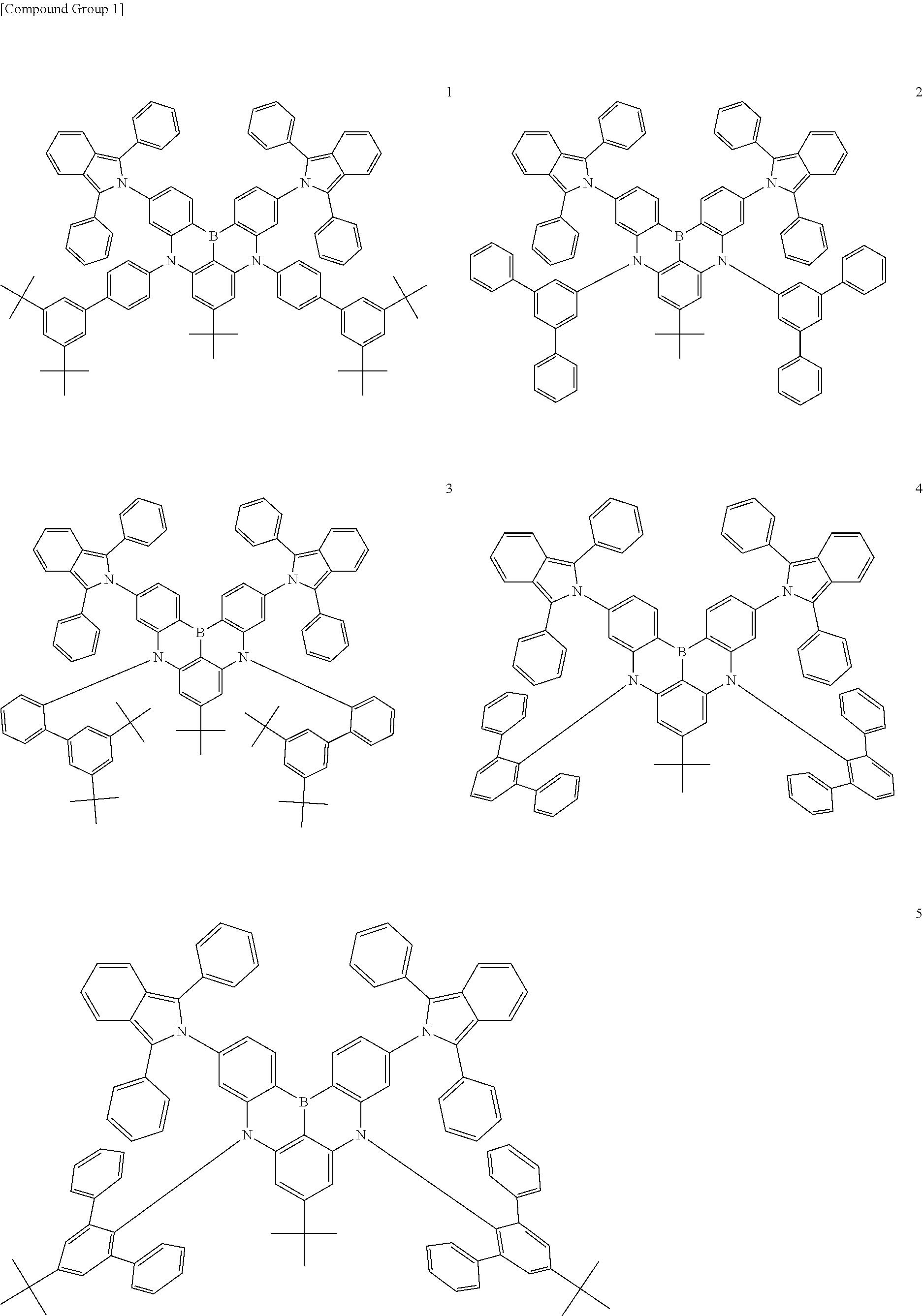 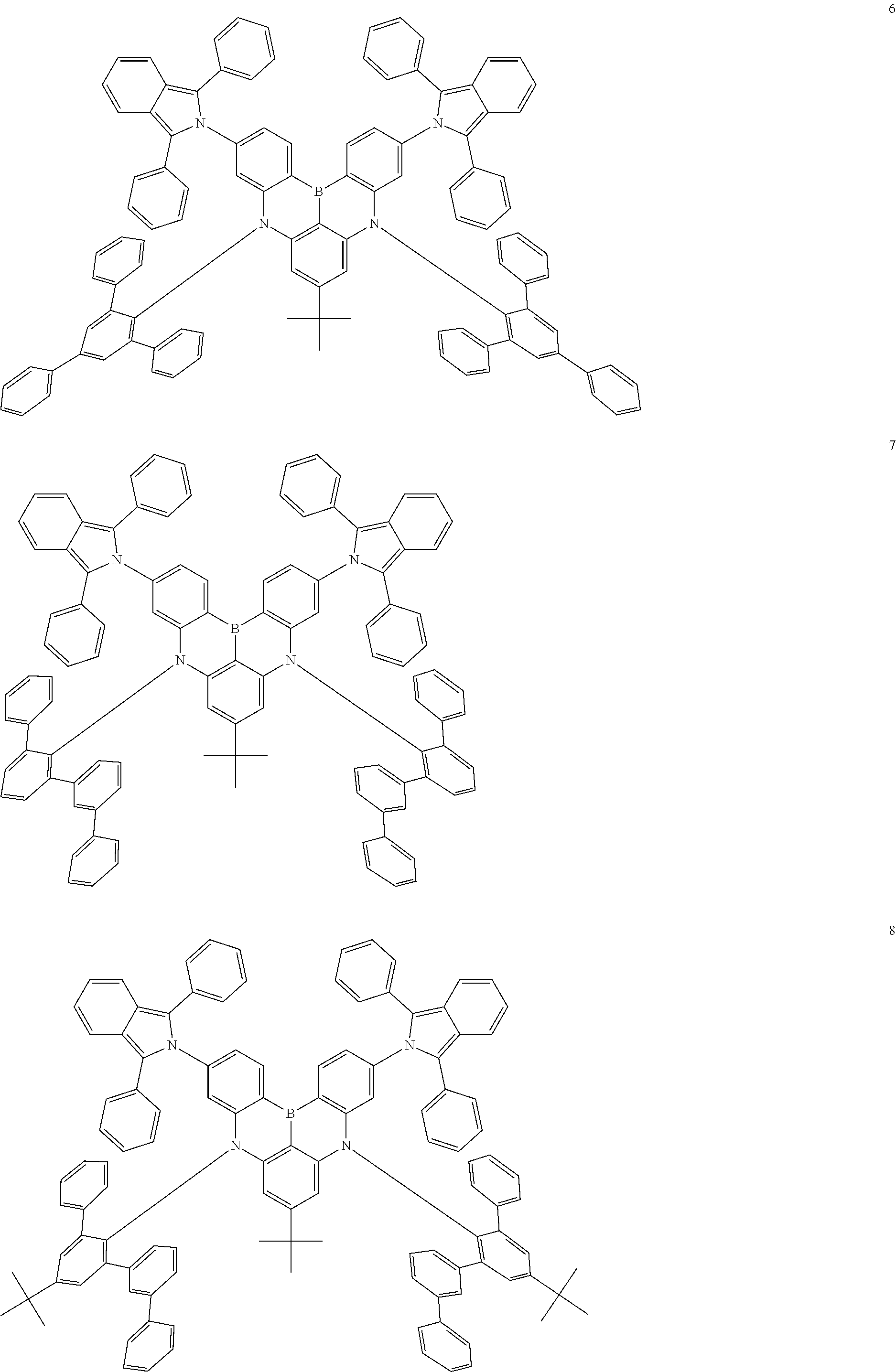 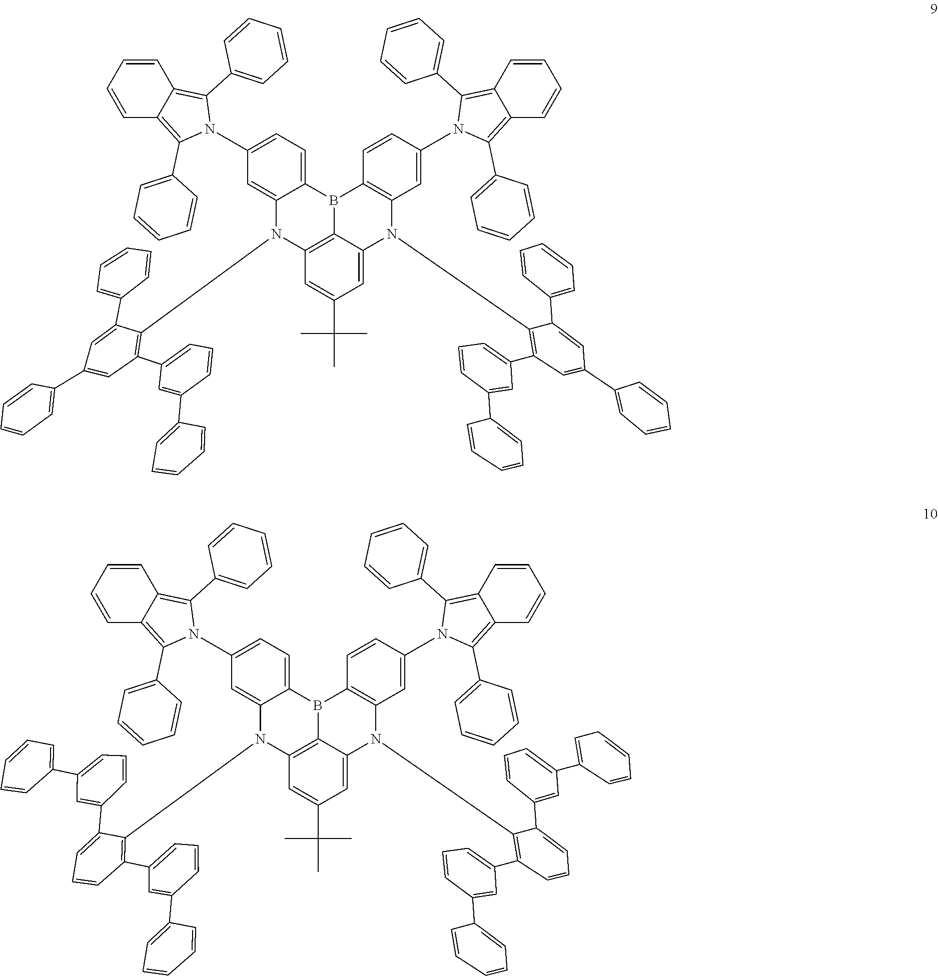 [SMILES: CC(C)(C)c1cc2c3c(c1)N(c1c(-c4ccccc4)cc(-c4ccccc4)cc1-c1cccc(-c4ccccc4)c1)c1cc(-n4c(-c5ccccc5)c5ccccc5c4-c4ccccc4)ccc1B3c1ccc(-n3c(-c4ccccc4)c4ccccc4c3-c3ccccc3)cc1N2C1=C(c2cccc(C3C=CC=CC=C3)c2)C=C(c2ccccc2)C=CC1c1ccccc1 ; CC(C)(C)c1cc2c3c(c1)N(c1c(-c4cccc(-c5ccccc5)c4)cccc1-c1cccc(-c4ccccc4)c1)c1cc(-n4c(-c5ccccc5)c5ccccc5c4-c4ccccc4)ccc1B3c1ccc(-n3c(-c4ccccc4)c4ccccc4c3-c3ccccc3)cc1N2C1=C(c2cccc(C3C=CC=CC=C3)c2)C=CC=CC1c1cccc(C2=CCC=CC=C2)c1] 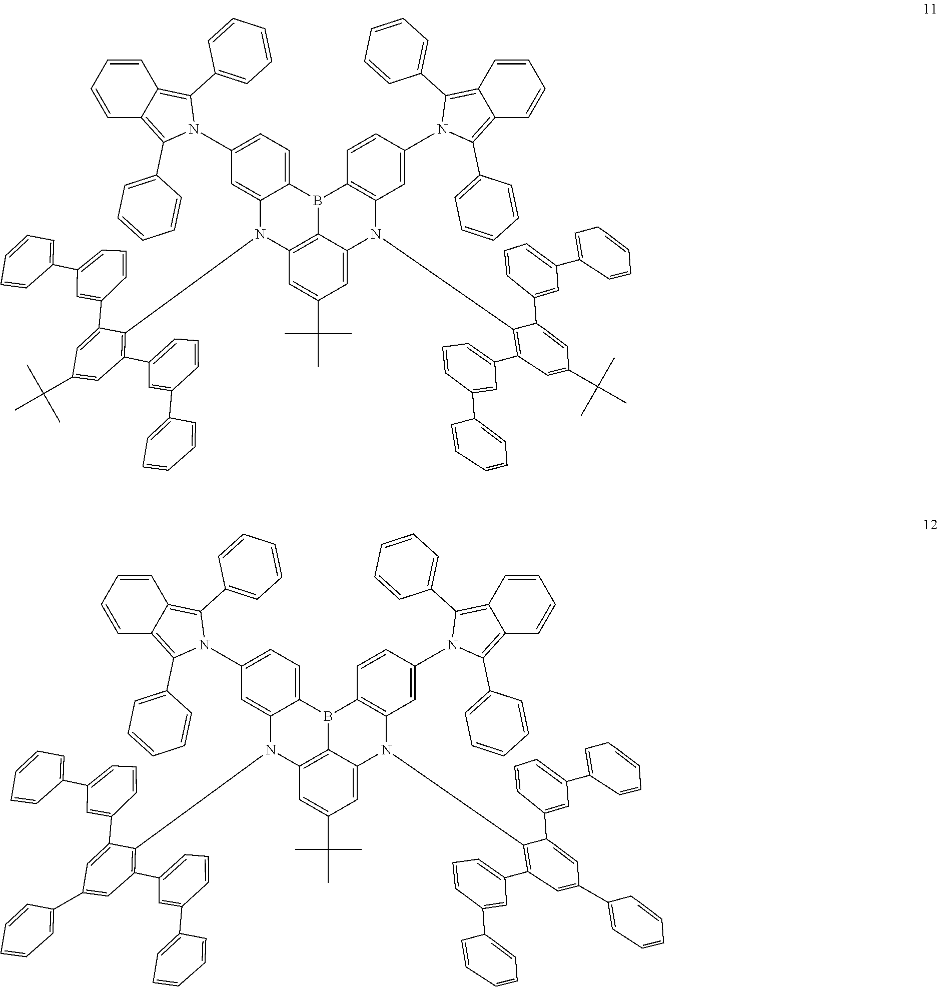 [SMILES: CC(C)(C)C1=CC(c2cccc(C3C=CC=CC=C3)c2)=C(N2c3cc(-n4c(-c5ccccc5)c5ccccc5c4-c4ccccc4)ccc3B3c4ccc(-n5c(-c6ccccc6)c6ccccc6c5-c5ccccc5)cc4N(c4c(-c5cccc(-c6ccccc6)c5)cc(C(C)(C)C)cc4-c4cccc(-c5ccccc5)c4)c4cc(C(C)(C)C)cc2c43)C(c2cccc(C3=CCC=CC=C3)c2)C=C1 ; CC(C)(C)c1cc2c3c(c1)N(c1c(-c4cccc(-c5ccccc5)c4)cc(-c4ccccc4)cc1-c1cccc(-c4ccccc4)c1)c1cc(-n4c(-c5ccccc5)c5ccccc5c4-c4ccccc4)ccc1B3c1ccc(-n3c(-c4ccccc4)c4ccccc4c3-c3ccccc3)cc1N2C1=C(c2cccc(C3C=CC=CC=C3)c2)C=C(C2=CC=CC=CC2)C=CC1c1cccc(C2=CCC=CC=C2)c1] 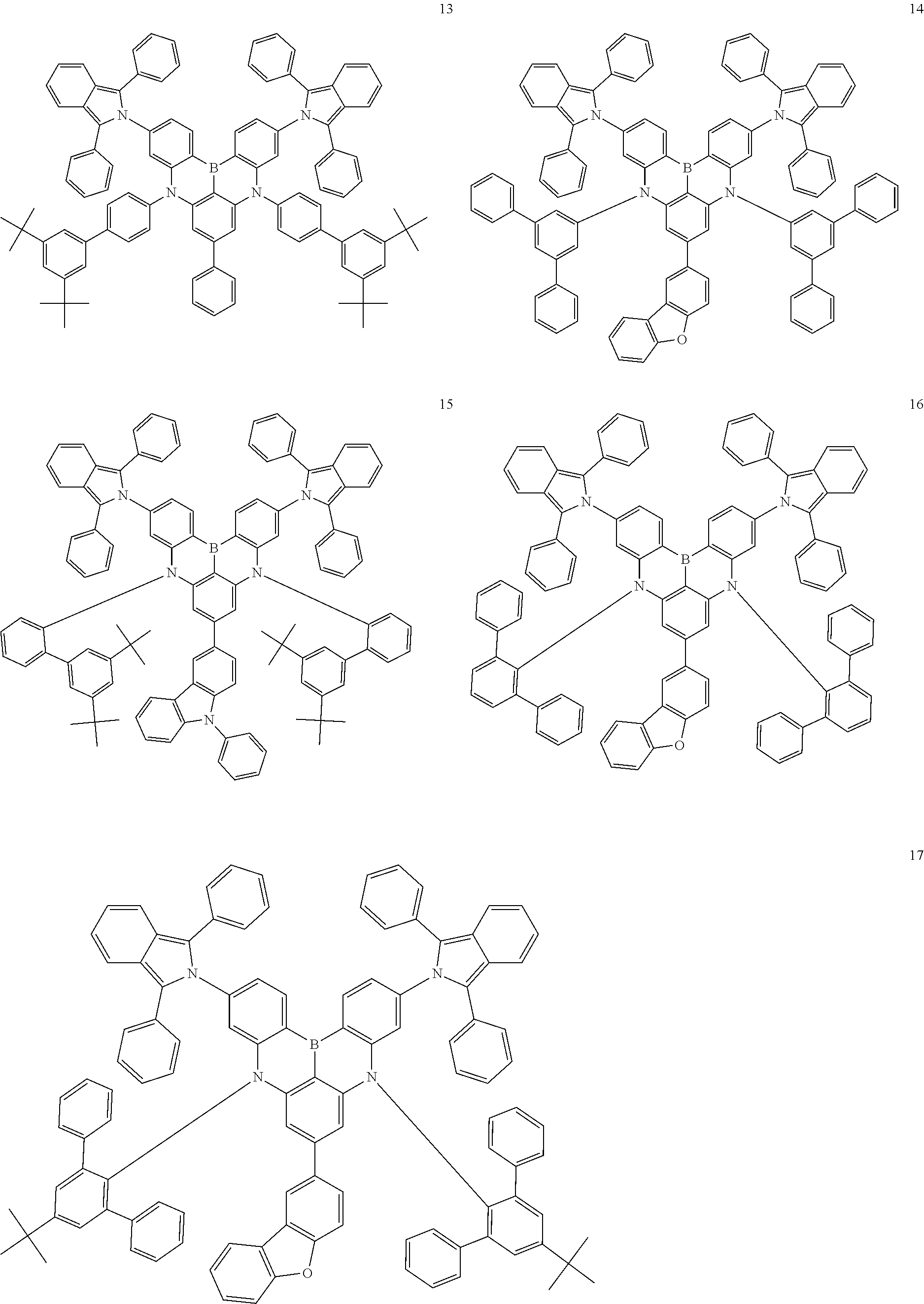 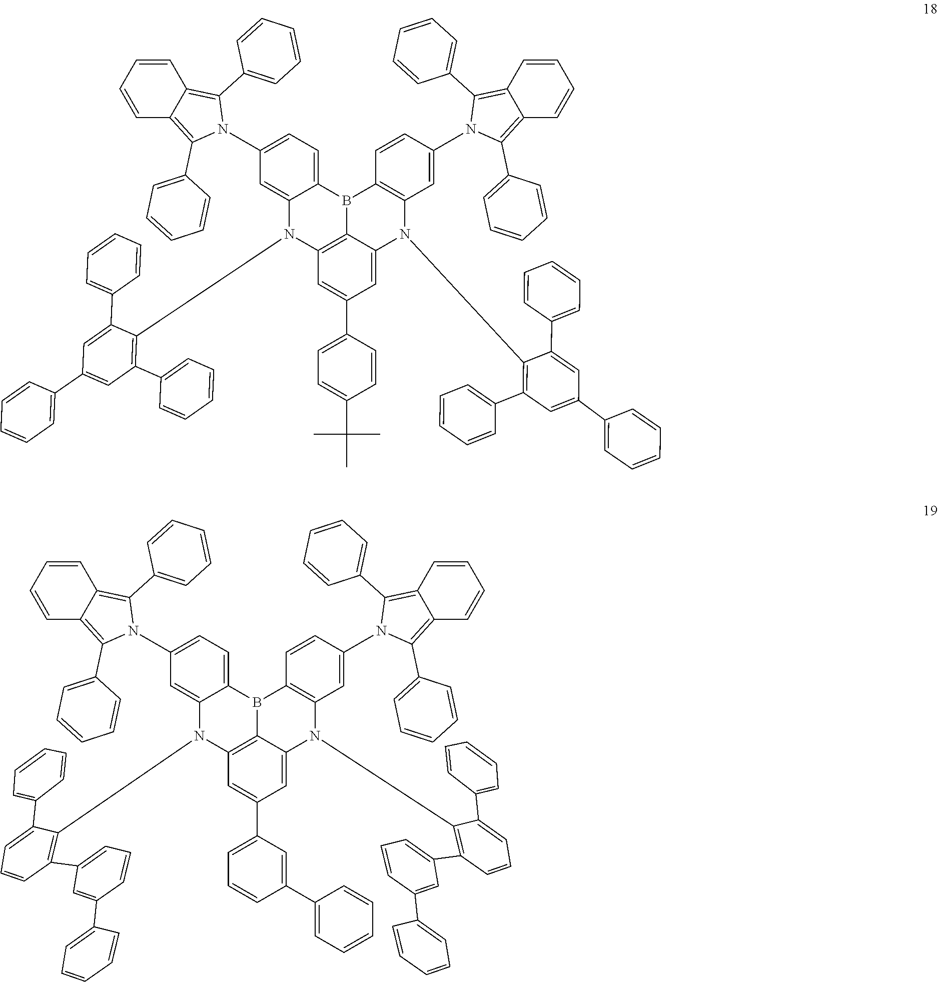 [SMILES: CC(C)(C)c1ccc(-c2cc3c4c(c2)N(c2c(-c5ccccc5)cc(-c5ccccc5)cc2-c2ccccc2)c2cc(-n5c(-c6ccccc6)c6ccccc6c5-c5ccccc5)ccc2B4c2ccc(-n4c(-c5ccccc5)c5ccccc5c4-c4ccccc4)cc2N3c2c(-c3ccccc3)cc(-c3ccccc3)cc2-c2ccccc2)cc1 ; c1ccc(-c2cccc(-c3cc4c5c(c3)N(c3c(-c6ccccc6)cccc3-c3cccc(-c6ccccc6)c3)c3cc(-n6c(-c7ccccc7)c7ccccc7c6-c6ccccc6)ccc3B5c3ccc(-n5c(-c6ccccc6)c6ccccc6c5-c5ccccc5)cc3N4c3c(-c4ccccc4)cccc3-c3cccc(-c4ccccc4)c3)c2)cc1] 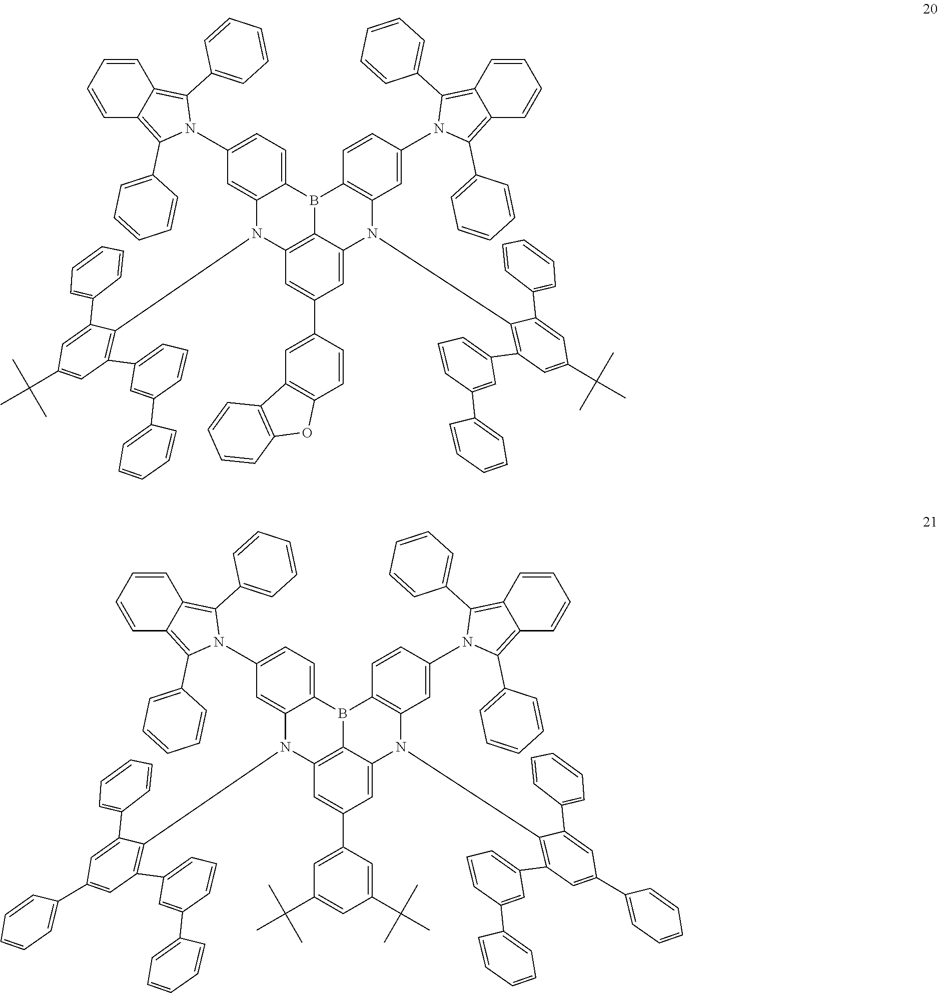 [SMILES: CC(C)(C)c1cc(-c2ccccc2)c(N2c3cc(-n4c(-c5ccccc5)c5ccccc5c4-c4ccccc4)ccc3B3c4ccc(-n5c(-c6ccccc6)c6ccccc6c5-c5ccccc5)cc4N(c4c(-c5ccccc5)cc(C(C)(C)C)cc4-c4cccc(-c5ccccc5)c4)c4cc(-c5ccc6oc7ccccc7c6c5)cc2c43)c(-c2cccc(-c3ccccc3)c2)c1 ; CC(C)(C)c1cc(-c2cc3c4c(c2)N(c2c(-c5ccccc5)cc(-c5ccccc5)cc2-c2cccc(-c5ccccc5)c2)c2cc(-n5c(-c6ccccc6)c6ccccc6c5-c5ccccc5)ccc2B4c2ccc(-n4c(-c5ccccc5)c5ccccc5c4-c4ccccc4)cc2N3c2c(-c3ccccc3)cc(-c3ccccc3)cc2-c2cccc(-c3ccccc3)c2)cc(C(C)(C)C)c1] 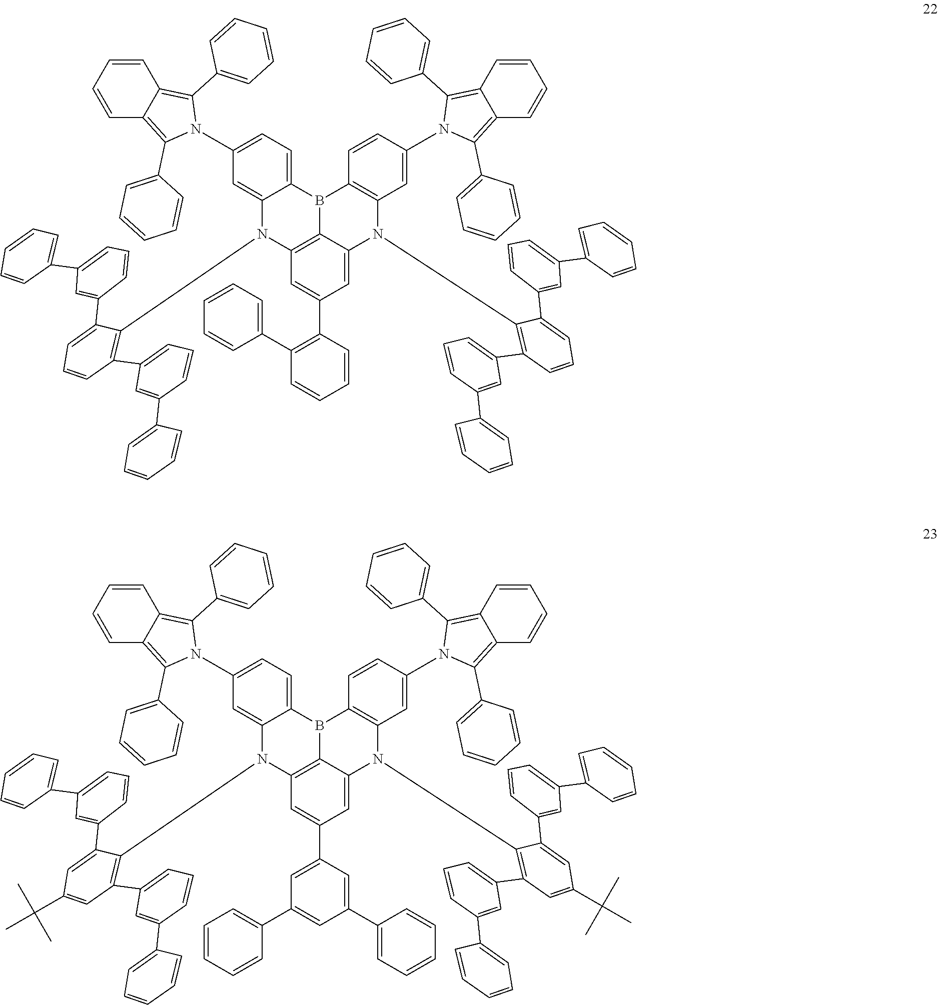 [SMILES: c1ccc(-c2cccc(-c3cccc(-c4cccc(-c5ccccc5)c4)c3N3c4cc(-n5c(-c6ccccc6)c6ccccc6c5-c5ccccc5)ccc4B4c5ccc(-n6c(-c7ccccc7)c7ccccc7c6-c6ccccc6)cc5N(c5c(-c6cccc(-c7ccccc7)c6)cccc5-c5cccc(-c6ccccc6)c5)c5cc(-c6ccccc6-c6ccccc6)cc3c54)c2)cc1 ; CC(C)(C)c1cc(-c2cccc(-c3ccccc3)c2)c(N2c3cc(-n4c(-c5ccccc5)c5ccccc5c4-c4ccccc4)ccc3B3c4ccc(-n5c(-c6ccccc6)c6ccccc6c5-c5ccccc5)cc4N(c4c(-c5cccc(-c6ccccc6)c5)cc(C(C)(C)C)cc4-c4cccc(-c5ccccc5)c4)c4cc(-c5cc(-c6ccccc6)cc(-c6ccccc6)c5)cc2c43)c(-c2cccc(-c3ccccc3)c2)c1] 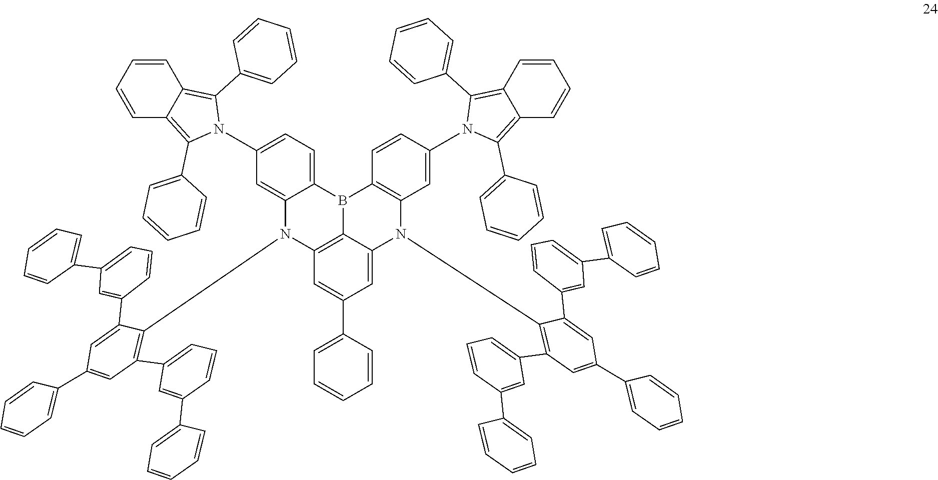 [SMILES: c1ccc(-c2cccc(-c3cc(-c4ccccc4)cc(-c4cccc(-c5ccccc5)c4)c3N3c4cc(-n5c(-c6ccccc6)c6ccccc6c5-c5ccccc5)ccc4B4c5ccc(-n6c(-c7ccccc7)c7ccccc7c6-c6ccccc6)cc5N(c5c(-c6cccc(-c7ccccc7)c6)cc(-c6ccccc6)cc5-c5cccc(-c6ccccc6)c5)c5cc(-c6ccccc6)cc3c54)c2)cc1] 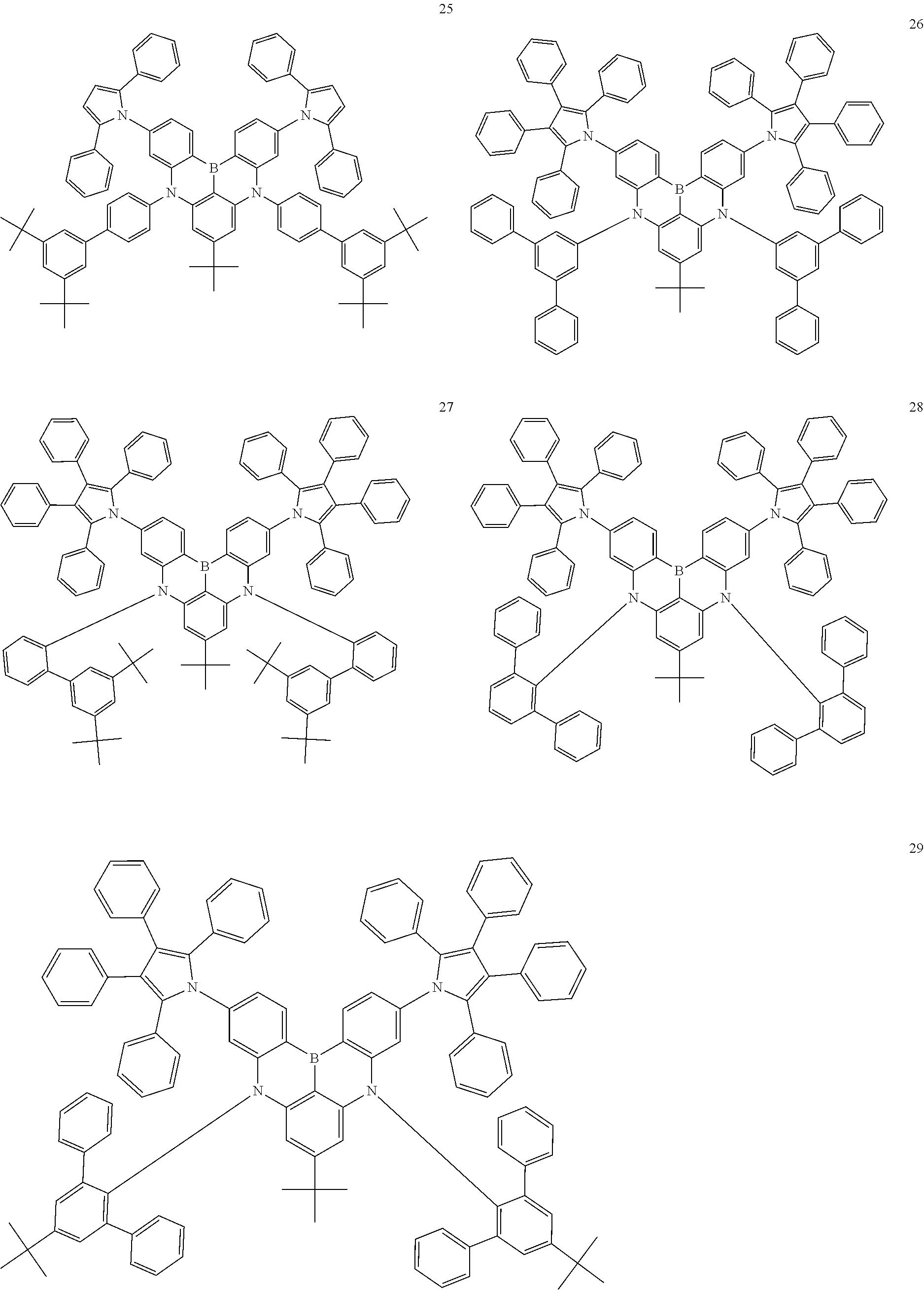 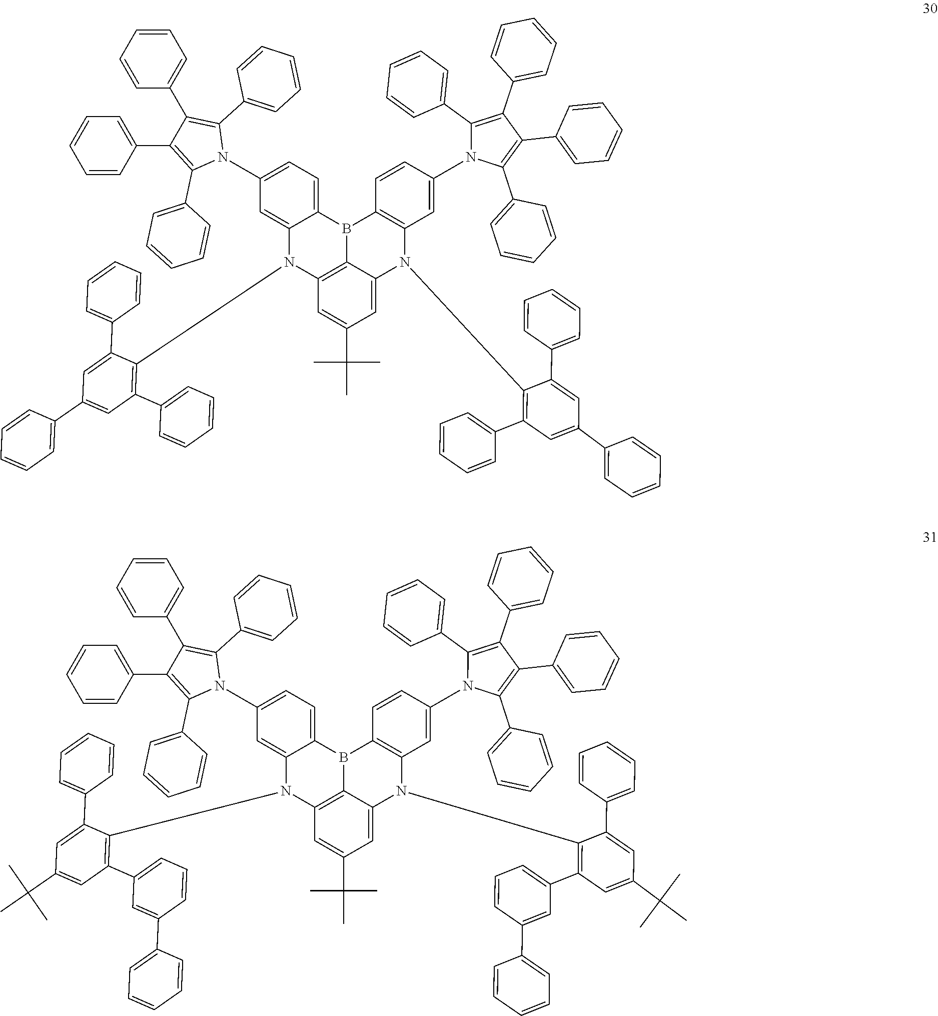 [SMILES: CC(C)(C)c1cc2c3c(c1)N(c1c(-c4ccccc4)cc(-c4ccccc4)cc1-c1ccccc1)c1cc(-n4c(-c5ccccc5)c(-c5ccccc5)c(-c5ccccc5)c4-c4ccccc4)ccc1B3c1ccc(-n3c(-c4ccccc4)c(-c4ccccc4)c(-c4ccccc4)c3-c3ccccc3)cc1N2c1c(-c2ccccc2)cc(-c2ccccc2)cc1-c1ccccc1 ; CC(C)(C)c1cc(-c2ccccc2)c(N2c3cc(-n4c(-c5ccccc5)c(-c5ccccc5)c(-c5ccccc5)c4-c4ccccc4)ccc3B3c4ccc(-n5c(-c6ccccc6)c(-c6ccccc6)c(-c6ccccc6)c5-c5ccccc5)cc4N(c4c(-c5ccccc5)cc(C(C)(C)C)cc4-c4cccc(-c5ccccc5)c4)c4cc(C(C)(C)C)cc2c43)c(-c2cccc(-c3ccccc3)c2)c1] 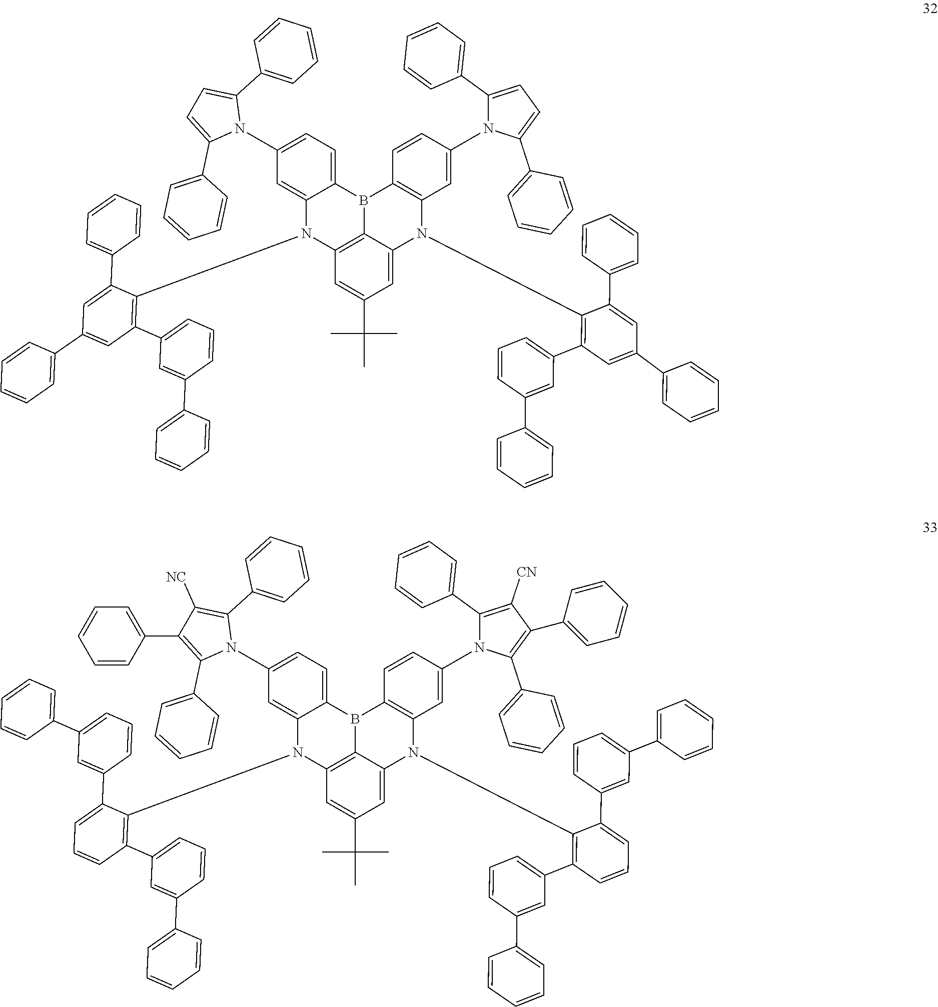 [SMILES: CC(C)(C)c1cc2c3c(c1)N(c1c(-c4ccccc4)cc(-c4ccccc4)cc1-c1cccc(-c4ccccc4)c1)c1cc(-n4c(-c5ccccc5)ccc4-c4ccccc4)ccc1B3c1ccc(-n3c(-c4ccccc4)ccc3-c3ccccc3)cc1N2c1c(-c2ccccc2)cc(-c2ccccc2)cc1-c1cccc(-c2ccccc2)c1 ; CC(C)(C)c1cc2c3c(c1)N(c1c(-c4cccc(-c5ccccc5)c4)cccc1-c1cccc(-c4ccccc4)c1)c1cc(-n4c(-c5ccccc5)c(C#N)c(-c5ccccc5)c4-c4ccccc4)ccc1B3c1ccc(-n3c(-c4ccccc4)c(C#N)c(-c4ccccc4)c3-c3ccccc3)cc1N2c1c(-c2cccc(-c3ccccc3)c2)cccc1-c1cccc(-c2ccccc2)c1] 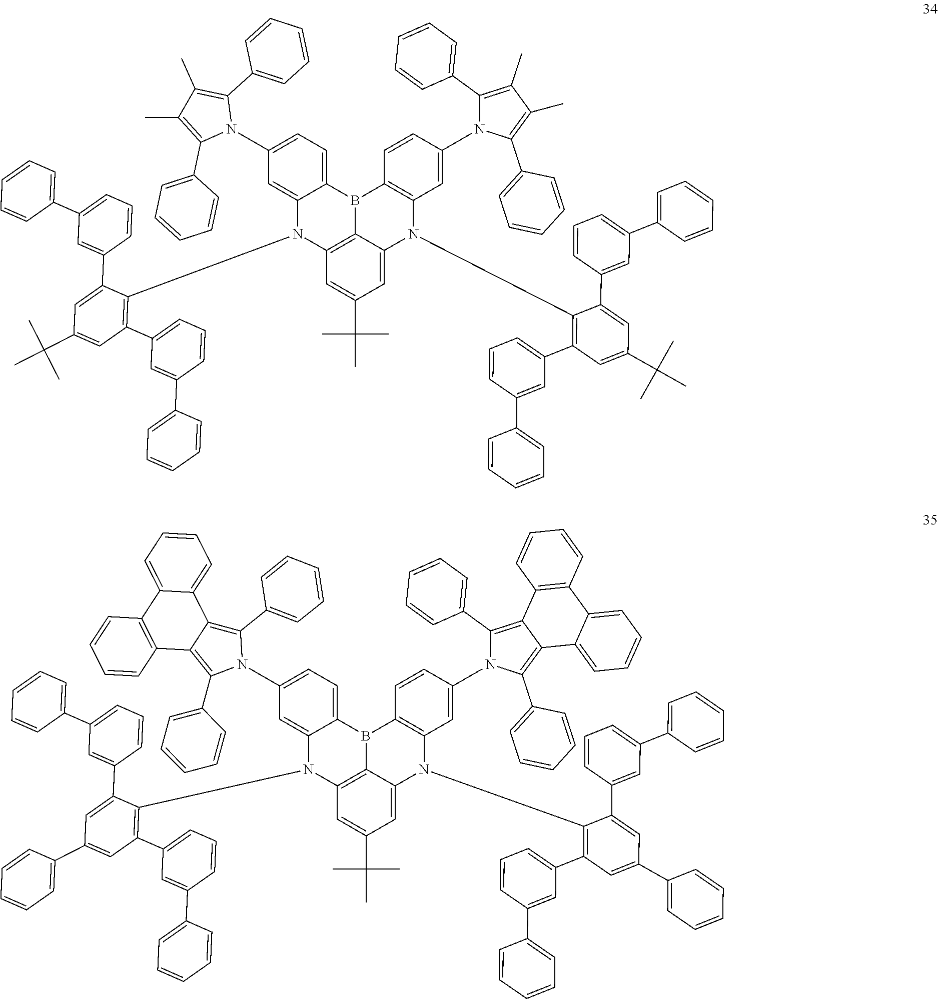 [SMILES: Cc1c(C)c(-c2ccccc2)n(-c2ccc3c(c2)N(c2c(-c4cccc(-c5ccccc5)c4)cc(C(C)(C)C)cc2-c2cccc(-c4ccccc4)c2)c2cc(C(C)(C)C)cc4c2B3c2ccc(-n3c(-c5ccccc5)c(C)c(C)c3-c3ccccc3)cc2N4c2c(-c3cccc(-c4ccccc4)c3)cc(C(C)(C)C)cc2-c2cccc(-c3ccccc3)c2)c1-c1ccccc1 ; CC(C)(C)c1cc2c3c(c1)N(c1c(-c4cccc(-c5ccccc5)c4)cc(-c4ccccc4)cc1-c1cccc(-c4ccccc4)c1)c1cc(-n4c(-c5ccccc5)c5c6ccccc6c6ccccc6c5c4-c4ccccc4)ccc1B3c1ccc(-n3c(-c4ccccc4)c4c5ccccc5c5ccccc5c4c3-c3ccccc3)cc1N2c1c(-c2cccc(-c3ccccc3)c2)cc(-c2ccccc2)cc1-c1cccc(-c2ccccc2)c1] 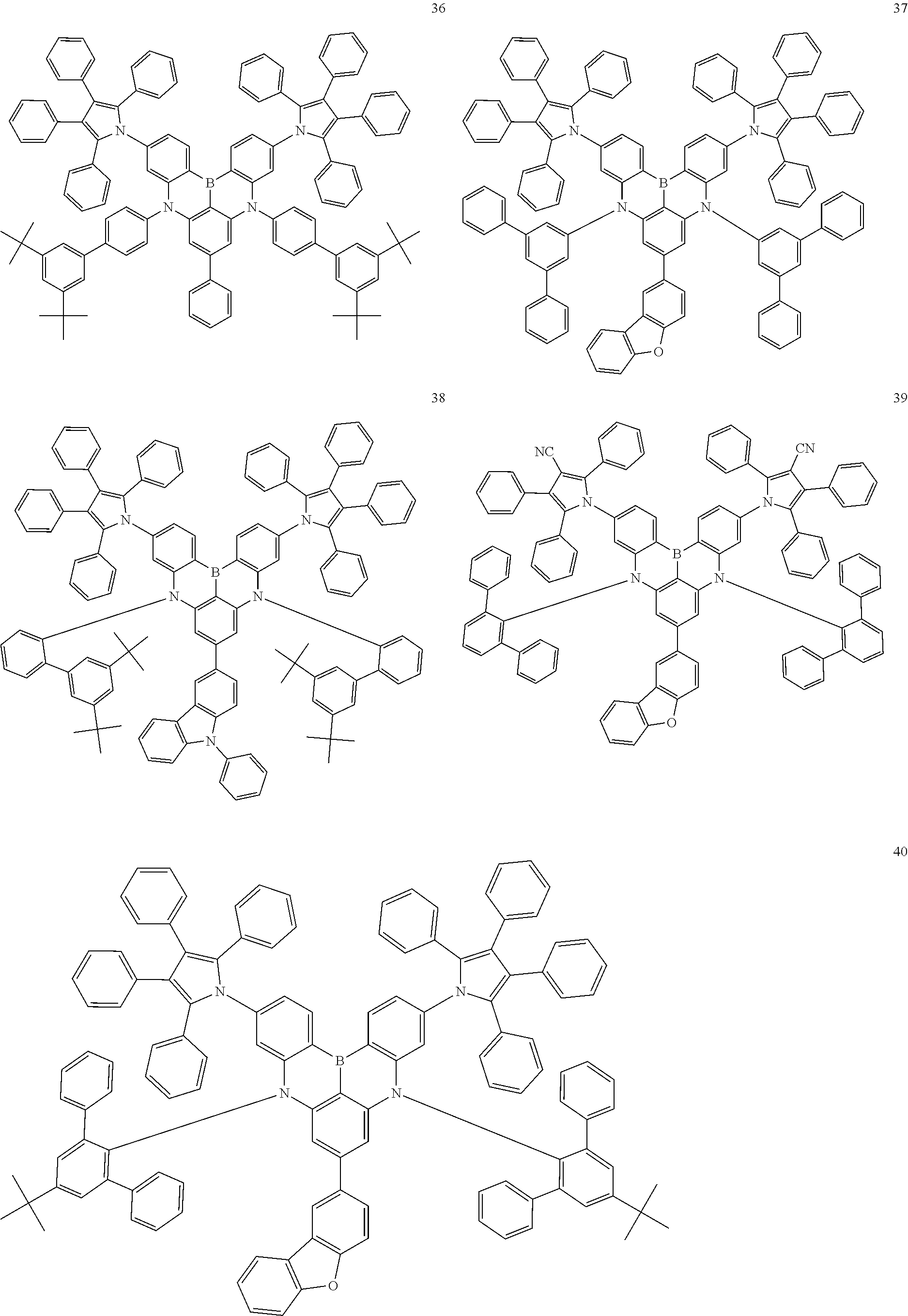 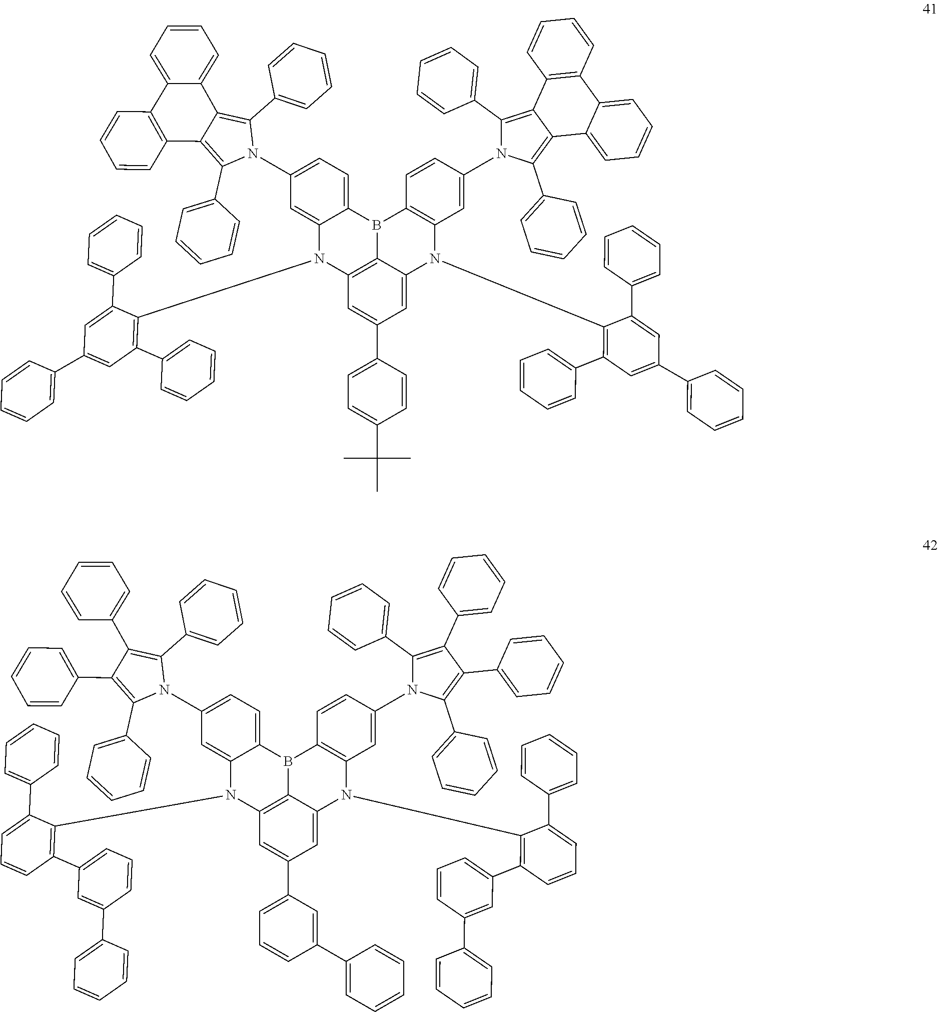 [SMILES: CC(C)(C)c1ccc(-c2cc3c4c(c2)N(c2c(-c5ccccc5)cc(-c5ccccc5)cc2-c2ccccc2)c2cc(-n5c(-c6ccccc6)c6c7ccccc7c7ccccc7c6c5-c5ccccc5)ccc2B4c2ccc(-n4c(-c5ccccc5)c5c6ccccc6c6ccccc6c5c4-c4ccccc4)cc2N3c2c(-c3ccccc3)cc(-c3ccccc3)cc2-c2ccccc2)cc1 ; c1ccc(-c2cccc(-c3cc4c5c(c3)N(c3c(-c6ccccc6)cccc3-c3cccc(-c6ccccc6)c3)c3cc(-n6c(-c7ccccc7)c(-c7ccccc7)c(-c7ccccc7)c6-c6ccccc6)ccc3B5c3ccc(-n5c(-c6ccccc6)c(-c6ccccc6)c(-c6ccccc6)c5-c5ccccc5)cc3N4c3c(-c4ccccc4)cccc3-c3cccc(-c4ccccc4)c3)c2)cc1] 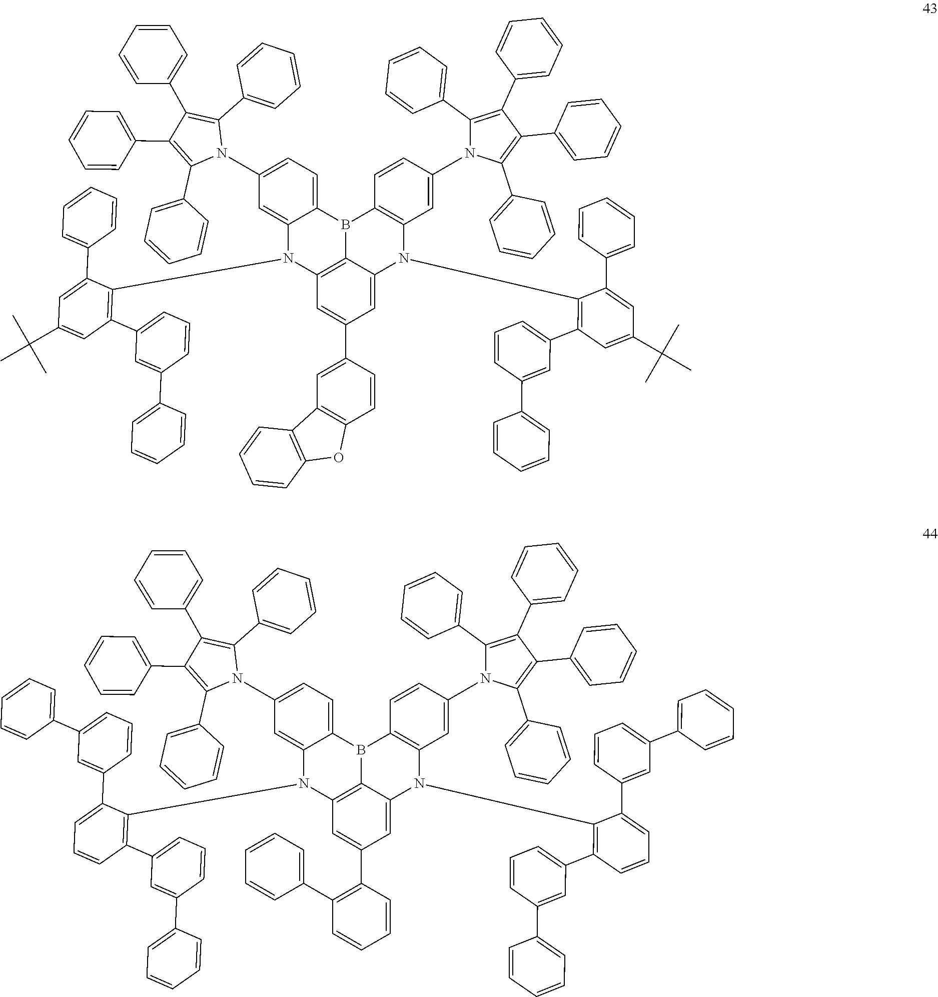 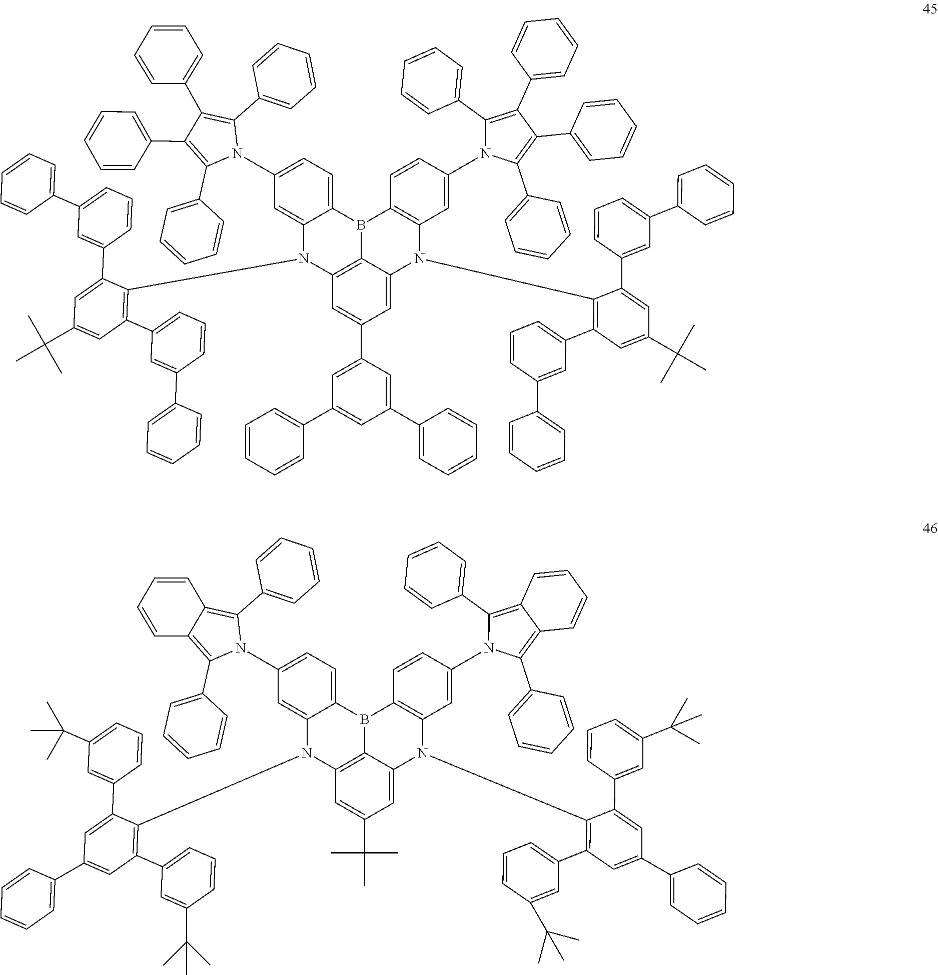 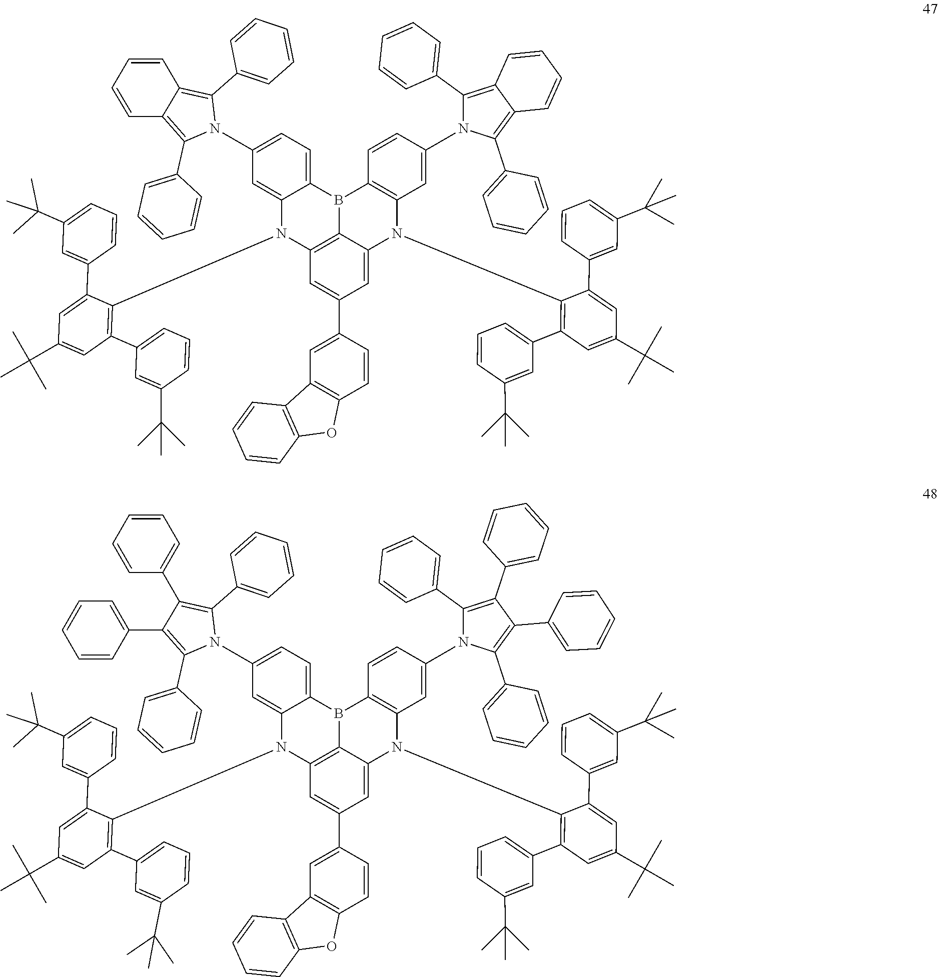 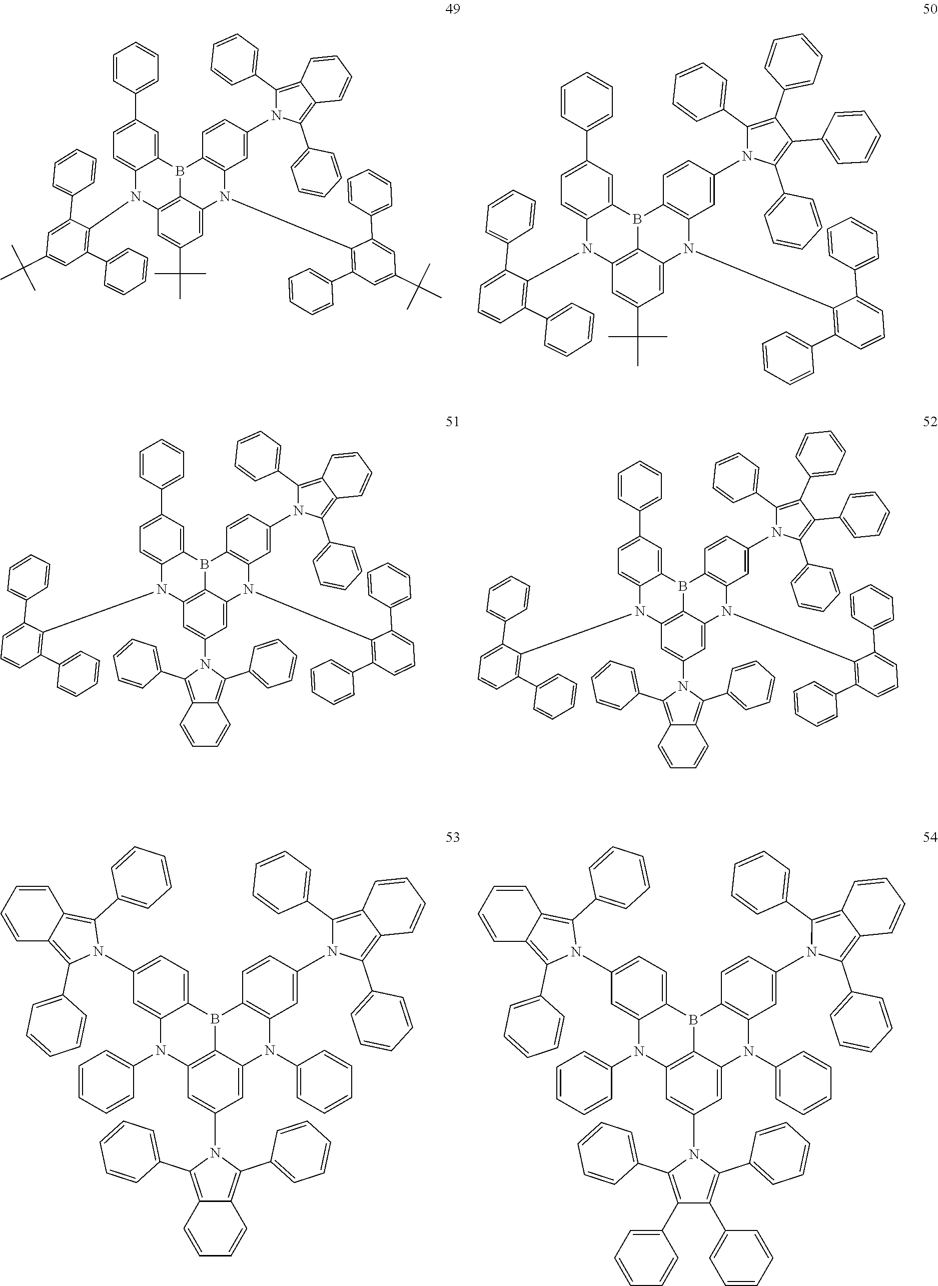 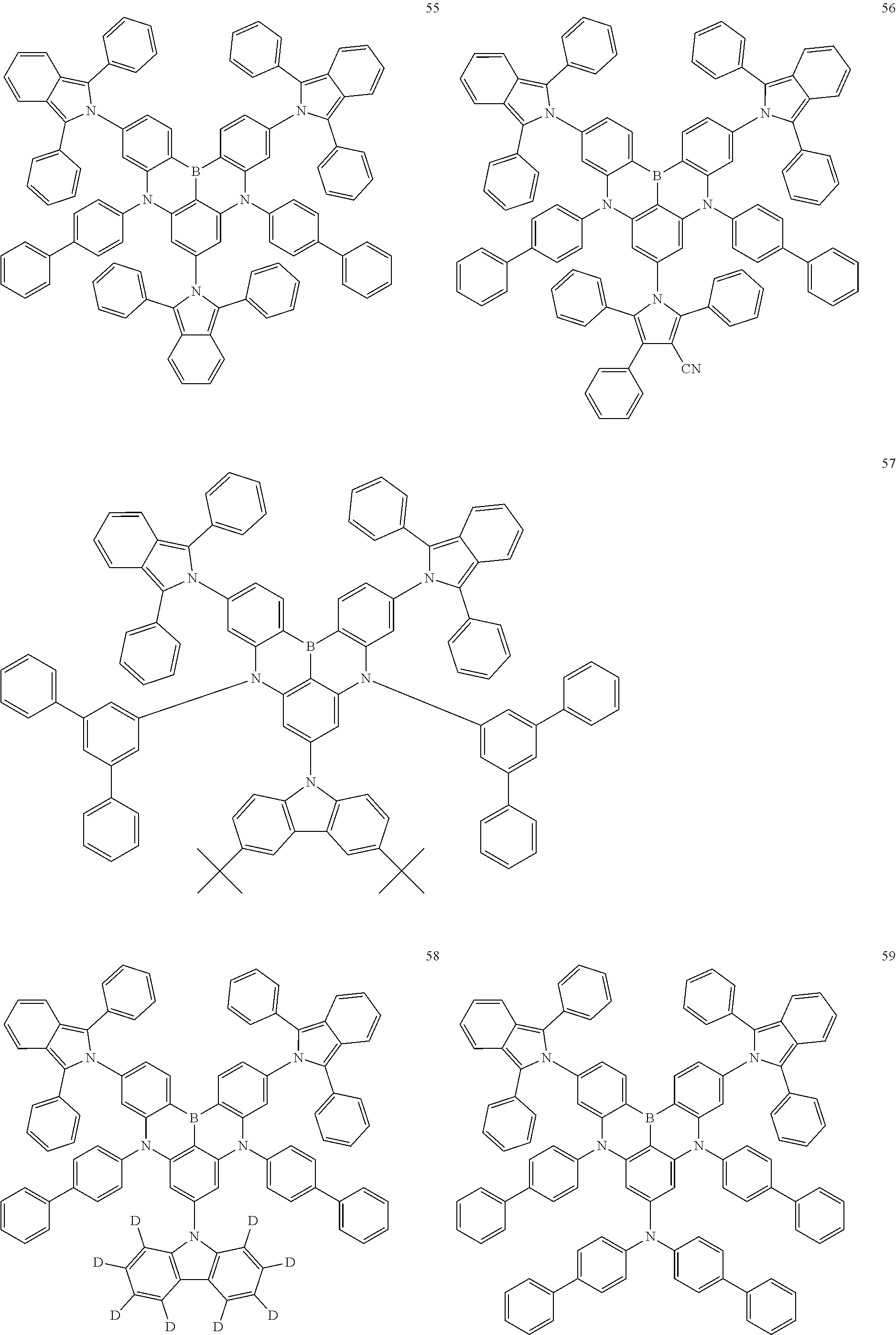 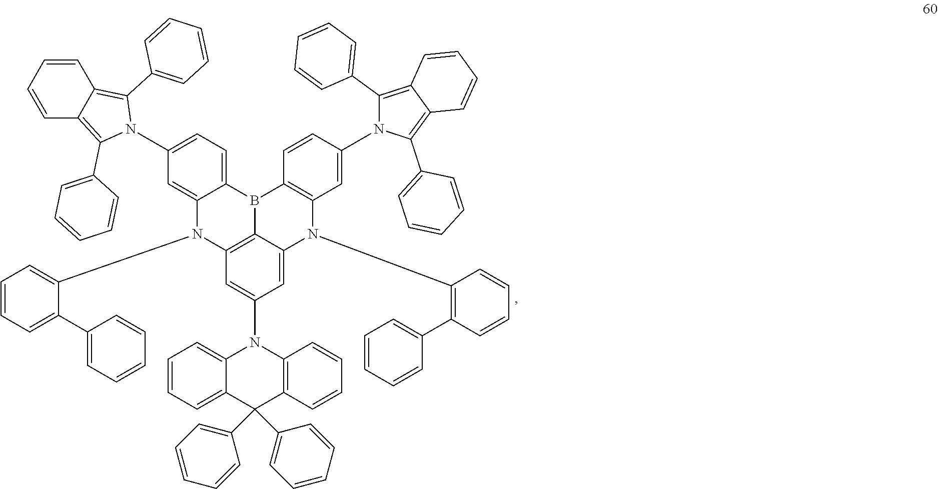 [SMILES: c1ccc(-c2ccccc2N2c3cc(-n4c(-c5ccccc5)c5ccccc5c4-c4ccccc4)ccc3B3c4ccc(-n5c(-c6ccccc6)c6ccccc6c5-c5ccccc5)cc4N(c4ccccc4-c4ccccc4)c4cc(N5c6ccccc6C(c6ccccc6)(c6ccccc6)c6ccccc65)cc2c43)cc1]
and
wherein in Compound Group 1, D is a deuterium atom.

12. A fused polycyclic compound represented by Formula 1: 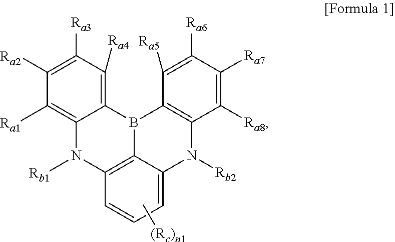
wherein in Formula 1,
Rₐ₁ to Rₐ₈ are each independently represented by Formula 2, a hydrogen atom, a deuterium atom, or a substituted or unsubstituted aryl group having 6 to 30 ring-forming carbon atoms,
at least one of Rₐ₁ to Rₐ₈ is represented by Formula 2,
n1 is an integer of 0 to 3, and
R_{b1}, R_{b2}, and R_{c} are each independently a hydrogen atom, a deuterium atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and 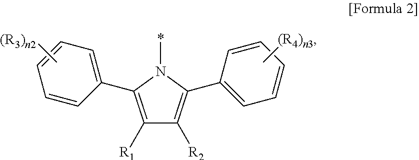
wherein in Formula 2,
R₁ and R₂ are each independently a hydrogen atom, a deuterium atom, a cyano group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring,
n2 and n3 are each independently an integer of 0 to 5, and
R₃ and R₄ are each independently a hydrogen atom, a deuterium atom, a cyano group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms.

13. The fused polycyclic compound of claim 12, wherein Formula 1 is represented by Formula 1-A1 or Formula 1-A2: 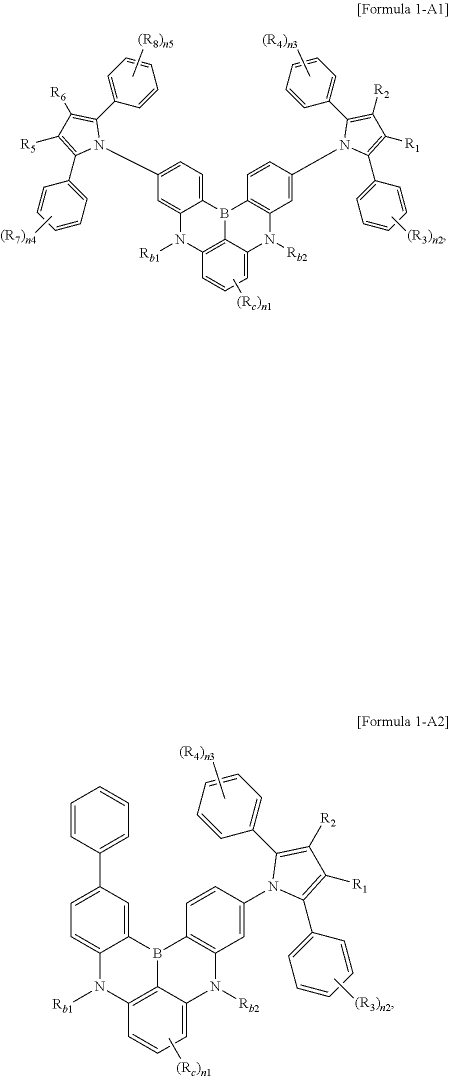
wherein in Formula 1-A1,
R₅ and R₆ are each independently a hydrogen atom, a deuterium atom, a cyano group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring,
n4 and n5 are each independently an integer of 0 to 5, and
R₇ and R₈ are each independently a hydrogen atom, a deuterium atom, a cyano group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and
wherein in Formulas 1-A1 and 1-A2,
n1 to n3, R_{b1}, R_{b2}, R_{c}, and R₁ to R₄ are as defined in Formulas 1 and 2.

14. The fused polycyclic compound of claim 12, wherein Formula 2 is represented by any one selected from among Formulas 2-1 to 2-6:

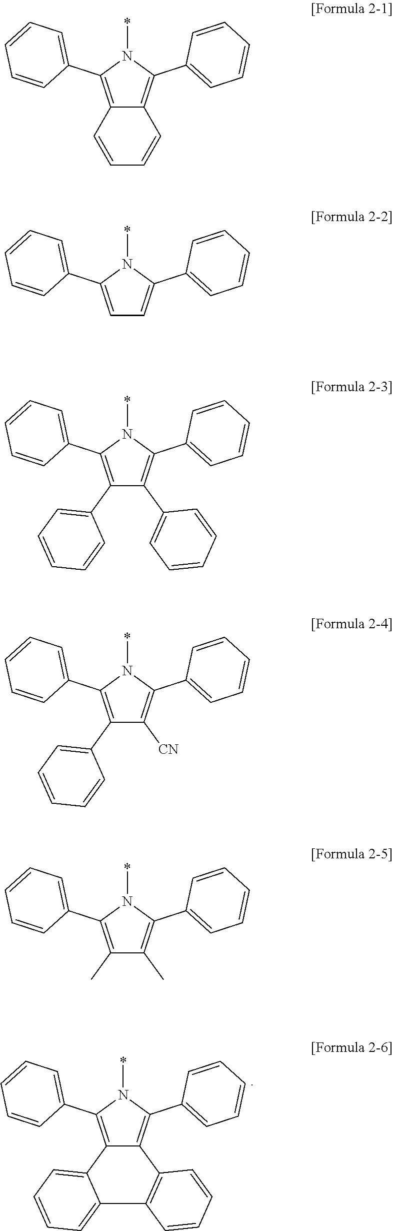 [SMILES: *n1c(-c2ccccc2)c2ccccc2c1-c1ccccc1 ; *n1c(-c2ccccc2)ccc1-c1ccccc1 ; *n1c(-c2ccccc2)c(-c2ccccc2)c(-c2ccccc2)c1-c1ccccc1 ; *n1c(-c2ccccc2)c(C#N)c(-c2ccccc2)c1-c1ccccc1 ; *n1c(-c2ccccc2)c(C)c(C)c1-c1ccccc1 ; *n1c(-c2ccccc2)c2c3ccccc3c3ccccc3c2c1-c1ccccc1]

15. The fused polycyclic compound of claim 12, wherein Formula 1 is represented by Formula 1-B: 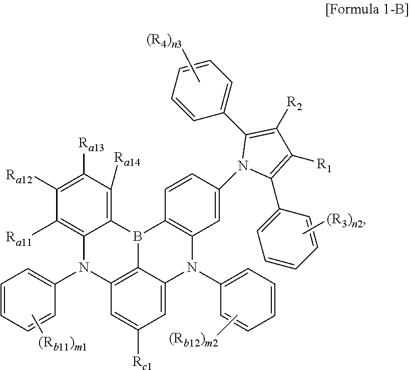
and
wherein in Formula 1-B,
Rₐ₁₁ to Rₐ₁₄ are each independently a hydrogen atom, a deuterium atom, or a substituted or unsubstituted aryl group having 6 to 30 ring-forming carbon atoms, or represented by Formula 2,
m1 and m2 are each independently an integer of 0 to 5,
R_{b1} and R_{b12} are each independently a hydrogen atom, a deuterium atom, a substituted or unsubstituted alkyl group having 1 to 20 carbon atoms, or a substituted or unsubstituted aryl group having 6 to 30 ring-forming carbon atoms,
R_{c1} is a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and
n2, n3, and R₁ to R₄ are as defined in Formula 2.

16. The fused polycyclic compound of claim 15, wherein Formula 1-B is represented by Formula 1-B1 or Formula 1-B2: 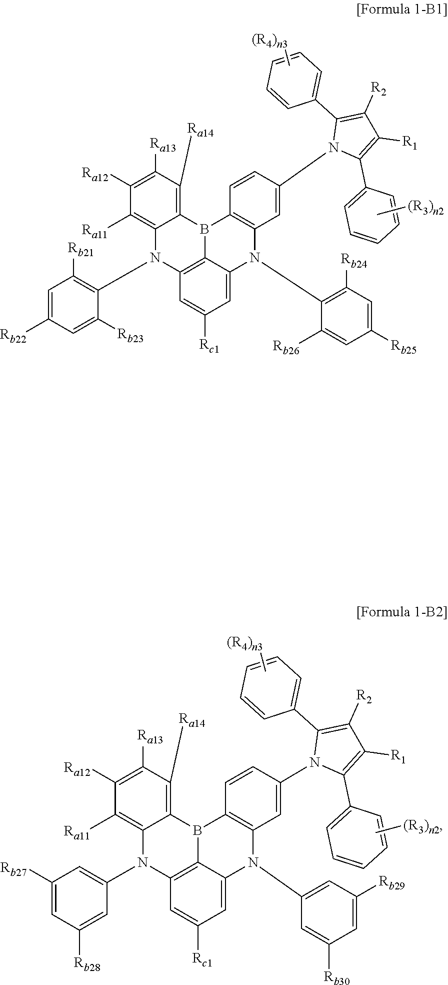
and
wherein in Formulas 1-B1 and 1-B2,
R_{b21} to R_{b30} are each independently a hydrogen atom, a deuterium atom, a substituted or unsubstituted t-butyl group, or a substituted or unsubstituted phenyl group, and
n2, n3, R₁ to R₄, Rₐ₁₁ to Rₐ₁₄, and R_{c1} are as defined in Formula 1-B.

17. The fused polycyclic compound of claim 15, wherein in Formula 1-B, R_{c1} is a substituted or unsubstituted t-butyl group, a substituted or unsubstituted aryl amine group, a substituted or unsubstituted phenyl group, a substituted or unsubstituted pyrrole group, a substituted or unsubstituted isoindole group, a substituted or unsubstituted dibenzofuran group, a substituted or unsubstituted carbazole group, or a substituted or unsubstituted acridine group.

18. The fused polycyclic compound of claim 15, wherein in Formula 1-B, R_{c1} is represented by any one selected from among RC-1 to RC-15: 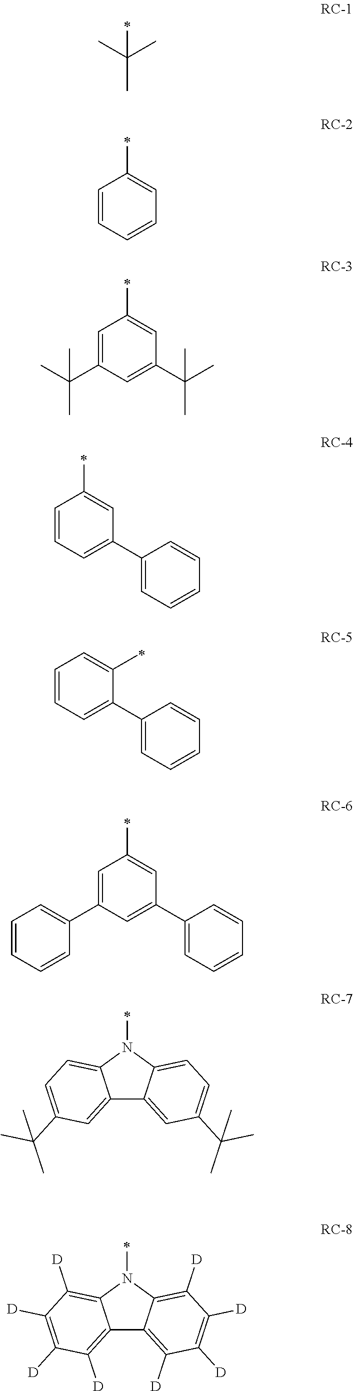 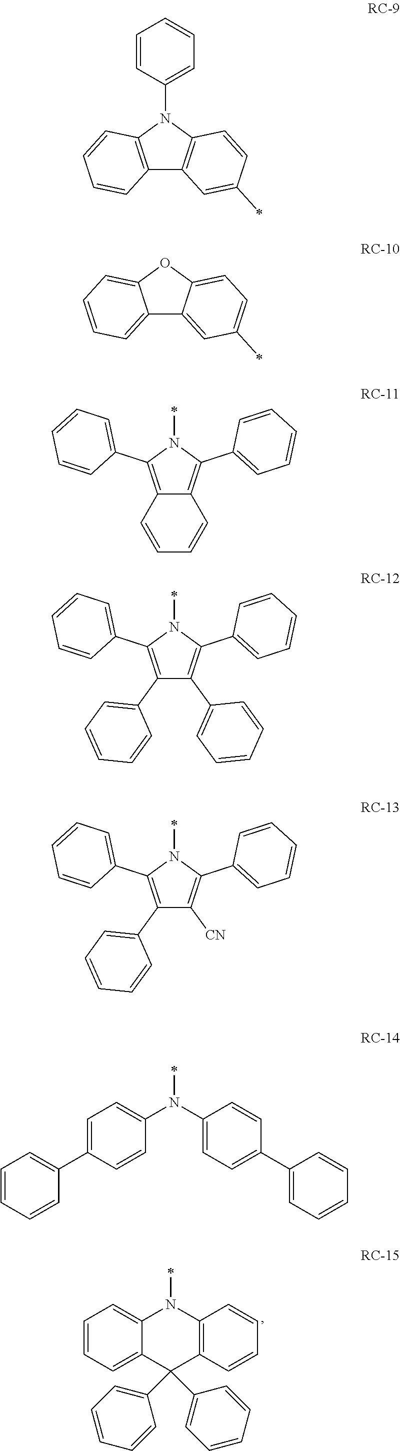
and
wherein in RC-8, D is a deuterium atom.

19. The fused polycyclic compound of claim 12, wherein in Formula 1, R_{b1} and R_{b2} are each independently represented by any one selected from among RB-1 to RB-15:

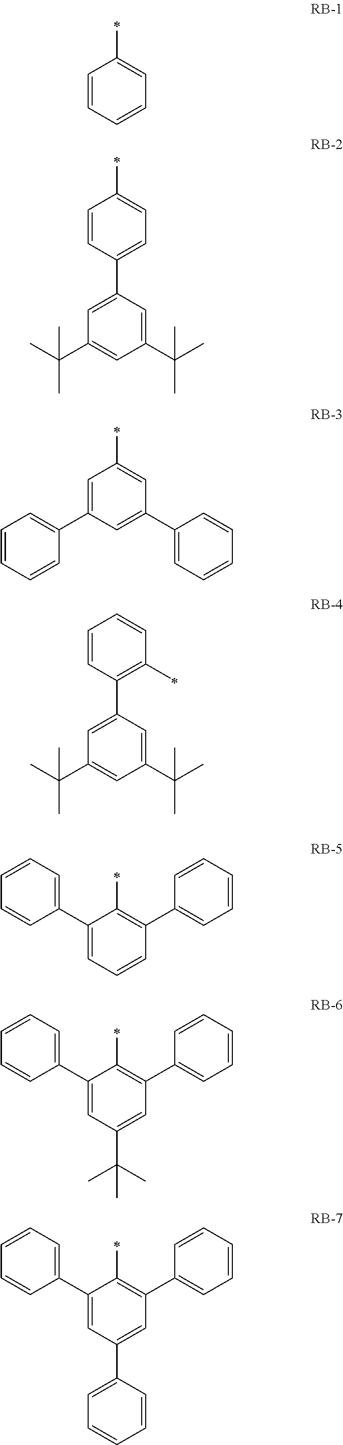

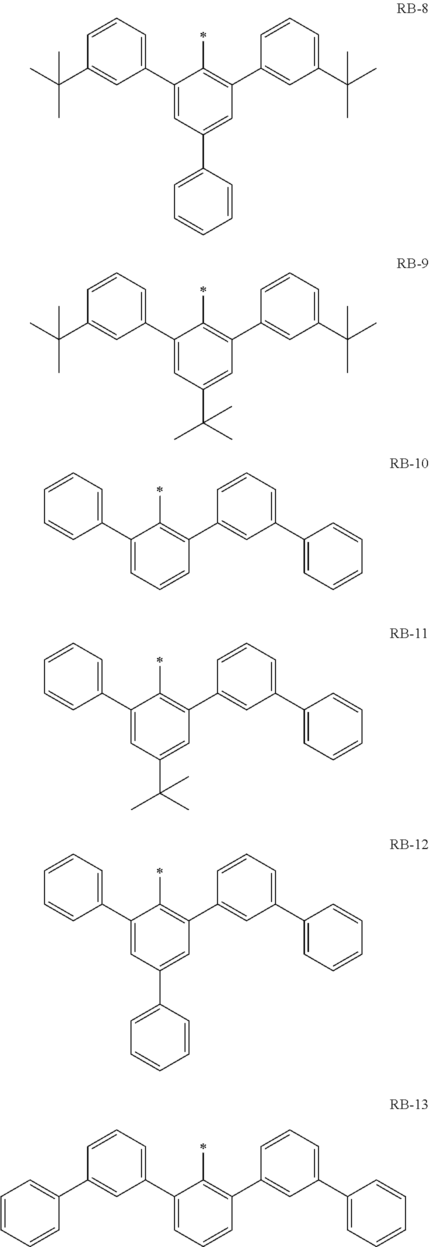

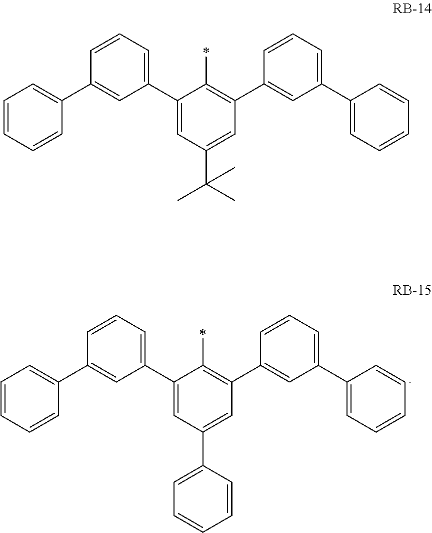

20. The fused polycyclic compound of claim 12, wherein Formula 1 is represented by any one selected from among Compound Group 1: 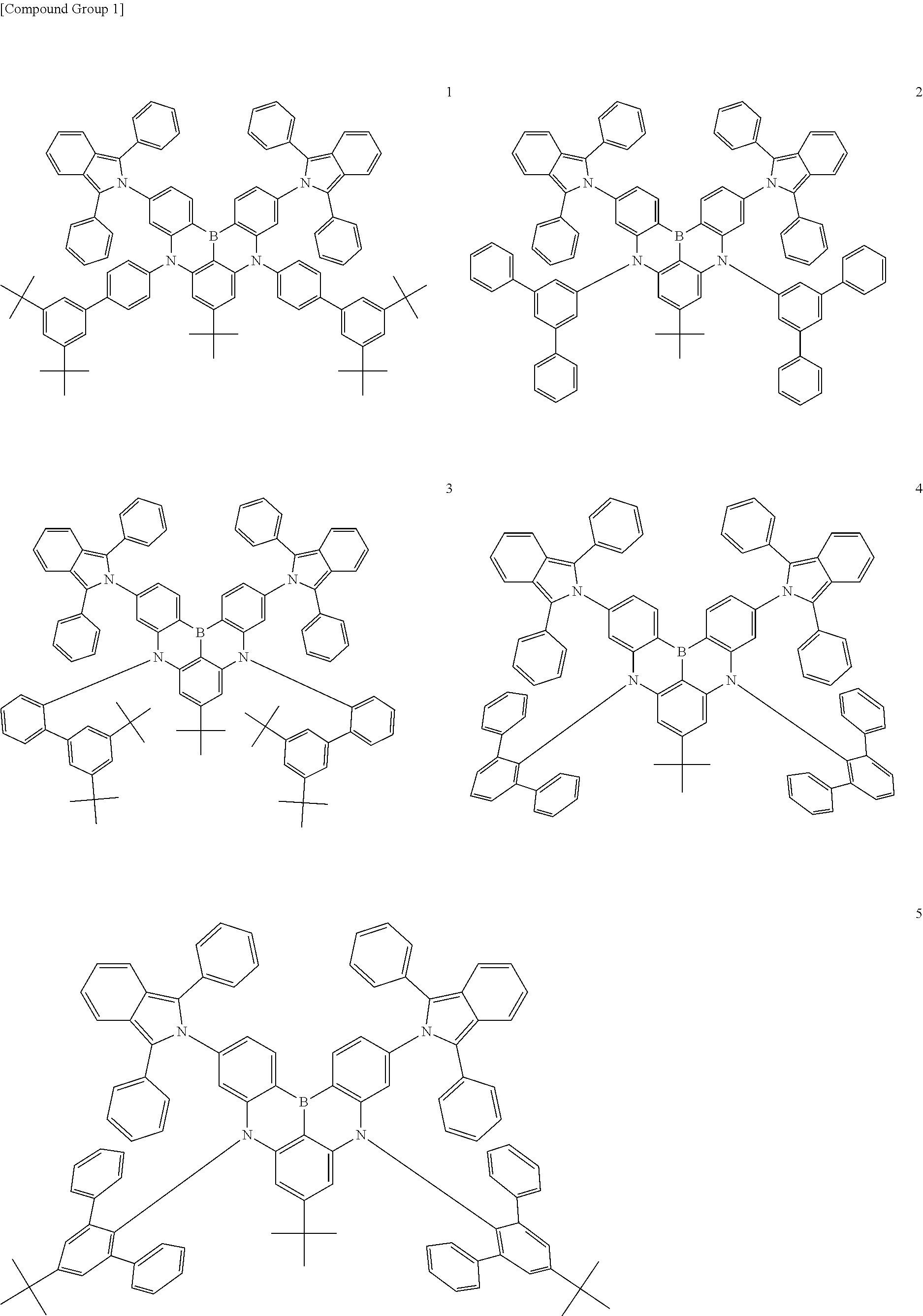 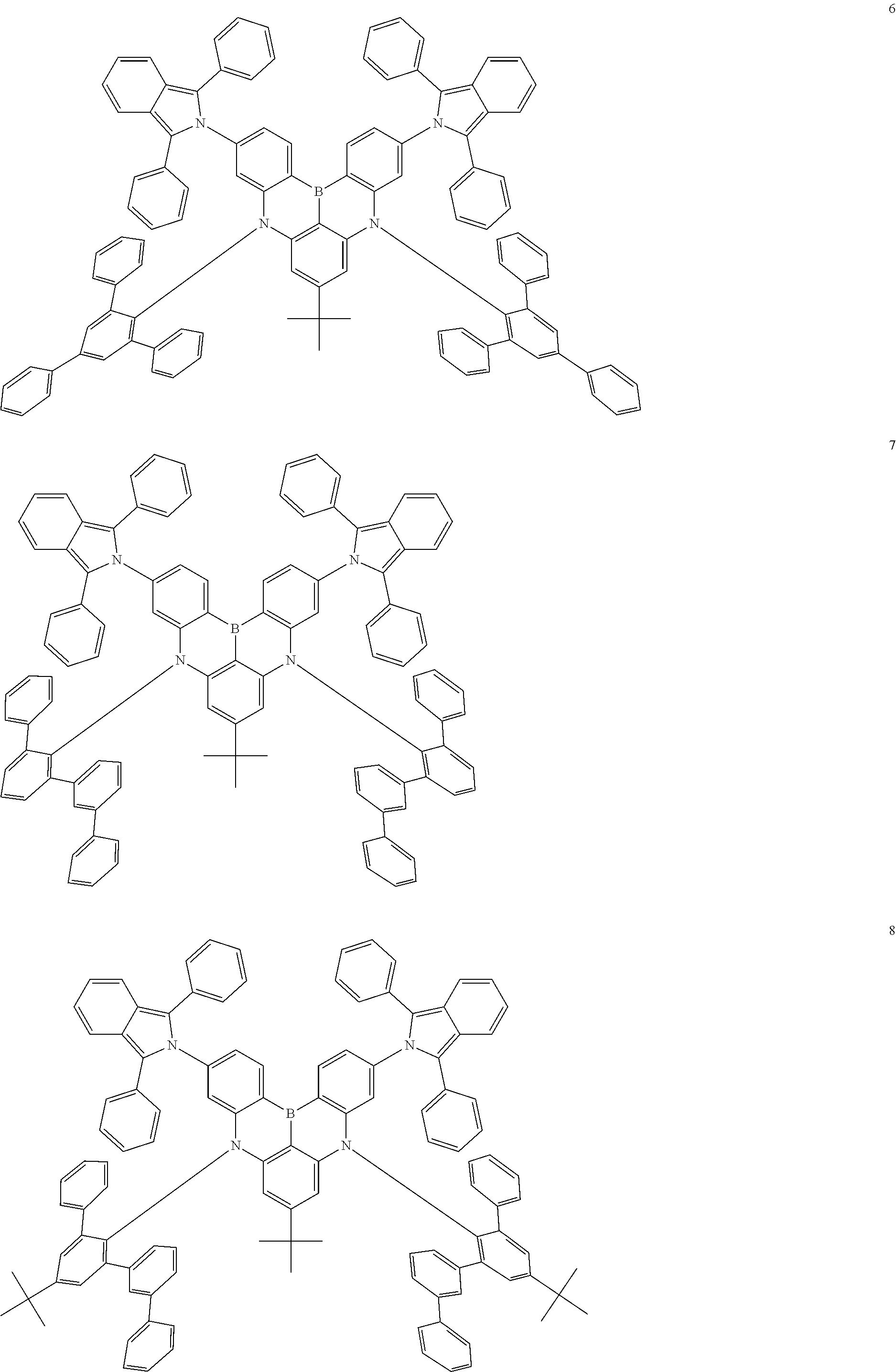 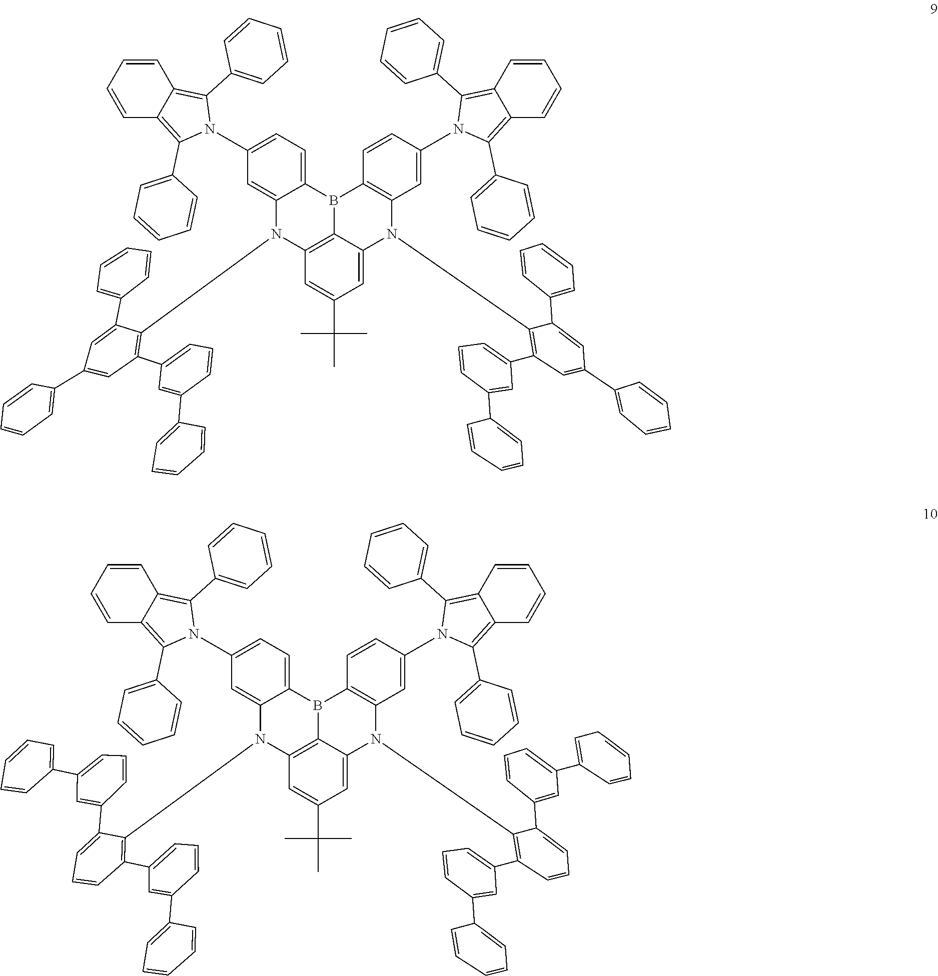 [SMILES: CC(C)(C)c1cc2c3c(c1)N(c1c(-c4ccccc4)cc(-c4ccccc4)cc1-c1cccc(-c4ccccc4)c1)c1cc(-n4c(-c5ccccc5)c5ccccc5c4-c4ccccc4)ccc1B3c1ccc(-n3c(-c4ccccc4)c4ccccc4c3-c3ccccc3)cc1N2C1=C(c2cccc(C3C=CC=CC=C3)c2)C=C(c2ccccc2)C=CC1c1ccccc1 ; CC(C)(C)c1cc2c3c(c1)N(c1c(-c4cccc(-c5ccccc5)c4)cccc1-c1cccc(-c4ccccc4)c1)c1cc(-n4c(-c5ccccc5)c5ccccc5c4-c4ccccc4)ccc1B3c1ccc(-n3c(-c4ccccc4)c4ccccc4c3-c3ccccc3)cc1N2C1=C(c2cccc(C3C=CC=CC=C3)c2)C=CC=CC1c1cccc(C2=CCC=CC=C2)c1] 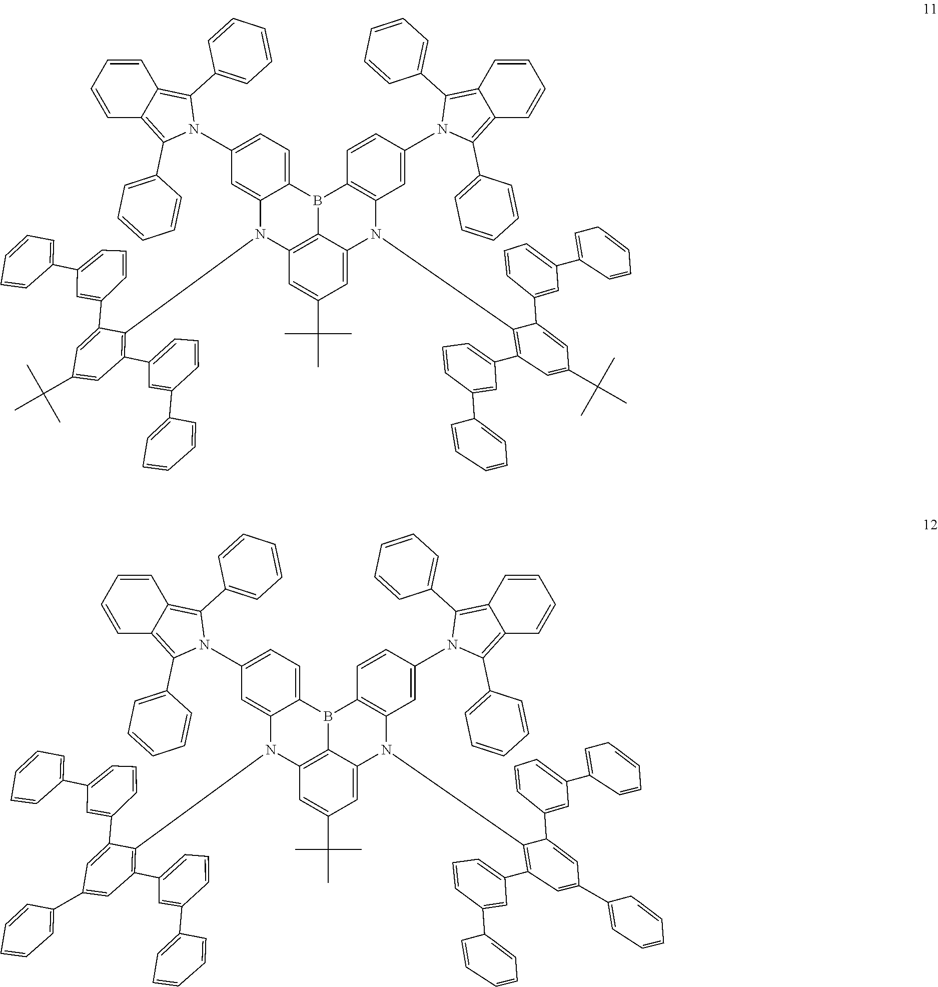 [SMILES: CC(C)(C)C1=CC(c2cccc(C3C=CC=CC=C3)c2)=C(N2c3cc(-n4c(-c5ccccc5)c5ccccc5c4-c4ccccc4)ccc3B3c4ccc(-n5c(-c6ccccc6)c6ccccc6c5-c5ccccc5)cc4N(c4c(-c5cccc(-c6ccccc6)c5)cc(C(C)(C)C)cc4-c4cccc(-c5ccccc5)c4)c4cc(C(C)(C)C)cc2c43)C(c2cccc(C3=CCC=CC=C3)c2)C=C1 ; CC(C)(C)c1cc2c3c(c1)N(c1c(-c4cccc(-c5ccccc5)c4)cc(-c4ccccc4)cc1-c1cccc(-c4ccccc4)c1)c1cc(-n4c(-c5ccccc5)c5ccccc5c4-c4ccccc4)ccc1B3c1ccc(-n3c(-c4ccccc4)c4ccccc4c3-c3ccccc3)cc1N2C1=C(c2cccc(C3C=CC=CC=C3)c2)C=C(C2=CC=CC=CC2)C=CC1c1cccc(C2=CCC=CC=C2)c1] 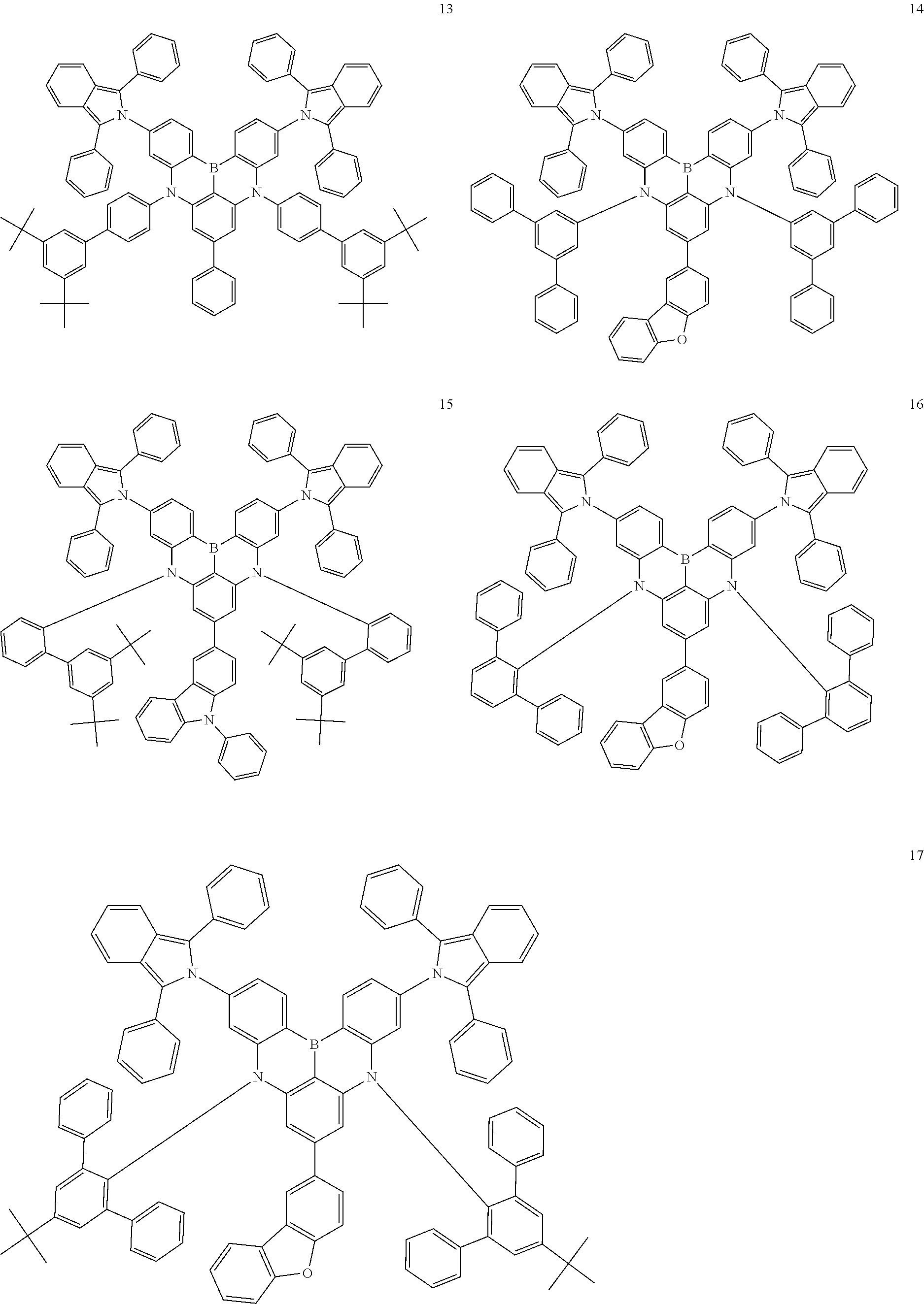 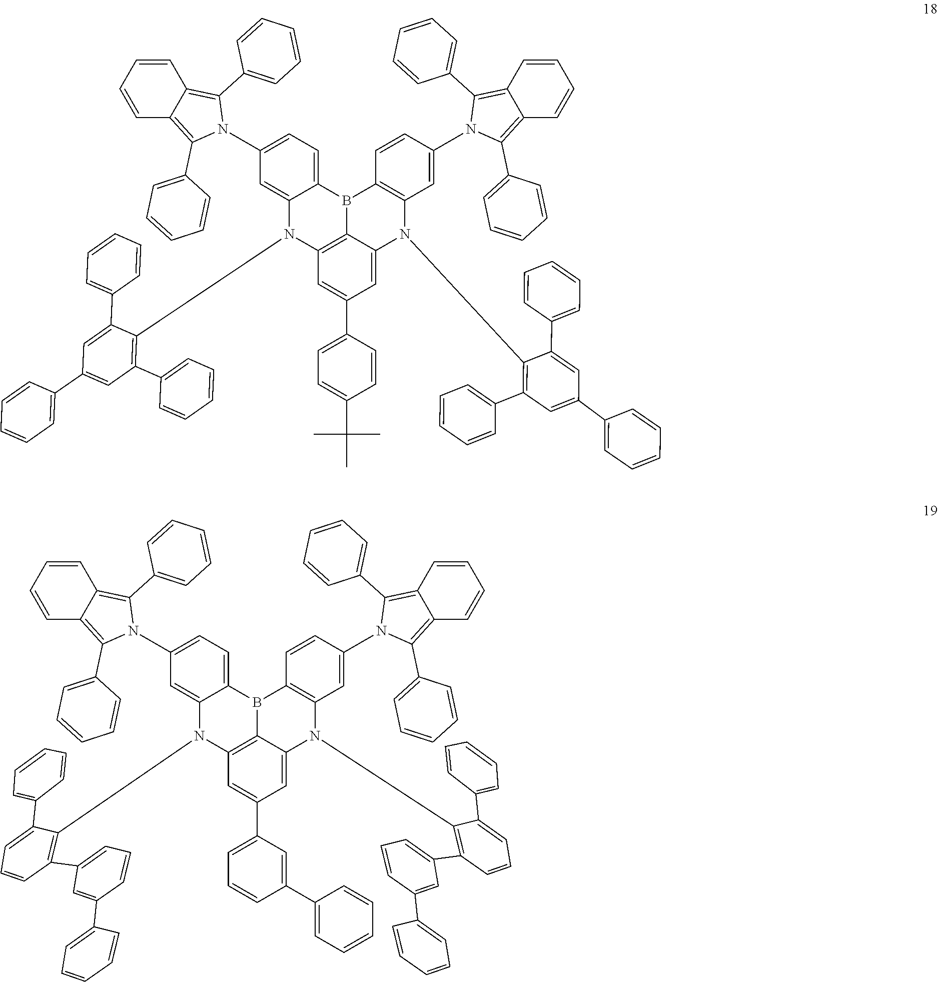 [SMILES: CC(C)(C)c1ccc(-c2cc3c4c(c2)N(c2c(-c5ccccc5)cc(-c5ccccc5)cc2-c2ccccc2)c2cc(-n5c(-c6ccccc6)c6ccccc6c5-c5ccccc5)ccc2B4c2ccc(-n4c(-c5ccccc5)c5ccccc5c4-c4ccccc4)cc2N3c2c(-c3ccccc3)cc(-c3ccccc3)cc2-c2ccccc2)cc1 ; c1ccc(-c2cccc(-c3cc4c5c(c3)N(c3c(-c6ccccc6)cccc3-c3cccc(-c6ccccc6)c3)c3cc(-n6c(-c7ccccc7)c7ccccc7c6-c6ccccc6)ccc3B5c3ccc(-n5c(-c6ccccc6)c6ccccc6c5-c5ccccc5)cc3N4c3c(-c4ccccc4)cccc3-c3cccc(-c4ccccc4)c3)c2)cc1] 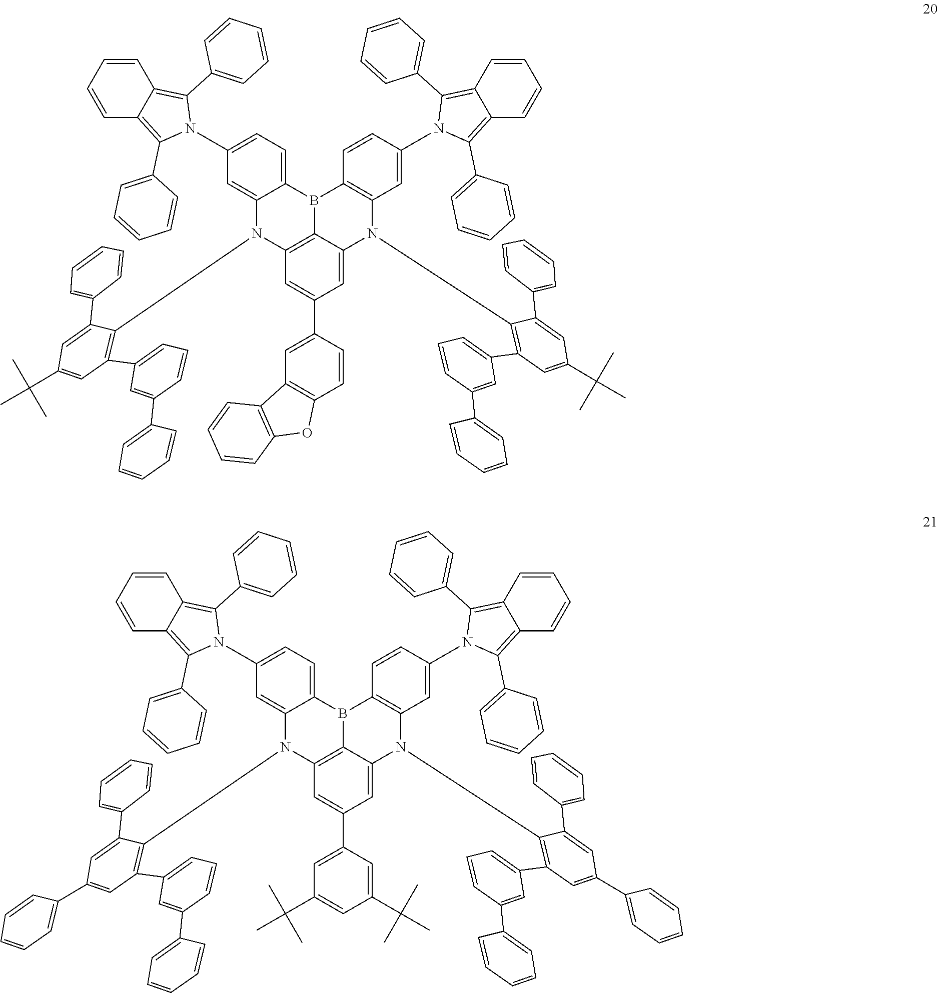 [SMILES: CC(C)(C)c1cc(-c2ccccc2)c(N2c3cc(-n4c(-c5ccccc5)c5ccccc5c4-c4ccccc4)ccc3B3c4ccc(-n5c(-c6ccccc6)c6ccccc6c5-c5ccccc5)cc4N(c4c(-c5ccccc5)cc(C(C)(C)C)cc4-c4cccc(-c5ccccc5)c4)c4cc(-c5ccc6oc7ccccc7c6c5)cc2c43)c(-c2cccc(-c3ccccc3)c2)c1 ; CC(C)(C)c1cc(-c2cc3c4c(c2)N(c2c(-c5ccccc5)cc(-c5ccccc5)cc2-c2cccc(-c5ccccc5)c2)c2cc(-n5c(-c6ccccc6)c6ccccc6c5-c5ccccc5)ccc2B4c2ccc(-n4c(-c5ccccc5)c5ccccc5c4-c4ccccc4)cc2N3c2c(-c3ccccc3)cc(-c3ccccc3)cc2-c2cccc(-c3ccccc3)c2)cc(C(C)(C)C)c1] 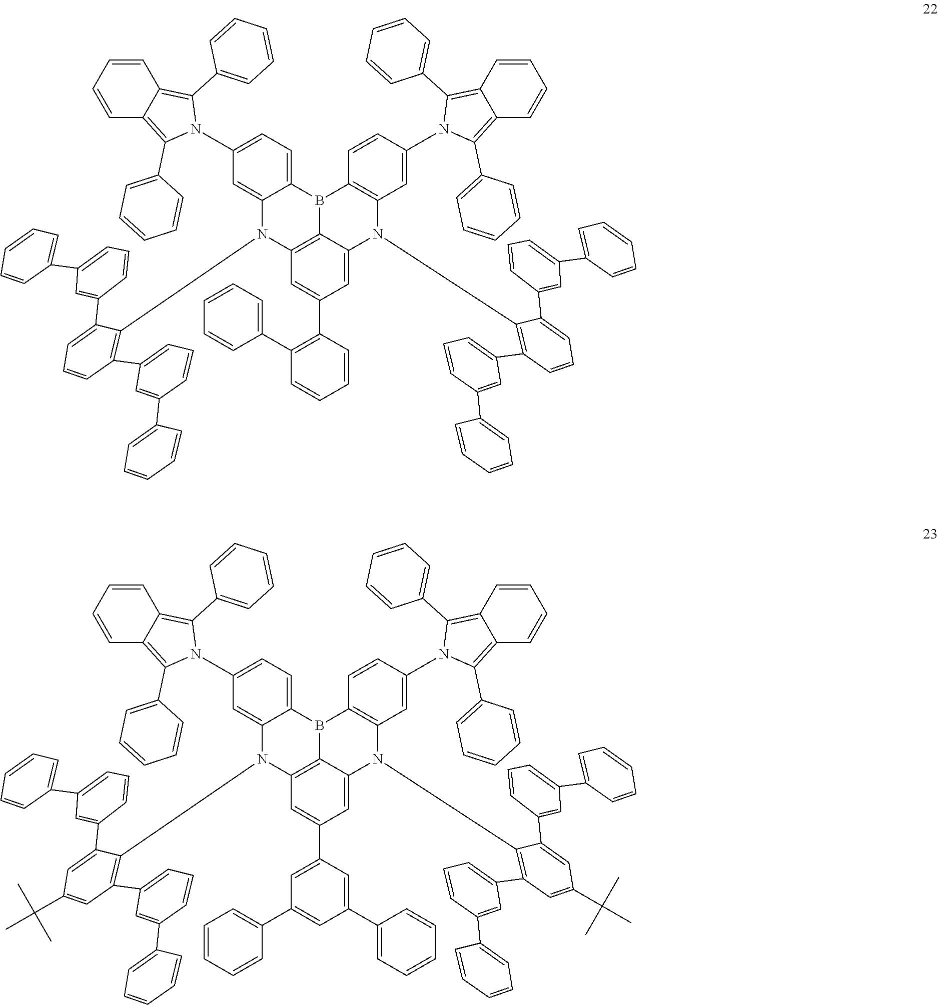 [SMILES: c1ccc(-c2cccc(-c3cccc(-c4cccc(-c5ccccc5)c4)c3N3c4cc(-n5c(-c6ccccc6)c6ccccc6c5-c5ccccc5)ccc4B4c5ccc(-n6c(-c7ccccc7)c7ccccc7c6-c6ccccc6)cc5N(c5c(-c6cccc(-c7ccccc7)c6)cccc5-c5cccc(-c6ccccc6)c5)c5cc(-c6ccccc6-c6ccccc6)cc3c54)c2)cc1 ; CC(C)(C)c1cc(-c2cccc(-c3ccccc3)c2)c(N2c3cc(-n4c(-c5ccccc5)c5ccccc5c4-c4ccccc4)ccc3B3c4ccc(-n5c(-c6ccccc6)c6ccccc6c5-c5ccccc5)cc4N(c4c(-c5cccc(-c6ccccc6)c5)cc(C(C)(C)C)cc4-c4cccc(-c5ccccc5)c4)c4cc(-c5cc(-c6ccccc6)cc(-c6ccccc6)c5)cc2c43)c(-c2cccc(-c3ccccc3)c2)c1] 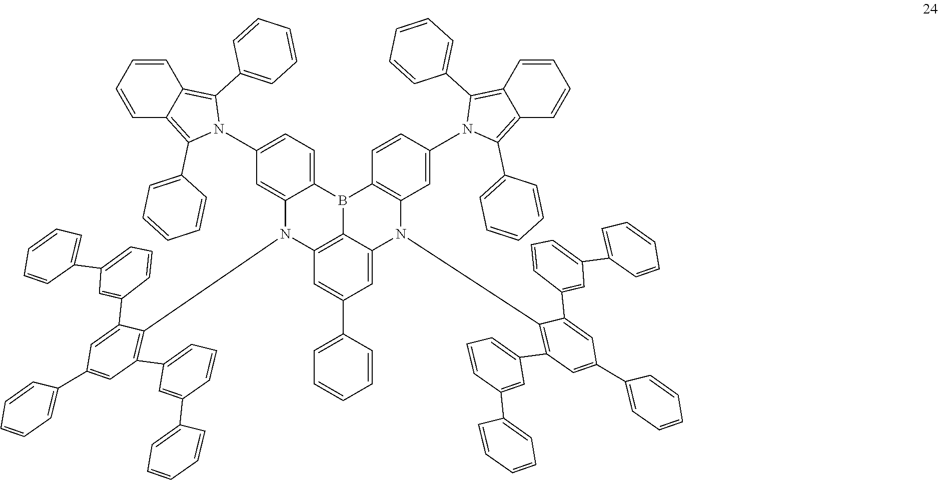 [SMILES: c1ccc(-c2cccc(-c3cc(-c4ccccc4)cc(-c4cccc(-c5ccccc5)c4)c3N3c4cc(-n5c(-c6ccccc6)c6ccccc6c5-c5ccccc5)ccc4B4c5ccc(-n6c(-c7ccccc7)c7ccccc7c6-c6ccccc6)cc5N(c5c(-c6cccc(-c7ccccc7)c6)cc(-c6ccccc6)cc5-c5cccc(-c6ccccc6)c5)c5cc(-c6ccccc6)cc3c54)c2)cc1] 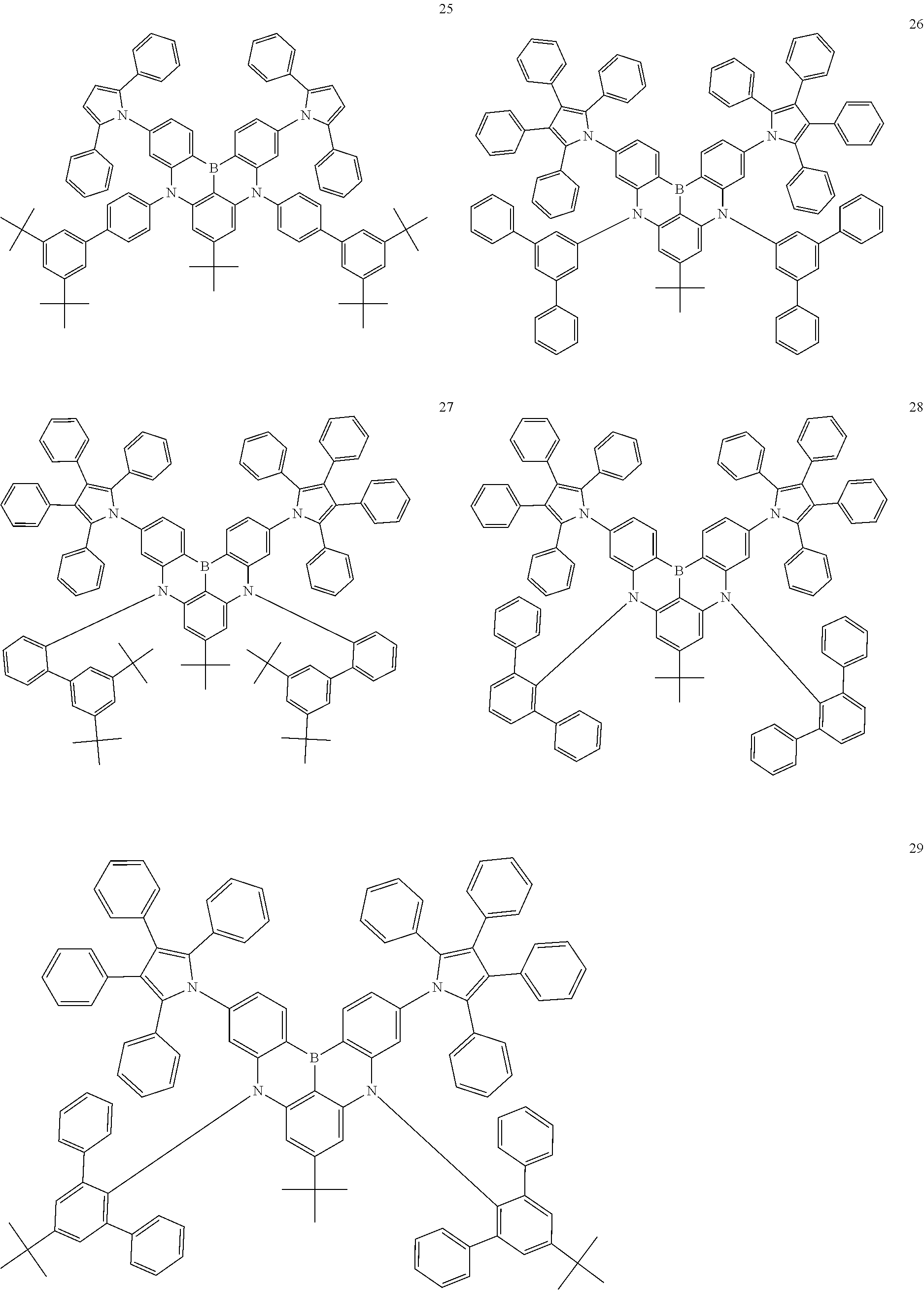 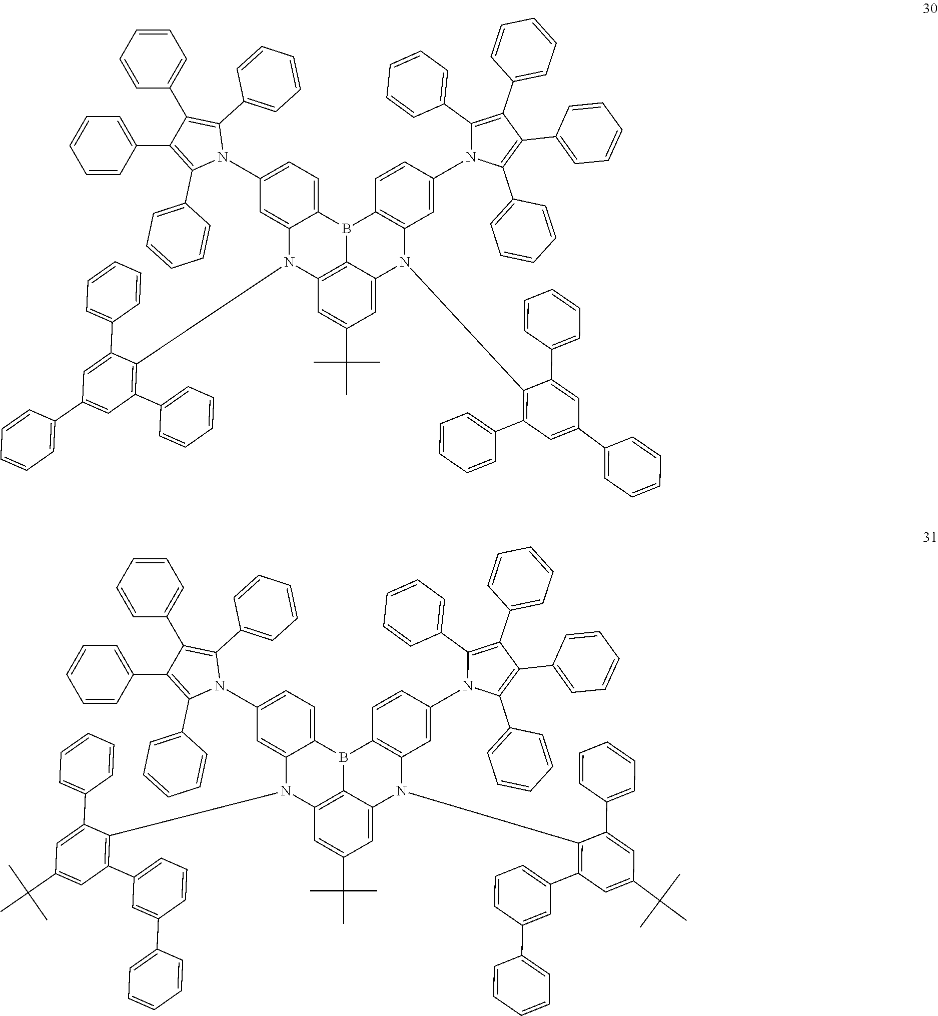 [SMILES: CC(C)(C)c1cc2c3c(c1)N(c1c(-c4ccccc4)cc(-c4ccccc4)cc1-c1ccccc1)c1cc(-n4c(-c5ccccc5)c(-c5ccccc5)c(-c5ccccc5)c4-c4ccccc4)ccc1B3c1ccc(-n3c(-c4ccccc4)c(-c4ccccc4)c(-c4ccccc4)c3-c3ccccc3)cc1N2c1c(-c2ccccc2)cc(-c2ccccc2)cc1-c1ccccc1 ; CC(C)(C)c1cc(-c2ccccc2)c(N2c3cc(-n4c(-c5ccccc5)c(-c5ccccc5)c(-c5ccccc5)c4-c4ccccc4)ccc3B3c4ccc(-n5c(-c6ccccc6)c(-c6ccccc6)c(-c6ccccc6)c5-c5ccccc5)cc4N(c4c(-c5ccccc5)cc(C(C)(C)C)cc4-c4cccc(-c5ccccc5)c4)c4cc(C(C)(C)C)cc2c43)c(-c2cccc(-c3ccccc3)c2)c1] 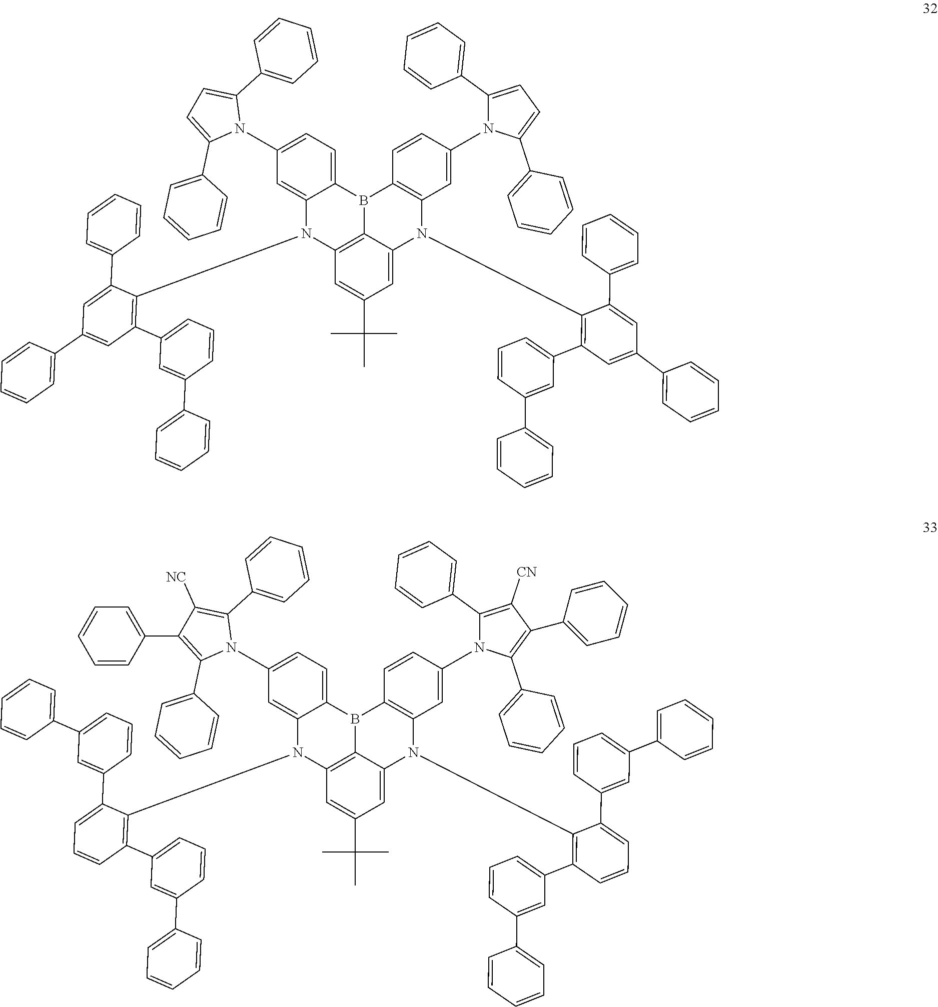 [SMILES: CC(C)(C)c1cc2c3c(c1)N(c1c(-c4ccccc4)cc(-c4ccccc4)cc1-c1cccc(-c4ccccc4)c1)c1cc(-n4c(-c5ccccc5)ccc4-c4ccccc4)ccc1B3c1ccc(-n3c(-c4ccccc4)ccc3-c3ccccc3)cc1N2c1c(-c2ccccc2)cc(-c2ccccc2)cc1-c1cccc(-c2ccccc2)c1 ; CC(C)(C)c1cc2c3c(c1)N(c1c(-c4cccc(-c5ccccc5)c4)cccc1-c1cccc(-c4ccccc4)c1)c1cc(-n4c(-c5ccccc5)c(C#N)c(-c5ccccc5)c4-c4ccccc4)ccc1B3c1ccc(-n3c(-c4ccccc4)c(C#N)c(-c4ccccc4)c3-c3ccccc3)cc1N2c1c(-c2cccc(-c3ccccc3)c2)cccc1-c1cccc(-c2ccccc2)c1] 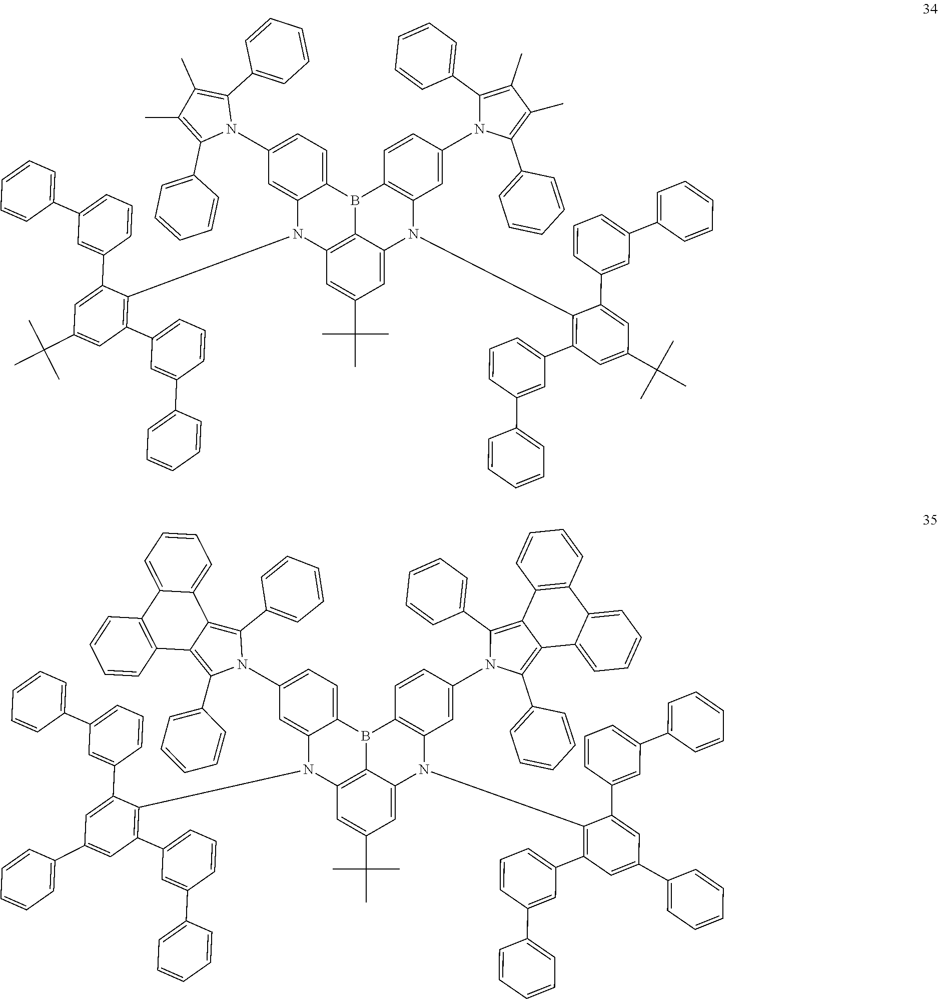 [SMILES: Cc1c(C)c(-c2ccccc2)n(-c2ccc3c(c2)N(c2c(-c4cccc(-c5ccccc5)c4)cc(C(C)(C)C)cc2-c2cccc(-c4ccccc4)c2)c2cc(C(C)(C)C)cc4c2B3c2ccc(-n3c(-c5ccccc5)c(C)c(C)c3-c3ccccc3)cc2N4c2c(-c3cccc(-c4ccccc4)c3)cc(C(C)(C)C)cc2-c2cccc(-c3ccccc3)c2)c1-c1ccccc1 ; CC(C)(C)c1cc2c3c(c1)N(c1c(-c4cccc(-c5ccccc5)c4)cc(-c4ccccc4)cc1-c1cccc(-c4ccccc4)c1)c1cc(-n4c(-c5ccccc5)c5c6ccccc6c6ccccc6c5c4-c4ccccc4)ccc1B3c1ccc(-n3c(-c4ccccc4)c4c5ccccc5c5ccccc5c4c3-c3ccccc3)cc1N2c1c(-c2cccc(-c3ccccc3)c2)cc(-c2ccccc2)cc1-c1cccc(-c2ccccc2)c1] 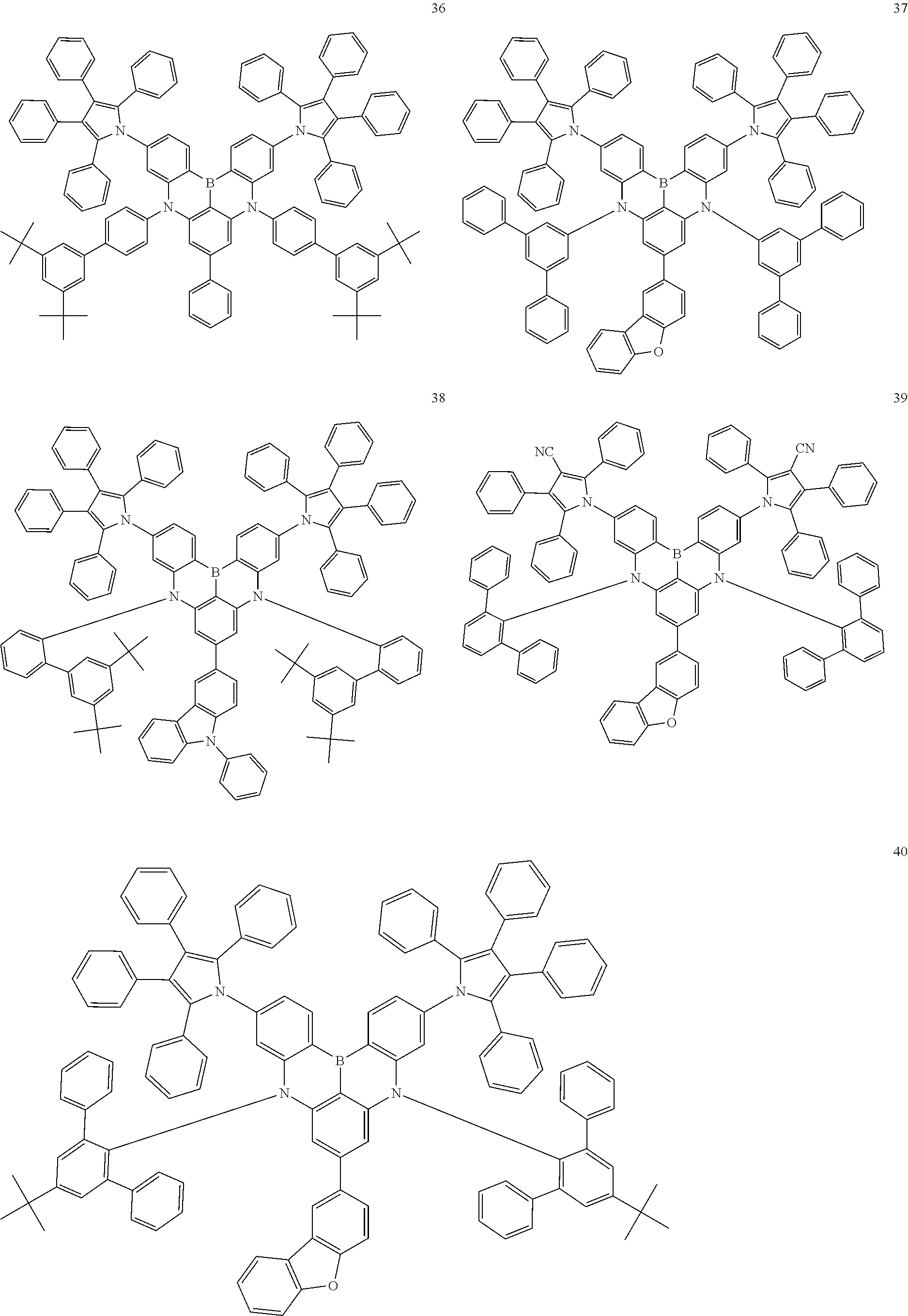 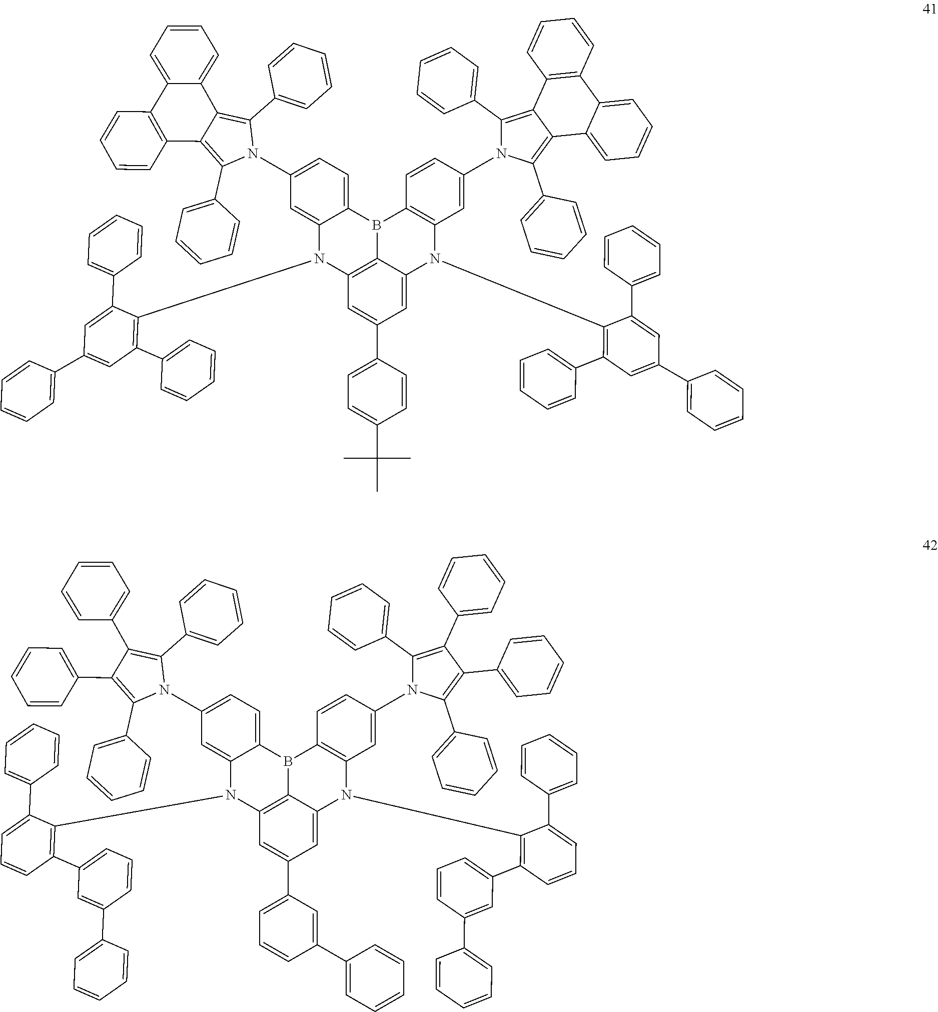 [SMILES: CC(C)(C)c1ccc(-c2cc3c4c(c2)N(c2c(-c5ccccc5)cc(-c5ccccc5)cc2-c2ccccc2)c2cc(-n5c(-c6ccccc6)c6c7ccccc7c7ccccc7c6c5-c5ccccc5)ccc2B4c2ccc(-n4c(-c5ccccc5)c5c6ccccc6c6ccccc6c5c4-c4ccccc4)cc2N3c2c(-c3ccccc3)cc(-c3ccccc3)cc2-c2ccccc2)cc1 ; c1ccc(-c2cccc(-c3cc4c5c(c3)N(c3c(-c6ccccc6)cccc3-c3cccc(-c6ccccc6)c3)c3cc(-n6c(-c7ccccc7)c(-c7ccccc7)c(-c7ccccc7)c6-c6ccccc6)ccc3B5c3ccc(-n5c(-c6ccccc6)c(-c6ccccc6)c(-c6ccccc6)c5-c5ccccc5)cc3N4c3c(-c4ccccc4)cccc3-c3cccc(-c4ccccc4)c3)c2)cc1] 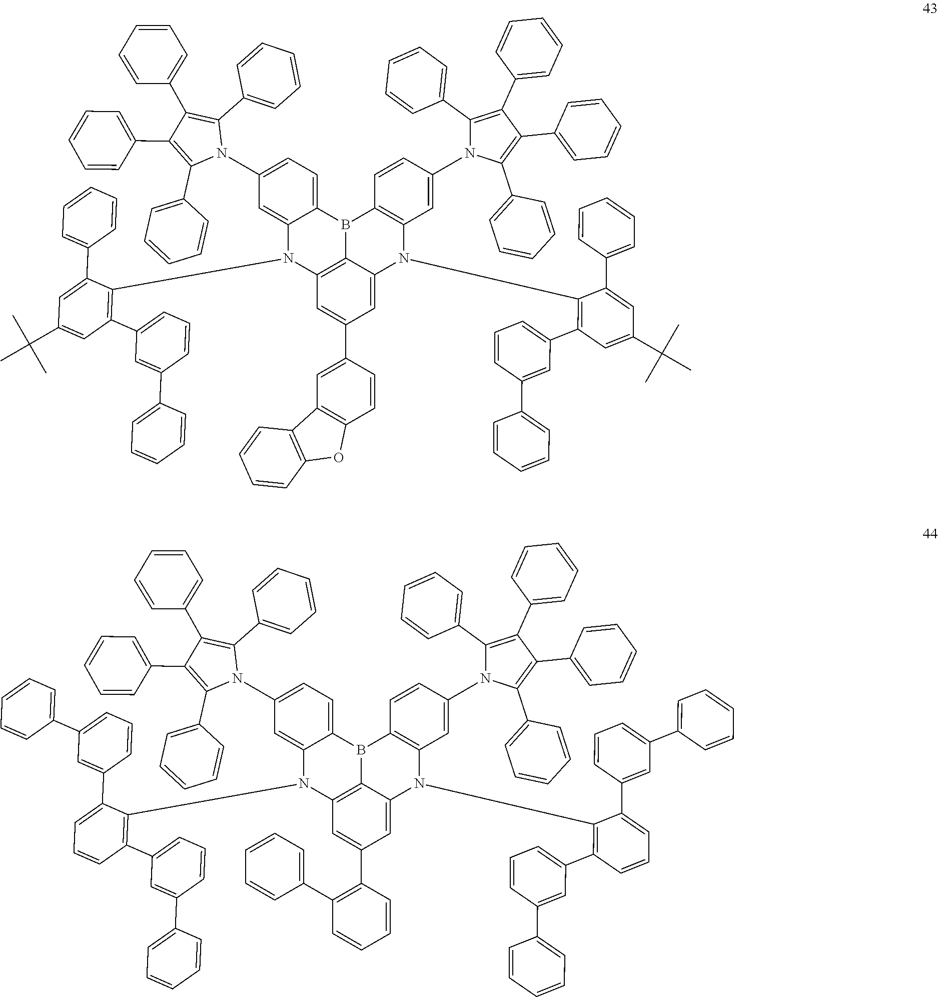 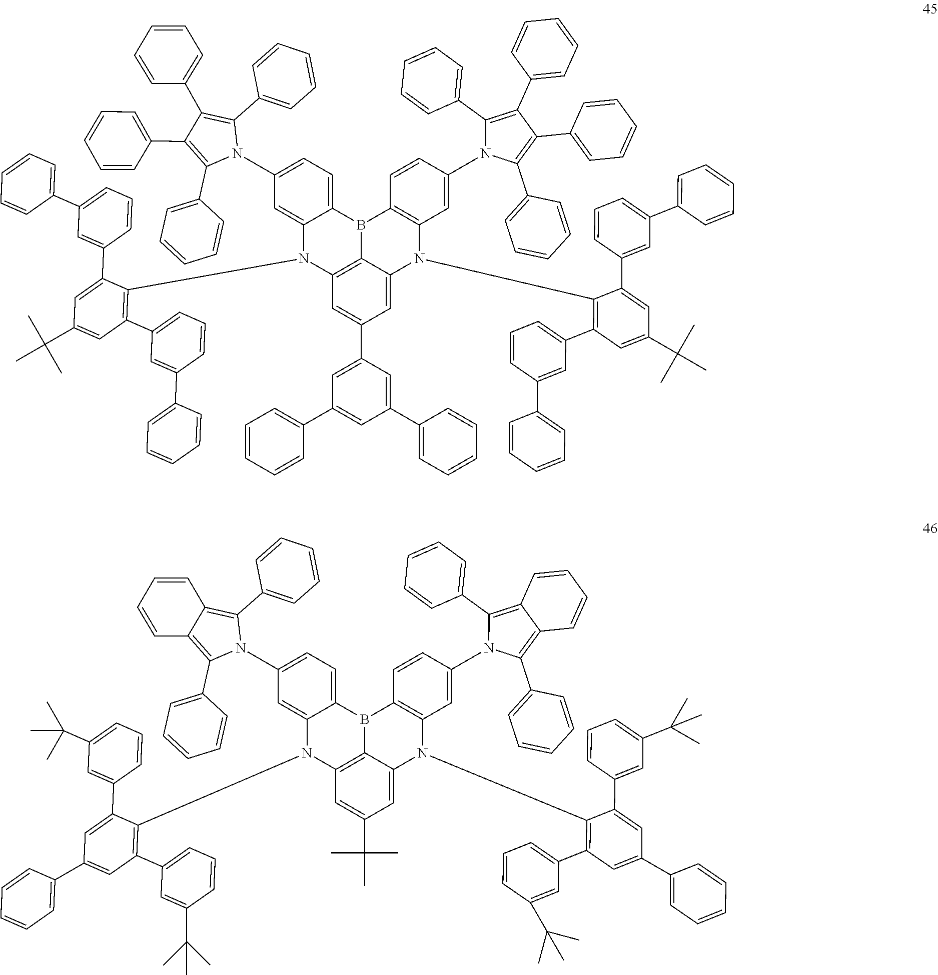 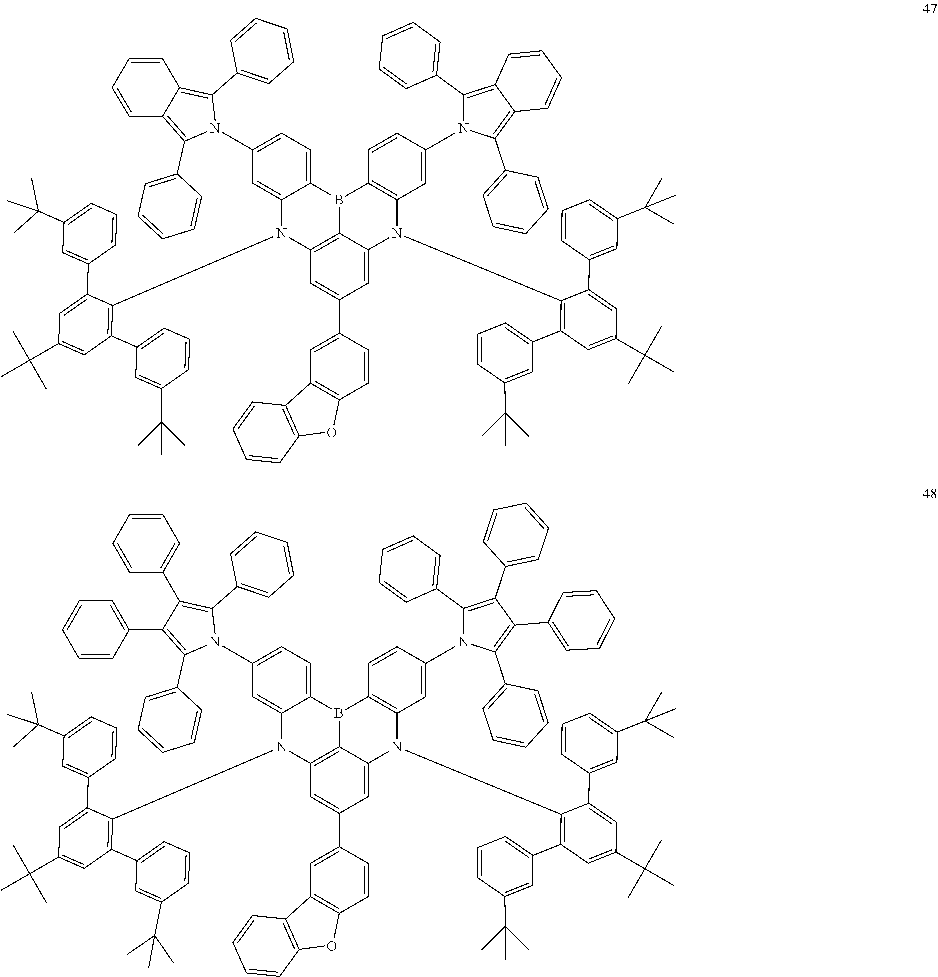 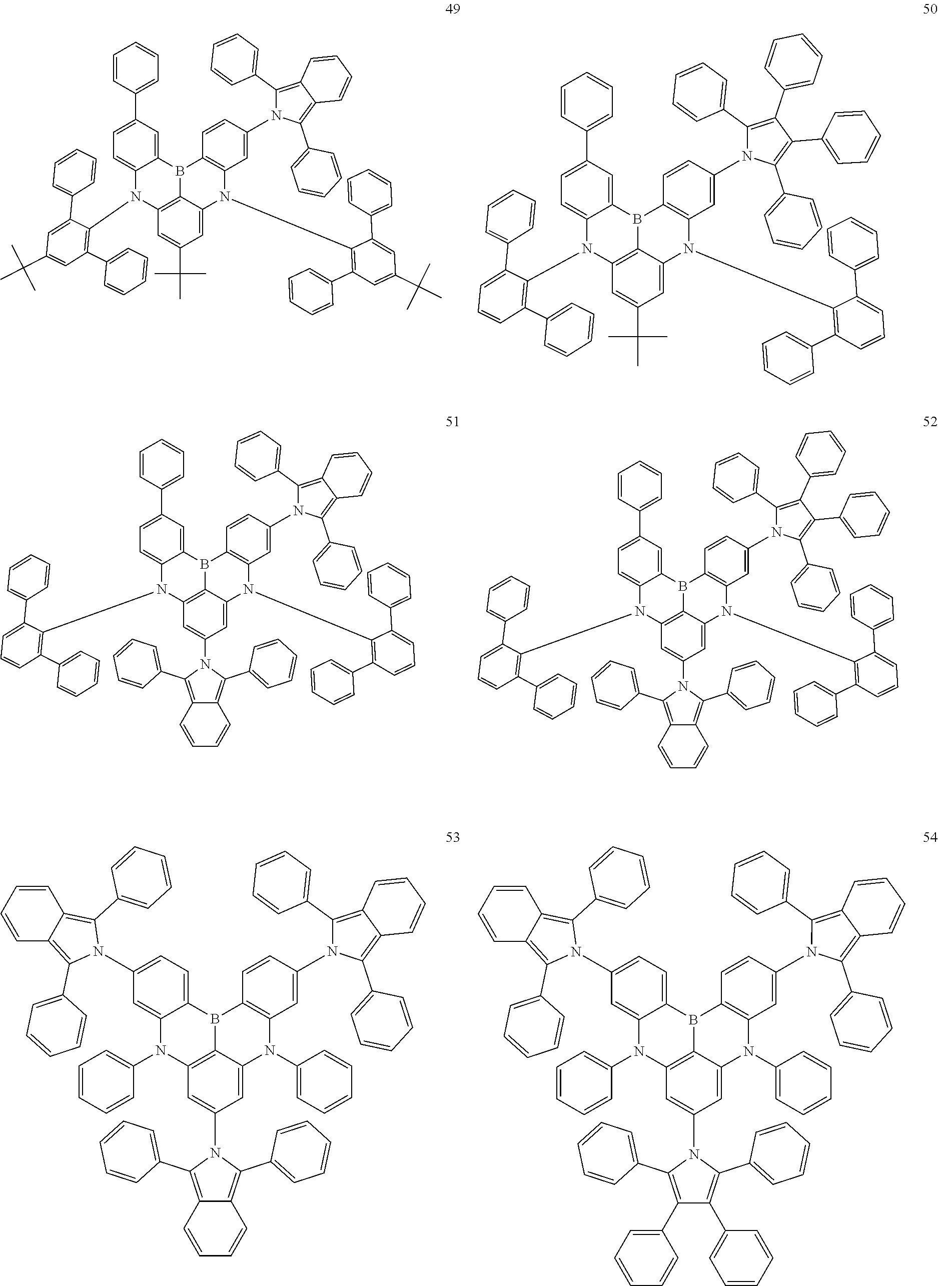 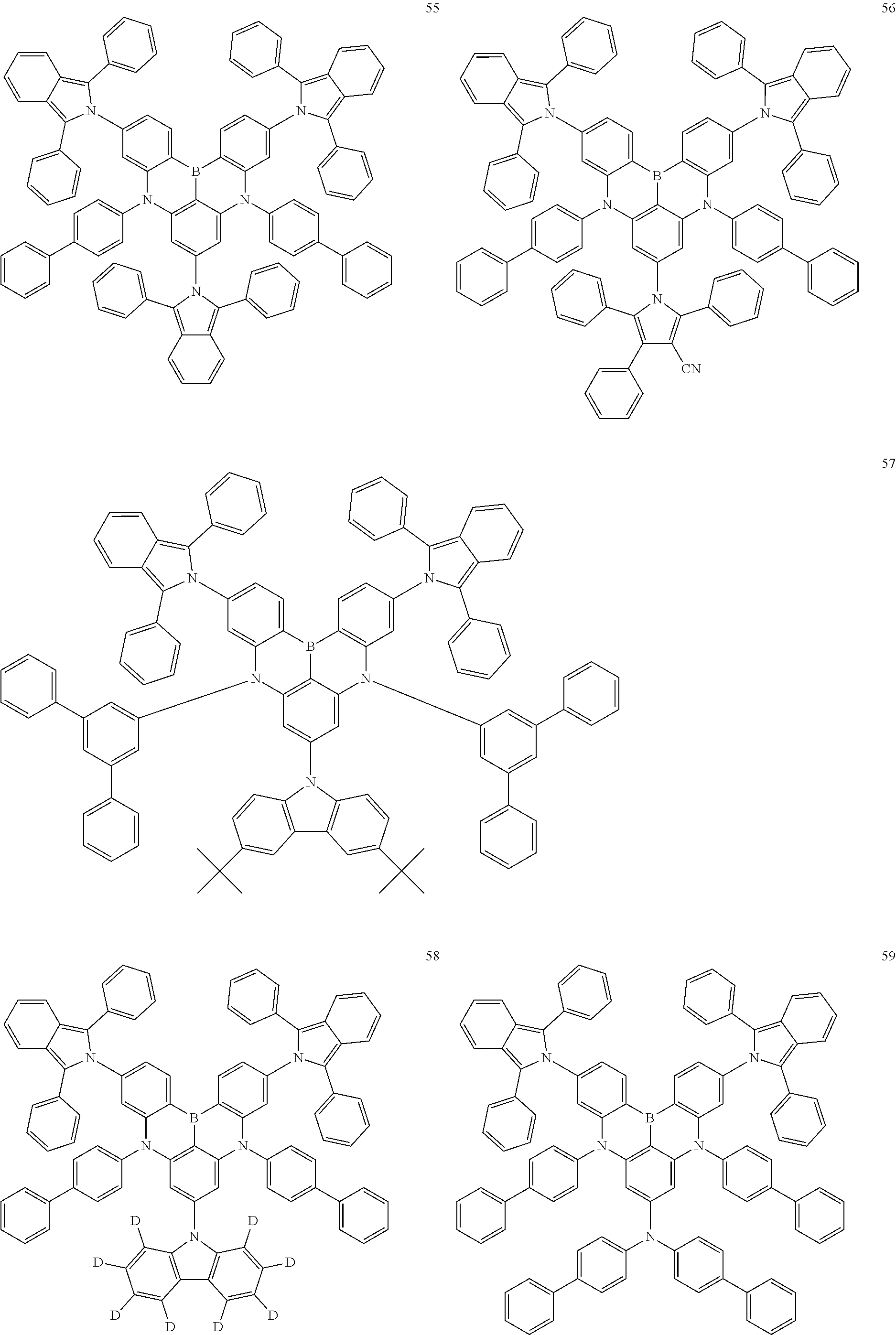 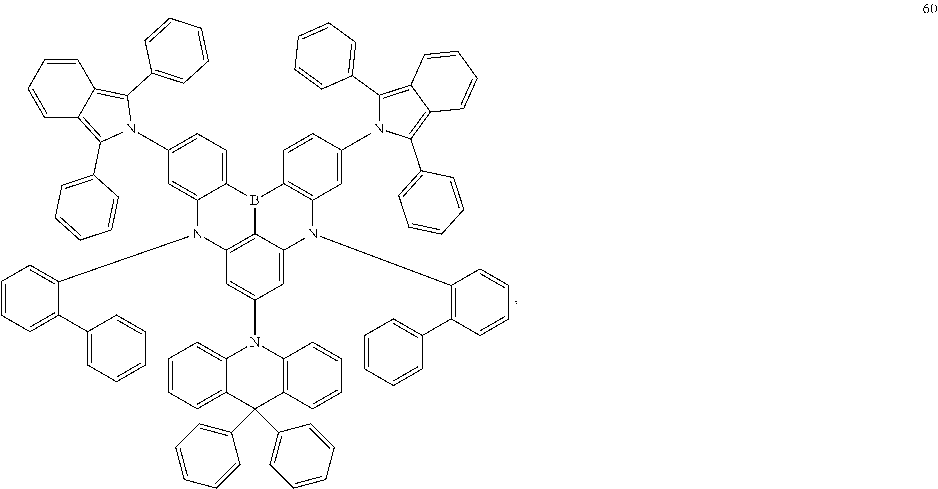 [SMILES: c1ccc(-c2ccccc2N2c3cc(-n4c(-c5ccccc5)c5ccccc5c4-c4ccccc4)ccc3B3c4ccc(-n5c(-c6ccccc6)c6ccccc6c5-c5ccccc5)cc4N(c4ccccc4-c4ccccc4)c4cc(N5c6ccccc6C(c6ccccc6)(c6ccccc6)c6ccccc65)cc2c43)cc1]
and
wherein in Compound Group 1, D is a deuterium atom.
